(19) United States
(12) Patent Application Publication
(10) Pub. No.: US 2026/0314158 A1
(43) Pub. Date: Oct. 8, 2026

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Cuifang Zhang, Beijing (CN); Qi Zhang, Beijing (CN); Han Zhang, Beijing (CN); Zhihong Dai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/631,508

(22) Filed: Mar. 27, 2026

(30) Foreign Application Priority Data
Mar. 31, 2025 (CN) 202510395537.0

(51) Int. Cl. H10K 50/11; C07B 59/00; C07F 5/02; C09K 11/06; H10K 85/30; H10K 85/40; H10K 85/60; H10K 101/00

(52) U.S. Cl. CPC H10K 50/11; C07B 59/002; C07F 5/027; C09K 11/06; H10K 85/342; H10K 85/40; H10K 85/622; H10K 85/626; H10K 85/633; H10K 85/636; H10K 85/654; H10K 85/656; H10K 85/6572; H10K 85/6574; H10K 85/6576; H10K 85/658; C07B 2200/05; C09K 2211/185; H10K 2101/90

(57) ABSTRACT

Provided are an organic electroluminescent material and a device thereof. The organic electroluminescent material is a compound having a structure represented by Formula 1, and particularly, Formula 1 includes a specific substituent. These new compounds can be used as light-emitting materials for organic electroluminescent devices, achieve orange to red light emission, possess a strong hole trapping capability, and have potential for application as excellent light-emitting materials. Further provided are an organic electroluminescent device including the compound and a compound composition including the compound.

### CROSS-REFERENCE TO RELATED APPLICATION(S)

This application claims priority to Chinese Patent Application No. 202510395537.0 filed Mar. 31, 2025, the disclosure of which is incorporated herein by reference in its entirety.

### TECHNICAL FIELD

The present disclosure relates to compounds for organic electronic devices such as organic light-emitting devices. In particular, the present disclosure relates to a compound having a structure of Formula 1, an organic electroluminescent device including the compound and a compound composition including the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid-state device, it offers tremendous potential for display and lighting applications. In addition, the inherent properties of organic materials, such as their flexibility, may make them well suited for particular applications such as fabrication on flexible substrates.

The OLED can be categorized into three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal-containing complexes as the emitter. As a result, both singlets and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have a small singlet-triplet gap that makes the transition from triplet back to singlet possible. In the TADF device, the triplet excitons can go through reverse intersystem crossing to generate singlet excitons, resulting in high IQE.

OLEDs can also be classified as small-molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation (VTE method). Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve the desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting colors, higher efficiency, and longer device lifetime.

WO2020080528A1 discloses a polycyclic compound having the following general formula:

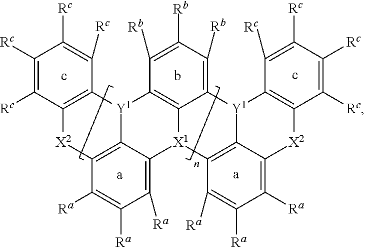

and also specifically discloses compounds such as

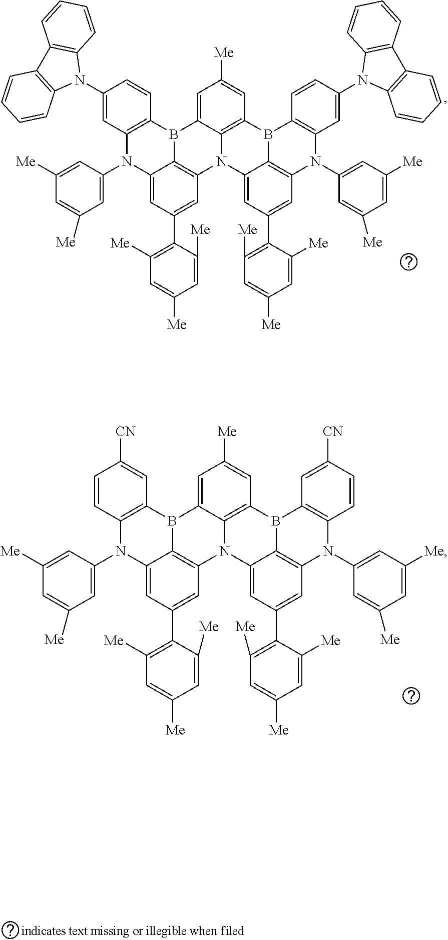 [SMILES: Cc1cc(C)cc(N2c3cc(-n4c5ccccc5c5ccccc54)ccc3B3c4cc(C)cc5c4N(c4cc(-c6c(C)cc(C)cc6C)cc2c43)c2cc(-c3c(C)cc(C)cc3C)cc3c2B5c2ccc(-n4c5ccccc5c5ccccc54)cc2N3c2cc(C)cc(C)c2)c1 ; Cc1cc(C)cc(N2c3ccc(C#N)cc3B3c4cc(C)cc5c4N(c4cc(-c6c(C)cc(C)cc6C)cc2c43)c2cc(-c3c(C)cc(C)cc3C)cc3c2B5c2cc(C#N)ccc2N3c2cc(C)cc(C)c2)c1]

etc. However, this disclosure does not disclose or teach a polycyclic compound that has a cyano group and also has any one of a carbazolyl group, fluorine or an alkylsilyl group, nor does it discover the unique advantages thereof; CN110225917A discloses a compound of the following general formula:

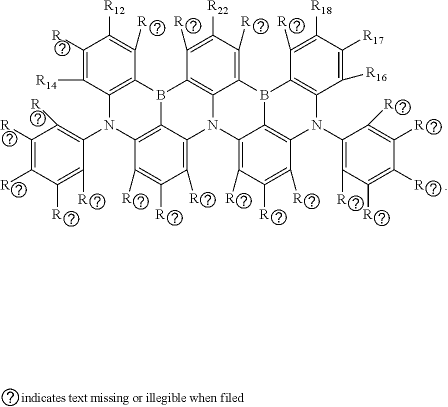

However, this disclosure does not disclose a compound having such a skeleton, particularly a compound having a cyano group and any one of a carbazolyl group, fluorine or an alkylsilyl group simultaneously on the polycyclic skeleton, nor does it discover the unique advantages possessed by such compounds with specific substituents.

### SUMMARY

The present disclosure aims to provide a series of compounds each having a structure of Formula 1 to solve at least part of the aforementioned problems. These compounds can achieve emission covering the spectrum from orange to red light and have a strong hole or electron trapping capability. These new compounds have excellent properties and potential application prospects of becoming excellent light-emitting materials.

According to an embodiment of the present disclosure, a compound is disclosed, the compound has a structure represented by Formula 1:

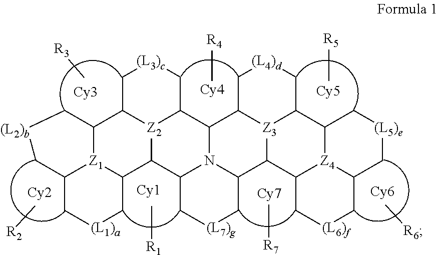

wherein the ring Cy1, the ring Cy2, the ring Cy3, the ring Cy4, the ring Cy5, the ring Cy6 and the ring Cy7 are, at each occurrence identically or differently, selected from an unsaturated carbocyclic ring having 5 to 30 carbon atoms or an unsaturated heterocyclic ring having 3 to 30 carbon atoms;
Z₁, Z₂, Z₃ and Z₄ are, at each occurrence identically or differently, selected from B, N, P, P═O, P═S, As, As═O, As═S, SiR or GeR;
L₁, L₂, L₃, L₄, L₅, L₆ and L₇ are, at each occurrence identically or differently, selected from a single bond, O, S, Se, BR′, NR′, PR′, P—OR′, P═SR′, AsR′, As—OR′, As═SR′, CR′R′, SiR′R′ or GeR′R′; and in a case where a plurality of R′ are present at the same time, the plurality of R′ are identical or different;
a, b, c, d, e, f and g are each independently selected from 0, 1 or 2;
R₁, R₂, R₃, R₄, R₅, R₆ and R₇ represent, at each occurrence identically or differently, mono-substitution, multiple substitutions or non-substitution; at least one of R₁ to R₇ is a cyano group, and at least one of R₁ to R₇ is, at each occurrence identically or differently, selected from the group consisting of: substituted or unsubstituted alkylsilyl having 3 to 20 carbon atoms, fluorine, substituted or unsubstituted carbazolyl having 3 to 20 carbon atoms and combinations thereof;
R, R′, R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and adjacent substituents R′, R″, R₁, R₂, R₃, R₄, R₅, R₆ and R₇ can be optionally joined to form a ring.

According to another embodiment of the present disclosure, an organic electroluminescent device is further disclosed, the organic electroluminescent device includes an anode, a cathode and an organic layer disposed between the anode and the cathode, wherein the organic layer includes a compound, and the specific structure of the compound is as shown in the preceding embodiment.

According to another embodiment of the present disclosure, a compound composition is further disclosed, the compound composition includes a compound having a structure of Formula 1, and the specific structure of the compound is as shown in the preceding embodiment.

The compounds each having a structure of Formula 1 disclosed in the present disclosure can achieve emission covering the spectrum from orange to red light and have a strong hole or electron trapping capability. These compounds have excellent properties and potential application prospects of becoming excellent light-emitting materials.

### BRIEF DESCRIPTION OF DRAWINGS

FIG. 1 is a schematic diagram of an organic light-emitting apparatus that may include a compound and a compound composition disclosed herein.

FIG. 2 is a schematic diagram of another organic light-emitting apparatus that may include a compound and a compound composition disclosed herein.

### DETAILED DESCRIPTION

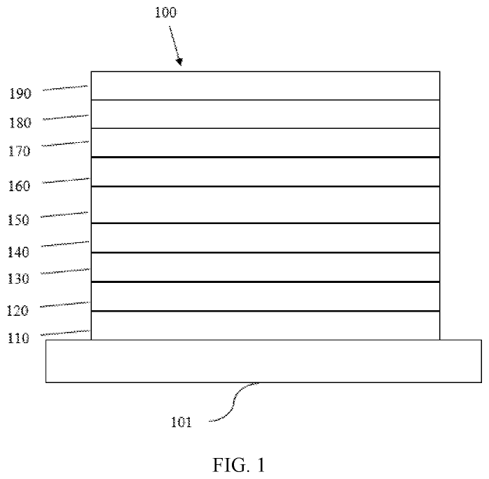

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or some layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve the desired emission spectrum.

In one embodiment, an OLED may be described as having an “organic layer” disposed between a cathode and an anode. This organic layer may include a single layer or multiple layers.

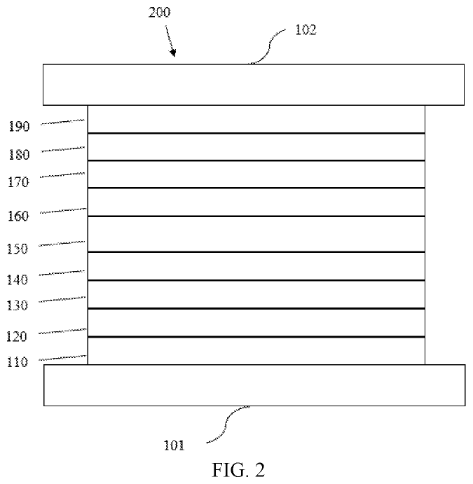

An OLED can be encapsulated by a barrier layer. FIG. 2 schematically shows an organic light-emitting device 200 without limitation. FIG. 2 differs from FIG. 1 in that the organic light emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as the temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal-containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in a small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the are and above, preferred cyclopentyl, cyclohexyl, 4-methylcyclohexyl, 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, and diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc., means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g., phenyl, phenylene, naphthyl, dibenzofuryl) or as if it were the whole molecule (e.g., benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to their enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), which means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined. For example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

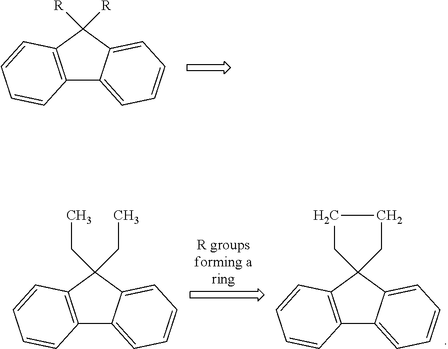

The expression that adjacent substituents can be optionally joined to form a ring is also intended to mean that two substituents bonded to carbon atoms which are directly bonded to each other are joined to each other via a chemical bond to form a ring, which can be exemplified by the following formula:

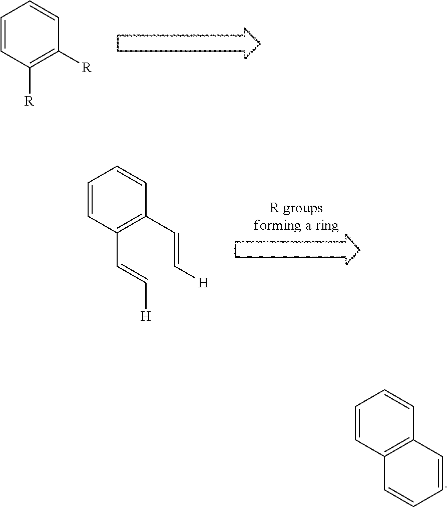

The expression that adjacent substituents can be optionally joined to form a ring is also intended to mean that two substituents bonded to further distant carbon atoms are joined to each other via a chemical bond to form a ring, which can be exemplified by the following formula:

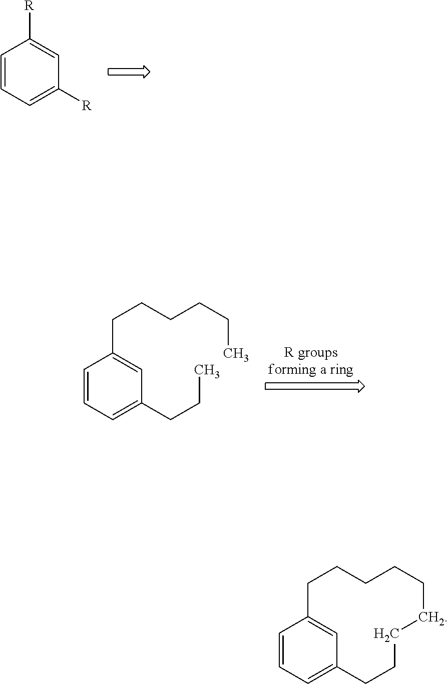

Furthermore, the expression that adjacent substituents can be optionally joined to form a ring is also intended to mean that, in the case where one of the two substituents bonded to carbon atoms represents hydrogen, the second substituent is bonded at a position at which the hydrogen atom is bonded, thereby forming a ring. This is exemplified by the following formula:

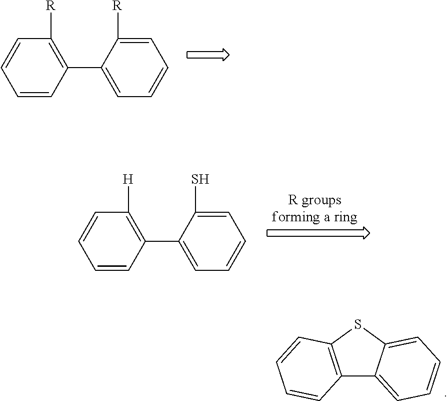

According to an embodiment of the present disclosure, a compound is disclosed, the compound has a structure represented by Formula 1:

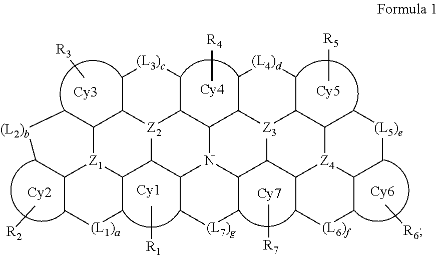

wherein the ring Cy1, the ring Cy2, the ring Cy3, the ring Cy4, the ring Cy5, the ring Cy6 and the ring Cy7 are, at each occurrence identically or differently, selected from an unsaturated carbocyclic ring having 5 to 30 carbon atoms or an unsaturated heterocyclic ring having 3 to 30 carbon atoms;
Z₁, Z₂, Z₃ and Z₄ are, at each occurrence identically or differently, selected from B, N, P, P═O, P═S, As, As═O, As═S, SiR or GeR;
L₁, L₂, L₃, L₄, L₅, L₆ and L₇ are, at each occurrence identically or differently, selected from a single bond, O, S, Se, BR′, NR′, PR′, P═OR′, P═SR′, AsR′, As═OR′, As═SR′, CR′R′, SiR′R′ or GeR′R′; and in a case where a plurality of R′ are present at the same time, the plurality of R′ are identical or different;
a, b, c, d, e, f and g are each independently selected from 0, 1 or 2;
R₁, R₂, R₃, R₄, R₅, R₆ and R₇ represent, at each occurrence identically or differently, mono-substitution, multiple substitutions or non-substitution; at least one of R₁ to R₇ is a cyano group, and at least one of R₁ to R₇ is, at each occurrence identically or differently, selected from the group consisting of: substituted or unsubstituted alkylsilyl having 3 to 20 carbon atoms, fluorine, substituted or unsubstituted carbazolyl having 3 to 20 carbon atoms and combinations thereof;
R, R′, R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, R″, R₁, R₂, R₃, R₄, R₅, R₆ and R₇ can be optionally joined to form a ring.

Herein, obviously, at least two of R₁ to R₇ are present, and a plurality of substituents may be identical or different. For example, there may be a plurality of R₁, or there may be a case where one R₃ and one R₅ are present, or one R₂ and one R₆ are present. Among at least two of R₁ to R₇, one must be a cyano group, and the other is selected from substituted or unsubstituted alkylsilyl having 3 to 20 carbon atoms, fluorine or substituted or unsubstituted carbazolyl having 3 to 20 carbon atoms.

Herein, the expression that adjacent substituents R′, R″, R₁, R₂, R₃, R₄, R₅, R₆ and R₇ can be optionally joined to form a ring is intended to mean that any one or more of groups of adjacent substituents, such as two substituents R′, two substituents R″, two substituents R₁, two substituents R₂, two substituents R₃, two substituents R₄, two substituents R₅, two substituents R₆, two substituents R₇, adjacent substituents R₁ and R₂, adjacent substituents R₁ and R₇, adjacent substituents R₃ and R₄, adjacent substituents R₄ and R₅, and adjacent substituents R₆ and R₇, can be joined to form a ring. Obviously, it is also possible that none of these substituents are joined to form a ring.

According to an embodiment of the present disclosure, wherein the ring Cy1, the ring Cy2, the ring Cy3, the ring Cy4, the ring Cy5, the ring Cy6 and the ring Cy7 are, at each occurrence identically or differently, selected from a five-membered unsaturated carbocyclic ring, an aromatic ring having 6 to 18 carbon atoms, a heteroaromatic ring having 3 to 18 carbon atoms, or a combination thereof.

According to an embodiment of the present disclosure, wherein the ring Cy1, the ring Cy2, the ring Cy3, the ring Cy4, the ring Cy5, the ring Cy6 and the ring Cy7 are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

According to an embodiment of the present disclosure, the compound has a structure represented by any one of Formula 1-1 to Formula 1-4:

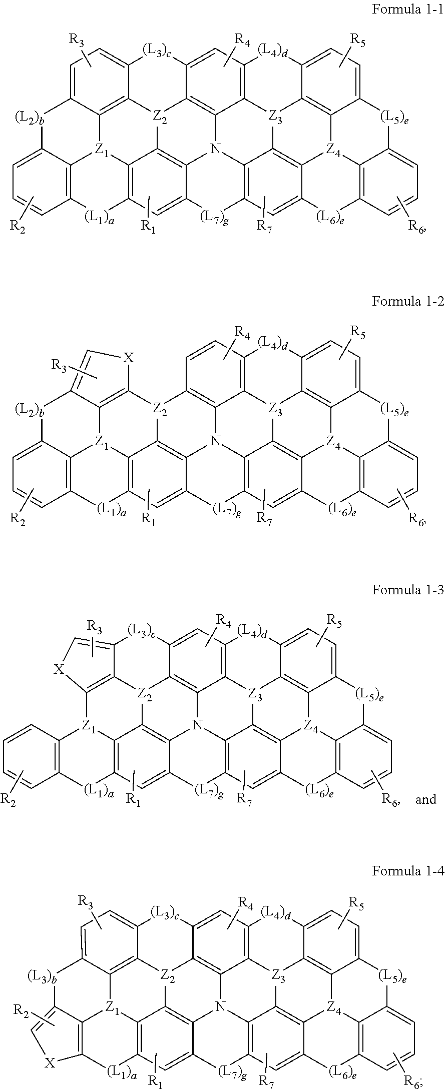

wherein Z₁, Z₂, Z₃ and Z₄ are, at each occurrence identically or differently, selected from B, N, P, P═O, P═S, As, As═O, As═S, SiR or GeR;
X is, at each occurrence identically or differently, selected from O, S, Se or NRₓ;
L₁, L₂, L₃, L₄, L₅, L₆ and L₇ are, at each occurrence identically or differently, selected from a single bond, O, S, Se, BR′, NR′, PR′, P═OR′, P═SR′, AsR′, As═OR′, As═SR′, CR′R′, SiR′R′ or GeR′R′; and in a case where two R′ are present at the same time, the two R′ are identical or different;
a, b, c, d, e, f and g are each independently selected from 0, 1 or 2;
R₁, R₂, R₃, R₄, R₅, R₆ and R₇ represent, at each occurrence identically or differently, mono-substitution, multiple substitutions or non-substitution; in Formula 1-1 to Formula 1-4, at least one of R₁ to R₇ is a cyano group, and at least one of R₁ to R₇ is selected from the group consisting of: substituted or unsubstituted alkylsilyl having 3 to 20 carbon atoms, fluorine, substituted or unsubstituted carbazolyl having 3 to 20 carbon atoms and combinations thereof;
R, R′, Rₓ, R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;

R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, Rₓ, R₁, R₂, R₃, R₄, R₅, R₆ and R₇ can be optionally joined to form a ring.

Herein, the expression that adjacent substituents R′, Rₓ, R₁, R₂, R₃, R₄, R₅, R₆ and R₇ can be optionally joined to form a ring is intended to mean that any one or more of groups of adjacent substituents, such as two substituents R′, two substituents Rₓ, two substituents R₁, two substituents R₂, two substituents R₃, two substituents R₄, two substituents R₅, two substituents R₆, two substituents R₇, adjacent substituents R₁ and R₂, adjacent substituents R₁ and R₇, adjacent substituents R₃ and R₄, adjacent substituents R₄ and R₅, adjacent substituents R₆ and R₇, adjacent substituents R′ and R₁ to R₇, and adjacent substituents Rₓ and R₁ to R₇, can be joined to form a ring. Obviously, it is also possible that none of these substituents are joined to form a ring.

According to an embodiment of the present disclosure, the compound has a structure represented by Formula 1-1.

According to an embodiment of the present disclosure, wherein L₁, L₂, L₃, L₄, L₅, L₆ and L₇ are, at each occurrence identically or differently, selected from a single bond, O, S, Se, BR′, NR′, POR′, CR′R′ or SiR′R′; and R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein L₁, L₂, L₃, L₄, L₅, L₆ and L₇ are, at each occurrence identically or differently, selected from a single bond, O, S, NR′ or CR′R′; and R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein Z₁, Z₂, Z₃ and Z₄ are, at each occurrence identically or differently, selected from B, N, P, P═O or P═S, and at least one of Z₁, Z₂, Z₃ and Z₄ is, at each occurrence identically or differently, selected from B, P, P═O or P═S.

According to an embodiment of the present disclosure, wherein Z₁, Z₂, Z₃ and Z₄ are, at each occurrence identically or differently, selected from B, N or P═O, and at least two of Z₁, Z₂, Z₃ and Z₄ are, at each occurrence identically or differently, selected from B or P═O.

According to an embodiment of the present disclosure, wherein Z₁ and Z₄ are N, and Z₂ and Z₃ are B.

According to an embodiment of the present disclosure, wherein R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms; and adjacent substituents R₁, R₂, R₃, R₄, R₅, R₆ and R₇ can be optionally joined to form a ring.

According to an embodiment of the present disclosure, wherein R₁, R₂, R₃, R₄, R₅, R₆ and R₇ are, at each occurrence identically or differently, selected from the group consisting of: hydrogen, deuterium, halogen, substituted or unsubstituted alkyl having 1 to 12 carbon atoms, substituted or unsubstituted cycloalkyl having 3 to 12 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 20 carbon atoms, substituted or unsubstituted amino having 0 to 20 carbon atoms, a cyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms; and adjacent substituents R₁, R₂, R₃, R₄, R₅, R₆ and R₇ can be optionally joined to form a ring.

According to an embodiment of the present disclosure, at least one of R₁ to R₇ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group and combinations thereof, at least one of R₁ to R₇ is a cyano group, and at least one of remaining R₁ to R₇ is selected from the group consisting of: substituted or unsubstituted alkylsilyl having 3 to 20 carbon atoms, fluorine and substituted or unsubstituted carbazolyl having 3 to 20 carbon atoms.

According to an embodiment of the present disclosure, at least one of R₁ to R₇ is, at each occurrence identically or differently, selected from the group consisting of: deuterium, halogen, substituted or unsubstituted alkyl having 1 to 12 carbon atoms, substituted or unsubstituted cycloalkyl having 3 to 12 ring carbon atoms, substituted or unsubstituted aryl having 6 to 12 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, a cyano group and combinations thereof, at least one of R₁ to R₇ is a cyano group, and at least one of remaining R₁ to R₇ is selected from the group consisting of: substituted or unsubstituted alkylsilyl having 3 to 20 carbon atoms, fluorine and substituted or unsubstituted carbazolyl having 3 to 20 carbon atoms.

According to an embodiment of the present disclosure, at least one of R₁ to R₇ is, at each occurrence identically or differently, selected from the group consisting of: deuterium, fluorine, methyl, ethyl, n-propyl, isopropyl, cyclopropyl, n-butyl, isobutyl, t-butyl, cyclopentyl, neopentyl, cyclohexyl, phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl and combinations thereof, at least one of R₁ to R₇ is a cyano group, and at least one of remaining R₁ to R₇ is selected from the group consisting of: substituted or unsubstituted alkylsilyl having 3 to 20 carbon atoms, fluorine and substituted or unsubstituted carbazolyl having 3 to 20 carbon atoms.

According to an embodiment of the present disclosure, at least one of R₁ to R₇ is a cyano group, and at least one of the remaining R₁ to R₇ is selected from substituted or unsubstituted alkylsilyl having 3 to 20 carbon atoms.

According to an embodiment of the present disclosure, at least one of R₁ to R₇ is a cyano group, and at least one of the remaining R₁ to R₇ is fluorine.

According to an embodiment of the present disclosure, at least one of R₁ to R₇ is a cyano group, and at least one of the remaining R₁ to R₇ is substituted or unsubstituted carbazolyl having 3 to 20 carbon atoms.

According to an embodiment of the present disclosure, at least two of R₁ to R₇ are cyano groups, and at least one of the remaining R₁ to R₇ is selected from substituted or unsubstituted alkylsilyl having 3 to 20 carbon atoms.

According to an embodiment of the present disclosure, at least two of R₁ to R₇ are cyano groups, and at least one of the remaining R₁ to R₇ is fluorine.

According to an embodiment of the present disclosure, at least two of R₁ to R₇ are cyano groups, and at least one of the remaining R₁ to R₇ is selected from substituted or unsubstituted carbazolyl having 3 to 20 carbon atoms.

According to an embodiment of the present disclosure, at least one of R₃ and R₅ is a cyano group.

According to an embodiment of the present disclosure, at least two of R₃ and R₅ are cyano groups.

According to an embodiment of the present disclosure, at least one of R₁, R₂, R₄, R₆ and R₇ is selected from the group consisting of: substituted or unsubstituted alkylsilyl having 3 to 20 carbon atoms, substituted or unsubstituted carbazolyl having 3 to 20 carbon atoms and fluorine.

According to an embodiment of the present disclosure, at least one of R₂, R₄ and R₆ is selected from the group consisting of: substituted or unsubstituted alkylsilyl having 3 to 20 carbon atoms, substituted or unsubstituted carbazolyl having 3 to 20 carbon atoms and fluorine.

According to an embodiment of the present disclosure, at least one of R₂, R₄ and R₆ is selected from substituted or unsubstituted alkylsilyl having 3 to 20 carbon atoms.

According to an embodiment of the present disclosure, at least two of R₂, R₄ and R₆ are selected from substituted or unsubstituted alkylsilyl having 3 to 20 carbon atoms.

According to an embodiment of the present disclosure, at least one of R₁, R₄ and R₇ is fluorine.

According to an embodiment of the present disclosure, at least two of R₁, R₄ and R₇ are fluorine.

According to an embodiment of the present disclosure, at least one of R₂, R₃, R₄, R₅ and R₆ is selected from substituted or unsubstituted carbazolyl having 3 to 20 carbon atoms.

According to an embodiment of the present disclosure, the compound is selected from the group consisting of Compound BN-1-1-k₁ to Compound BN-1-22-k₁, wherein the specific structures of Compound BN-1-1-k₁ to Compound BN-1-22-k₁ are referred to claim 11.

According to an embodiment of the present disclosure, wherein hydrogens in Compound BN-1-1-k₁ to Compound BN-1-22-k₁ can be partially or fully substituted with deuterium.

According to an embodiment of the present disclosure, an organic electroluminescent device is disclosed. The organic electroluminescent device includes an anode, a cathode and an organic layer disposed between the anode and the cathode, wherein the organic layer includes a compound of Formula 1, and the specific structure of the compound is as shown in any one of the preceding embodiments.

According to an embodiment of the present disclosure, wherein the organic layer is a light-emitting layer, and the compound is a light-emitting material.

According to an embodiment of the present disclosure, wherein the organic electroluminescent device emits red light or white light.

According to an embodiment of the present disclosure, wherein the light-emitting layer at least includes a first host material.

According to an embodiment of the present disclosure, wherein the light-emitting layer at least includes a first host material and a second host material.

According to an embodiment of the present disclosure, wherein the first host material has a structure represented by Formula PH-1, Formula PH-2 or Formula PH-3:

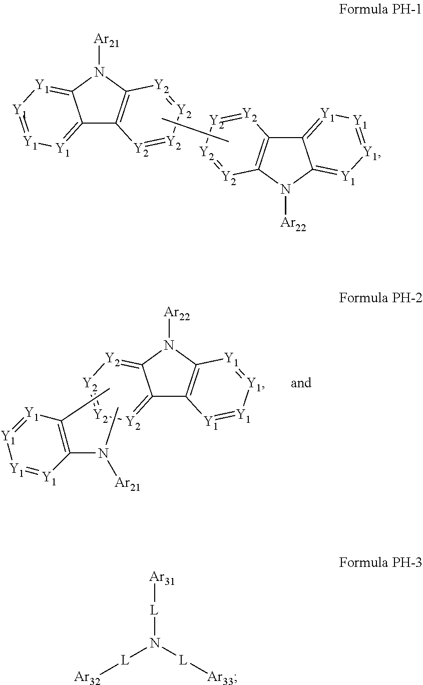

wherein Y₁ is, at each occurrence identically or differently, selected from CR_{y} or N;
Y₂ is, at each occurrence identically or differently, selected from C, CR_{y} or N;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar₂₁, Ar₂₂, Ar₃₁, Ar₃₂ and Ar₃₃ are, at each occurrence identically or differently, selected from substituted or unsubstituted aryl having 6 to 30 carbon atoms or substituted or unsubstituted heteroaryl having 3 to 30 carbon atoms;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{y} can be optionally joined to form a ring.

Herein, the expression that adjacent substituents R_{y} can be optionally joined to form a ring is intended to mean that a group of adjacent substituents, such as adjacent substituents R_{y}, can be joined to form a ring. Obviously, it is also possible that none of these substituents are joined to form a ring.

According to an embodiment of the present disclosure, the first host material is selected from the group consisting of Compound 1-1-1 to Compound 1-1-104, Compound 1-2-1 to Compound 1-2-100 and Compound 1-3-1 to Compound 1-3-110, wherein the specific structures of Compound 1-1-1 to Compound 1-1-104, Compound 1-2-1 to Compound 1-2-100 and Compound 1-3-1 to Compound 1-3-110 are referred to claim 14.

According to an embodiment of the present disclosure, wherein hydrogens in Compound 1-1-1 to Compound 1-1-104, Compound 1-2-1 to Compound 1-2-100 and Compound 1-3-1 to Compound 1-3-110 can be partially or fully substituted with deuterium.

According to an embodiment of the present disclosure, wherein the second host material has a structure represented by Formula NH-1:

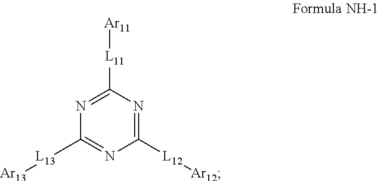

wherein L₁₁ to L₁₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof; and
Ar₁₁ to Ar₁₃ are, at each occurrence identically or differently, selected from substituted or unsubstituted aryl having 6 to 30 carbon atoms, substituted or unsubstituted heteroaryl having 3 to 30 carbon atoms, or a combination thereof.

According to an embodiment of the present disclosure, the second host material is selected from the group consisting of Compound B-1 to Compound B-243, wherein the specific structures of Compound B-1 to Compound B-243 are referred to claim 14.

According to an embodiment of the present disclosure, wherein hydrogens in Compound B-1 to Compound B-243 can be partially or fully substituted with deuterium.

According to an embodiment of the present disclosure, wherein the light-emitting layer includes at least one metal complex.

According to an embodiment of the present disclosure, wherein the metal complex is a phosphorescent sensitizer.

According to an embodiment of the present disclosure, wherein the metal complex has a general formula of M(Lₐ)ₘ(L_{b})ₙ(L_{c});
wherein M is selected from a metal with a relative atomic mass greater than 40;
Lₐ, L_{b} and L_{c} are a first ligand, a second ligand and a third ligand coordinated to M, respectively, wherein Lₐ, L_{b} and L_{c} can be optionally joined to form a multidentate ligand;
Lₐ, L_{b} and L_{c} are identical or different; m is 1, 2 or 3; n is 0, 1 or 2; q is 0, 1 or 2; the sum of m, n and q is equal to an oxidation state of M; when m is greater than or equal to 2, a plurality of Lₐ are identical or different; when n is 2, two L_{b} are identical or different; and when q is 2, two L_{c} are identical or different;
Lₐ is, at each occurrence identically or differently, selected from a structure represented by Formula 2:

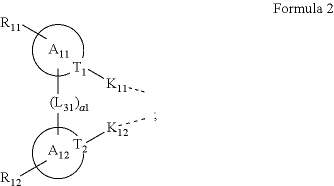

wherein
the ring A₁₁ and the ring A₁₂ are selected from an aromatic ring having 6 to 30 ring atoms, a heteroaromatic ring having 5 to 30 ring atoms, or a combination thereof;
T₁ and T₂ are, at each occurrence identically or differently, selected from C or N;
K₁₁ and K₁₂ are, at each occurrence identically or differently, selected from a single bond, O, S or NRₖ;
L₃₁ is, at each occurrence identically or differently, selected from the group consisting of: a single bond, BR_{L11}, CR_{L11}R_{L11}, NR_{L11}, O, SiR_{L11}R_{L11}, PR_{L11}, S, GeR_{L11}R_{L11}, Se, substituted or unsubstituted vinylene, ethynylene, substituted or unsubstituted arylene having 6 to 30 carbon atoms, substituted or unsubstituted heteroarylene having 3 to 30 carbon atoms and combinations thereof, when two R_{L11} are present at the same time, the two R_{L11} are identical or different;
a₁ is selected from 0 or 1;
R₁₁ and R₁₂ represent, at each occurrence identically or differently, mono-substitution, multiple substitutions or non-substitution;
R_{L11}, R₁₁, R₁₂ and Rₖ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{L11}, R₁₁ and R₁₂ can be optionally joined to form a ring; and
L_{b} and Le are, at each occurrence identically or differently, selected from any one of the following structures:

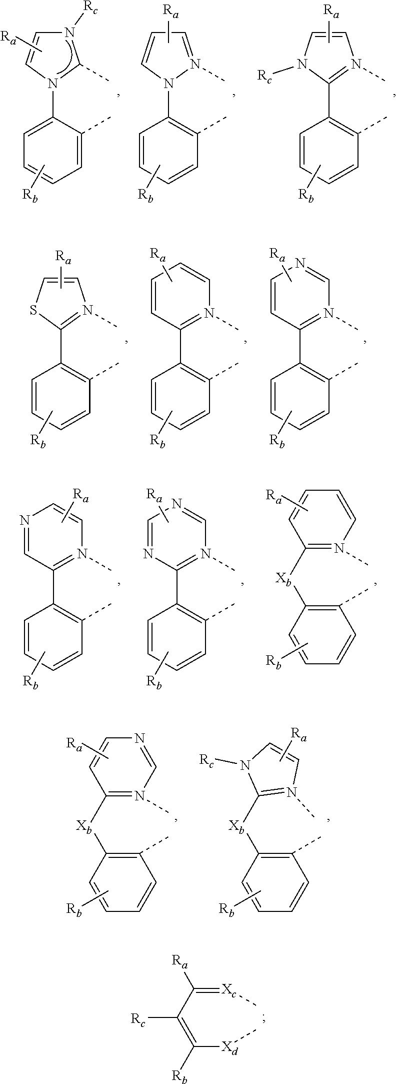

wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of O, S, Se and NR_{N2};

Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

Herein, the expression that adjacent substituents R_{L11}, R₁₁ and R₁₂ can be optionally joined to form a ring is intended to mean that in the presence of substituents R_{L11}, R₁₁ and R₁₂, any one or more of groups of adjacent substituents, such as adjacent substituents R_{L11}, adjacent substituents R₁₁, adjacent substituents R₁₂, adjacent substituents R_{L11} and R₁₁, adjacent substituents R_{L11} and R₁₂, and adjacent substituents R₁₁ and R₁₂, can be joined to form a ring. Obviously, in the presence of substituents R_{L11}, R₁₁ and R₁₂, it is also possible that none of these groups of substituents are joined to form a ring.

Herein, the expression that adjacent substituents Rₐ, R_{b}, R_{c}, R_{N1}, R_{N2}, R_{C1} and R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. Obviously, it is also possible that none of these substituents are joined to form a ring.

According to an embodiment of the present disclosure, the metal complex is selected from the group consisting of Compound RD1 to Compound RD214 and Compound GD1 to Compound GD185, wherein the specific structures of Compound RD1 to Compound RD214 and Compound GD1 to Compound GD185 are referred to claim 15.

According to an embodiment of the present disclosure, hydrogens in the structures of Compound RD1 to Compound RD214 and Compound GD1 to Compound GD185 can be partially or fully substituted with deuterium.

According to another embodiment of the present disclosure, a compound composition is further disclosed. The compound composition includes a compound having a structure of Formula 1, and the specific structure of the compound is as shown in the preceding embodiment.

Combination with Other Materials

The materials described in the present disclosure for a particular layer in an organic light-emitting device can be used in combination with various other materials present in the device. The combinations of these materials are described in more detail in U.S. patent application No. 20160359122 at paragraphs 0132-0161, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, the mixtures and compound compositions disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods, and other related contents, the inherent data of the sample can be obtained with certainty and without influence, so the above related contents are not further described in this patent.

### Material Synthesis Example

The method for preparing the compound of the present disclosure is not limited here, and those skilled in the art can select suitable raw materials and process routes according to synthesis targets. Those skilled in the art may also prepare the compound according to the following example synthesis route.

### Step One:

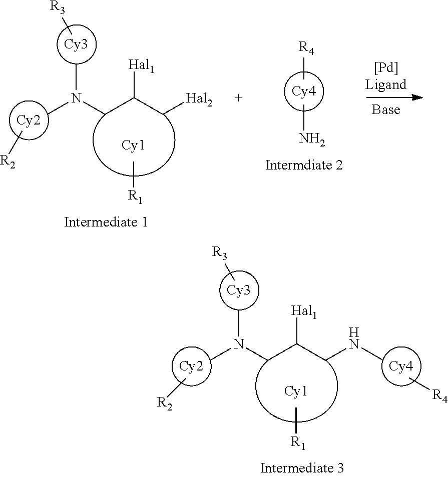

In step one, Intermediate 1 and Intermediate 2 were coupled via a Buchwald reaction to obtain Intermediate 3, wherein Hal₁ was H, Cl, Br, etc., and Hal₂ was Cl, Br, I, OTf, etc. The reaction conditions for the Buchwald reaction are well-known to those skilled in the art. For example, common palladium reagents, such as palladium acetate, Pd₂(dba)₃, etc., were typically used. Phosphine ligands, such as PtBu₃, X-phos, Xantphos, S-phos, DPPF, BINAP, Ruphos, etc., were commonly employed as ligands. Organic or inorganic bases, such as sodium t-butoxide, lithium t-butoxide, potassium t-butoxide, potassium carbonate, sodium carbonate, cesium carbonate, etc., were typically used as bases. Solvents, such as toluene, t-butylbenzene or xylene, which are common organic solvents, were generally used. Generally, the reaction concentration ranged from 0.01 [M] to 0.5 [M], and the reaction temperature ranged from 90° C. to 180° C.

### Step Two:

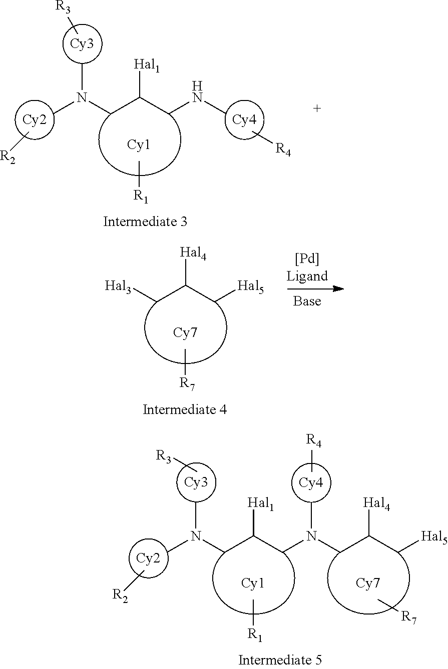

In step two, Intermediate 3 and Intermediate 4 were coupled via a Buchwald reaction to obtain Intermediate 5, wherein Hal₃, Hal₄ and Hal₅ were Br, I, OTf, etc.

### Step Three:

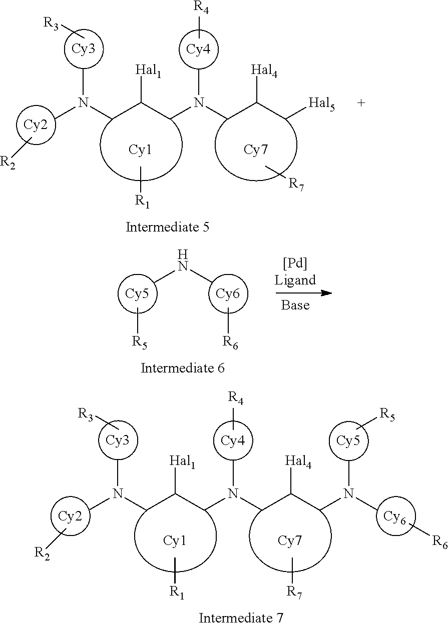

In step three, Intermediate 5 and Intermediate 6 were coupled via a Buchwald reaction to obtain Intermediate 7.

### Step Four:

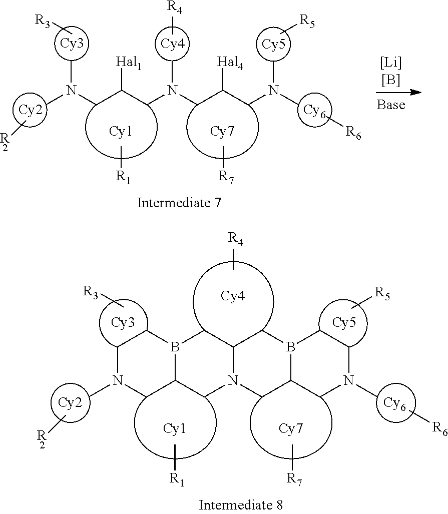

In step four, a metalation reaction was carried out at a specific aryl position of Intermediate 7 by using a metal lithium reagent, a boron reagent was added to carry out lithium-boron transmetalation, and then a Brønsted base was introduced to carry out a tandem bora-Friedel-Crafts reaction to obtain a target compound. To facilitate the reaction, a Lewis acid may also be added.

Wherein the reaction conditions for the metalation reaction and the Friedel-Crafts reaction are well-known to those skilled in the art. For example, the metalation reaction may be carried out directly via dehydrogenation and lithiation at the Hal₁ and Hal₄ positions using metal lithium reagents or may be carried out by performing lithiation through a lithium-halogen exchange reaction. The metal lithium reagents commonly used included alkyl lithium, such as methyl lithium, n-butyllithium, s-butyllithium, t-butyllithium, etc., or lithium diisopropylamide, lithium tetramethylpiperidide, etc. The amount of the metal lithium reagent used was typically 2-5 equivalents. The boron reagent commonly employed included boron trichloride, boron tribromide, etc., and the amount of the boron reagent used was typically 3-6 equivalents. The Brønsted base used was usually an organic base, such as N,N-diisopropylethylamine, triethylamine, 2,2,6,6-tetramethylpiperidine, etc., and the amount of the Brønsted base used was typically 5-10 equivalents. Generally, the reaction concentration ranged from 0.01 [M] to 0.5 [M], and the reaction temperature ranged from −78° C. to 180° C.

To facilitate the reaction, a Lewis acid, such as AlCl₃, BF₃·OEt₂, BCl₃, BBr₃, InCl₃, InBr₃, In(OTf)₃, SnCl₄, SnBr₄, AgOTf, ScCl₃, Sc(OTf)₃, etc., may also be added.

Those skilled in the art will appreciate that the above preparation method is merely exemplary. Those skilled in the art can modify the preparation method to obtain other compound structures encompassed by the present disclosure.

The compound of the present disclosure, due to the polycyclic structure design with specific substituents, can achieve the desired emission covering the spectrum from orange to red light. To further verify the luminescent effect, the maximum emission wavelengths and the energy levels of some compounds of the present disclosure were calculated through density functional theory (DFT) calculation.

The DFT calculation method used in the present disclosure is as follows.

Using the B3LYP hybrid functional and the 6-311G** basis set within the Gaussian software package and using the SMD solvation model to simulate the THF solvent environment, the DFT calculation was carried out on the compounds of the present disclosure and comparative compound A. The HOMO values, LUMO values, and singlet energy levels (S1) of the compounds were obtained. The maximum emission wavelength λₘₐₓ (nm) of the compounds was calculated according to the formula λₘₐₓ (nm)=1240/S1. The data are recorded and presented in Table 1.

TABLE 1
DFT calculation results

| | HOMO | LUMO | S1 | λₘₐₓ | T1 |
|---|---|---|---|---|---|
| Compound | (eV) | (eV) | (eV) | (nm) | (nm) |
| Compound | −5.42 | −2.74 | 2.0298 | 611.2 | 674.0 |
| BN-1-6-990 | | | | | |
| Compound | −5.55 | −2.82 | 2.0506 | 604.7 | 668.4 |
| BN-1-6-928 | | | | | |
| Compound | −5.54 | −2.73 | 2.1258 | 583.3 | 642.9 |
| BN-1-6-256 | | | | | |
| Compound | −5.56 | −2.77 | 2.1031 | 589.6 | 650.4 |
| BN-1-6-266 | | | | | |
| Compound | −5.57 | −2.76 | 2.1139 | 586.6 | 646.6 |
| BN-1-5-266 | | | | | |
| Compound | −5.57 | −2.82 | 2.0622 | 601.3 | 666.4 |
| BN-1-6-592 | | | | | |
| Compound A | −5.49 | −2.50 | 2.2669 | 547.0 | 600.3 |

The structures of the related compounds are as follows:

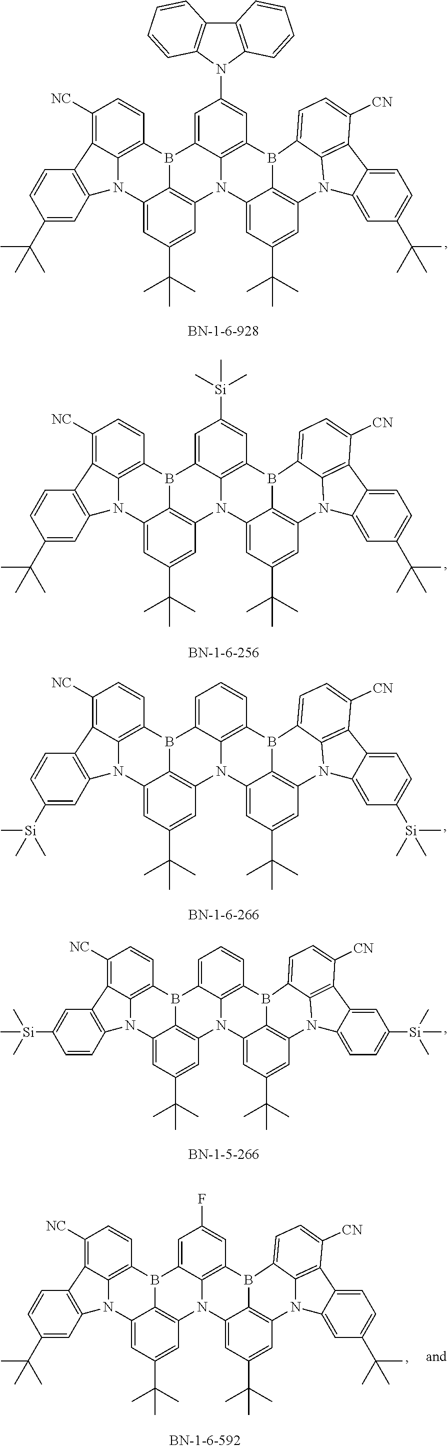

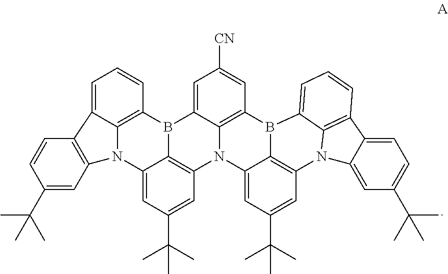 [SMILES: CC(C)(C)c1cc2c3c(c1)-n1c4cc(C(C)(C)C)ccc4c4cccc(c41)B3c1cc(C#N)cc3c1N2c1cc(C(C)(C)C)cc2c1B3c1cccc3c4ccc(C(C)(C)C)cc4n-2c13]

### DISCUSSION

As can be seen from the data in Table 1, compared with Comparative Example Compound A, the compounds of the present disclosure, BN-1-6-990, BN-1-6-928, BN-1-6-256, BN-1-6-266, BN-1-5-266, and BN-1-6-592, to which a cyano group is incorporated on the polycyclic skeleton and any one of a carbazolyl group, fluorine or an alkylsilyl group is additionally introduced, all exhibit a redshift of 35 nm to 65 nm in their maximum emission wavelength (λₘₐₓ). Such a significant redshift effect is unexpected. Furthermore, the HOMO and LUMO energy levels of the compounds of the present disclosure, BN-1-6-990, BN-1-6-928, BN-1-6-256, BN-1-6-266, BN-1-5-266, and BN-1-6-592, generally fall within the range of −5.42 eV to −5.57 eV, which are comparable to or deeper than those of Comparative Example Compound A, indicating that the compounds of the present disclosure possess a hole or electron trapping capability comparable to or stronger than that of the comparative example compound. Such a strong hole or electron trapping capability is conducive to achieving excellent performance in devices, such as low voltage, high device efficiency, and long device lifetime, suggesting that the compounds of the present disclosure, as light-emitting materials, have the potential and application prospects for achieving high device efficiency.

In summary, the compounds of the present disclosure having the specific structure of Formula 1 can achieve orange to red light emission, possess a strong hole or electron trapping capability, and demonstrate their potential as excellent light-emitting materials, confirming the excellent performance of the compounds of the present disclosure having the specific structure of Formula 1 and their broad potential for application as light-emitting materials.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound has a structure of Formula 1: 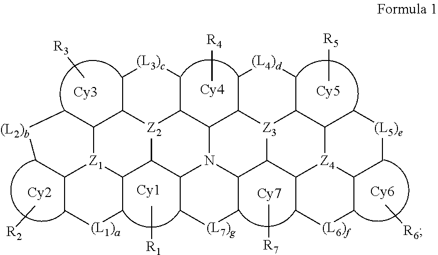
wherein the ring Cy1, the ring Cy2, the ring Cy3, the ring Cy4, the ring Cy5, the ring Cy6 and the ring Cy7 are, at each occurrence identically or differently, selected from an unsaturated carbocyclic ring having 5 to 30 carbon atoms or an unsaturated heterocyclic ring having 3 to 30 carbon atoms;
Z₁, Z₂, Z₃ and Z₄ are, at each occurrence identically or differently, selected from B, N, P, P═O, P═S, As, As═O, As═S, SiR or GeR;
L₁, L₂, L₃, L₄, L₅, L₆ and L₇ are, at each occurrence identically or differently, selected from a single bond, O, S, Se, BR′, NR′, PR′, P═OR′, P═SR′, AsR′, As═OR′, As═SR′, CR′R′, SiR′R′ or GeR′R′; in a case where a plurality of R′ are present at the same time, the plurality of R′ are identical or different;
a, b, c, d, e, f and g are each independently selected from 0, 1 or 2;
R₁, R₂, R₃, R₄, R₅, R₆ and R₇ represent, at each occurrence identically or differently, mono-substitution, multiple substitutions or non-substitution; at least one of R₁ to R₇ is a cyano group, and at least one of R₁ to R₇ is, at each occurrence identically or differently, selected from the group consisting of: substituted or unsubstituted alkylsilyl having 3 to 20 carbon atoms, fluorine, substituted or unsubstituted carbazolyl having 3 to 20 carbon atoms and combinations thereof;
R, R′, R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, R″, R₁, R₂, R₃, R₄, R₅, R₆ and R₇ can be optionally joined to form a ring.

2. The compound of claim 1, wherein the ring Cy1, the ring Cy2, the ring Cy3, the ring Cy4, the ring Cy5, the ring Cy6 and the ring Cy7 are, at each occurrence identically or differently, selected from a five-membered unsaturated carbocyclic ring, an aromatic ring having 6 to 18 carbon atoms, a heteroaromatic ring having 3 to 18 carbon atoms, or a combination thereof, and
preferably, the ring Cy1, the ring Cy2, the ring Cy3, the ring Cy4, the ring Cy5, the ring Cy6 and the ring Cy7 are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

3. The compound of claim 1, wherein the compound has a structure represented by any one of Formula 1-1 to Formula 1-4: 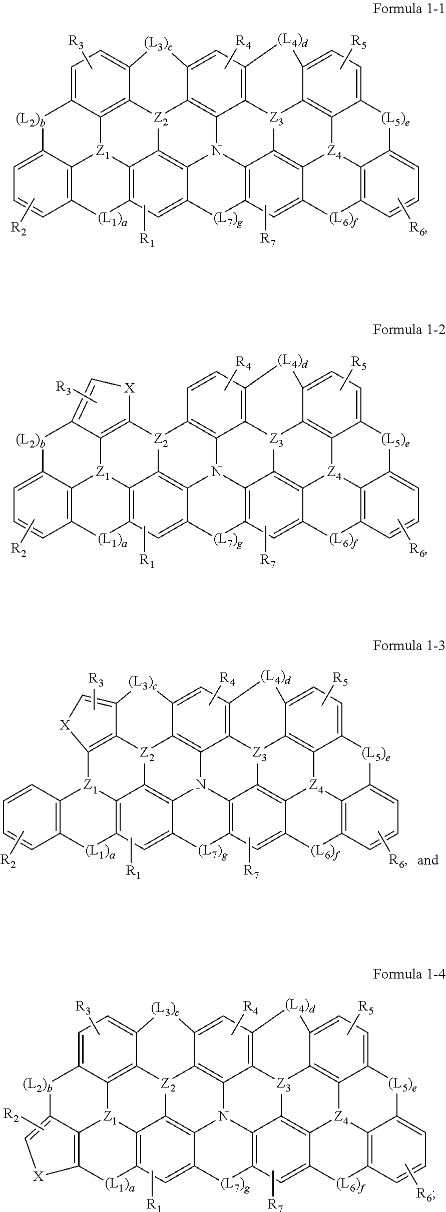
wherein Z₁, Z₂, Z₃ and Z₄ are, at each occurrence identically or differently, selected from B, N, P, P═O, P═S, As, As═O, As═S, SiR or GeR;
X is, at each occurrence identically or differently, selected from O, S, Se or NRx;
L₁, L₂, L₃, L₄, L₅, L₆ and L₇ are, at each occurrence identically or differently, selected from a single bond, O, S, Se, BR′, NR′, PR′, P═OR′, P═SR′, AsR′, As—OR′, As═SR′, CR′R′, SiR′R′ or GeR′R′; and in a case where two R′ are present at the same time, the two R′ are identical or different;
a, b, c, d, e, f and g are each independently selected from 0, 1 or 2;
R₁, R₂, R₃, R₄, R₅, R₆ and R₇ represent, at each occurrence identically or differently, mono-substitution, multiple substitutions or non-substitution; in Formula 1-1 to Formula 1-4, at least one of R₁ to R₇ is a cyano group, and at least one of R₁ to R₇ is selected from the group consisting of: substituted or unsubstituted alkylsilyl having 3 to 20 carbon atoms, fluorine, substituted or unsubstituted carbazolyl having 3 to 20 carbon atoms and combinations thereof;
R, R′, Rₓ, R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
the R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R′, R″, Rₓ, R₁, R₂, R₃, R₄, R₅, R₆ and R₇ can be optionally joined to form a ring; and
preferably, the compound has a structure represented by Formula 1-1.

4. The compound of claim 1, wherein L₁, L₂, L₃, L₄, L₅, L₆ and L₇ are, at each occurrence identically or differently, selected from a single bond, O, S, Se, BR′, NR′, P═OR′, CR′R′ or SiR′R′;
the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms and combinations thereof; and
preferably, L₁, L₂, L₃, L₄, L₅, L₆ and L₇ are, at each occurrence identically or differently, selected from a single bond, O, S, NR′ or CR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

5. The compound of claim 1, wherein Z₁, Z₂, Z₃ and Z₄ are, at each occurrence identically or differently, selected from B, N, P, P—O or P═S, and at least one of Z₁, Z₂, Z₃ and Z₄ is selected from B, P, P═O or P═S;
preferably, Z₁, Z₂, Z₃ and Z₄ are, at each occurrence identically or differently, selected from B, N or P═O, and at least two of Z₁, Z₂, Z₃ and Z₄ are, at each occurrence identically or differently, selected from B or P—O; and
more preferably, Z₁ and Z₄ are N, and Z₂ and Z₃ are B.

6. The compound of claim 1, wherein R₁, R₂, R₃, R₄, R₅, R₆ and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms; and
preferably, R₁, R₂, R₃, R₄, R₅, R₆ and R₇ are, at each occurrence identically or differently, selected from the group consisting of: hydrogen, deuterium, halogen, substituted or unsubstituted alkyl having 1 to 12 carbon atoms, substituted or unsubstituted cycloalkyl having 3 to 12 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 20 carbon atoms, substituted or unsubstituted amino having 0 to 20 carbon atoms, a cyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms.

7. The compound of claim 1, wherein at least one of R₁ to R₇ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms; and
preferably, at least one of R₁ to R₇ is, at each occurrence identically or differently, selected from the group consisting of: deuterium, halogen, substituted or unsubstituted alkyl having 1 to 12 carbon atoms, substituted or unsubstituted cycloalkyl having 3 to 12 ring carbon atoms, substituted or unsubstituted aryl having 6 to 12 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, a cyano group and combinations thereof; at least one of R₁ to R₇ is a cyano group, and at least one of R₁ to R₇ is selected from the group consisting of: substituted or unsubstituted alkylsilyl having 3 to 20 carbon atoms, fluorine and substituted or unsubstituted carbazolyl having 3 to 20 carbon atoms.

8. The compound of claim 1, wherein at least one of R₁ to R₇ is a cyano group, and at least one of remaining R₁ to R₇ is selected from substituted or unsubstituted alkylsilyl having 3 to 20 carbon atoms, substituted or unsubstituted carbazolyl having 3 to 20 carbon atoms or fluorine; and
preferably, at least two of R₁ to R₇ are cyano groups, and at least one of remaining R₁ to R₇ is selected from substituted or unsubstituted alkylsilyl having 3 to 20 carbon atoms, substituted or unsubstituted carbazolyl having 3 to 20 carbon atoms or fluorine.

9. The compound of claim 1, wherein at least one of R₃ and R₅ is a cyano group; and
preferably, at least two of R₃ and R₅ are cyano groups.

10. The compound of claim 1, wherein at least one of R₁, R₂, R₄, R₆ and R₇ is selected from the group consisting of: substituted or unsubstituted alkylsilyl having 3 to 20 carbon atoms, substituted or unsubstituted carbazolyl having 3 to 20 carbon atoms and fluorine; and
preferably, at least one of R₂, R₄ and R₆ is selected from the group consisting of: substituted or unsubstituted alkylsilyl having 3 to 20 carbon atoms, substituted or unsubstituted carbazolyl having 3 to 20 carbon atoms and fluorine.

11. The compound of claim 3, wherein the compound is selected from the group consisting of Compound BN-1-1-k₁ to Compound BN-1-22-k₁;
wherein the Compound BN-1-1-k₁ to Compound BN-1-22-k₁ have the following structures: 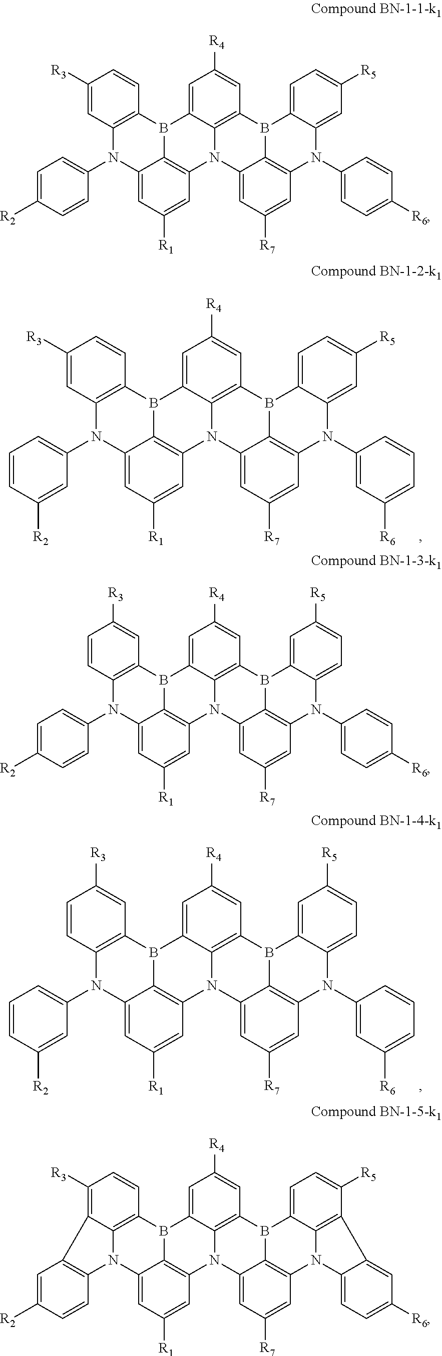 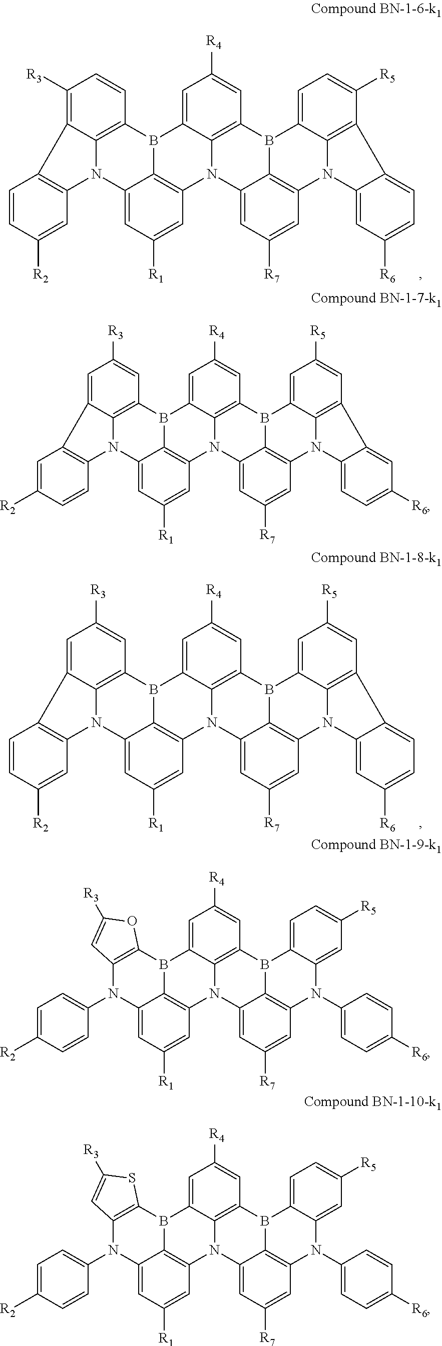 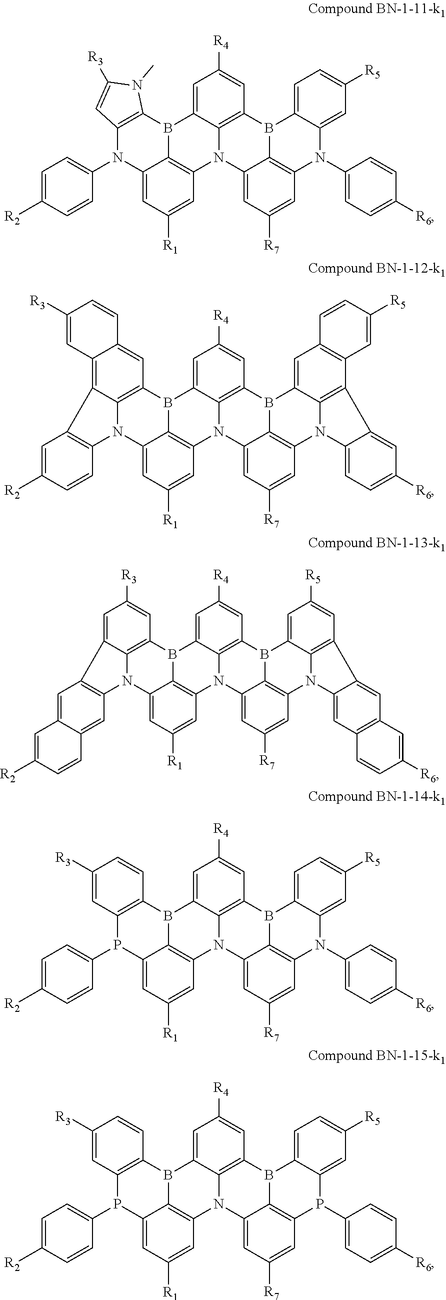 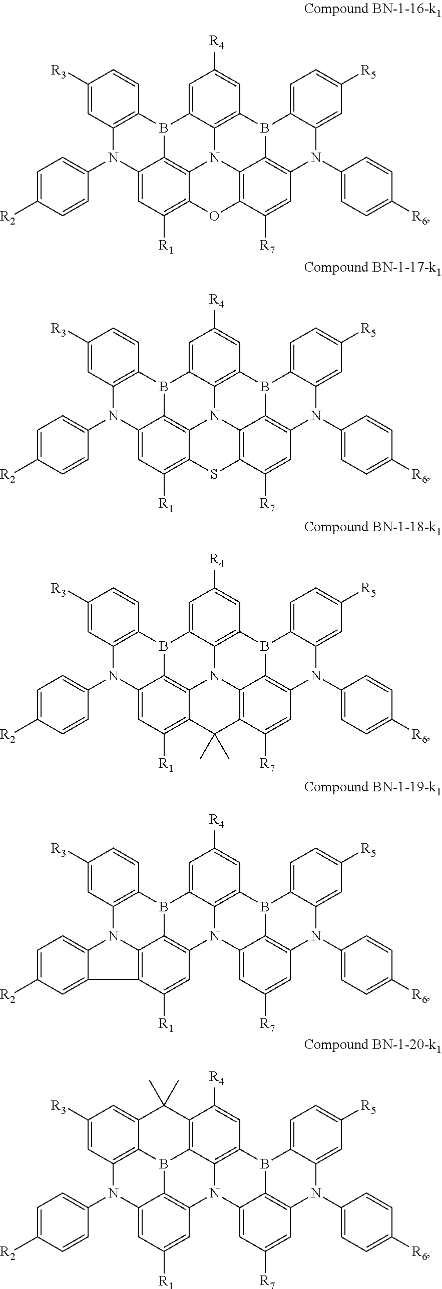 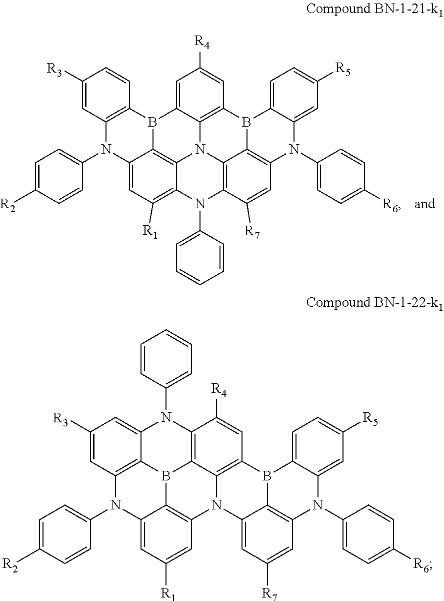
wherein R₁, R₂, R₃, R₄, R₅, R₆, R₇ and k₁ are selected from atoms or groups listed in the following table, respectively:

| k₁ | R₁ | R₂ | R₃ | R₄ | R₅ | R₆ | R₇ |
|---|---|---|---|---|---|---|---|
| 1 | CN | TMS | H | H | H | H | H |
| 2 | CN | H | TMS | H | H | H | H |
| 3 | CN | H | H | TMS | H | H | H |
| 4 | CN | H | H | H | TMS | H | H |
| 5 | CN | H | H | H | H | TMS | H |
| 6 | CN | H | H | H | H | H | TMS |
| 7 | TMS | CN | H | H | H | H | H |
| 8 | H | CN | TMS | H | H | H | H |
| 9 | H | CN | H | TMS | H | H | H |
| 10 | H | CN | H | H | TMS | H | H |
| 11 | H | CN | H | H | H | TMS | H |
| 12 | H | CN | H | H | H | H | TMS |
| 13 | TMS | H | CN | H | H | H | H |
| 14 | H | TMS | CN | H | H | H | H |
| 15 | H | H | CN | TMS | H | H | H |
| 16 | H | H | CN | H | TMS | H | H |
| 17 | H | H | CN | H | H | TMS | H |
| 18 | H | H | CN | H | H | H | TMS |
| 19 | TMS | H | H | CN | H | H | H |
| 20 | H | TMS | H | CN | H | H | H |
| 21 | H | H | TMS | CN | H | H | H |
| 22 | H | H | H | CN | TMS | H | H |
| 23 | H | H | H | CN | H | TMS | H |
| 24 | H | H | H | CN | H | H | TMS |
| 25 | TMS | H | H | H | CN | H | H |
| 26 | H | TMS | H | H | CN | H | H |
| 27 | H | H | TMS | H | CN | H | H |
| 28 | H | H | H | TMS | CN | H | H |
| 29 | H | H | H | H | CN | TMS | H |
| 30 | H | H | H | H | CN | H | TMS |
| 31 | TMS | H | H | H | H | CN | H |
| 32 | H | TMS | H | H | H | CN | H |
| 33 | H | H | TMS | H | H | CN | H |
| 34 | H | H | H | TMS | H | CN | H |
| 35 | H | H | H | H | TMS | CN | H |
| 36 | H | H | H | H | H | CN | TMS |
| 37 | TMS | H | H | H | H | H | CN |
| 38 | H | TMS | H | H | H | H | CN |
| 39 | H | H | TMS | H | H | H | CN |
| 40 | H | H | H | TMS | H | H | CN |
| 41 | H | H | H | H | TMS | H | CN |
| 42 | H | H | H | H | H | TMS | CN |
| 43 | CN | TMS | H | H | H | H | CN |
| 44 | CN | H | TMS | H | H | H | CN |
| 45 | CN | H | H | TMS | H | H | CN |
| 46 | CN | H | H | H | TMS | H | CN |
| 47 | CN | H | H | H | H | TMS | CN |
| 48 | TMS | CN | H | H | H | CN | H |
| 49 | H | CN | TMS | H | H | CN | H |
| 50 | H | CN | H | TMS | H | CN | H |
| 51 | H | CN | H | H | TMS | CN | H |
| 52 | H | CN | H | H | H | CN | TMS |
| 53 | TMS | H | CN | H | CN | H | H |
| 54 | H | TMS | CN | H | CN | H | H |
| 55 | H | H | CN | TMS | CN | H | H |
| 56 | H | H | CN | H | CN | TMS | H |
| 57 | H | H | CN | H | CN | H | TMS |
| 58 | CN | TMS | H | H | H | TMS | CN |
| 59 | CN | H | TMS | H | TMS | H | CN |
| 60 | CN | TMS | H | H | H | TMS | H |
| 61 | CN | H | TMS | H | TMS | H | H |
| 62 | TMS | CN | H | H | H | CN | TMS |
| 63 | H | CN | TMS | H | TMS | CN | H |
| 64 | TMS | H | CN | H | CN | H | TMS |
| 65 | H | TMS | CN | H | CN | TMS | H |
| 66 | TMS | CN | H | H | H | H | TMS |
| 67 | H | CN | TMS | H | TMS | H | H |
| 68 | CN | TMS | D | D | D | D | D |
| 69 | CN | D | TMS | D | D | D | D |
| 70 | CN | D | D | TMS | D | D | D |
| 71 | CN | D | D | D | TMS | D | D |
| 72 | CN | D | D | D | D | TMS | D |
| 73 | CN | D | D | D | D | D | TMS |
| 74 | TMS | CN | D | D | D | D | D |
| 75 | D | CN | TMS | D | D | D | D |
| 76 | D | CN | D | TMS | D | D | D |
| 77 | D | CN | D | D | TMS | D | D |
| 78 | D | CN | D | D | D | TMS | D |
| 79 | D | CN | D | D | D | D | TMS |
| 80 | TMS | D | CN | D | D | D | D |
| 81 | D | TMS | CN | D | D | D | D |
| 82 | D | D | CN | TMS | D | D | D |
| 83 | D | D | CN | D | TMS | D | D |
| 84 | D | D | CN | D | D | TMS | D |
| 85 | D | D | CN | D | D | D | TMS |
| 86 | TMS | D | D | CN | D | D | D |
| 87 | D | TMS | D | CN | D | D | D |
| 88 | D | D | TMS | CN | D | D | D |
| 89 | D | D | D | CN | TMS | D | D |
| 90 | D | D | D | CN | D | TMS | D |
| 91 | D | D | D | CN | D | D | TMS |
| 92 | TMS | D | D | D | CN | D | D |
| 93 | D | TMS | D | D | CN | D | D |
| 94 | D | D | TMS | D | CN | D | D |
| 95 | D | D | D | TMS | CN | D | D |
| 96 | D | D | D | D | CN | TMS | D |
| 97 | D | D | D | D | CN | D | TMS |
| 98 | TMS | D | D | D | D | CN | D |
| 99 | D | TMS | D | D | D | CN | D |
| 100 | D | D | TMS | D | D | CN | D |
| 101 | D | D | D | TMS | D | CN | D |
| 102 | D | D | D | D | TMS | CN | D |
| 103 | D | D | D | D | D | CN | TMS |
| 104 | TMS | D | D | D | D | D | CN |
| 105 | D | TMS | D | D | D | D | CN |
| 106 | D | D | TMS | D | D | D | CN |
| 107 | D | D | D | TMS | D | D | CN |
| 108 | D | D | D | D | TMS | D | CN |
| 109 | D | D | D | D | D | TMS | CN |
| 110 | CN | TMS | D | D | D | D | CN |
| 111 | CN | D | TMS | D | D | D | CN |
| 112 | CN | D | D | TMS | D | D | CN |
| 113 | CN | D | D | D | TMS | D | CN |
| 114 | CN | D | D | D | D | TMS | CN |
| 115 | TMS | CN | D | D | D | CN | D |
| 116 | D | CN | TMS | D | D | CN | D |
| 117 | D | CN | D | TMS | D | CN | D |
| 118 | D | CN | D | D | TMS | CN | D |
| 119 | D | CN | D | D | D | CN | TMS |
| 120 | TMS | D | CN | D | CN | D | D |
| 121 | D | TMS | CN | D | CN | D | D |
| 122 | D | D | CN | TMS | CN | D | D |
| 123 | D | D | CN | D | CN | TMS | D |
| 124 | D | D | CN | D | CN | D | TMS |
| 125 | CN | TMS | D | D | D | TMS | CN |
| 126 | CN | D | TMS | D | TMS | D | CN |
| 127 | CN | TMS | D | D | D | TMS | D |
| 128 | CN | D | TMS | D | TMS | D | D |
| 129 | TMS | CN | D | D | D | CN | TMS |
| 130 | D | CN | TMS | D | TMS | CN | D |
| 131 | TMS | D | CN | D | CN | D | TMS |
| 132 | D | TMS | CN | D | CN | TMS | D |
| 133 | TMS | CN | D | D | D | D | TMS |
| 134 | D | CN | TMS | D | TMS | D | D |
| 135 | CN | TMS | P1 | P1 | P1 | P1 | P1 |
| 136 | CN | P1 | TMS | P1 | P1 | P1 | P1 |
| 137 | CN | P1 | P1 | TMS | P1 | P1 | P1 |
| 138 | CN | P1 | P1 | P1 | TMS | P1 | P1 |
| 139 | CN | P1 | P1 | P1 | P1 | TMS | P1 |
| 140 | CN | P1 | P1 | P1 | P1 | P1 | TMS |
| 141 | TMS | CN | P1 | P1 | P1 | P1 | P1 |
| 142 | P1 | CN | TMS | P1 | P1 | P1 | P1 |
| 143 | P1 | CN | P1 | TMS | P1 | P1 | P1 |
| 144 | P1 | CN | P1 | P1 | TMS | P1 | P1 |
| 145 | P1 | CN | P1 | P1 | P1 | TMS | P1 |
| 146 | P1 | CN | P1 | P1 | P1 | P1 | TMS |
| 147 | TMS | P1 | CN | P1 | P1 | P1 | P1 |
| 148 | P1 | TMS | CN | P1 | P1 | P1 | P1 |
| 149 | P1 | P1 | CN | TMS | P1 | P1 | P1 |
| 150 | P1 | P1 | CN | P1 | TMS | P1 | P1 |
| 151 | P1 | P1 | CN | P1 | P1 | TMS | P1 |
| 152 | P1 | P1 | CN | P1 | P1 | P1 | TMS |
| 153 | TMS | P1 | P1 | CN | P1 | P1 | P1 |
| 154 | P1 | TMS | P1 | CN | P1 | P1 | P1 |
| 155 | P1 | P1 | TMS | CN | P1 | P1 | P1 |
| 156 | P1 | P1 | P1 | CN | TMS | P1 | P1 |
| 157 | P1 | P1 | P1 | CN | P1 | TMS | P1 |
| 158 | P1 | P1 | P1 | CN | P1 | P1 | TMS |
| 159 | TMS | P1 | P1 | P1 | CN | P1 | P1 |
| 160 | P1 | TMS | P1 | P1 | CN | P1 | P1 |
| 161 | P1 | P1 | TMS | P1 | CN | P1 | P1 |
| 162 | P1 | P1 | P1 | TMS | CN | P1 | P1 |
| 163 | P1 | P1 | P1 | P1 | CN | TMS | P1 |
| 164 | P1 | P1 | P1 | P1 | CN | P1 | TMS |
| 165 | TMS | P1 | P1 | P1 | P1 | CN | P1 |
| 166 | P1 | TMS | P1 | P1 | P1 | CN | P1 |
| 167 | P1 | P1 | TMS | P1 | P1 | CN | P1 |
| 168 | P1 | P1 | P1 | TMS | P1 | CN | P1 |
| 169 | P1 | P1 | P1 | P1 | TMS | CN | P1 |
| 170 | P1 | P1 | P1 | P1 | P1 | CN | TMS |
| 171 | TMS | P1 | P1 | P1 | P1 | P1 | CN |
| 172 | P1 | TMS | P1 | P1 | P1 | P1 | CN |
| 173 | P1 | P1 | TMS | P1 | P1 | P1 | CN |
| 174 | P1 | P1 | P1 | TMS | P1 | P1 | CN |
| 175 | P1 | P1 | P1 | P1 | TMS | P1 | CN |
| 176 | P1 | P1 | P1 | P1 | P1 | TMS | CN |
| 177 | CN | TMS | P1 | P1 | P1 | P1 | CN |
| 178 | CN | P1 | TMS | P1 | P1 | P1 | CN |
| 179 | CN | P1 | P1 | TMS | P1 | P1 | CN |
| 180 | CN | P1 | P1 | P1 | TMS | P1 | CN |
| 181 | CN | P1 | P1 | P1 | P1 | TMS | CN |
| 182 | TMS | CN | P1 | P1 | P1 | CN | P1 |
| 183 | P1 | CN | TMS | P1 | P1 | CN | P1 |
| 184 | P1 | CN | P1 | TMS | P1 | CN | P1 |
| 185 | P1 | CN | P1 | P1 | TMS | CN | P1 |
| 186 | P1 | CN | P1 | P1 | P1 | CN | TMS |
| 187 | TMS | P1 | CN | P1 | CN | P1 | P1 |
| 188 | P1 | TMS | CN | P1 | CN | P1 | P1 |
| 189 | P1 | P1 | CN | TMS | CN | P1 | P1 |
| 190 | P1 | P1 | CN | P1 | CN | TMS | P1 |
| 191 | P1 | P1 | CN | P1 | CN | P1 | TMS |
| 192 | CN | TMS | P1 | P1 | P1 | TMS | CN |
| 193 | CN | P1 | TMS | P1 | TMS | P1 | CN |
| 194 | CN | TMS | P1 | P1 | P1 | TMS | P1 |
| 195 | CN | P1 | TMS | P1 | TMS | P1 | P1 |
| 196 | TMS | CN | P1 | P1 | P1 | CN | TMS |
| 197 | P1 | CN | TMS | P1 | TMS | CN | P1 |
| 198 | TMS | P1 | CN | P1 | CN | P1 | TMS |
| 199 | P1 | TMS | CN | P1 | CN | TMS | P1 |
| 200 | TMS | CN | P1 | P1 | P1 | P1 | TMS |
| 201 | P1 | CN | TMS | P1 | TMS | P1 | P1 |
| 202 | CN | TMS | P6 | P6 | P6 | P6 | P6 |
| 203 | CN | P6 | TMS | P6 | P6 | P6 | P6 |
| 204 | CN | P6 | P6 | TMS | P6 | P6 | P6 |
| 205 | CN | P6 | P6 | P6 | TMS | P6 | P6 |
| 206 | CN | P6 | P6 | P6 | P6 | TMS | P6 |
| 207 | CN | P6 | P6 | P6 | P6 | P6 | TMS |
| 208 | TMS | CN | P6 | P6 | P6 | P6 | P6 |
| 209 | P6 | CN | TMS | P6 | P6 | P6 | P6 |
| 210 | P6 | CN | P6 | TMS | P6 | P6 | P6 |
| 211 | P6 | CN | P6 | P6 | TMS | P6 | P6 |
| 212 | P6 | CN | P6 | P6 | P6 | TMS | P6 |
| 213 | P6 | CN | P6 | P6 | P6 | P6 | TMS |
| 214 | TMS | P6 | CN | P6 | P6 | P6 | P6 |
| 215 | P6 | TMS | CN | P6 | P6 | P6 | P6 |
| 216 | P6 | P6 | CN | TMS | P6 | P6 | P6 |
| 217 | P6 | P6 | CN | P6 | TMS | P6 | P6 |
| 218 | P6 | P6 | CN | P6 | P6 | TMS | P6 |
| 219 | P6 | P6 | CN | P6 | P6 | P6 | TMS |
| 220 | TMS | P6 | P6 | CN | P6 | P6 | P6 |
| 221 | P6 | TMS | P6 | CN | P6 | P6 | P6 |
| 222 | P6 | P6 | TMS | CN | P6 | P6 | P6 |
| 223 | P6 | P6 | P6 | CN | TMS | P6 | P6 |
| 224 | P6 | P6 | P6 | CN | P6 | TMS | P6 |
| 225 | P6 | P6 | P6 | CN | P6 | P6 | TMS |
| 226 | TMS | P6 | P6 | P6 | CN | P6 | P6 |
| 227 | P6 | TMS | P6 | P6 | CN | P6 | P6 |
| 228 | P6 | P6 | TMS | P6 | CN | P6 | P6 |
| 229 | P6 | P6 | P6 | TMS | CN | P6 | P6 |
| 230 | P6 | P6 | P6 | P6 | CN | TMS | P6 |
| 231 | P6 | P6 | P6 | P6 | CN | P6 | TMS |
| 232 | TMS | P6 | P6 | P6 | P6 | CN | P6 |
| 233 | P6 | TMS | P6 | P6 | P6 | CN | P6 |
| 234 | P6 | P6 | TMS | P6 | P6 | CN | P6 |
| 235 | P6 | P6 | P6 | TMS | P6 | CN | P6 |
| 236 | P6 | P6 | P6 | P6 | TMS | CN | P6 |
| 237 | P6 | P6 | P6 | P6 | P6 | CN | TMS |
| 238 | TMS | P6 | P6 | P6 | P6 | P6 | CN |
| 239 | P6 | TMS | P6 | P6 | P6 | P6 | CN |
| 240 | P6 | P6 | TMS | P6 | P6 | P6 | CN |
| 241 | P6 | P6 | P6 | TMS | P6 | P6 | CN |
| 242 | P6 | P6 | P6 | P6 | TMS | P6 | CN |
| 243 | P6 | P6 | P6 | P6 | P6 | TMS | CN |
| 244 | CN | TMS | P6 | P6 | P6 | P6 | CN |
| 245 | CN | P6 | TMS | P6 | P6 | P6 | CN |
| 246 | CN | P6 | P6 | TMS | P6 | P6 | CN |
| 247 | CN | P6 | P6 | P6 | TMS | P6 | CN |
| 248 | CN | P6 | P6 | P6 | P6 | TMS | CN |
| 249 | TMS | CN | P6 | P6 | P6 | CN | P6 |
| 250 | P6 | CN | TMS | P6 | P6 | CN | P6 |
| 251 | P6 | CN | P6 | TMS | P6 | CN | P6 |
| 252 | P6 | CN | P6 | P6 | TMS | CN | P6 |
| 253 | P6 | CN | P6 | P6 | P6 | CN | TMS |
| 254 | TMS | P6 | CN | P6 | CN | P6 | P6 |
| 255 | P6 | TMS | CN | P6 | CN | P6 | P6 |
| 256 | P6 | P6 | CN | TMS | CN | P6 | P6 |
| 257 | P6 | P6 | CN | P6 | CN | TMS | P6 |
| 258 | P6 | P6 | CN | P6 | CN | P6 | TMS |
| 259 | CN | TMS | P6 | H | P6 | TMS | CN |
| 260 | CN | P6 | TMS | H | TMS | P6 | CN |
| 261 | CN | TMS | P6 | H | P6 | TMS | P6 |
| 262 | CN | P6 | TMS | H | TMS | P6 | P6 |
| 263 | TMS | CN | P6 | H | P6 | CN | TMS |
| 264 | P6 | CN | TMS | H | TMS | CN | P6 |
| 265 | TMS | P6 | CN | H | CN | P6 | TMS |
| 266 | P6 | TMS | CN | H | CN | TMS | P6 |
| 267 | TMS | CN | P6 | H | P6 | P6 | TMS |
| 268 | P6 | CN | TMS | H | TMS | P6 | P6 |
| 269 | H | TMS | CN | P1 | H | H | H |
| 270 | H | TMS | CN | P2 | H | H | H |
| 271 | H | TMS | CN | P3 | H | H | H |
| 272 | H | TMS | CN | P4 | H | H | H |
| 273 | H | TMS | CN | P5 | H | H | H |
| 274 | H | TMS | CN | P6 | H | H | H |
| 275 | H | TMS | CN | P7 | H | H | H |
| 276 | H | TMS | CN | P8 | H | H | H |
| 277 | H | TMS | CN | P9 | H | H | H |
| 278 | H | TMS | CN | P10 | H | H | H |
| 279 | H | TMS | CN | P11 | H | H | H |
| 280 | H | TMS | CN | P12 | H | H | H |
| 281 | H | TMS | CN | P13 | H | H | H |
| 282 | H | TMS | CN | P14 | H | H | H |
| 283 | H | TMS | CN | P15 | H | H | H |
| 284 | H | TMS | CN | P16 | H | H | H |
| 285 | H | TMS | CN | P17 | H | H | H |
| 286 | CN | H | TMS | P1 | TMS | H | CN |
| 287 | CN | H | TMS | P2 | TMS | H | CN |
| 288 | CN | H | TMS | P3 | TMS | H | CN |
| 289 | CN | H | TMS | P4 | TMS | H | CN |
| 290 | CN | H | TMS | P5 | TMS | H | CN |
| 291 | CN | H | TMS | P6 | TMS | H | CN |
| 292 | CN | H | TMS | P7 | TMS | H | CN |
| 293 | CN | H | TMS | P8 | TMS | H | CN |
| 294 | CN | H | TMS | P9 | TMS | H | CN |
| 295 | CN | H | TMS | P10 | TMS | H | CN |
| 296 | CN | H | TMS | P11 | TMS | H | CN |
| 297 | CN | H | TMS | P12 | TMS | H | CN |
| 298 | CN | H | TMS | P13 | TMS | H | CN |
| 299 | CN | H | TMS | P14 | TMS | H | CN |
| 300 | CN | H | TMS | P15 | TMS | H | CN |
| 301 | CN | H | TMS | P16 | TMS | H | CN |
| 302 | CN | H | TMS | P17 | TMS | H | CN |
| 303 | P6 | TMS | CN | P1 | P6 | P6 | P6 |
| 304 | P6 | TMS | CN | P2 | P6 | P6 | P6 |
| 305 | P6 | TMS | CN | P3 | P6 | P6 | P6 |
| 306 | P6 | TMS | CN | P4 | P6 | P6 | P6 |
| 307 | P6 | TMS | CN | P5 | P6 | P6 | P6 |
| 308 | P6 | TMS | CN | P6 | P6 | P6 | P6 |
| 309 | P6 | TMS | CN | P7 | P6 | P6 | P6 |
| 310 | P6 | TMS | CN | P8 | P6 | P6 | P6 |
| 311 | P6 | TMS | CN | P9 | P6 | P6 | P6 |
| 312 | P6 | TMS | CN | P10 | P6 | P6 | P6 |
| 313 | P6 | TMS | CN | P11 | P6 | P6 | P6 |
| 314 | P6 | TMS | CN | P12 | P6 | P6 | P6 |
| 315 | P6 | TMS | CN | P13 | P6 | P6 | P6 |
| 316 | P6 | TMS | CN | P14 | P6 | P6 | P6 |
| 317 | P6 | TMS | CN | P15 | P6 | P6 | P6 |
| 318 | P6 | TMS | CN | P16 | P6 | P6 | P6 |
| 319 | P6 | TMS | CN | P17 | P6 | P6 | P6 |
| 320 | CN | P6 | TMS | P1 | TMS | P6 | CN |
| 321 | CN | P6 | TMS | P2 | TMS | P6 | CN |
| 322 | CN | P6 | TMS | P3 | TMS | P6 | CN |
| 323 | CN | P6 | TMS | P4 | TMS | P6 | CN |
| 324 | CN | P6 | TMS | P5 | TMS | P6 | CN |
| 325 | CN | P6 | TMS | P6 | TMS | P6 | CN |
| 326 | CN | P6 | TMS | P7 | TMS | P6 | CN |
| 327 | CN | P6 | TMS | P8 | TMS | P6 | CN |
| 328 | CN | P6 | TMS | P9 | TMS | P6 | CN |
| 329 | CN | P6 | TMS | P10 | TMS | P6 | CN |
| 330 | CN | P6 | TMS | P11 | TMS | P6 | CN |
| 331 | CN | P6 | TMS | P12 | TMS | P6 | CN |
| 332 | CN | P6 | TMS | P13 | TMS | P6 | CN |
| 333 | CN | P6 | TMS | P14 | TMS | P6 | CN |
| 334 | CN | P6 | TMS | P15 | TMS | P6 | CN |
| 335 | CN | P6 | TMS | P16 | TMS | P6 | CN |
| 336 | CN | P6 | TMS | P17 | TMS | P6 | CN |
| 337 | CN | F | H | H | H | H | H |
| 338 | CN | H | F | H | H | H | H |
| 339 | CN | H | H | F | H | H | H |
| 340 | CN | H | H | H | F | H | H |
| 341 | CN | H | H | H | H | F | H |
| 342 | CN | H | H | H | H | H | F |
| 343 | F | CN | H | H | H | H | H |
| 344 | H | CN | F | H | H | H | H |
| 345 | H | CN | H | F | H | H | H |
| 346 | H | CN | H | H | F | H | H |
| 347 | H | CN | H | H | H | F | H |
| 348 | H | CN | H | H | H | H | F |
| 349 | F | H | CN | H | H | H | H |
| 350 | H | F | CN | H | H | H | H |
| 351 | H | H | CN | F | H | H | H |
| 352 | H | H | CN | H | F | H | H |
| 353 | H | H | CN | H | H | F | H |
| 354 | H | H | CN | H | H | H | F |
| 355 | F | H | H | CN | H | H | H |
| 356 | H | F | H | CN | H | H | H |
| 357 | H | H | F | CN | H | H | H |
| 358 | H | H | H | CN | F | H | H |
| 359 | H | H | H | CN | H | F | H |
| 360 | H | H | H | CN | H | H | F |
| 361 | F | H | H | H | CN | H | H |
| 362 | H | F | H | H | CN | H | H |
| 363 | H | H | F | H | CN | H | H |
| 364 | H | H | H | F | CN | H | H |
| 365 | H | H | H | H | CN | F | H |
| 366 | H | H | H | H | CN | H | F |
| 367 | F | H | H | H | H | CN | H |
| 368 | H | F | H | H | H | CN | H |
| 369 | H | H | F | H | H | CN | H |
| 370 | H | H | H | F | H | CN | H |
| 371 | H | H | H | H | F | CN | H |
| 372 | H | H | H | H | H | CN | F |
| 373 | F | H | H | H | H | H | CN |
| 374 | H | F | H | H | H | H | CN |
| 375 | H | H | F | H | H | H | CN |
| 376 | H | H | H | F | H | H | CN |
| 377 | H | H | H | H | F | H | CN |
| 378 | H | H | H | H | H | F | CN |
| 379 | CN | F | H | H | H | H | CN |
| 380 | CN | H | F | H | H | H | CN |
| 381 | CN | H | H | F | H | H | CN |
| 382 | CN | H | H | H | F | H | CN |
| 383 | CN | H | H | H | H | F | CN |
| 384 | F | CN | H | H | H | CN | H |
| 385 | H | CN | F | H | H | CN | H |
| 386 | H | CN | H | F | H | CN | H |
| 387 | H | CN | H | H | F | CN | H |
| 388 | H | CN | H | H | H | CN | F |
| 389 | F | H | CN | H | CN | H | H |
| 390 | H | F | CN | H | CN | H | H |
| 391 | H | H | CN | F | CN | H | H |
| 392 | H | H | CN | H | CN | F | H |
| 393 | H | H | CN | H | CN | H | F |
| 394 | CN | F | H | H | H | F | CN |
| 395 | CN | H | F | H | F | H | CN |
| 396 | CN | F | H | H | H | F | H |
| 397 | CN | H | F | H | F | H | H |
| 398 | F | CN | H | H | H | CN | F |
| 399 | H | CN | F | H | F | CN | H |
| 400 | F | H | CN | H | CN | H | F |
| 401 | H | F | CN | H | CN | F | H |
| 402 | F | CN | H | H | H | H | F |
| 403 | H | CN | F | H | F | H | H |
| 404 | CN | F | D | D | D | D | D |
| 405 | CN | D | F | D | D | D | D |
| 406 | CN | D | D | F | D | D | D |
| 407 | CN | D | D | D | F | D | D |
| 408 | CN | D | D | D | D | F | D |
| 409 | CN | D | D | D | D | D | F |
| 410 | F | CN | D | D | D | D | D |
| 411 | D | CN | F | D | D | D | D |
| 412 | D | CN | D | F | D | D | D |
| 413 | D | CN | D | D | F | D | D |
| 414 | D | CN | D | D | D | F | D |
| 415 | D | CN | D | D | D | D | F |
| 416 | F | D | CN | D | D | D | D |
| 417 | D | F | CN | D | D | D | D |
| 418 | D | D | CN | F | D | D | D |
| 419 | D | D | CN | D | F | D | D |
| 420 | D | D | CN | D | D | F | D |
| 421 | D | D | CN | D | D | D | F |
| 422 | F | D | D | CN | D | D | D |
| 423 | D | F | D | CN | D | D | D |
| 424 | D | D | F | CN | D | D | D |
| 425 | D | D | D | CN | F | D | D |
| 426 | D | D | D | CN | D | F | D |
| 427 | D | D | D | CN | D | D | F |
| 428 | F | D | D | D | CN | D | D |
| 429 | D | F | D | D | CN | D | D |
| 430 | D | D | F | D | CN | D | D |
| 431 | D | D | D | F | CN | D | D |
| 432 | D | D | D | D | CN | F | D |
| 433 | D | D | D | D | CN | D | F |
| 434 | F | D | D | D | D | CN | D |
| 435 | D | F | D | D | D | CN | D |
| 436 | D | D | F | D | D | CN | D |
| 437 | D | D | D | F | D | CN | D |
| 438 | D | D | D | D | F | CN | D |
| 439 | D | D | D | D | D | CN | F |
| 440 | F | D | D | D | D | D | CN |
| 441 | D | F | D | D | D | D | CN |
| 442 | D | D | F | D | D | D | CN |
| 443 | D | D | D | F | D | D | CN |
| 444 | D | D | D | D | F | D | CN |
| 445 | D | D | D | D | D | F | CN |
| 446 | CN | F | D | D | D | D | CN |
| 447 | CN | D | F | D | D | D | CN |
| 448 | CN | D | D | F | D | D | CN |
| 449 | CN | D | D | D | F | D | CN |
| 450 | CN | D | D | D | D | F | CN |
| 451 | F | CN | D | D | D | CN | D |
| 452 | D | CN | F | D | D | CN | D |
| 453 | D | CN | D | F | D | CN | D |
| 454 | D | CN | D | D | F | CN | D |
| 455 | D | CN | D | D | D | CN | F |
| 456 | F | D | CN | D | CN | D | D |
| 457 | D | F | CN | D | CN | D | D |
| 458 | D | D | CN | F | CN | D | D |
| 459 | D | D | CN | D | CN | F | D |
| 460 | D | D | CN | D | CN | D | F |
| 461 | CN | F | D | D | D | F | CN |
| 462 | CN | D | F | D | F | D | CN |
| 463 | CN | F | D | D | D | F | D |
| 464 | CN | D | F | D | F | D | D |
| 465 | F | CN | D | D | D | CN | F |
| 466 | D | CN | F | D | F | CN | D |
| 467 | F | D | CN | D | CN | D | F |
| 468 | D | F | CN | D | CN | F | D |
| 469 | F | CN | D | D | D | D | F |
| 470 | D | CN | F | D | F | D | D |
| 471 | CN | F | P1 | P1 | P1 | P1 | P1 |
| 472 | CN | P1 | F | P1 | P1 | P1 | P1 |
| 473 | CN | P1 | P1 | F | P1 | P1 | P1 |
| 474 | CN | P1 | P1 | P1 | F | P1 | P1 |
| 475 | CN | P1 | P1 | P1 | P1 | F | P1 |
| 476 | CN | P1 | P1 | P1 | P1 | P1 | F |
| 477 | F | CN | P1 | P1 | P1 | P1 | P1 |
| 478 | P1 | CN | F | P1 | P1 | P1 | P1 |
| 479 | P1 | CN | P1 | F | P1 | P1 | P1 |
| 480 | P1 | CN | P1 | P1 | F | P1 | P1 |
| 481 | P1 | CN | P1 | P1 | P1 | F | P1 |
| 482 | P1 | CN | P1 | P1 | P1 | P1 | F |
| 483 | F | P1 | CN | P1 | P1 | P1 | P1 |
| 484 | P1 | F | CN | P1 | P1 | P1 | P1 |
| 485 | P1 | P1 | CN | F | P1 | P1 | P1 |
| 486 | P1 | P1 | CN | P1 | F | P1 | P1 |
| 487 | P1 | P1 | CN | P1 | P1 | F | P1 |
| 488 | P1 | P1 | CN | P1 | P1 | P1 | F |
| 489 | F | P1 | P1 | CN | P1 | P1 | P1 |
| 490 | P1 | F | P1 | CN | P1 | P1 | P1 |
| 491 | P1 | P1 | F | CN | P1 | P1 | P1 |
| 492 | P1 | P1 | P1 | CN | F | P1 | P1 |
| 493 | P1 | P1 | P1 | CN | P1 | F | P1 |
| 494 | P1 | P1 | P1 | CN | P1 | P1 | F |
| 495 | F | P1 | P1 | P1 | CN | P1 | P1 |
| 496 | P1 | F | P1 | P1 | CN | P1 | P1 |
| 497 | P1 | P1 | F | P1 | CN | P1 | P1 |
| 498 | P1 | P1 | P1 | F | CN | P1 | P1 |
| 499 | P1 | P1 | P1 | P1 | CN | F | P1 |
| 500 | P1 | P1 | P1 | P1 | CN | P1 | F |
| 501 | F | P1 | P1 | P1 | P1 | CN | P1 |
| 502 | P1 | F | P1 | P1 | P1 | CN | P1 |
| 503 | P1 | P1 | F | P1 | P1 | CN | P1 |
| 504 | P1 | P1 | P1 | F | P1 | CN | P1 |
| 505 | P1 | P1 | P1 | P1 | F | CN | P1 |
| 506 | P1 | P1 | P1 | P1 | P1 | CN | F |
| 507 | F | P1 | P1 | P1 | P1 | P1 | CN |
| 508 | P1 | F | P1 | P1 | P1 | P1 | CN |
| 509 | P1 | P1 | F | P1 | P1 | P1 | CN |
| 510 | P1 | P1 | P1 | F | P1 | P1 | CN |
| 511 | P1 | P1 | P1 | P1 | F | P1 | CN |
| 512 | P1 | P1 | P1 | P1 | P1 | F | CN |
| 513 | CN | F | P1 | P1 | P1 | P1 | CN |
| 514 | CN | P1 | F | P1 | P1 | P1 | CN |
| 515 | CN | P1 | P1 | F | P1 | P1 | CN |
| 516 | CN | P1 | P1 | P1 | F | P1 | CN |
| 517 | CN | P1 | P1 | P1 | P1 | F | CN |
| 518 | F | CN | P1 | P1 | P1 | CN | P1 |
| 519 | P1 | CN | F | P1 | P1 | CN | P1 |
| 520 | P1 | CN | P1 | F | P1 | CN | P1 |
| 521 | P1 | CN | P1 | P1 | F | CN | P1 |
| 522 | P1 | CN | P1 | P1 | P1 | CN | F |
| 523 | F | P1 | CN | P1 | CN | P1 | P1 |
| 524 | P1 | F | CN | P1 | CN | P1 | P1 |
| 525 | P1 | P1 | CN | F | CN | P1 | P1 |
| 526 | P1 | P1 | CN | P1 | CN | F | P1 |
| 527 | P1 | P1 | CN | P1 | CN | P1 | F |
| 528 | CN | F | P1 | P1 | P1 | F | CN |
| 529 | CN | P1 | F | P1 | F | P1 | CN |
| 530 | CN | F | P1 | P1 | P1 | F | P1 |
| 531 | CN | P1 | F | P1 | F | P1 | P1 |
| 532 | F | CN | P1 | P1 | P1 | CN | F |
| 533 | P1 | CN | F | P1 | F | CN | P1 |
| 534 | F | P1 | CN | P1 | CN | P1 | F |
| 535 | P1 | F | CN | P1 | CN | F | P1 |
| 536 | F | CN | P1 | P1 | P1 | P1 | F |
| 537 | P1 | CN | F | P1 | F | P1 | P1 |
| 538 | CN | F | P6 | P6 | P6 | P6 | P6 |
| 539 | CN | P6 | F | P6 | P6 | P6 | P6 |
| 540 | CN | P6 | P6 | F | P6 | P6 | P6 |
| 541 | CN | P6 | P6 | P6 | F | P6 | P6 |
| 542 | CN | P6 | P6 | P6 | P6 | F | P6 |
| 543 | CN | P6 | P6 | P6 | P6 | P6 | F |
| 544 | F | CN | P6 | P6 | P6 | P6 | P6 |
| 545 | P6 | CN | F | P6 | P6 | P6 | P6 |
| 546 | P6 | CN | P6 | F | P6 | P6 | P6 |
| 547 | P6 | CN | P6 | P6 | F | P6 | P6 |
| 548 | P6 | CN | P6 | P6 | P6 | F | P6 |
| 549 | P6 | CN | P6 | P6 | P6 | P6 | F |
| 550 | F | P6 | CN | P6 | P6 | P6 | P6 |
| 551 | P6 | F | CN | P6 | P6 | P6 | P6 |
| 552 | P6 | P6 | CN | F | P6 | P6 | P6 |
| 553 | P6 | P6 | CN | P6 | F | P6 | P6 |
| 554 | P6 | P6 | CN | P6 | P6 | F | P6 |
| 555 | P6 | P6 | CN | P6 | P6 | P6 | F |
| 556 | F | P6 | P6 | CN | P6 | P6 | P6 |
| 557 | P6 | F | P6 | CN | P6 | P6 | P6 |
| 558 | P6 | P6 | F | CN | P6 | P6 | P6 |
| 559 | P6 | P6 | (6 | CN | F | P6 | P6 |
| 560 | P6 | P6 | P6 | CN | P6 | F | P6 |
| 561 | P6 | P6 | P6 | CN | P6 | P6 | F |
| 562 | F | P6 | P6 | P6 | CN | P6 | P6 |
| 563 | P6 | F | P6 | P6 | CN | P6 | P6 |
| 564 | P6 | P6 | F | P6 | CN | P6 | P6 |
| 565 | P6 | P6 | P6 | F | CN | P6 | P6 |
| 566 | P6 | P6 | P6 | P6 | CN | F | P6 |
| 567 | P6 | P6 | P6 | P6 | CN | P6 | F |
| 568 | F | P6 | P6 | P6 | P6 | CN | P6 |
| 569 | P6 | F | P6 | P6 | P6 | CN | P6 |
| 570 | P6 | P6 | F | P6 | P6 | CN | P6 |
| 571 | P6 | P6 | P6 | F | P6 | CN | P6 |
| 572 | P6 | P6 | P6 | P6 | F | CN | P6 |
| 573 | P6 | P6 | P6 | P6 | P6 | CN | F |
| 574 | F | P6 | P6 | P6 | P6 | P6 | CN |
| 575 | P6 | F | P6 | P6 | P6 | P6 | CN |
| 576 | P6 | P6 | F | P6 | P6 | P6 | CN |
| 577 | P6 | P6 | P6 | F | P6 | P6 | CN |
| 578 | P6 | P6 | P6 | P6 | F | P6 | CN |
| 579 | P6 | P6 | P6 | P6 | P6 | F | CN |
| 580 | CN | F | P6 | P6 | P6 | P6 | CN |
| 581 | CN | P6 | F | P6 | P6 | P6 | CN |
| 582 | CN | P6 | P6 | F | P6 | P6 | CN |
| 583 | CN | P6 | P6 | P6 | F | P6 | CN |
| 584 | CN | P6 | P6 | P6 | P6 | F | CN |
| 585 | F | CN | P6 | P6 | P6 | CN | P6 |
| 586 | P6 | CN | F | P6 | P6 | CN | P6 |
| 587 | P6 | CN | P6 | F | P6 | CN | P6 |
| 588 | P6 | CN | P6 | P6 | F | CN | P6 |
| 589 | P6 | CN | P6 | P6 | P6 | CN | F |
| 590 | F | P6 | CN | P6 | CN | P6 | P6 |
| 591 | P6 | F | CN | P6 | CN | P6 | P6 |
| 592 | P6 | P6 | CN | F | CN | P6 | P6 |
| 593 | P6 | P6 | CN | P6 | CN | F | P6 |
| 594 | P6 | P6 | CN | P6 | CN | P6 | F |
| 595 | CN | F | P6 | P6 | P6 | F | CN |
| 596 | CN | P6 | F | P6 | F | P6 | CN |
| 597 | CN | F | P6 | P6 | P6 | F | P6 |
| 598 | CN | P6 | F | P6 | F | P6 | P6 |
| 599 | F | CN | P6 | P6 | P6 | CN | F |
| 600 | P6 | CN | F | P6 | F | CN | P6 |
| 601 | F | P6 | CN | P6 | CN | P6 | F |
| 602 | P6 | F | CN | P6 | CN | F | P6 |
| 603 | F | CN | P6 | P6 | P6 | P6 | F |
| 604 | P6 | CN | F | P6 | F | P6 | P6 |
| 605 | H | F | CN | P1 | H | H | H |
| 606 | H | F | CN | P2 | H | H | H |
| 607 | H | F | CN | P3 | H | H | H |
| 608 | H | F | CN | P4 | H | H | H |
| 609 | H | F | CN | P5 | H | H | H |
| 610 | H | F | CN | P6 | H | H | H |
| 611 | H | F | CN | P7 | H | H | H |
| 612 | H | F | CN | P8 | H | H | H |
| 613 | H | F | CN | P9 | H | H | H |
| 614 | H | F | CN | P10 | H | H | H |
| 615 | H | F | CN | P11 | H | H | H |
| 616 | H | F | CN | P12 | H | H | H |
| 617 | H | F | CN | P13 | H | H | H |
| 618 | H | F | CN | P14 | H | H | H |
| 619 | H | F | CN | P15 | H | H | H |
| 620 | H | F | CN | P16 | H | H | H |
| 621 | H | F | CN | P17 | H | H | H |
| 622 | CN | H | F | P1 | F | H | CN |
| 623 | CN | H | F | P2 | F | H | CN |
| 624 | CN | H | F | P3 | F | H | CN |
| 625 | CN | H | F | P4 | F | H | CN |
| 626 | CN | H | F | P5 | F | H | CN |
| 627 | CN | H | F | P6 | F | H | CN |
| 628 | CN | H | F | P7 | F | H | CN |
| 629 | CN | H | F | P8 | F | H | CN |
| 630 | CN | H | F | P9 | F | H | CN |
| 631 | CN | H | F | P10 | F | H | CN |
| 632 | CN | H | F | P11 | F | H | CN |
| 633 | CN | H | F | P12 | F | H | CN |
| 635 | CN | H | F | P14 | F | H | CN |
| 636 | CN | H | F | P15 | F | H | CN |
| 637 | CN | H | F | P16 | F | H | CN |
| 638 | CN | H | F | P17 | F | H | CN |
| 639 | P6 | F | CN | P1 | P6 | P6 | P6 |
| 640 | P6 | F | CN | P2 | P6 | P6 | P6 |
| 641 | P6 | F | CN | P3 | P6 | P6 | P6 |
| 642 | P6 | F | CN | P4 | P6 | P6 | P6 |
| 643 | P6 | F | CN | P5 | P6 | P6 | P6 |
| 644 | P6 | F | CN | P6 | P6 | P6 | P6 |
| 645 | P6 | F | CN | P7 | P6 | P6 | P6 |
| 646 | P6 | F | CN | P8 | P6 | P6 | P6 |
| 647 | P6 | F | CN | P9 | P6 | P6 | P6 |
| 648 | P6 | F | CN | P10 | P6 | P6 | P6 |
| 649 | P6 | F | CN | P11 | P6 | P6 | P6 |
| 650 | P6 | F | CN | P12 | P6 | P6 | P6 |
| 651 | P6 | F | CN | P13 | P6 | P6 | P6 |
| 652 | P6 | F | CN | P14 | P6 | P6 | P6 |
| 653 | P6 | F | CN | P15 | P6 | P6 | P6 |
| 654 | P6 | F | CN | P16 | P6 | P6 | P6 |
| 655 | P6 | F | CN | P17 | P6 | P6 | P6 |
| 656 | CN | P6 | F | P1 | F | P6 | CN |
| 657 | CN | P6 | F | P2 | F | P6 | CN |
| 658 | CN | P6 | F | P3 | F | P6 | CN |
| 659 | CN | P6 | F | P4 | F | P6 | CN |
| 660 | CN | P6 | F | P5 | F | P6 | CN |
| 661 | CN | P6 | F | P6 | F | P6 | CN |
| 662 | CN | P6 | F | P7 | F | P6 | CN |
| 663 | CN | P6 | F | P8 | F | P6 | CN |
| 664 | CN | P6 | F | P9 | F | P6 | CN |
| 665 | CN | P6 | F | P10 | F | P6 | CN |
| 666 | CN | P6 | F | P11 | F | P6 | CN |
| 667 | CN | P6 | F | P12 | F | P6 | CN |
| 668 | CN | P6 | F | P13 | F | P6 | CN |
| 669 | CN | P6 | F | P14 | F | P6 | CN |
| 670 | CN | P6 | F | P15 | F | P6 | CN |
| 671 | CN | P6 | F | P16 | F | P6 | CN |
| 672 | CN | P6 | F | P17 | F | P6 | CN |
| 673 | CN | P17 | H | H | H | H | H |
| 674 | CN | H | P17 | H | H | H | H |
| 675 | CN | H | H | P17 | H | H | H |
| 676 | CN | H | H | H | P17 | H | H |
| 677 | CN | H | H | H | H | P17 | H |
| 678 | CN | H | H | H | H | H | P17 |
| 679 | P17 | CN | H | H | H | H | H |
| 680 | H | CN | P17 | H | H | H | H |
| 681 | H | CN | H | P17 | H | H | H |
| 682 | H | CN | H | H | P17 | H | H |
| 683 | H | CN | H | H | H | P17 | H |
| 684 | H | CN | H | H | H | H | P17 |
| 685 | P17 | H | CN | H | H | H | H |
| 686 | H | P17 | CN | H | H | H | H |
| 687 | H | H | CN | P17 | H | H | H |
| 688 | H | H | CN | H | P17 | H | H |
| 689 | H | H | CN | H | H | P17 | H |
| 690 | H | H | CN | H | H | H | P17 |
| 691 | P17 | H | H | CN | H | H | H |
| 692 | H | P17 | H | CN | H | H | H |
| 693 | H | H | P17 | CN | H | H | H |
| 694 | H | H | H | CN | P17 | H | H |
| 695 | H | H | H | CN | H | P17 | H |
| 696 | H | H | H | CN | H | H | P17 |
| 697 | P17 | H | H | H | CN | H | H |
| 698 | H | P17 | H | H | CN | H | H |
| 699 | H | H | P17 | H | CN | H | H |
| 700 | H | H | H | P17 | CN | H | H |
| 701 | H | H | H | H | CN | P17 | H |
| 702 | H | H | H | H | CN | H | P17 |
| 703 | P17 | H | H | H | H | CN | H |
| 704 | H | P17 | H | H | H | CN | H |
| 705 | H | H | P17 | H | H | CN | H |
| 706 | H | H | H | P17 | H | CN | H |
| 707 | H | H | H | H | P17 | CN | H |
| 708 | H | H | H | H | H | CN | P17 |
| 709 | P17 | H | H | H | H | H | CN |
| 710 | H | P17 | H | H | H | H | CN |
| 711 | H | H | P17 | H | H | H | CN |
| 712 | H | H | H | P17 | H | H | CN |
| 713 | H | H | H | H | P17 | H | CN |
| 714 | H | H | H | H | H | P17 | CN |
| 715 | CN | P17 | H | H | H | H | CN |
| 716 | CN | H | P17 | H | H | H | CN |
| 717 | CN | H | H | P17 | H | H | CN |
| 718 | CN | H | H | H | P17 | H | CN |
| 719 | CN | H | H | H | H | P17 | CN |
| 720 | P17 | CN | H | H | H | CN | H |
| 721 | H | CN | P17 | H | H | CN | H |
| 722 | H | CN | H | P17 | H | CN | H |
| 723 | H | CN | H | H | P17 | CN | H |
| 724 | H | CN | H | H | H | CN | P17 |
| 725 | P17 | H | CN | H | CN | H | H |
| 726 | H | P17 | CN | H | CN | H | H |
| 727 | H | H | CN | P17 | CN | H | H |
| 728 | H | H | CN | H | CN | P17 | H |
| 729 | H | H | CN | H | CN | H | P17 |
| 730 | CN | P17 | H | H | H | P17 | CN |
| 731 | CN | H | P17 | H | P17 | H | CN |
| 732 | CN | P17 | H | H | H | P17 | H |
| 733 | CN | H | P17 | H | P17 | H | H |
| 734 | P17 | CN | H | H | H | CN | P17 |
| 735 | H | CN | P17 | H | P17 | CN | H |
| 736 | P17 | H | CN | H | CN | H | P17 |
| 737 | H | P17 | CN | H | CN | P17 | H |
| 738 | P17 | CN | H | H | H | H | P17 |
| 739 | H | CN | P17 | H | P17 | H | H |
| 740 | CN | P17 | D | D | D | D | D |
| 741 | CN | D | P17 | D | D | D | D |
| 742 | CN | D | D | P17 | D | D | D |
| 743 | CN | D | D | D | P17 | D | D |
| 744 | CN | D | D | D | D | P17 | D |
| 745 | CN | D | D | D | D | D | P17 |
| 746 | P17 | CN | D | D | D | D | D |
| 747 | D | CN | P17 | D | D | D | D |
| 748 | D | CN | D | P17 | D | D | D |
| 749 | D | CN | D | D | P17 | D | D |
| 750 | D | CN | D | D | D | P17 | D |
| 751 | D | CN | D | D | D | D | P17 |
| 752 | P17 | D | CN | D | D | D | D |
| 753 | D | P17 | CN | D | D | D | D |
| 754 | D | D | CN | P17 | D | D | D |
| 755 | D | D | CN | D | P17 | D | D |
| 756 | D | D | CN | D | D | P17 | D |
| 757 | D | D | CN | D | D | D | P17 |
| 758 | P17 | D | D | CN | D | D | D |
| 759 | D | P17 | D | CN | D | D | D |
| 760 | D | D | P17 | CN | D | D | D |
| 761 | D | D | D | CN | P17 | D | D |
| 762 | D | D | D | CN | D | P17 | D |
| 763 | D | D | D | CN | D | D | P17 |
| 764 | P17 | D | D | D | CN | D | D |
| 765 | D | P17 | D | D | CN | D | D |
| 766 | D | D | P17 | D | CN | D | D |
| 767 | D | D | D | P17 | CN | D | D |
| 768 | D | D | D | D | CN | P17 | D |
| 769 | D | D | D | D | CN | D | P17 |
| 770 | P17 | D | D | D | D | CN | D |
| 771 | D | P17 | D | D | D | CN | D |
| 772 | D | D | P17 | D | D | CN | D |
| 773 | D | D | D | P17 | D | CN | D |
| 774 | D | D | D | D | P17 | CN | D |
| 775 | D | D | D | D | D | CN | P17 |
| 776 | P17 | D | D | D | D | D | CN |
| 777 | D | P17 | D | D | D | D | CN |
| 778 | D | D | P17 | D | D | D | CN |
| 779 | D | D | D | P17 | D | D | CN |
| 780 | D | D | D | D | P17 | D | CN |
| 781 | D | D | D | D | D | P17 | CN |
| 782 | CN | P17 | D | D | D | D | CN |
| 783 | CN | D | P17 | D | D | D | CN |
| 784 | CN | D | D | P17 | D | D | CN |
| 785 | CN | D | D | D | P17 | D | CN |
| 786 | CN | D | D | D | D | P17 | CN |
| 787 | P17 | CN | D | D | D | CN | D |
| 788 | D | CN | P17 | D | D | CN | D |
| 789 | D | CN | D | P17 | D | CN | D |
| 790 | D | CN | D | D | P17 | CN | D |
| 791 | D | CN | D | D | D | CN | P17 |
| 792 | P17 | D | CN | D | CN | D | D |
| 793 | D | P17 | CN | D | CN | D | D |
| 794 | D | D | CN | P17 | CN | D | D |
| 795 | D | D | CN | D | CN | P17 | D |
| 796 | D | D | CN | D | CN | D | P17 |
| 797 | CN | P17 | D | D | D | P17 | CN |
| 798 | CN | D | P17 | D | P17 | D | CN |
| 799 | CN | P17 | D | D | D | P17 | D |
| 800 | CN | D | P17 | D | P17 | D | D |
| 801 | P17 | CN | D | D | D | CN | P17 |
| 802 | D | CN | P17 | D | P17 | CN | D |
| 803 | P17 | D | CN | D | CN | D | P17 |
| 804 | D | P17 | CN | D | CN | P17 | D |
| 805 | P17 | CN | D | D | D | D | P17 |
| 806 | D | CN | P17 | D | P17 | D | D |
| 807 | CN | P17 | P1 | P1 | P1 | P1 | P1 |
| 808 | CN | P1 | P17 | P1 | P1 | P1 | P1 |
| 809 | CN | P1 | P1 | P17 | P1 | P1 | P1 |
| 810 | CN | P1 | P1 | P1 | P17 | P1 | P1 |
| 811 | CN | P1 | P1 | P1 | P1 | P17 | P1 |
| 812 | CN | P1 | P1 | P1 | P1 | P1 | P17 |
| 813 | P17 | CN | P1 | P1 | P1 | P1 | P1 |
| 814 | P1 | CN | P17 | P1 | P1 | P1 | P1 |
| 815 | P1 | CN | P1 | P17 | P1 | P1 | P1 |
| 816 | P1 | CN | P1 | P1 | P17 | P1 | P1 |
| 817 | P1 | CN | P1 | P1 | P1 | P17 | P1 |
| 818 | P1 | CN | P1 | P1 | P1 | P1 | P17 |
| 819 | P17 | P1 | CN | P1 | P1 | P1 | P1 |
| 820 | P1 | P17 | CN | P1 | P1 | P1 | P1 |
| 821 | P1 | P1 | CN | P17 | P1 | P1 | P1 |
| 822 | P1 | P1 | CN | P1 | P17 | P1 | P1 |
| 823 | P1 | P1 | CN | P1 | P1 | P17 | P1 |
| 824 | P1 | P1 | CN | P1 | P1 | P1 | P17 |
| 825 | P17 | P1 | P1 | CN | P1 | P1 | P1 |
| 826 | P1 | P17 | P1 | CN | P1 | P1 | P1 |
| 827 | P1 | P1 | P17 | CN | P1 | P1 | P1 |
| 828 | P1 | P1 | P1 | CN | P17 | P1 | P1 |
| 829 | P1 | P1 | P1 | CN | P1 | P17 | P1 |
| 830 | P1 | P1 | P1 | CN | P1 | P1 | P17 |
| 831 | P17 | P1 | P1 | P1 | CN | P1 | P1 |
| 832 | P1 | P17 | P1 | P1 | CN | P1 | P1 |
| 833 | P1 | P1 | P17 | P1 | CN | P1 | P1 |
| 834 | P1 | P1 | P1 | P17 | CN | P1 | P1 |
| 835 | P1 | P1 | P1 | P1 | CN | P17 | P1 |
| 836 | P1 | P1 | P1 | P1 | CN | P1 | P17 |
| 837 | P17 | P1 | P1 | P1 | P1 | CN | P1 |
| 838 | P1 | P17 | P1 | P1 | P1 | CN | P1 |
| 839 | P1 | P1 | P17 | P1 | P1 | CN | P1 |
| 840 | P1 | P1 | P1 | P17 | P1 | CN | P1 |
| 841 | P1 | P1 | P1 | P1 | P17 | CN | P1 |
| 842 | P1 | P1 | P1 | P1 | P1 | CN | P17 |
| 843 | P17 | P1 | P1 | P1 | P1 | P1 | CN |
| 844 | P1 | P17 | P1 | P1 | P1 | P1 | CN |
| 845 | P1 | P1 | P17 | P1 | P1 | P1 | CN |
| 846 | P1 | P1 | P1 | P17 | P1 | P1 | CN |
| 847 | P1 | P1 | P1 | P1 | P17 | P1 | CN |
| 848 | P1 | P1 | P1 | P1 | P1 | P17 | CN |
| 849 | CN | P17 | P1 | P1 | P1 | P1 | CN |
| 850 | CN | P1 | P17 | P1 | P1 | P1 | CN |
| 851 | CN | P1 | P1 | P17 | P1 | P1 | CN |
| 852 | CN | P1 | P1 | P1 | P17 | P1 | CN |
| 853 | CN | P1 | P1 | P1 | P1 | P17 | CN |
| 854 | P17 | CN | P1 | P1 | P1 | CN | P1 |
| 855 | P1 | CN | P17 | P1 | P1 | CN | P1 |
| 856 | P1 | CN | P1 | P17 | P1 | CN | P1 |
| 857 | P1 | CN | P1 | P1 | P17 | CN | P1 |
| 858 | P1 | CN | P1 | P1 | P1 | CN | P17 |
| 859 | P17 | P1 | CN | P1 | CN | P1 | P1 |
| 860 | P1 | P17 | CN | P1 | CN | P1 | P1 |
| 861 | P1 | P1 | CN | P17 | CN | P1 | P1 |
| 862 | P1 | P1 | CN | P1 | CN | P17 | P1 |
| 863 | P1 | P1 | CN | P1 | CN | P1 | P17 |
| 864 | CN | P17 | P1 | P1 | P1 | P17 | CN |
| 865 | CN | P1 | P17 | P1 | P17 | P1 | CN |
| 866 | CN | P17 | P1 | P1 | P1 | P17 | P1 |
| 867 | CN | P1 | P17 | P1 | P17 | P1 | P1 |
| 868 | P17 | CN | P1 | P1 | P1 | CN | P17 |
| 869 | P1 | CN | P17 | P1 | P17 | CN | P1 |
| 870 | P17 | P1 | CN | P1 | CN | P1 | P17 |
| 871 | P1 | P17 | CN | P1 | CN | P17 | P1 |
| 872 | P17 | CN | P1 | P1 | P1 | P1 | P17 |
| 873 | P1 | CN | P17 | P1 | P17 | P1 | P1 |
| 874 | CN | P17 | P6 | P6 | P6 | P6 | P6 |
| 875 | CN | P6 | P17 | P6 | P6 | P6 | P6 |
| 876 | CN | P6 | P6 | P17 | P6 | P6 | P6 |
| 877 | CN | P6 | P6 | P6 | P17 | P6 | P6 |
| 878 | CN | P6 | P6 | P6 | P6 | P17 | P6 |
| 879 | CN | P6 | P6 | P6 | P6 | P6 | P17 |
| 880 | P17 | CN | P6 | P6 | P6 | P6 | P6 |
| 881 | P6 | CN | P17 | P6 | P6 | P6 | P6 |
| 882 | P6 | CN | P6 | P17 | P6 | P6 | P6 |
| 883 | P6 | CN | P6 | P6 | P17 | P6 | P6 |
| 884 | P6 | CN | P6 | P6 | P6 | P17 | P6 |
| 885 | P6 | CN | P6 | P6 | P6 | P6 | P17 |
| 886 | P17 | P6 | CN | P6 | P6 | P6 | P6 |
| 887 | P6 | P17 | CN | P6 | P6 | P6 | P6 |
| 888 | P6 | P6 | CN | P17 | P6 | P6 | P6 |
| 889 | P6 | P6 | CN | P6 | P17 | P6 | P6 |
| 890 | P6 | P6 | CN | P6 | P6 | P17 | P6 |
| 891 | P6 | P6 | CN | P6 | P6 | P6 | P17 |
| 892 | P17 | P6 | P6 | CN | P6 | P6 | P6 |
| 893 | P6 | P17 | P6 | CN | P6 | P6 | P6 |
| 894 | P6 | P6 | P17 | CN | P6 | P6 | P6 |
| 895 | P6 | P6 | P6 | CN | P17 | P6 | P6 |
| 896 | P6 | P6 | P6 | CN | P6 | P17 | P6 |
| 897 | P6 | P6 | P6 | CN | P6 | P6 | P17 |
| 898 | P17 | P6 | P6 | P6 | CN | P6 | P6 |
| 899 | P6 | P17 | P6 | P6 | CN | P6 | P6 |
| 900 | P6 | P6 | P17 | P6 | CN | P6 | P6 |
| 901 | P6 | P6 | P6 | P17 | CN | P6 | P6 |
| 902 | P6 | P6 | P6 | P6 | CN | P17 | P6 |
| 903 | P6 | P6 | P6 | P6 | CN | P6 | P17 |
| 904 | P17 | P6 | P6 | P6 | P6 | CN | P6 |
| 905 | P6 | P17 | P6 | P6 | P6 | CN | P6 |
| 906 | P6 | P6 | P17 | P6 | P6 | CN | P6 |
| 907 | P6 | P6 | P6 | P17 | P6 | CN | P6 |
| 908 | P6 | P6 | P6 | P6 | P17 | CN | P6 |
| 909 | P6 | P6 | P6 | P6 | P6 | CN | P17 |
| 910 | P17 | P6 | P6 | P6 | P6 | P6 | CN |
| 911 | P6 | P17 | P6 | P6 | P6 | P6 | CN |
| 912 | P6 | P6 | P17 | P6 | P6 | P6 | CN |
| 913 | P6 | P6 | P6 | P17 | P6 | P6 | CN |
| 914 | P6 | P6 | P6 | P6 | P17 | P6 | CN |
| 915 | P6 | P6 | P6 | P6 | P6 | P17 | CN |
| 916 | CN | P17 | P6 | P6 | P6 | P6 | CN |
| 917 | CN | P6 | P17 | P6 | P6 | P6 | CN |
| 918 | CN | P6 | P6 | P17 | P6 | P6 | CN |
| 919 | CN | P6 | P6 | P6 | P17 | P6 | CN |
| 920 | CN | P6 | P6 | P6 | P6 | P17 | CN |
| 921 | P17 | CN | P6 | P6 | P6 | CN | P6 |
| 922 | P6 | CN | P17 | P6 | P6 | CN | P6 |
| 923 | P6 | CN | P6 | P17 | P6 | CN | P6 |
| 924 | P6 | CN | P6 | P6 | P17 | CN | P6 |
| 925 | P6 | CN | P6 | P6 | P6 | CN | P17 |
| 926 | P17 | P6 | CN | P6 | CN | P6 | P6 |
| 927 | P6 | P17 | CN | P6 | CN | P6 | P6 |
| 928 | P6 | P6 | CN | P17 | CN | P6 | P6 |
| 929 | P6 | P6 | CN | P6 | CN | P17 | P6 |
| 930 | P6 | P6 | CN | P6 | CN | P6 | P17 |
| 931 | CN | P17 | P6 | P6 | P6 | P17 | CN |
| 932 | CN | P6 | P17 | P6 | P17 | P6 | CN |
| 933 | CN | P17 | P6 | P6 | P6 | P17 | P6 |
| 934 | CN | P6 | P17 | P6 | P17 | P6 | P6 |
| 935 | P17 | CN | P6 | P6 | P6 | CN | P17 |
| 936 | P6 | CN | P17 | P6 | P17 | CN | P6 |
| 937 | P17 | P6 | CN | P6 | CN | P6 | P17 |
| 938 | P6 | P17 | CN | P6 | CN | P17 | P6 |
| 939 | P17 | CN | P6 | P6 | P6 | P6 | P17 |
| 940 | P6 | CN | P17 | P6 | P17 | P6 | P6 |
| 941 | H | P17 | CN | P1 | H | H | H |
| 942 | H | P17 | CN | P2 | H | H | H |
| 943 | H | P17 | CN | P3 | H | H | H |
| 944 | H | P17 | CN | P4 | H | H | H |
| 945 | H | P17 | CN | P5 | H | H | H |
| 946 | H | P17 | CN | P6 | H | H | H |
| 947 | H | P17 | CN | P7 | H | H | H |
| 948 | H | P17 | CN | P8 | H | H | H |
| 949 | H | P17 | CN | P9 | H | H | H |
| 950 | H | P17 | CN | P10 | H | H | H |
| 951 | H | P17 | CN | P11 | H | H | H |
| 952 | H | P17 | CN | P12 | H | H | H |
| 953 | H | P17 | CN | P13 | H | H | H |
| 954 | H | P17 | CN | P14 | H | H | H |
| 955 | H | P17 | CN | P15 | H | H | H |
| 956 | H | P17 | CN | P16 | H | H | H |
| 957 | H | P17 | CN | P18 | H | H | H |
| 958 | CN | H | P17 | P1 | P17 | H | CN |
| 959 | CN | H | P17 | P2 | P17 | H | CN |
| 960 | CN | H | P17 | P3 | P17 | H | CN |
| 961 | CN | H | P17 | P4 | P17 | H | CN |
| 962 | CN | H | P17 | P5 | P17 | H | CN |
| 963 | CN | H | P17 | P6 | P17 | H | CN |
| 964 | CN | H | P17 | P7 | P17 | H | CN |
| 965 | CN | H | P17 | P8 | P17 | H | CN |
| 966 | CN | H | P17 | P9 | P17 | H | CN |
| 967 | CN | H | P17 | P10 | P17 | H | CN |
| 968 | CN | H | P17 | P11 | P17 | H | CN |
| 969 | CN | H | P17 | P12 | P17 | H | CN |
| 970 | CN | H | P17 | P13 | P17 | H | CN |
| 971 | CN | H | P17 | P14 | P17 | H | CN |
| 972 | CN | H | P17 | P15 | P17 | H | CN |
| 973 | CN | H | P17 | P16 | P17 | H | CN |
| 974 | CN | H | P17 | P18 | P17 | H | CN |
| 975 | P6 | P17 | CN | P1 | P6 | P6 | P6 |
| 976 | P6 | P17 | CN | P2 | P6 | P6 | P6 |
| 977 | P6 | P17 | CN | P3 | P6 | P6 | P6 |
| 978 | P6 | P17 | CN | P4 | P6 | P6 | P6 |
| 979 | P6 | P17 | CN | P5 | P6 | P6 | P6 |
| 980 | P6 | P17 | CN | P6 | P6 | P6 | P6 |
| 981 | P6 | P17 | CN | P7 | P6 | P6 | P6 |
| 982 | P6 | P17 | CN | P8 | P6 | P6 | P6 |
| 983 | P6 | P17 | CN | P9 | P6 | P6 | P6 |
| 984 | P6 | P17 | CN | P10 | P6 | P6 | P6 |
| 985 | P6 | P17 | CN | P11 | P6 | P6 | P6 |
| 986 | P6 | P17 | CN | P12 | P6 | P6 | P6 |
| 987 | P6 | P17 | CN | P13 | P6 | P6 | P6 |
| 988 | P6 | P17 | CN | P14 | P6 | P6 | P6 |
| 989 | P6 | P17 | CN | P15 | P6 | P6 | P6 |
| 990 | P6 | P6 | CN | P16 | CN | P6 | P6 |
| 991 | P6 | P17 | CN | P18 | P6 | P6 | P6 |
| 992 | CN | P6 | P17 | P1 | P17 | P6 | CN |
| 993 | CN | P6 | P17 | P2 | P17 | P6 | CN |
| 994 | CN | P6 | P17 | P3 | P17 | P6 | CN |
| 995 | CN | P6 | P17 | P4 | P17 | P6 | CN |
| 996 | CN | P6 | P17 | P5 | P17 | P6 | CN |
| 997 | CN | P6 | P17 | P6 | P17 | P6 | CN |
| 998 | CN | P6 | P17 | P7 | P17 | P6 | CN |
| 999 | CN | P6 | P17 | P8 | P17 | P6 | CN |
| 1000 | CN | P6 | P17 | P9 | P17 | P6 | CN |
| 1001 | CN | P6 | P17 | P10 | P17 | P6 | CN |
| 1002 | CN | P6 | P17 | P11 | P17 | P6 | CN |
| 1003 | CN | P6 | P17 | P12 | P17 | P6 | CN |
| 1004 | CN | P6 | P17 | P13 | P17 | P6 | CN |
| 1005 | CN | P6 | P17 | P14 | P17 | P6 | CN |
| 1006 | CN | P6 | P17 | P15 | P17 | P6 | CN |
| 1007 | CN | P6 | P17 | P16 | P17 | P6 | CN |
| 1008 | CN | P6 | P17 | P18 | P17 | P6 | CN |

wherein P1 to P18 have the following structures: 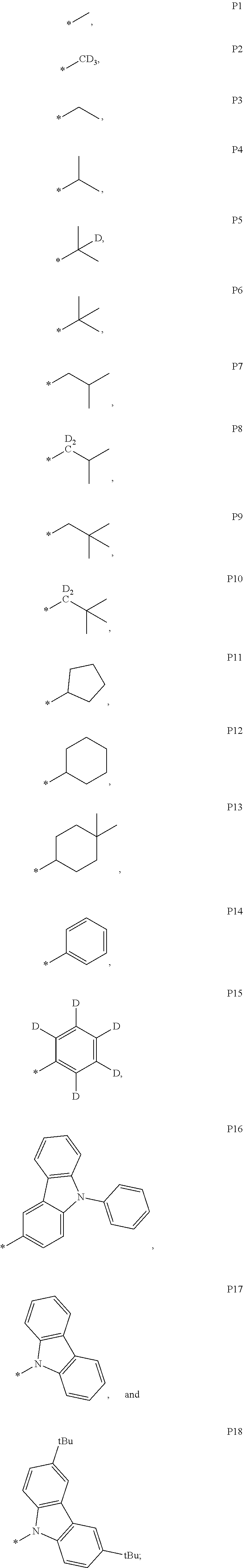
wherein optionally, hydrogens in the Compound BN-1-1-k₁ to Compound BN-1-22-k₁ can be partially or fully substituted with deuterium.

12. An organic electroluminescent device, comprising:
an anode,
a cathode, and
an organic layer disposed between the anode and the cathode, wherein the organic layer comprises the compound of claim 1.

13. The organic electroluminescent device of claim 12, wherein the organic layer is a light-emitting layer, and the compound is a light-emitting material.

14. The organic electroluminescent device of claim 13, wherein the light-emitting layer at least comprises a first host material or comprises a first host material and a second host material;
preferably, the first host material has a structure represented by Formula PH-1, Formula PH-2 or Formula PH-3: 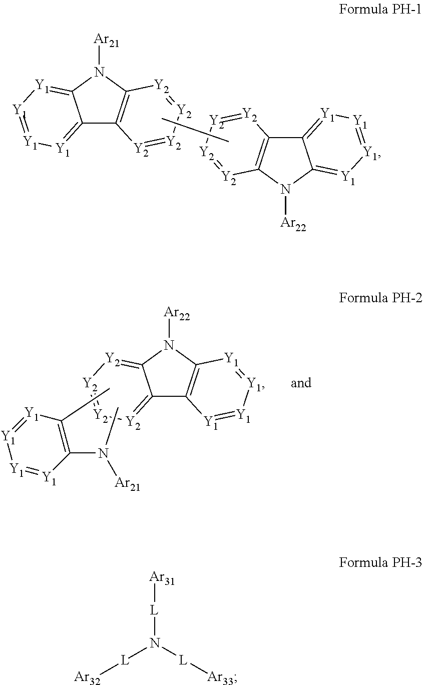
wherein Y₁ is, at each occurrence identically or differently, selected from CR_{y} or N;
Y₂ is, at each occurrence identically or differently, selected from C, CR_{y} or N;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar₂₁, Ar₂₂, Ar₃₁, Ar₃₂ and Ar₃₃ are, at each occurrence identically or differently, selected from substituted or unsubstituted aryl having 6 to 30 carbon atoms or substituted or unsubstituted heteroaryl having 3 to 30 carbon atoms;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} can be optionally joined to form a ring;
the second host material has a structure represented by Formula NH-1: 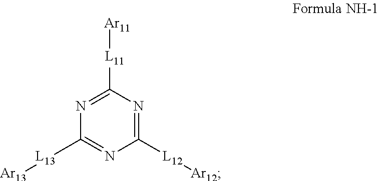
wherein L₁₁ to L₁₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof; and
Ar₁₁ to Ar₁₃ are, at each occurrence identically or differently, selected from substituted or unsubstituted aryl having 6 to 30 carbon atoms, substituted or unsubstituted heteroaryl having 3 to 30 carbon atoms, or a combination thereof;
more preferably, the first host material is selected from the group consisting of Compound 1-1-1 to Compound 1-1-104, Compound 1-2-1 to Compound 1-2-100 and Compound 1-3-1 to Compound 1-3-110: 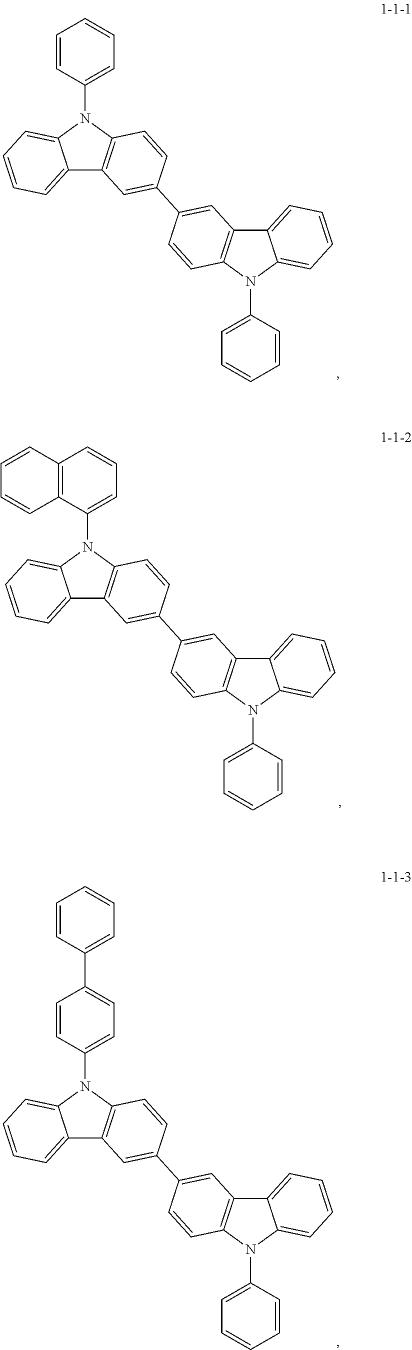 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccccc5)ccc43)cc2)cc1] 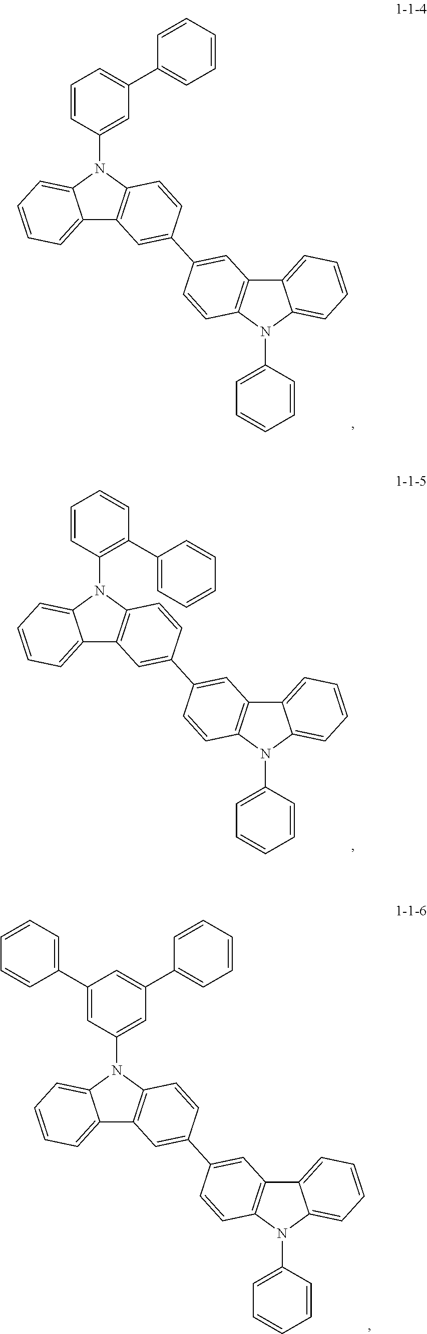 [SMILES: c1ccc(-c2cccc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccccc4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1] 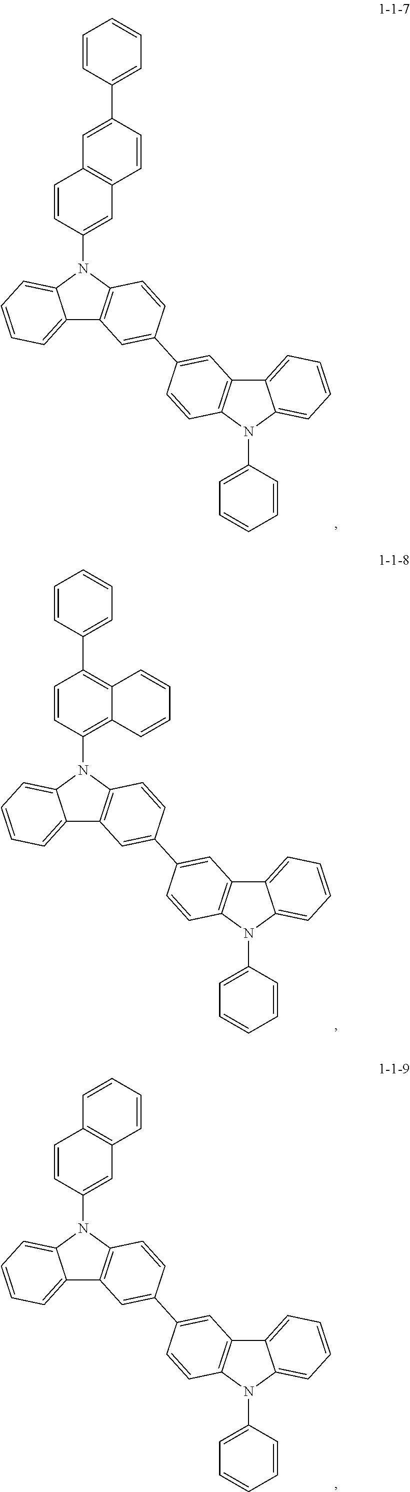 [SMILES: c1ccc(-c2ccc3cc(-n4c5ccccc5c5cc(-c6ccc7c(c6)c6ccccc6n7-c6ccccc6)ccc54)ccc3c2)cc1 ; c1ccc(-c2ccc(-n3c4ccccc4c4cc(-c5ccc6c(c5)c5ccccc5n6-c5ccccc5)ccc43)c3ccccc23)cc1 ; c1ccc(-n2c3ccccc3c3cc(-c4ccc5c(c4)c4ccccc4n5-c4ccc5ccccc5c4)ccc32)cc1] 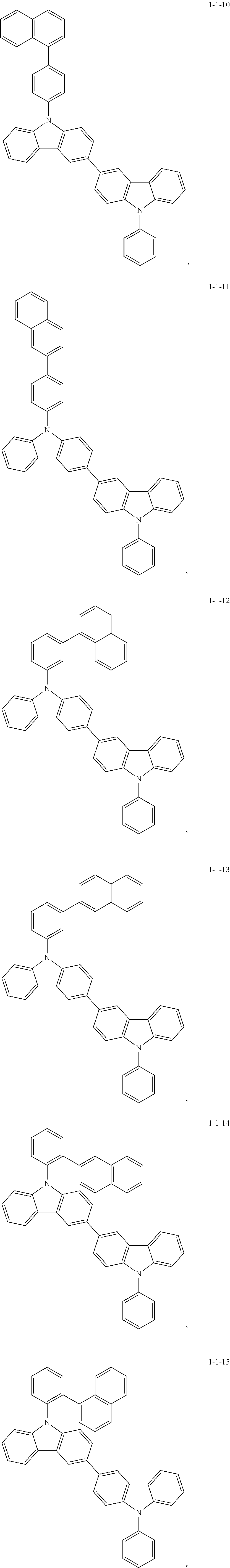 [SMILES: c1ccc(-n2c3ccccc3c3cc(-c4ccc5c(c4)c4ccccc4n5-c4ccc(-c5cccc6ccccc56)cc4)ccc32)cc1 ; c1ccc(-n2c3ccccc3c3cc(-c4ccc5c(c4)c4ccccc4n5-c4ccc(-c5ccc6ccccc6c5)cc4)ccc32)cc1 ; c1ccc(-n2c3ccccc3c3cc(-c4ccc5c(c4)c4ccccc4n5-c4cccc(-c5cccc6ccccc56)c4)ccc32)cc1 ; c1ccc(-n2c3ccccc3c3cc(-c4ccc5c(c4)c4ccccc4n5-c4cccc(-c5ccc6ccccc6c5)c4)ccc32)cc1 ; c1ccc(-n2c3ccccc3c3cc(-c4ccc5c(c4)c4ccccc4n5-c4ccccc4-c4ccc5ccccc5c4)ccc32)cc1 ; c1ccc(-n2c3ccccc3c3cc(-c4ccc5c(c4)c4ccccc4n5-c4ccccc4-c4cccc5ccccc45)ccc32)cc1] 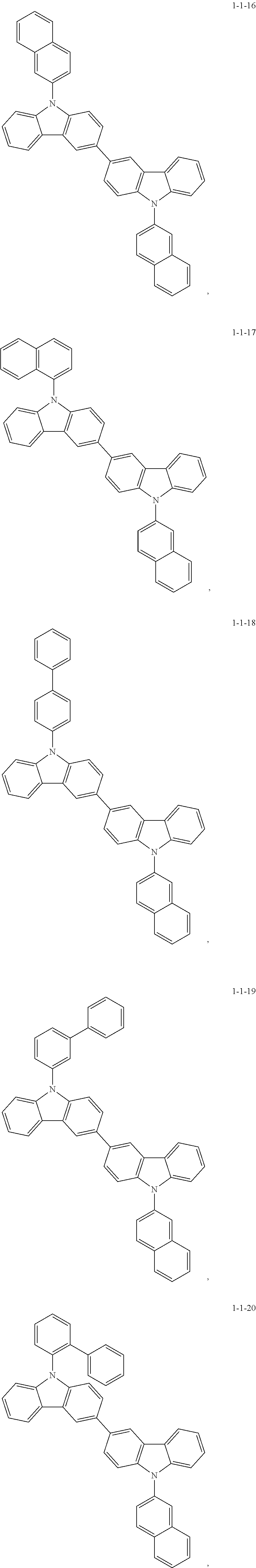 [SMILES: c1ccc2cc(-n3c4ccccc4c4cc(-c5ccc6c(c5)c5ccccc5n6-c5ccc6ccccc6c5)ccc43)ccc2c1 ; c1ccc2cc(-n3c4ccccc4c4cc(-c5ccc6c(c5)c5ccccc5n6-c5cccc6ccccc56)ccc43)ccc2c1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccc5ccccc5c4)ccc32)cc1] 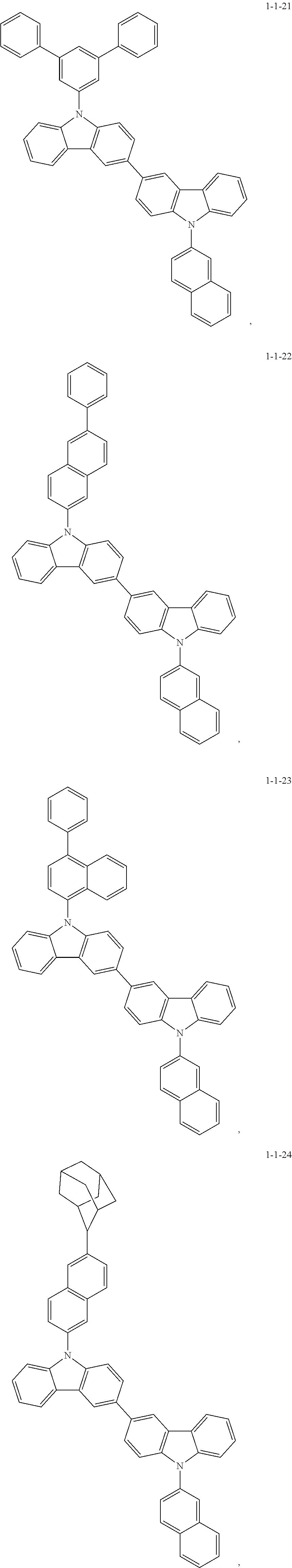 [SMILES: c1ccc(-c2cc(-c3ccccc3)cc(-n3c4ccccc4c4cc(-c5ccc6c(c5)c5ccccc5n6-c5ccc6ccccc6c5)ccc43)c2)cc1 ; c1ccc(-c2ccc3cc(-n4c5ccccc5c5cc(-c6ccc7c(c6)c6ccccc6n7-c6ccc7ccccc7c6)ccc54)ccc3c2)cc1 ; c1ccc(-c2ccc(-n3c4ccccc4c4cc(-c5ccc6c(c5)c5ccccc5n6-c5ccc6ccccc6c5)ccc43)c3ccccc23)cc1 ; c1ccc2cc(-n3c4ccccc4c4cc(-c5ccc6c(c5)c5ccccc5n6-c5ccc6cc(C7C8CC9CC(C8)CC7C9)ccc6c5)ccc43)ccc2c1] 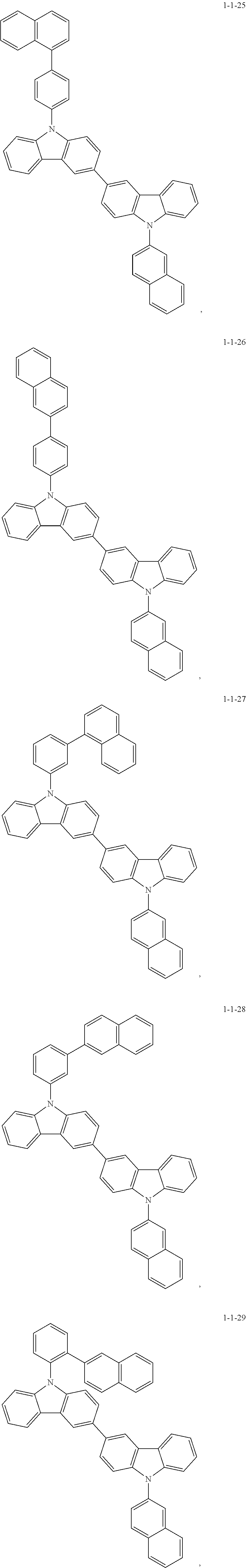 [SMILES: c1ccc2cc(-n3c4ccccc4c4cc(-c5ccc6c(c5)c5ccccc5n6-c5ccc(-c6cccc7ccccc67)cc5)ccc43)ccc2c1 ; c1ccc2cc(-c3ccc(-n4c5ccccc5c5cc(-c6ccc7c(c6)c6ccccc6n7-c6ccc7ccccc7c6)ccc54)cc3)ccc2c1 ; c1cc(-c2cccc3ccccc23)cc(-n2c3ccccc3c3cc(-c4ccc5c(c4)c4ccccc4n5-c4ccc5ccccc5c4)ccc32)c1 ; c1cc(-c2ccc3ccccc3c2)cc(-n2c3ccccc3c3cc(-c4ccc5c(c4)c4ccccc4n5-c4ccc5ccccc5c4)ccc32)c1 ; c1ccc(-n2c3ccccc3c3cc(-c4ccc5c(c4)c4ccccc4n5-c4ccc5ccccc5c4)ccc32)c(-c2ccc3ccccc3c2)c1] 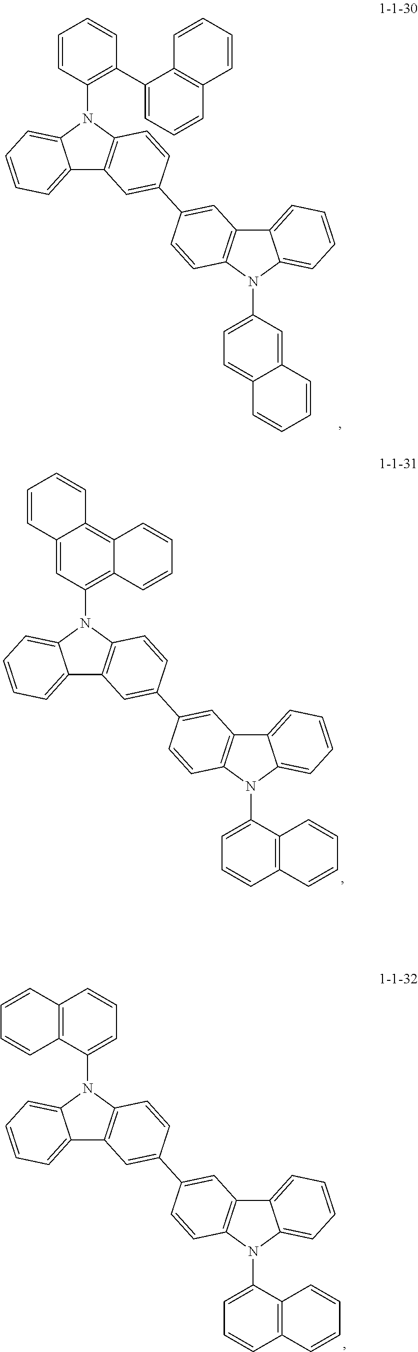 [SMILES: c1ccc(-n2c3ccccc3c3cc(-c4ccc5c(c4)c4ccccc4n5-c4ccc5ccccc5c4)ccc32)c(-c2cccc3ccccc23)c1 ; c1ccc2c(-n3c4ccccc4c4cc(-c5ccc6c(c5)c5ccccc5n6-c5cc6ccccc6c6ccccc56)ccc43)cccc2c1 ; c1ccc2c(-n3c4ccccc4c4cc(-c5ccc6c(c5)c5ccccc5n6-c5cccc6ccccc56)ccc43)cccc2c1] 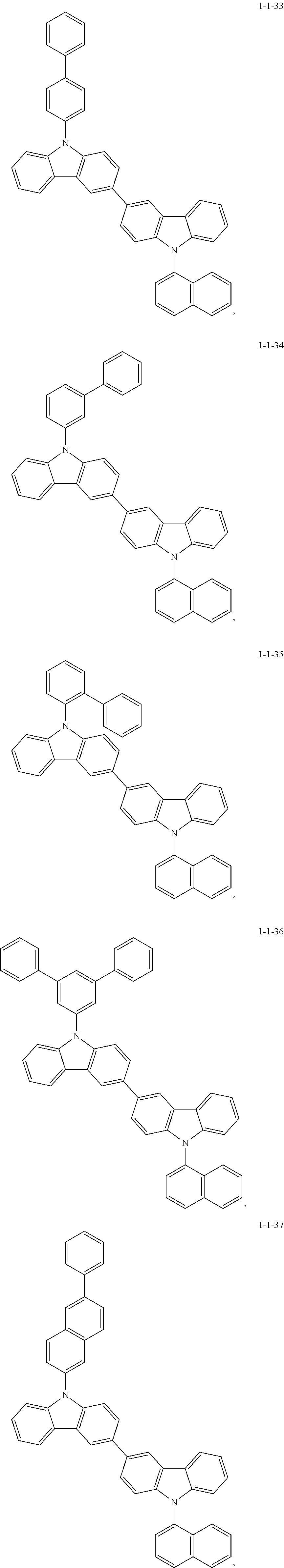 [SMILES: c1ccc(-c2ccc(-n3c4ccccc4c4cc(-c5ccc6c(c5)c5ccccc5n6-c5cccc6ccccc56)ccc43)cc2)cc1 ; c1ccc(-c2cccc(-n3c4ccccc4c4cc(-c5ccc6c(c5)c5ccccc5n6-c5cccc6ccccc56)ccc43)c2)cc1 ; c1ccc(-c2ccccc2-n2c3ccccc3c3cc(-c4ccc5c(c4)c4ccccc4n5-c4cccc5ccccc45)ccc32)cc1 ; c1ccc(-c2cc(-c3ccccc3)cc(-n3c4ccccc4c4cc(-c5ccc6c(c5)c5ccccc5n6-c5cccc6ccccc56)ccc43)c2)cc1 ; c1ccc(-c2ccc3cc(-n4c5ccccc5c5cc(-c6ccc7c(c6)c6ccccc6n7-c6cccc7ccccc67)ccc54)ccc3c2)cc1] 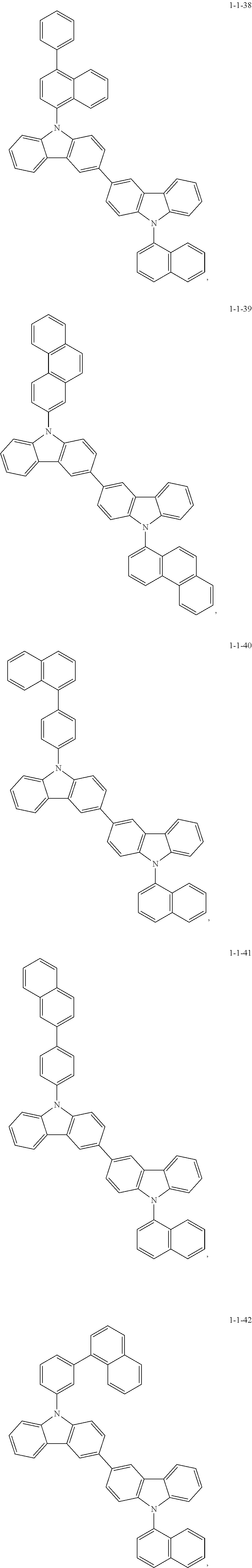 [SMILES: c1ccc(-c2ccc(-n3c4ccccc4c4cc(-c5ccc6c(c5)c5ccccc5n6-c5cccc6ccccc56)ccc43)c3ccccc23)cc1 ; c1ccc2c(c1)ccc1cc(-n3c4ccccc4c4cc(-c5ccc6c(c5)c5ccccc5n6-c5cccc6c5ccc5ccccc56)ccc43)ccc12 ; c1ccc2c(-c3ccc(-n4c5ccccc5c5cc(-c6ccc7c(c6)c6ccccc6n7-c6cccc7ccccc67)ccc54)cc3)cccc2c1 ; c1ccc2cc(-c3ccc(-n4c5ccccc5c5cc(-c6ccc7c(c6)c6ccccc6n7-c6cccc7ccccc67)ccc54)cc3)ccc2c1 ; c1cc(-c2cccc3ccccc23)cc(-n2c3ccccc3c3cc(-c4ccc5c(c4)c4ccccc4n5-c4cccc5ccccc45)ccc32)c1] 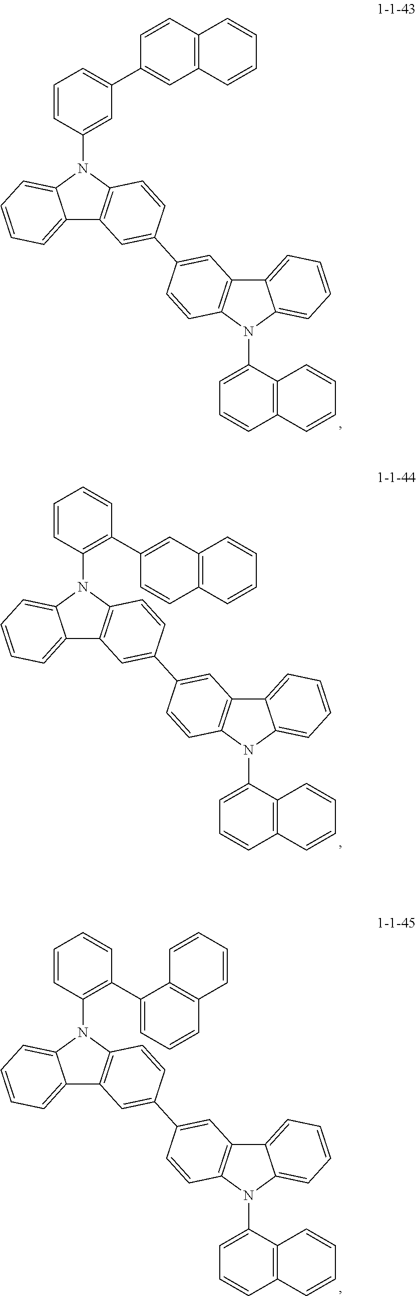 [SMILES: c1cc(-c2ccc3ccccc3c2)cc(-n2c3ccccc3c3cc(-c4ccc5c(c4)c4ccccc4n5-c4cccc5ccccc45)ccc32)c1 ; c1ccc(-n2c3ccccc3c3cc(-c4ccc5c(c4)c4ccccc4n5-c4cccc5ccccc45)ccc32)c(-c2ccc3ccccc3c2)c1 ; c1ccc(-n2c3ccccc3c3cc(-c4ccc5c(c4)c4ccccc4n5-c4cccc5ccccc45)ccc32)c(-c2cccc3ccccc23)c1] 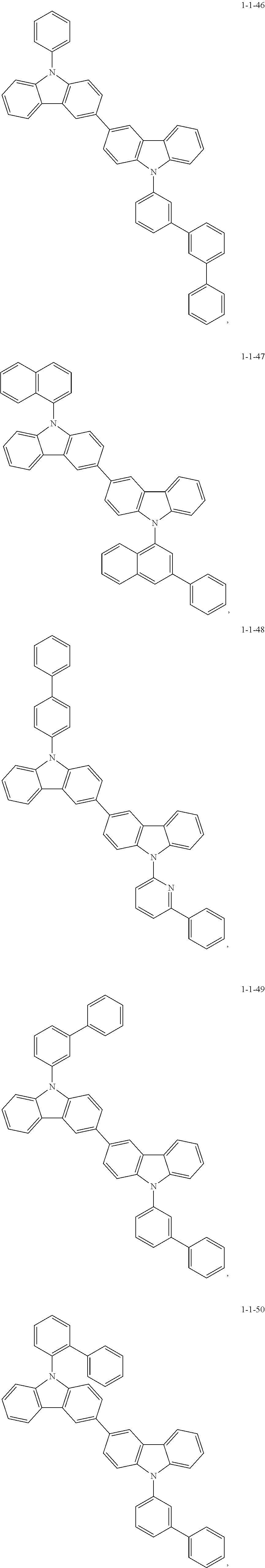 [SMILES: c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cc(-n3c4ccccc4c4cc(-c5ccc6c(c5)c5ccccc5n6-c5cccc6ccccc56)ccc43)c3ccccc3c2)cc1 ; c1ccc(-c2ccc(-n3c4ccccc4c4cc(-c5ccc6c(c5)c5ccccc5n6-c5cccc(-c6ccccc6)n5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1] 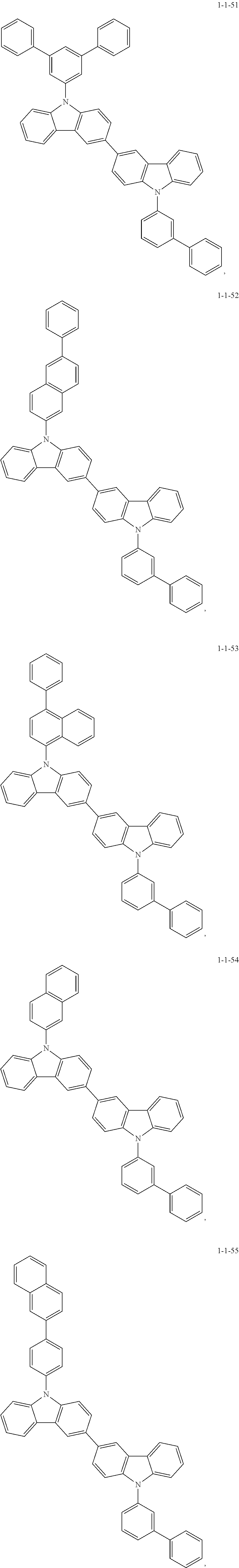 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1 ; c1ccc(-c2cccc(-n3c4ccccc4c4cc(-c5ccc6c(c5)c5ccccc5n6-c5ccc6cc(-c7ccccc7)ccc6c5)ccc43)c2)cc1 ; c1ccc(-c2cccc(-n3c4ccccc4c4cc(-c5ccc6c(c5)c5ccccc5n6-c5ccc(-c6ccccc6)c6ccccc56)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2cccc(-n3c4ccccc4c4cc(-c5ccc6c(c5)c5ccccc5n6-c5ccc(-c6ccc7ccccc7c6)cc5)ccc43)c2)cc1] 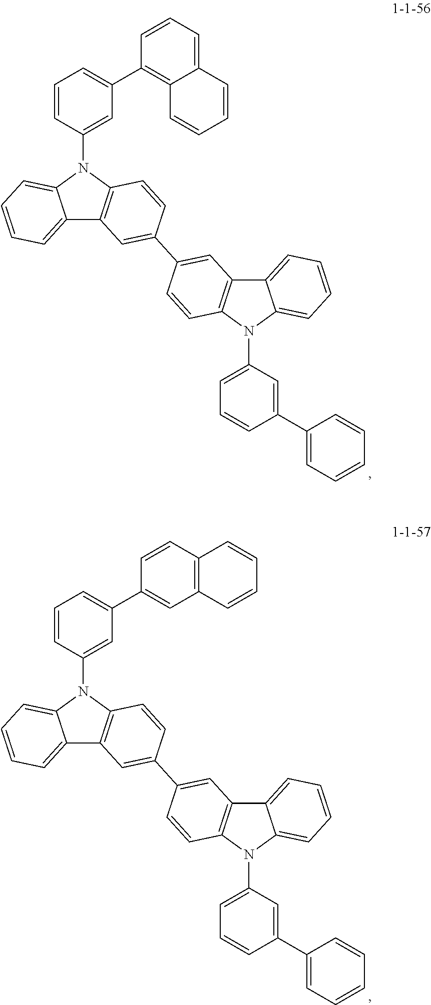 [SMILES: c1ccc(-c2cccc(-n3c4ccccc4c4cc(-c5ccc6c(c5)c5ccccc5n6-c5cccc(-c6cccc7ccccc67)c5)ccc43)c2)cc1 ; c1ccc(-c2cccc(-n3c4ccccc4c4cc(-c5ccc6c(c5)c5ccccc5n6-c5cccc(-c6ccc7ccccc7c6)c5)ccc43)c2)cc1] 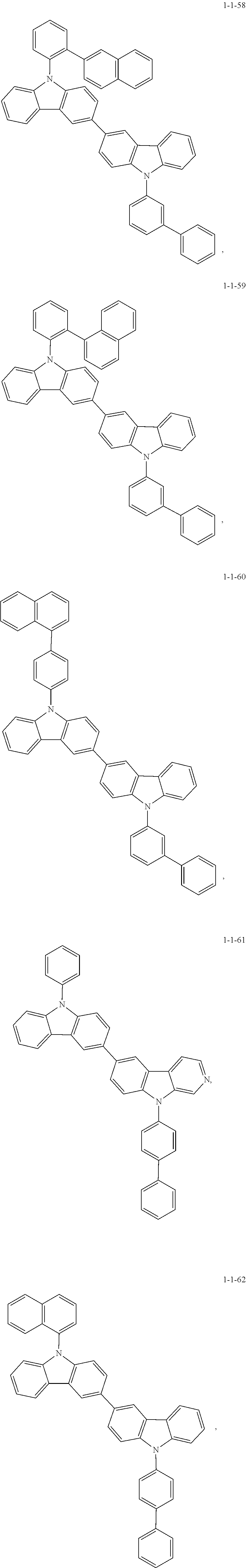 [SMILES: c1ccc(-c2cccc(-n3c4ccccc4c4cc(-c5ccc6c(c5)c5ccccc5n6-c5ccccc5-c5ccc6ccccc6c5)ccc43)c2)cc1 ; c1ccc(-c2cccc(-n3c4ccccc4c4cc(-c5ccc6c(c5)c5ccccc5n6-c5ccccc5-c5cccc6ccccc56)ccc43)c2)cc1 ; c1ccc(-c2cccc(-n3c4ccccc4c4cc(-c5ccc6c(c5)c5ccccc5n6-c5ccc(-c6cccc7ccccc67)cc5)ccc43)c2)cc1 ; c1ccc(-c2ccc(-n3c4ccc(-c5ccc6c(c5)c5ccccc5n6-c5ccccc5)cc4c4ccncc43)cc2)cc1 ; c1ccc(-c2ccc(-n3c4ccccc4c4cc(-c5ccc6c(c5)c5ccccc5n6-c5cccc6ccccc56)ccc43)cc2)cc1] 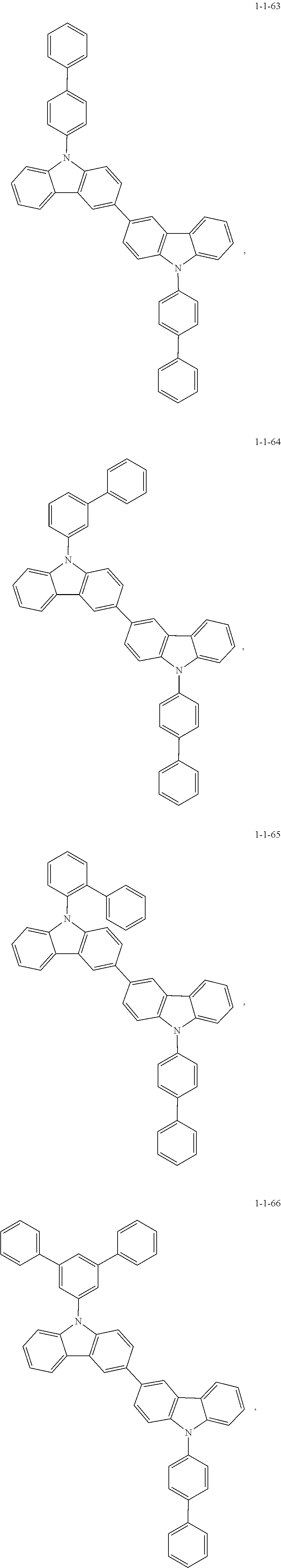 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1] 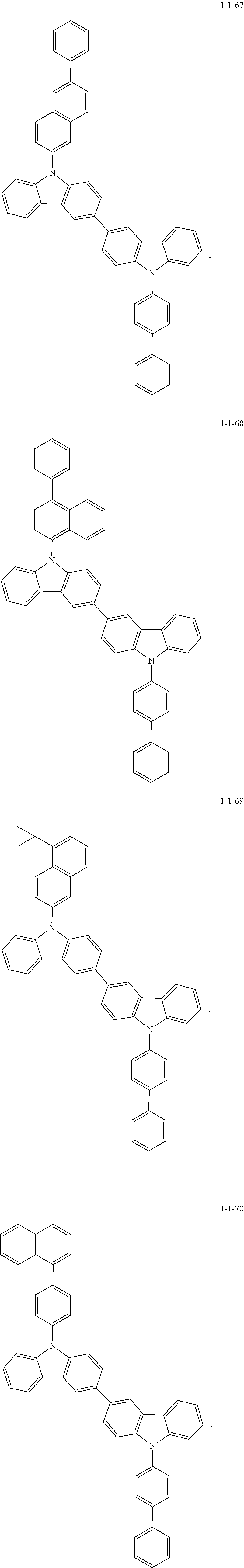 [SMILES: c1ccc(-c2ccc(-n3c4ccccc4c4cc(-c5ccc6c(c5)c5ccccc5n6-c5ccc6cc(-c7ccccc7)ccc6c5)ccc43)cc2)cc1 ; c1ccc(-c2ccc(-n3c4ccccc4c4cc(-c5ccc6c(c5)c5ccccc5n6-c5ccc(-c6ccccc6)c6ccccc56)ccc43)cc2)cc1 ; CC(C)(C)c1cccc2cc(-n3c4ccccc4c4cc(-c5ccc6c(c5)c5ccccc5n6-c5ccc(-c6ccccc6)cc5)ccc43)ccc12 ; c1ccc(-c2ccc(-n3c4ccccc4c4cc(-c5ccc6c(c5)c5ccccc5n6-c5ccc(-c6cccc7ccccc67)cc5)ccc43)cc2)cc1] 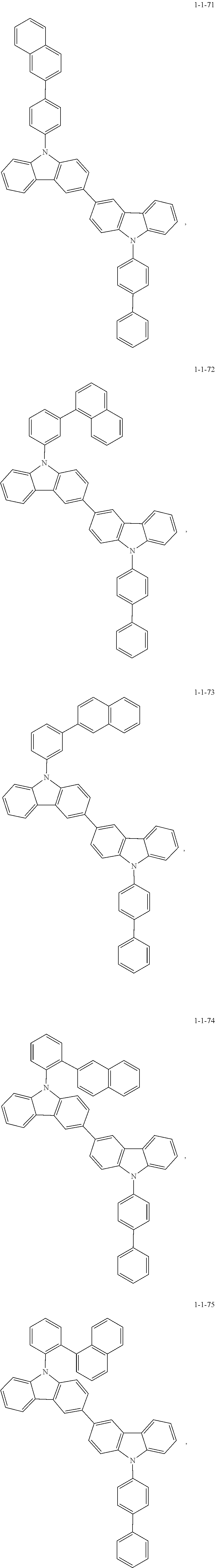 [SMILES: c1ccc(-c2ccc(-n3c4ccccc4c4cc(-c5ccc6c(c5)c5ccccc5n6-c5ccc(-c6ccc7ccccc7c6)cc5)ccc43)cc2)cc1 ; c1ccc(-c2ccc(-n3c4ccccc4c4cc(-c5ccc6c(c5)c5ccccc5n6-c5cccc(-c6cccc7ccccc67)c5)ccc43)cc2)cc1 ; c1ccc(-c2ccc(-n3c4ccccc4c4cc(-c5ccc6c(c5)c5ccccc5n6-c5cccc(-c6ccc7ccccc7c6)c5)ccc43)cc2)cc1 ; c1ccc(-c2ccc(-n3c4ccccc4c4cc(-c5ccc6c(c5)c5ccccc5n6-c5ccccc5-c5ccc6ccccc6c5)ccc43)cc2)cc1 ; c1ccc(-c2ccc(-n3c4ccccc4c4cc(-c5ccc6c(c5)c5ccccc5n6-c5ccccc5-c5cccc6ccccc56)ccc43)cc2)cc1] 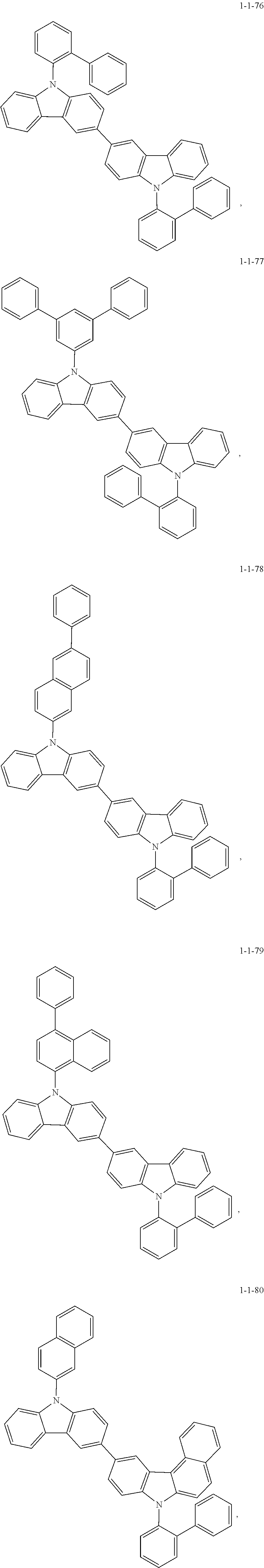 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2cc(-c3ccccc3)cc(-n3c4ccccc4c4cc(-c5ccc6c(c5)c5ccccc5n6-c5ccccc5-c5ccccc5)ccc43)c2)cc1 ; c1ccc(-c2ccc3cc(-n4c5ccccc5c5cc(-c6ccc7c(c6)c6ccccc6n7-c6ccccc6-c6ccccc6)ccc54)ccc3c2)cc1 ; c1ccc(-c2ccccc2-n2c3ccccc3c3cc(-c4ccc5c(c4)c4ccccc4n5-c4ccc(-c5ccccc5)c5ccccc45)ccc32)cc1 ; c1ccc(-c2ccccc2-n2c3ccc(-c4ccc5c(c4)c4ccccc4n5-c4ccc5ccccc5c4)cc3c3c4ccccc4ccc32)cc1] 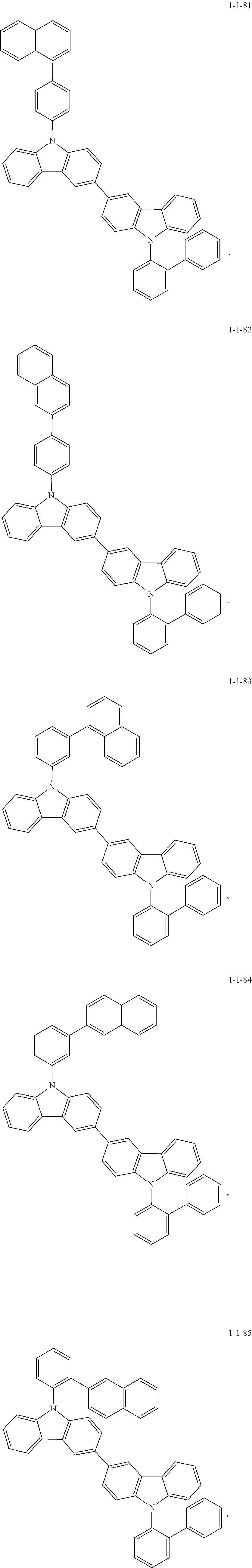 [SMILES: c1ccc(-c2ccccc2-n2c3ccccc3c3cc(-c4ccc5c(c4)c4ccccc4n5-c4ccc(-c5cccc6ccccc56)cc4)ccc32)cc1 ; c1ccc(-c2ccccc2-n2c3ccccc3c3cc(-c4ccc5c(c4)c4ccccc4n5-c4ccc(-c5ccc6ccccc6c5)cc4)ccc32)cc1 ; c1ccc(-c2ccccc2-n2c3ccccc3c3cc(-c4ccc5c(c4)c4ccccc4n5-c4cccc(-c5cccc6ccccc56)c4)ccc32)cc1 ; c1ccc(-c2ccccc2-n2c3ccccc3c3cc(-c4ccc5c(c4)c4ccccc4n5-c4cccc(-c5ccc6ccccc6c5)c4)ccc32)cc1 ; c1ccc(-c2ccccc2-n2c3ccccc3c3cc(-c4ccc5c(c4)c4ccccc4n5-c4ccccc4-c4ccc5ccccc5c4)ccc32)cc1] 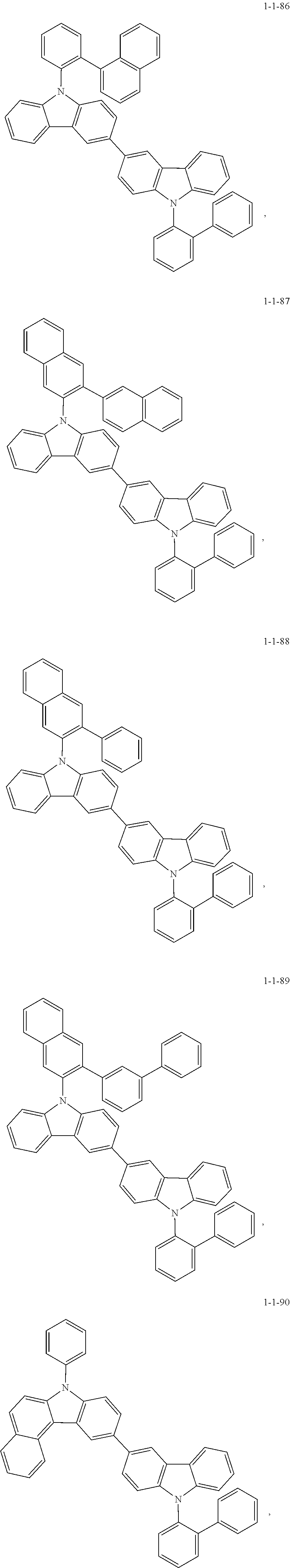 [SMILES: c1ccc(-c2ccccc2-n2c3ccccc3c3cc(-c4ccc5c(c4)c4ccccc4n5-c4ccccc4-c4cccc5ccccc45)ccc32)cc1 ; c1ccc(-c2ccccc2-n2c3ccccc3c3cc(-c4ccc5c(c4)c4ccccc4n5-c4cc5ccccc5cc4-c4ccc5ccccc5c4)ccc32)cc1 ; c1ccc(-c2ccccc2-n2c3ccccc3c3cc(-c4ccc5c(c4)c4ccccc4n5-c4cc5ccccc5cc4-c4ccccc4)ccc32)cc1 ; c1ccc(-c2cccc(-c3cc4ccccc4cc3-n3c4ccccc4c4cc(-c5ccc6c(c5)c5ccccc5n6-c5ccccc5-c5ccccc5)ccc43)c2)cc1 ; c1ccc(-c2ccccc2-n2c3ccccc3c3cc(-c4ccc5c(c4)c4c6ccccc6ccc4n5-c4ccccc4)ccc32)cc1] 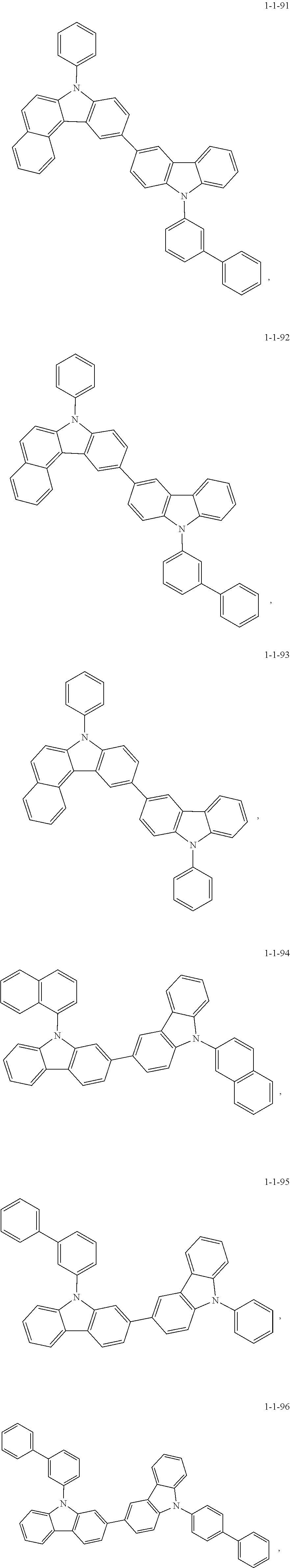 [SMILES: c1ccc(-c2cccc(-n3c4ccccc4c4cc(-c5ccc6c(c5)c5c7ccccc7ccc5n6-c5ccccc5)ccc43)c2)cc1 ; c1ccc(-c2cccc(-n3c4ccccc4c4cc(-c5ccc6c(c5)c5c7ccccc7ccc5n6-c5ccccc5)ccc43)c2)cc1 ; c1ccc(-n2c3ccccc3c3cc(-c4ccc5c(c4)c4c6ccccc6ccc4n5-c4ccccc4)ccc32)cc1 ; c1ccc2cc(-n3c4ccccc4c4cc(-c5ccc6c7ccccc7n(-c7cccc8ccccc78)c6c5)ccc43)ccc2c1 ; c1ccc(-c2cccc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cccc(-c8ccccc8)c7)c6c5)ccc43)cc2)cc1] 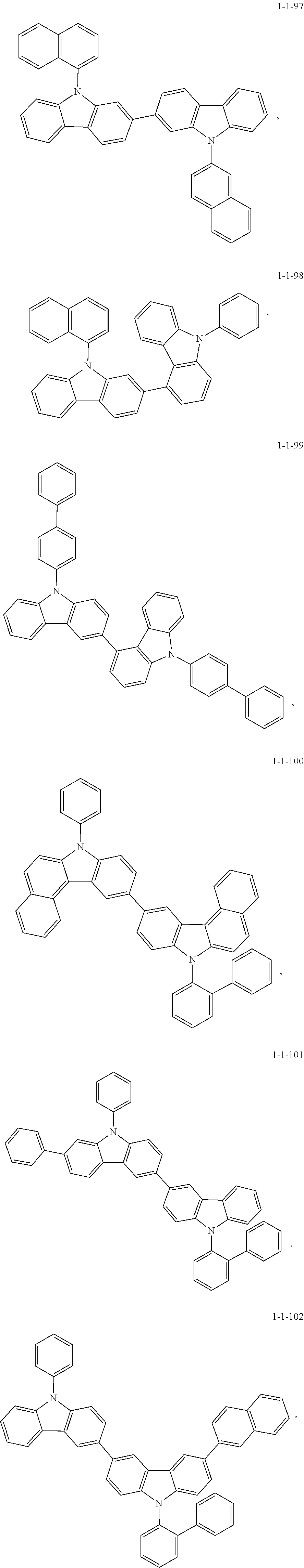 [SMILES: c1ccc2cc(-n3c4ccccc4c4ccc(-c5ccc6c7ccccc7n(-c7cccc8ccccc78)c6c5)cc43)ccc2c1 ; c1ccc(-n2c3ccccc3c3c(-c4ccc5c6ccccc6n(-c6cccc7ccccc67)c5c4)cccc32)cc1 ; c1ccc(-c2ccc(-n3c4ccccc4c4cc(-c5cccc6c5c5ccccc5n6-c5ccc(-c6ccccc6)cc5)ccc43)cc2)cc1 ; c1ccc(-c2ccccc2-n2c3ccc(-c4ccc5c(c4)c4c6ccccc6ccc4n5-c4ccccc4)cc3c3c4ccccc4ccc32)cc1 ; c1ccc(-c2ccc3c4cc(-c5ccc6c(c5)c5ccccc5n6-c5ccccc5-c5ccccc5)ccc4n(-c4ccccc4)c3c2)cc1 ; c1ccc(-c2ccccc2-n2c3ccc(-c4ccc5ccccc5c4)cc3c3cc(-c4ccc5c(c4)c4ccccc4n5-c4ccccc4)ccc32)cc1] 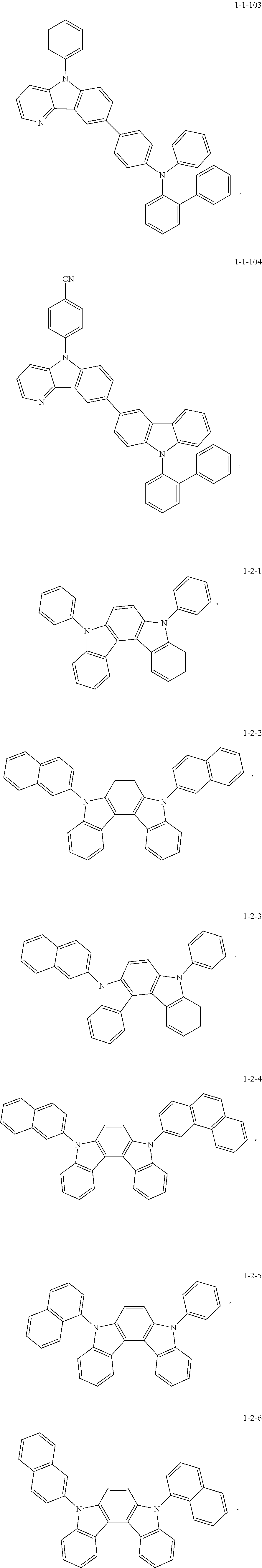 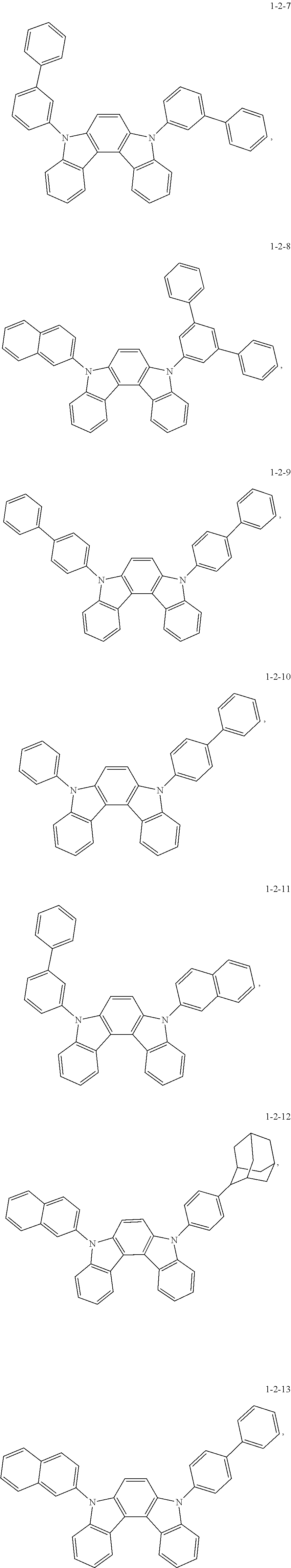 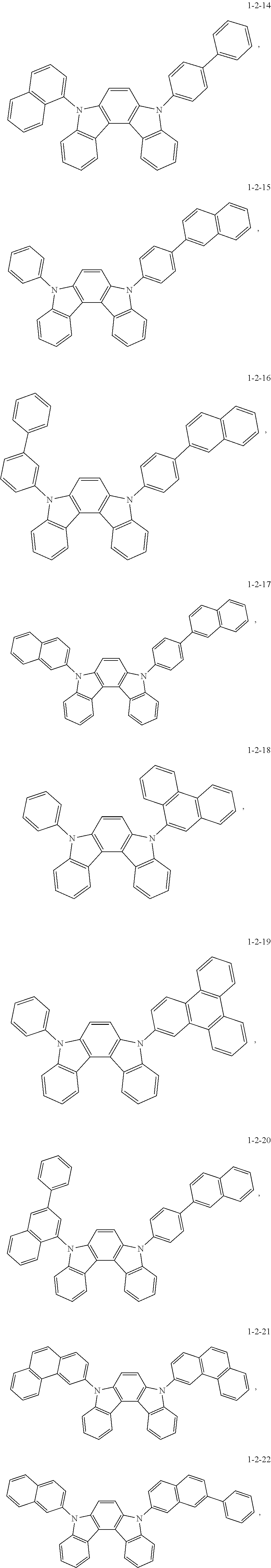 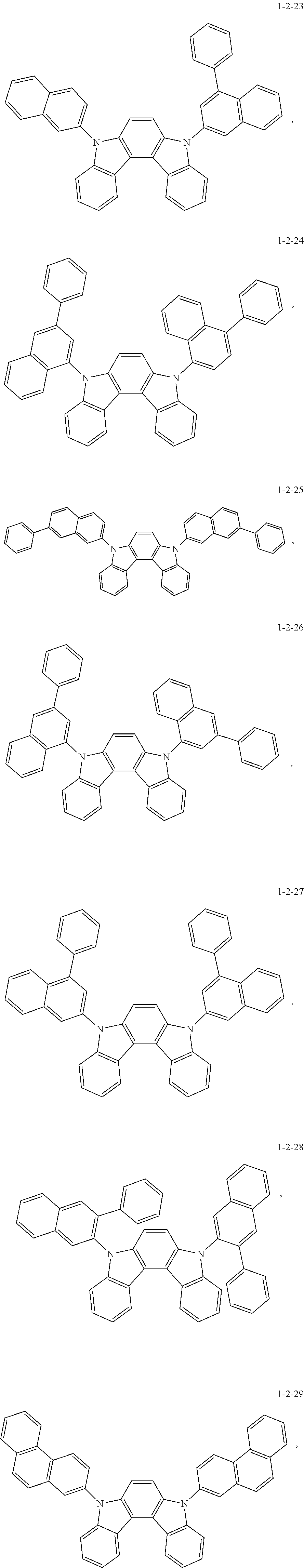 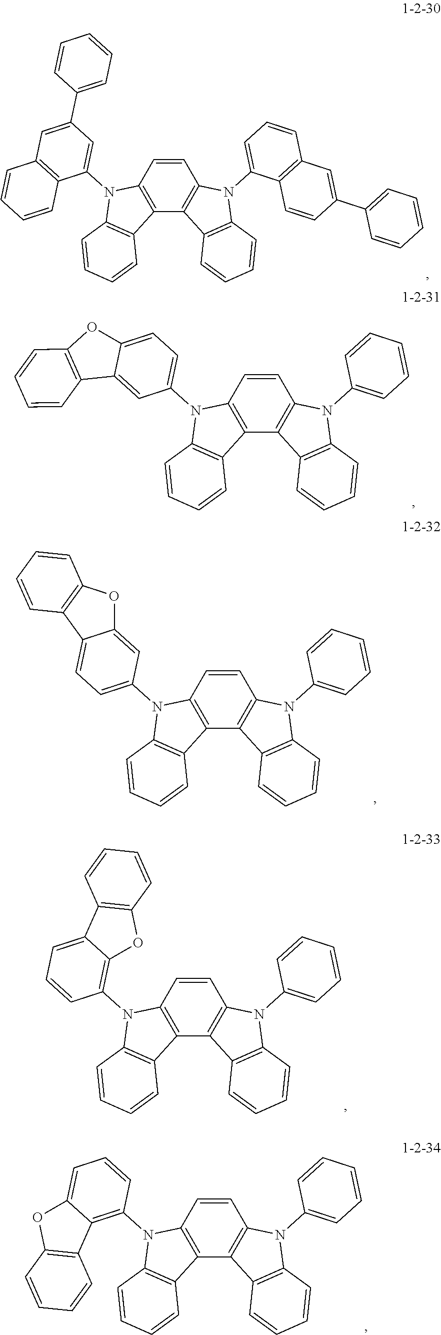 [SMILES: c1ccc(-c2ccc3c(-n4c5ccccc5c5c6c7ccccc7n(-c7cc(-c8ccccc8)cc8ccccc78)c6ccc54)cccc3c2)cc1 ; c1ccc(-n2c3ccccc3c3c4c5ccccc5n(-c5ccc6oc7ccccc7c6c5)c4ccc32)cc1 ; c1ccc(-n2c3ccccc3c3c4c5ccccc5n(-c5ccc6c(c5)oc5ccccc56)c4ccc32)cc1 ; c1ccc(-n2c3ccccc3c3c4c5ccccc5n(-c5cccc6c5oc5ccccc56)c4ccc32)cc1 ; c1ccc(-n2c3ccccc3c3c4c5ccccc5n(-c5cccc6oc7ccccc7c56)c4ccc32)cc1] 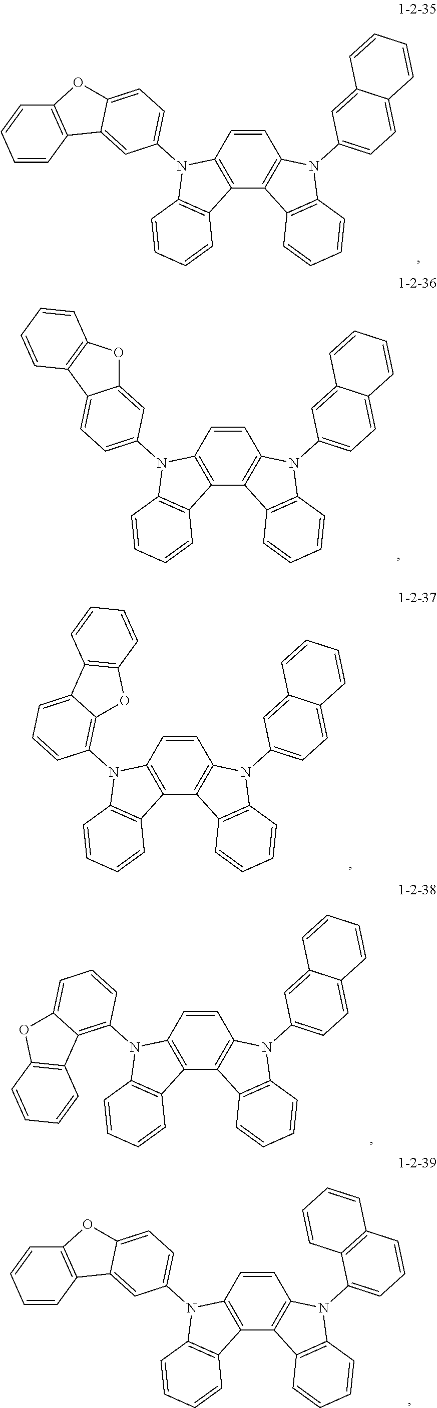 [SMILES: c1ccc2cc(-n3c4ccccc4c4c5c6ccccc6n(-c6ccc7oc8ccccc8c7c6)c5ccc43)ccc2c1 ; c1ccc2cc(-n3c4ccccc4c4c5c6ccccc6n(-c6ccc7c(c6)oc6ccccc67)c5ccc43)ccc2c1 ; c1ccc2cc(-n3c4ccccc4c4c5c6ccccc6n(-c6cccc7c6oc6ccccc67)c5ccc43)ccc2c1 ; c1ccc2cc(-n3c4ccccc4c4c5c6ccccc6n(-c6cccc7oc8ccccc8c67)c5ccc43)ccc2c1 ; c1ccc2c(-n3c4ccccc4c4c5c6ccccc6n(-c6ccc7oc8ccccc8c7c6)c5ccc43)cccc2c1] 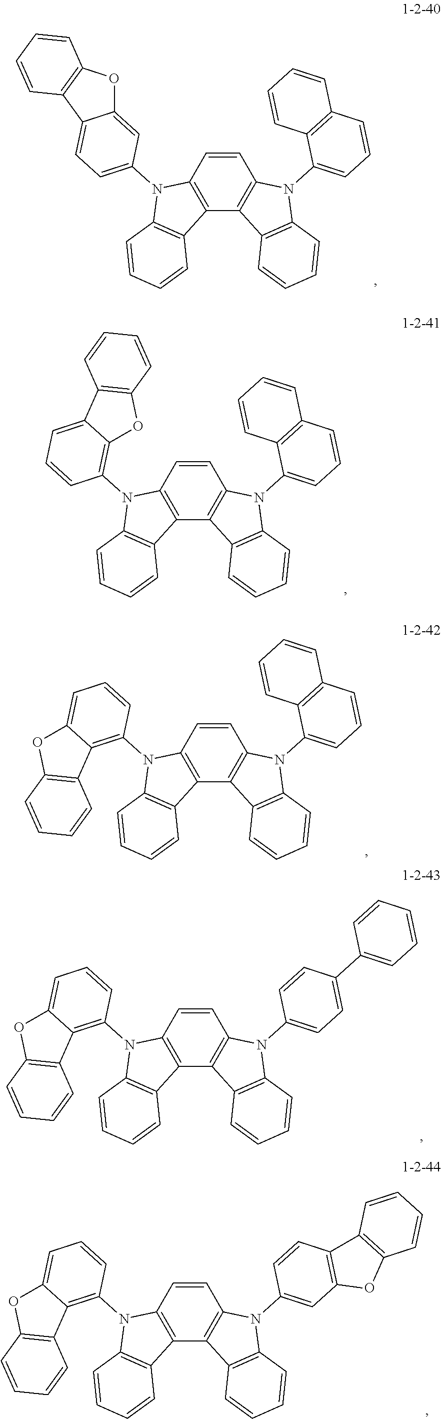 [SMILES: c1ccc2c(-n3c4ccccc4c4c5c6ccccc6n(-c6ccc7c(c6)oc6ccccc67)c5ccc43)cccc2c1 ; c1ccc2c(-n3c4ccccc4c4c5c6ccccc6n(-c6cccc7c6oc6ccccc67)c5ccc43)cccc2c1 ; c1ccc2c(-n3c4ccccc4c4c5c6ccccc6n(-c6cccc7oc8ccccc8c67)c5ccc43)cccc2c1 ; c1ccc(-c2ccc(-n3c4ccccc4c4c5c6ccccc6n(-c6cccc7oc8ccccc8c67)c5ccc43)cc2)cc1 ; c1ccc2c(c1)oc1cc(-n3c4ccccc4c4c5c6ccccc6n(-c6cccc7oc8ccccc8c67)c5ccc43)ccc12] 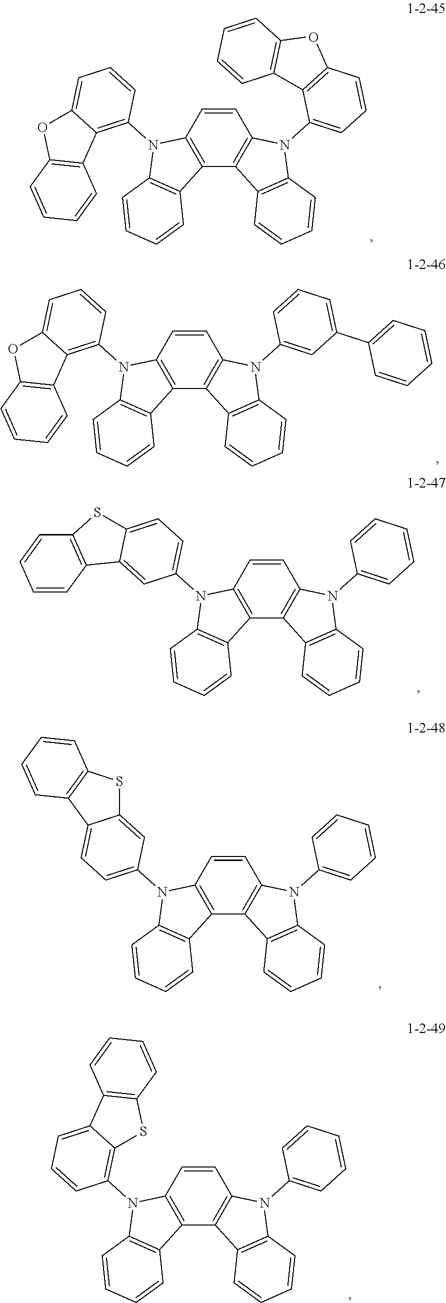 [SMILES: c1ccc2c(c1)oc1cccc(-n3c4ccccc4c4c5c6ccccc6n(-c6cccc7oc8ccccc8c67)c5ccc43)c12 ; c1ccc(-c2cccc(-n3c4ccccc4c4c5c6ccccc6n(-c6cccc7oc8ccccc8c67)c5ccc43)c2)cc1 ; c1ccc(-n2c3ccccc3c3c4c5ccccc5n(-c5ccc6sc7ccccc7c6c5)c4ccc32)cc1 ; c1ccc(-n2c3ccccc3c3c4c5ccccc5n(-c5ccc6c(c5)sc5ccccc56)c4ccc32)cc1 ; c1ccc(-n2c3ccccc3c3c4c5ccccc5n(-c5cccc6c5sc5ccccc56)c4ccc32)cc1] 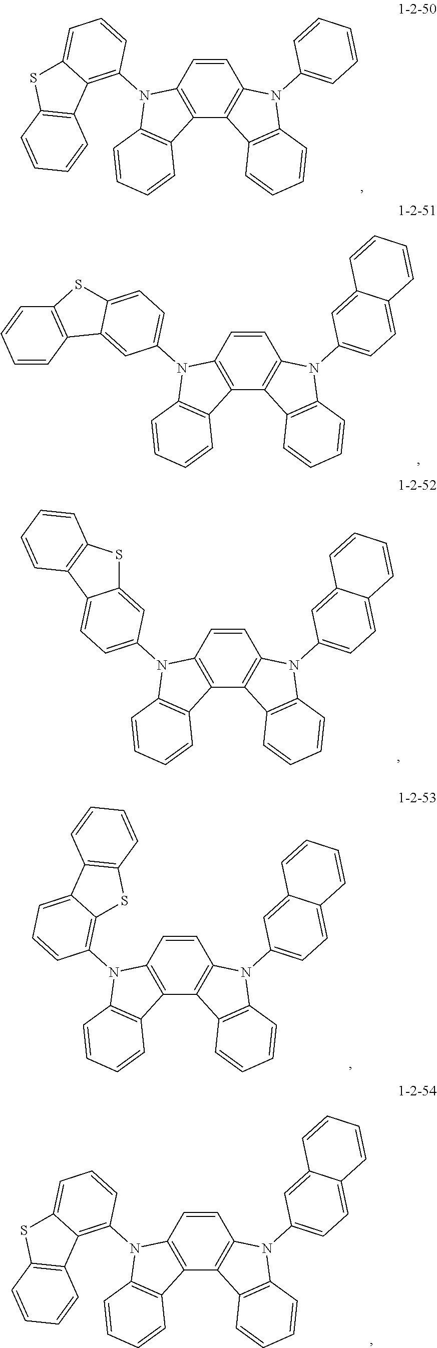 [SMILES: c1ccc(-n2c3ccccc3c3c4c5ccccc5n(-c5cccc6sc7ccccc7c56)c4ccc32)cc1 ; c1ccc2cc(-n3c4ccccc4c4c5c6ccccc6n(-c6ccc7sc8ccccc8c7c6)c5ccc43)ccc2c1 ; c1ccc2cc(-n3c4ccccc4c4c5c6ccccc6n(-c6ccc7c(c6)sc6ccccc67)c5ccc43)ccc2c1 ; c1ccc2cc(-n3c4ccccc4c4c5c6ccccc6n(-c6cccc7c6sc6ccccc67)c5ccc43)ccc2c1 ; c1ccc2cc(-n3c4ccccc4c4c5c6ccccc6n(-c6cccc7sc8ccccc8c67)c5ccc43)ccc2c1] 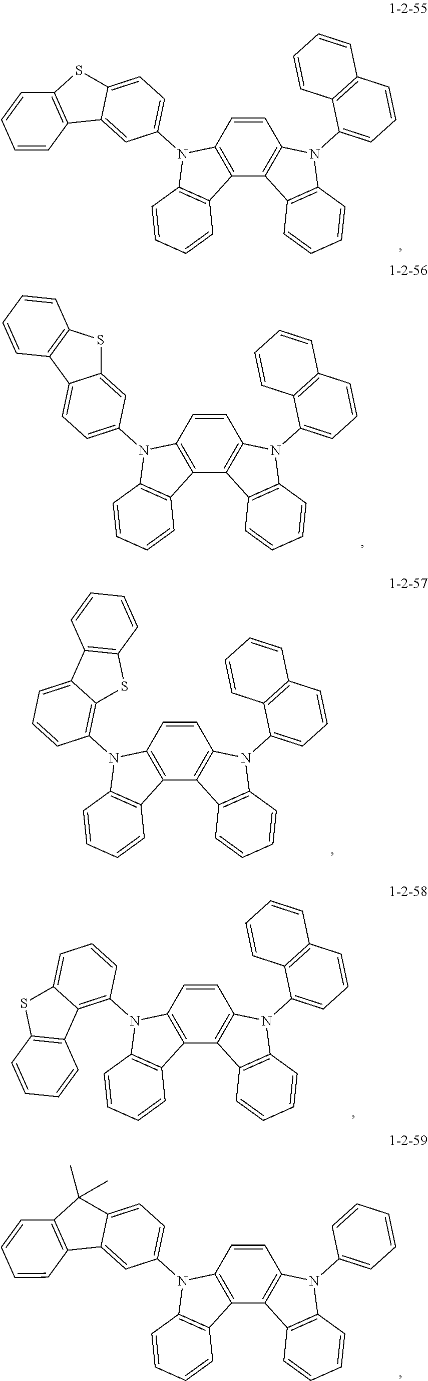 [SMILES: c1ccc2c(-n3c4ccccc4c4c5c6ccccc6n(-c6ccc7sc8ccccc8c7c6)c5ccc43)cccc2c1 ; c1ccc2c(-n3c4ccccc4c4c5c6ccccc6n(-c6ccc7c(c6)sc6ccccc67)c5ccc43)cccc2c1 ; c1ccc2c(-n3c4ccccc4c4c5c6ccccc6n(-c6cccc7c6sc6ccccc67)c5ccc43)cccc2c1 ; c1ccc2c(-n3c4ccccc4c4c5c6ccccc6n(-c6cccc7sc8ccccc8c67)c5ccc43)cccc2c1 ; CC1(C)c2ccccc2-c2cc(-n3c4ccccc4c4c5c6ccccc6n(-c6ccccc6)c5ccc43)ccc21] 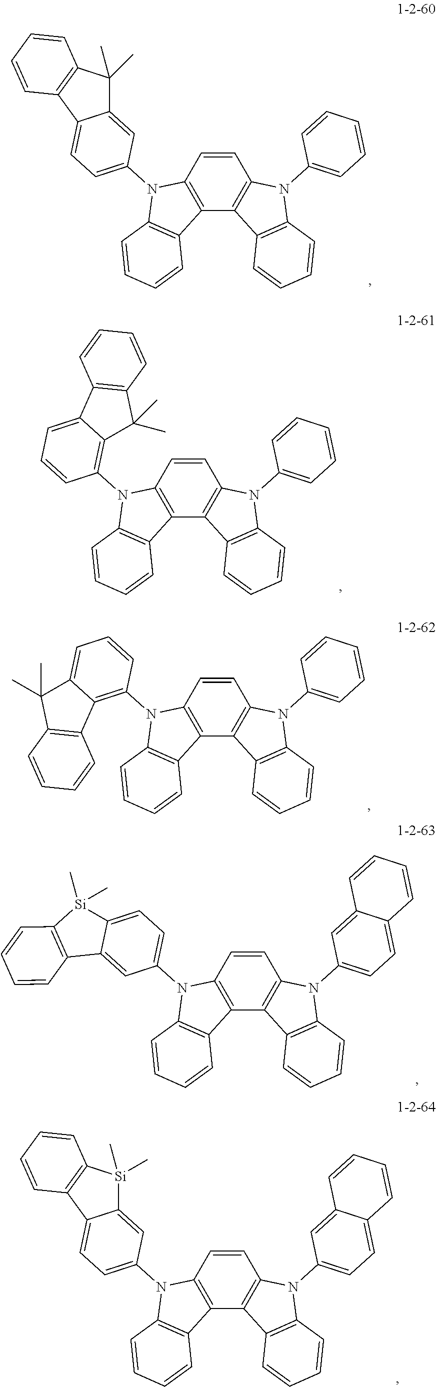 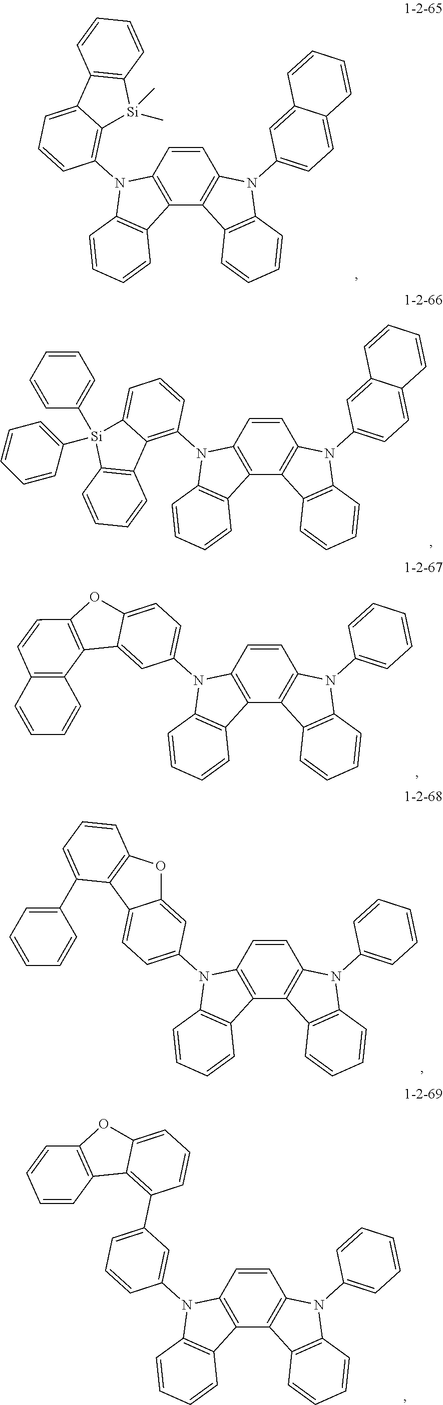 [SMILES: C[Si]1(C)c2ccccc2-c2cccc(-n3c4ccccc4c4c5c6ccccc6n(-c6ccc7ccccc7c6)c5ccc43)c21 ; c1ccc([Si]2(c3ccccc3)c3ccccc3-c3c(-n4c5ccccc5c5c6c7ccccc7n(-c7ccc8ccccc8c7)c6ccc54)cccc32)cc1 ; c1ccc(-n2c3ccccc3c3c4c5ccccc5n(-c5ccc6oc7ccc8ccccc8c7c6c5)c4ccc32)cc1 ; c1ccc(-c2cccc3oc4cc(-n5c6ccccc6c6c7c8ccccc8n(-c8ccccc8)c7ccc65)ccc4c23)cc1 ; c1ccc(-n2c3ccccc3c3c4c5ccccc5n(-c5cccc(-c6cccc7oc8ccccc8c67)c5)c4ccc32)cc1] 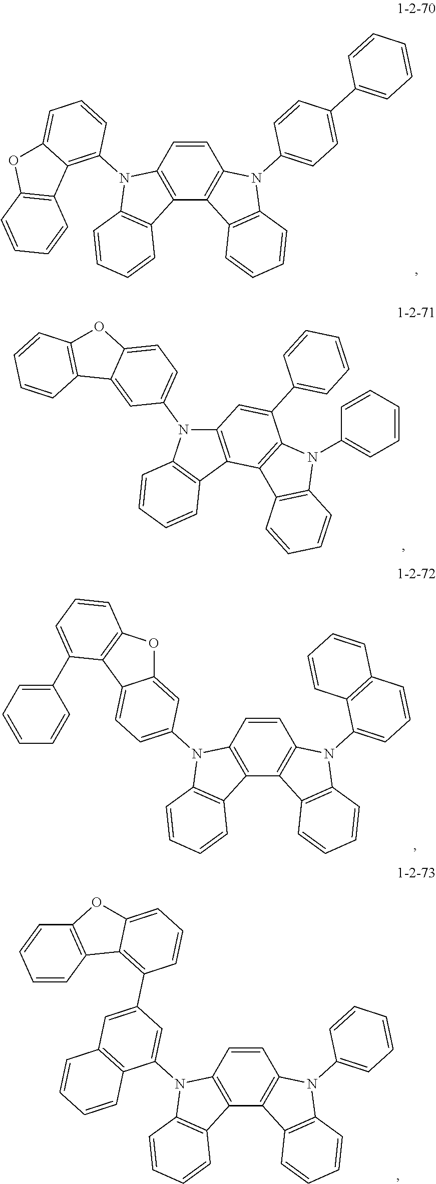 [SMILES: c1ccc(-c2ccc(-n3c4ccccc4c4c5c6ccccc6n(-c6cccc7oc8ccccc8c67)c5ccc43)cc2)cc1 ; c1ccc(-c2cc3c(c4ccccc4n3-c3ccc4oc5ccccc5c4c3)c3c4ccccc4n(-c4ccccc4)c23)cc1 ; c1ccc(-c2cccc3oc4cc(-n5c6ccccc6c6c7c8ccccc8n(-c8cccc9ccccc89)c7ccc65)ccc4c23)cc1 ; c1ccc(-n2c3ccccc3c3c4c5ccccc5n(-c5cc(-c6cccc7oc8ccccc8c67)cc6ccccc56)c4ccc32)cc1] 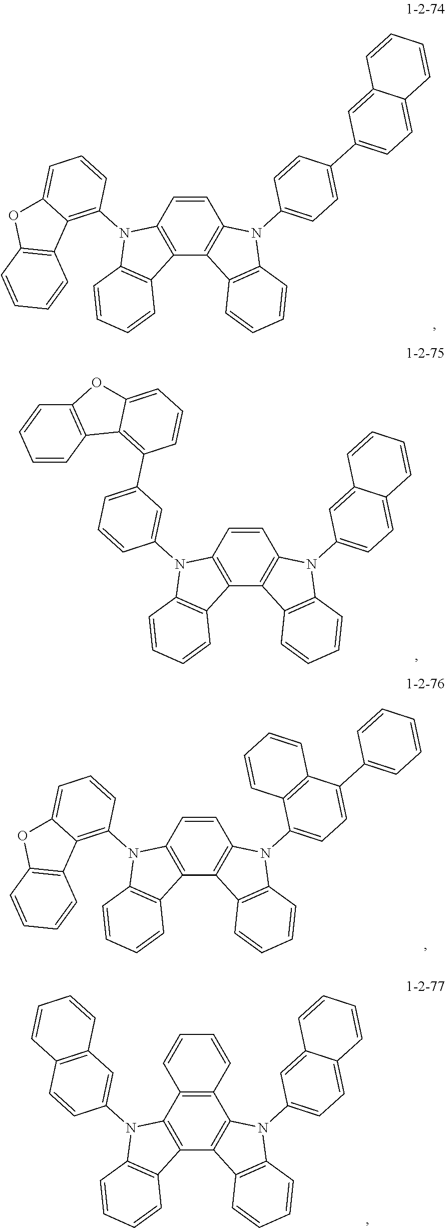 [SMILES: c1ccc2cc(-c3ccc(-n4c5ccccc5c5c6c7ccccc7n(-c7cccc8oc9ccccc9c78)c6ccc54)cc3)ccc2c1 ; c1cc(-c2cccc3oc4ccccc4c23)cc(-n2c3ccccc3c3c4c5ccccc5n(-c5ccc6ccccc6c5)c4ccc32)c1 ; c1ccc(-c2ccc(-n3c4ccccc4c4c5c6ccccc6n(-c6cccc7oc8ccccc8c67)c5ccc43)c3ccccc23)cc1 ; c1ccc2cc(-n3c4ccccc4c4c5c6ccccc6n(-c6ccc7ccccc7c6)c5c5ccccc5c43)ccc2c1] 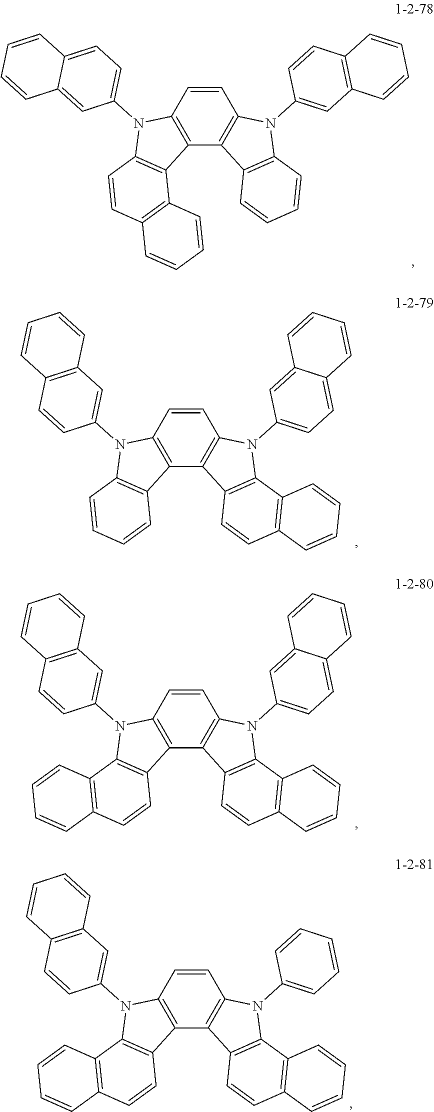 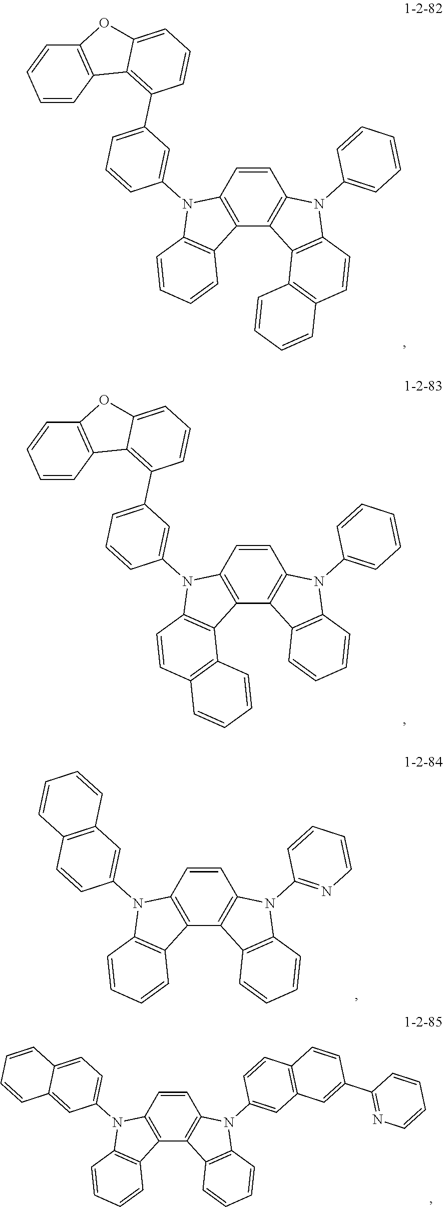 [SMILES: c1ccc(-n2c3ccc4ccccc4c3c3c4c5ccccc5n(-c5cccc(-c6cccc7oc8ccccc8c67)c5)c4ccc32)cc1 ; c1ccc(-n2c3ccccc3c3c4c5c6ccccc6ccc5n(-c5cccc(-c6cccc7oc8ccccc8c67)c5)c4ccc32)cc1 ; c1ccc(-n2c3ccccc3c3c4c5ccccc5n(-c5ccc6ccccc6c5)c4ccc32)nc1 ; c1ccc(-c2ccc3ccc(-n4c5ccccc5c5c6c7ccccc7n(-c7ccc8ccccc8c7)c6ccc54)cc3c2)nc1] 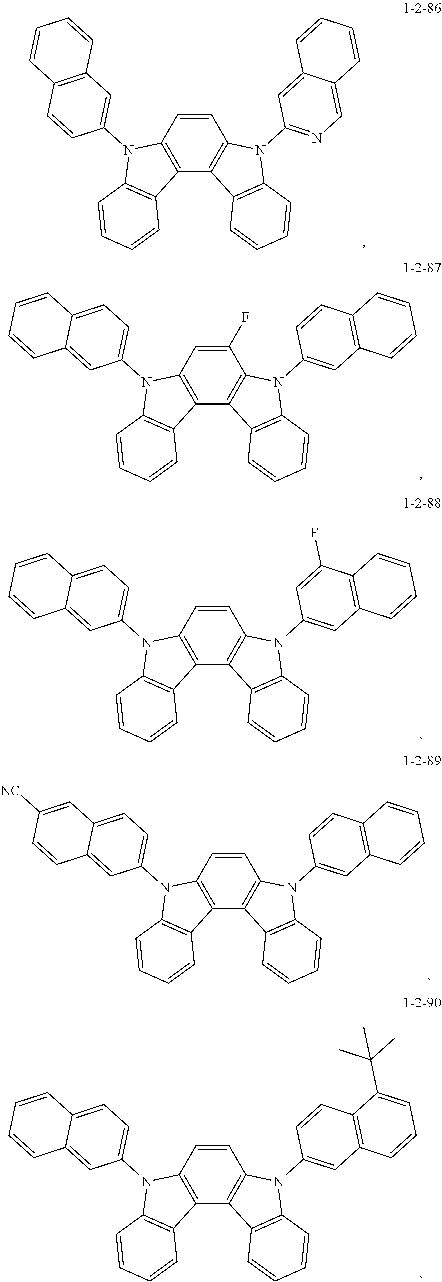 [SMILES: c1ccc2cc(-n3c4ccccc4c4c5c6ccccc6n(-c6cc7ccccc7cn6)c5ccc43)ccc2c1 ; Fc1cc2c(c3ccccc3n2-c2ccc3ccccc3c2)c2c3ccccc3n(-c3ccc4ccccc4c3)c12 ; Fc1cc(-n2c3ccccc3c3c4c5ccccc5n(-c5ccc6ccccc6c5)c4ccc32)cc2ccccc12 ; N#Cc1ccc2cc(-n3c4ccccc4c4c5c6ccccc6n(-c6ccc7ccccc7c6)c5ccc43)ccc2c1 ; CC(C)(C)c1cccc2cc(-n3c4ccccc4c4c5c6ccccc6n(-c6ccc7ccccc7c6)c5ccc43)ccc12] 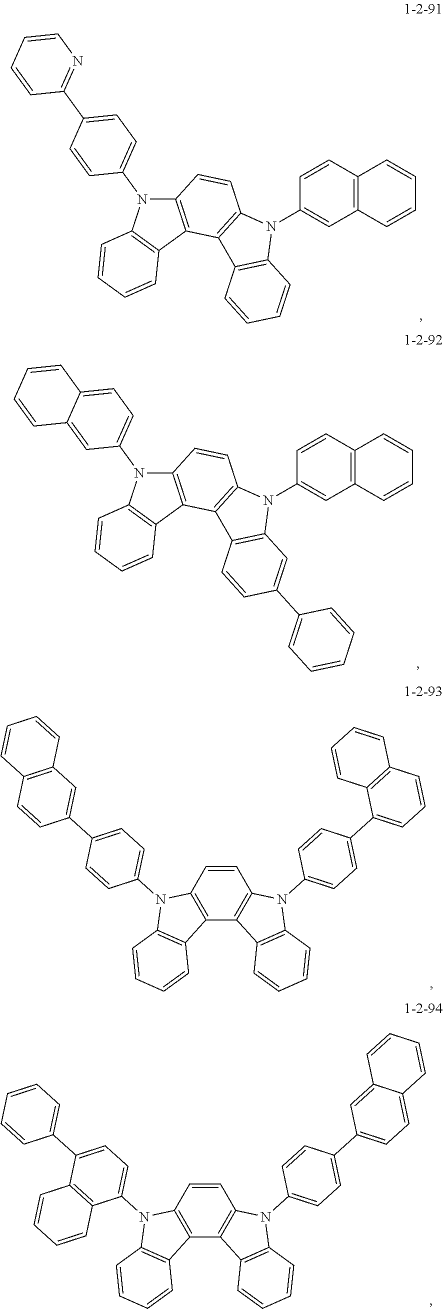 [SMILES: c1ccc(-c2ccc(-n3c4ccccc4c4c5c6ccccc6n(-c6ccc7ccccc7c6)c5ccc43)cc2)nc1 ; c1ccc(-c2ccc3c4c5c6ccccc6n(-c6ccc7ccccc7c6)c5ccc4n(-c4ccc5ccccc5c4)c3c2)cc1 ; c1ccc2cc(-c3ccc(-n4c5ccccc5c5c6c7ccccc7n(-c7ccc(-c8cccc9ccccc89)cc7)c6ccc54)cc3)ccc2c1 ; c1ccc(-c2ccc(-n3c4ccccc4c4c5c6ccccc6n(-c6ccc(-c7ccc8ccccc8c7)cc6)c5ccc43)c3ccccc23)cc1] 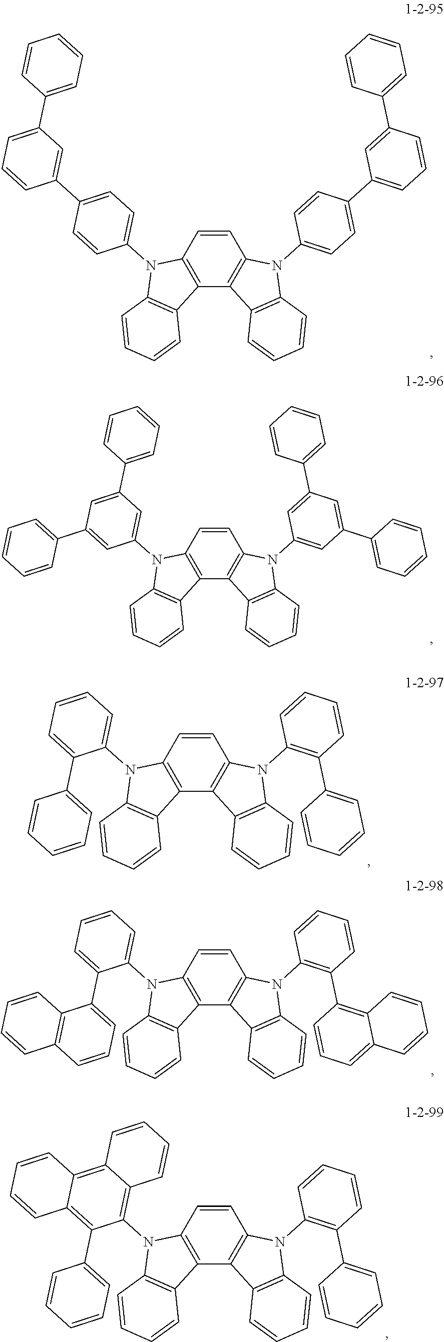 [SMILES: c1ccc(-c2cccc(-c3ccc(-n4c5ccccc5c5c6c7ccccc7n(-c7ccc(-c8cccc(-c9ccccc9)c8)cc7)c6ccc54)cc3)c2)cc1 ; c1ccc(-c2cc(-c3ccccc3)cc(-n3c4ccccc4c4c5c6ccccc6n(-c6cc(-c7ccccc7)cc(-c7ccccc7)c6)c5ccc43)c2)cc1 ; c1ccc(-c2ccccc2-n2c3ccccc3c3c4c5ccccc5n(-c5ccccc5-c5ccccc5)c4ccc32)cc1 ; c1ccc(-n2c3ccccc3c3c4c5ccccc5n(-c5ccccc5-c5cccc6ccccc56)c4ccc32)c(-c2cccc3ccccc23)c1 ; c1ccc(-c2ccccc2-n2c3ccccc3c3c4c5ccccc5n(-c5c(-c6ccccc6)c6ccccc6c6ccccc56)c4ccc32)cc1] 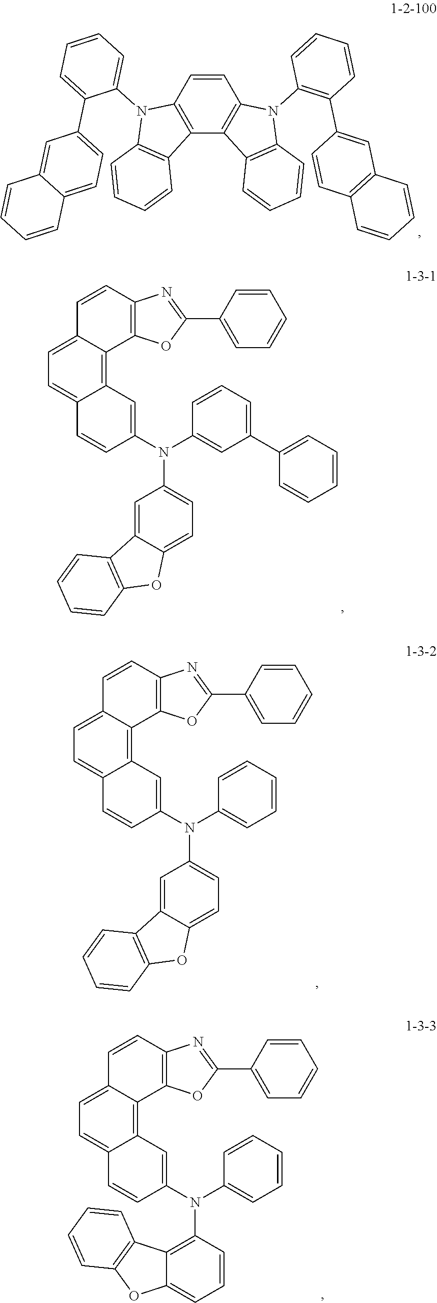 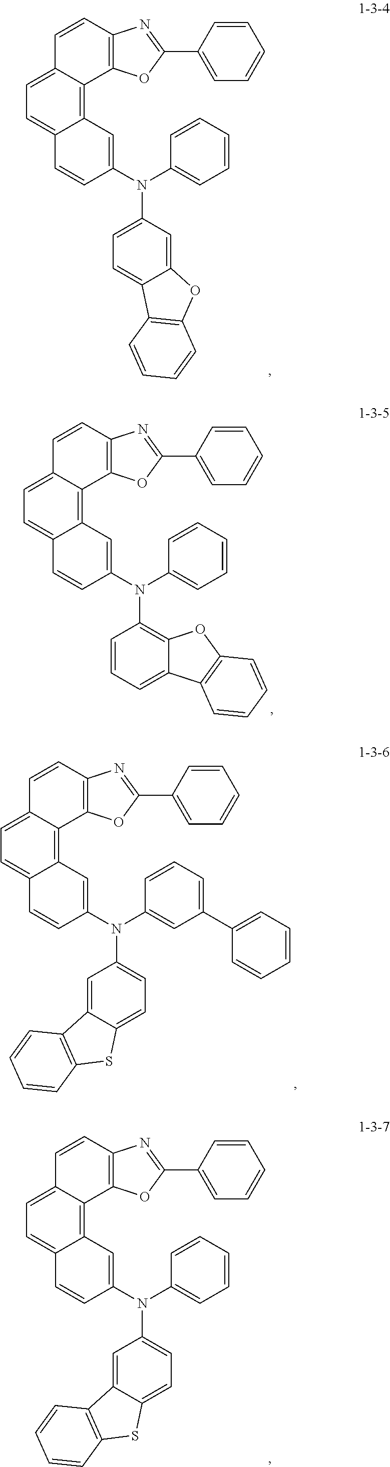 [SMILES: c1ccc(-c2nc3ccc4ccc5ccc(N(c6ccccc6)c6ccc7c(c6)oc6ccccc67)cc5c4c3o2)cc1 ; c1ccc(-c2nc3ccc4ccc5ccc(N(c6ccccc6)c6cccc7c6oc6ccccc67)cc5c4c3o2)cc1 ; c1ccc(-c2cccc(N(c3ccc4sc5ccccc5c4c3)c3ccc4ccc5ccc6nc(-c7ccccc7)oc6c5c4c3)c2)cc1 ; c1ccc(-c2nc3ccc4ccc5ccc(N(c6ccccc6)c6ccc7sc8ccccc8c7c6)cc5c4c3o2)cc1] 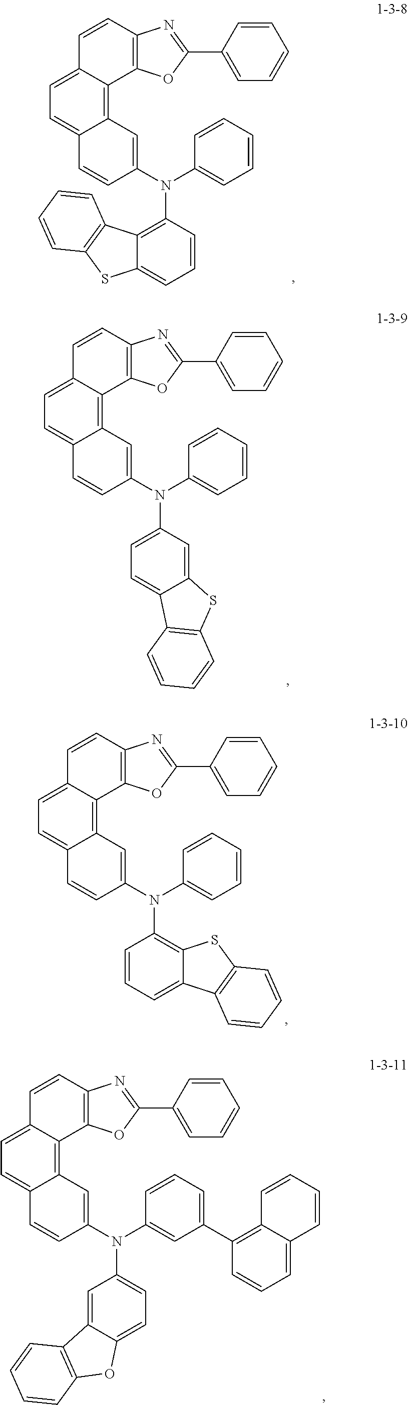 [SMILES: c1ccc(-c2nc3ccc4ccc5ccc(N(c6ccccc6)c6cccc7sc8ccccc8c67)cc5c4c3o2)cc1 ; c1ccc(-c2nc3ccc4ccc5ccc(N(c6ccccc6)c6ccc7c(c6)sc6ccccc67)cc5c4c3o2)cc1 ; c1ccc(-c2nc3ccc4ccc5ccc(N(c6ccccc6)c6cccc7c6sc6ccccc67)cc5c4c3o2)cc1 ; c1ccc(-c2nc3ccc4ccc5ccc(N(c6cccc(-c7cccc8ccccc78)c6)c6ccc7oc8ccccc8c7c6)cc5c4c3o2)cc1] 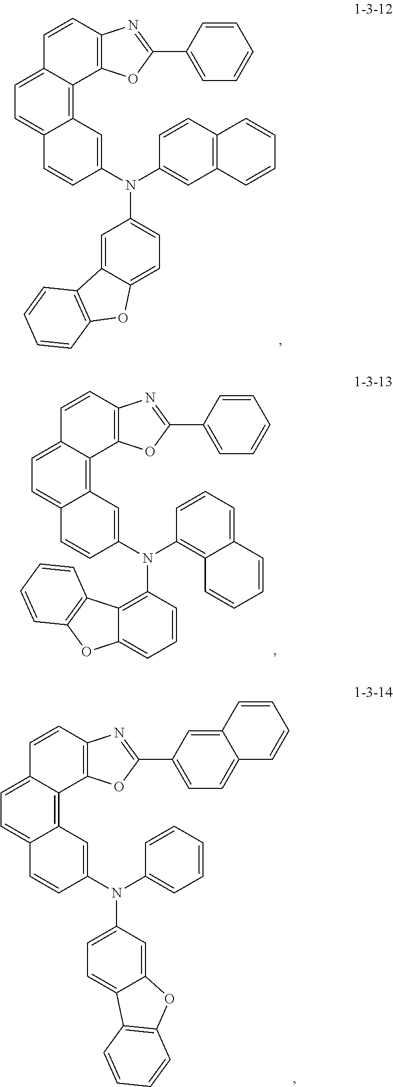 [SMILES: c1ccc(-c2nc3ccc4ccc5ccc(N(c6ccc7ccccc7c6)c6ccc7oc8ccccc8c7c6)cc5c4c3o2)cc1 ; c1ccc(-c2nc3ccc4ccc5ccc(N(c6cccc7ccccc67)c6cccc7oc8ccccc8c67)cc5c4c3o2)cc1 ; c1ccc(N(c2ccc3c(c2)oc2ccccc23)c2ccc3ccc4ccc5nc(-c6ccc7ccccc7c6)oc5c4c3c2)cc1] 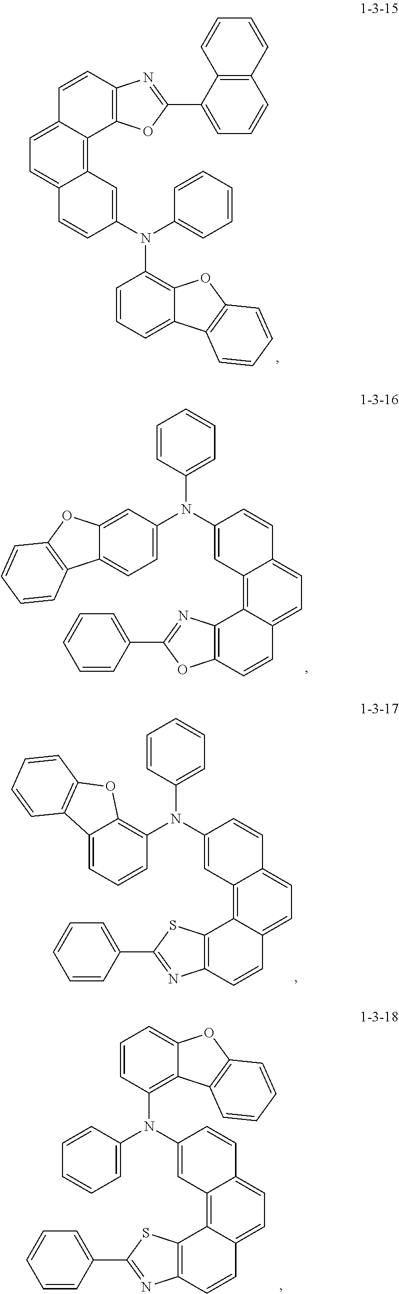 [SMILES: c1ccc(N(c2ccc3ccc4ccc5nc(-c6cccc7ccccc67)oc5c4c3c2)c2cccc3c2oc2ccccc23)cc1 ; c1ccc(-c2nc3c(ccc4ccc5ccc(N(c6ccccc6)c6ccc7c(c6)oc6ccccc67)cc5c43)o2)cc1 ; c1ccc(-c2nc3ccc4ccc5ccc(N(c6ccccc6)c6cccc7c6oc6ccccc67)cc5c4c3s2)cc1 ; c1ccc(-c2nc3ccc4ccc5ccc(N(c6ccccc6)c6cccc7oc8ccccc8c67)cc5c4c3s2)cc1] 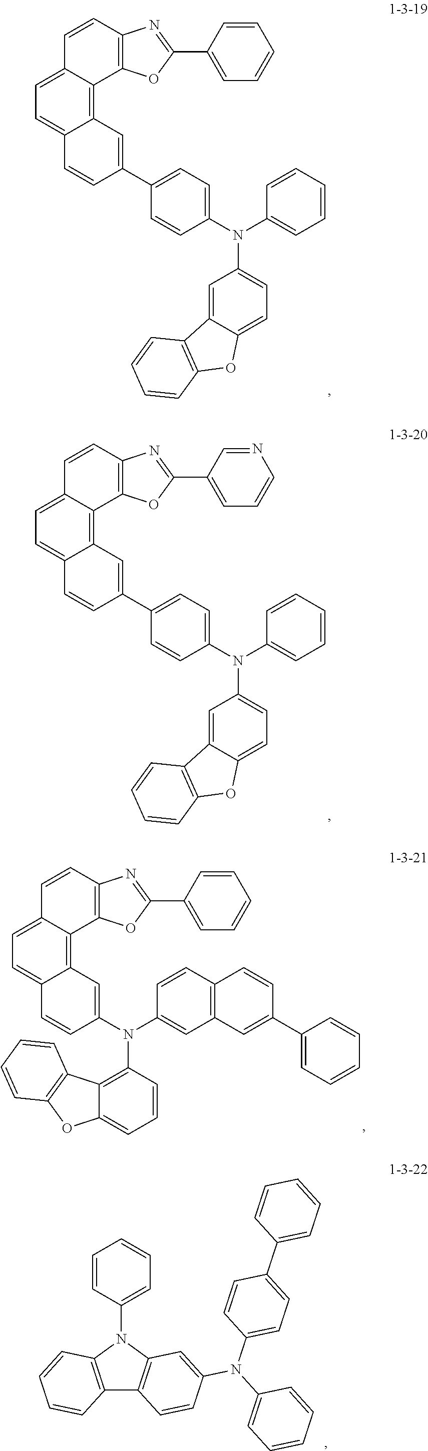 [SMILES: c1ccc(-c2nc3ccc4ccc5ccc(-c6ccc(N(c7ccccc7)c7ccc8oc9ccccc9c8c7)cc6)cc5c4c3o2)cc1 ; c1ccc(N(c2ccc(-c3ccc4ccc5ccc6nc(-c7cccnc7)oc6c5c4c3)cc2)c2ccc3oc4ccccc4c3c2)cc1 ; c1ccc(-c2ccc3ccc(N(c4ccc5ccc6ccc7nc(-c8ccccc8)oc7c6c5c4)c4cccc5oc6ccccc6c45)cc3c2)cc1 ; c1ccc(-c2ccc(N(c3ccccc3)c3ccc4c5ccccc5n(-c5ccccc5)c4c3)cc2)cc1] 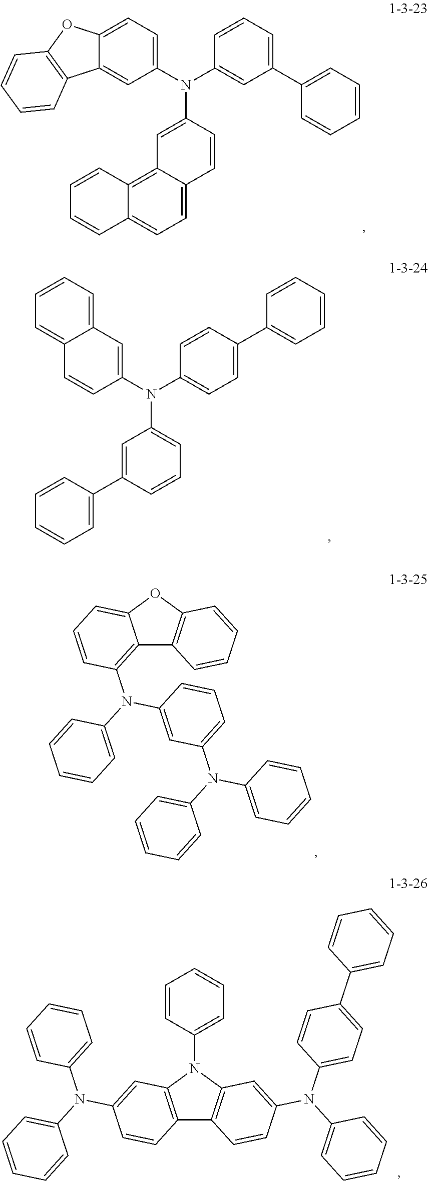 [SMILES: c1ccc(-c2cccc(N(c3ccc4ccc5ccccc5c4c3)c3ccc4oc5ccccc5c4c3)c2)cc1 ; c1ccc(-c2ccc(N(c3cccc(-c4ccccc4)c3)c3ccc4ccccc4c3)cc2)cc1 ; c1ccc(N(c2ccccc2)c2cccc(N(c3ccccc3)c3cccc4oc5ccccc5c34)c2)cc1 ; c1ccc(-c2ccc(N(c3ccccc3)c3ccc4c5ccc(N(c6ccccc6)c6ccccc6)cc5n(-c5ccccc5)c4c3)cc2)cc1] 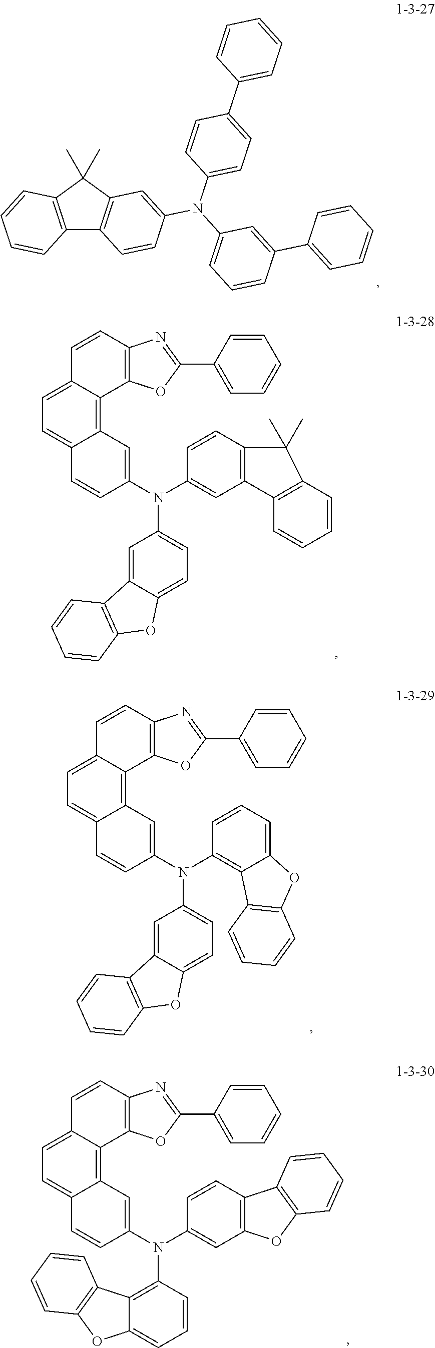 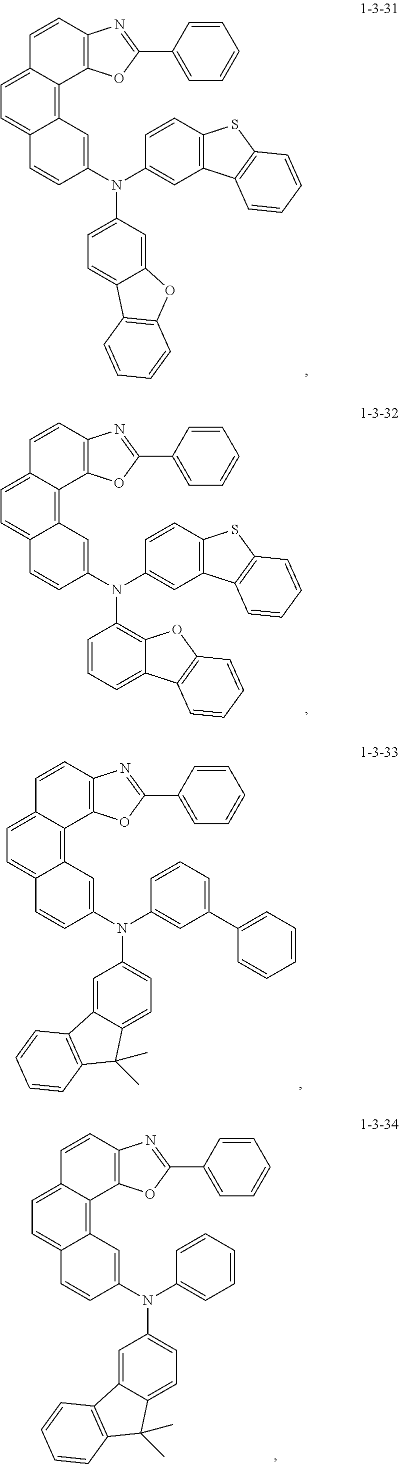 [SMILES: c1ccc(-c2nc3ccc4ccc5ccc(N(c6ccc7c(c6)oc6ccccc67)c6ccc7sc8ccccc8c7c6)cc5c4c3o2)cc1 ; c1ccc(-c2nc3ccc4ccc5ccc(N(c6ccc7sc8ccccc8c7c6)c6cccc7c6oc6ccccc67)cc5c4c3o2)cc1 ; CC1(C)c2ccccc2-c2cc(N(c3cccc(-c4ccccc4)c3)c3ccc4ccc5ccc6nc(-c7ccccc7)oc6c5c4c3)ccc21 ; CC1(C)c2ccccc2-c2cc(N(c3ccccc3)c3ccc4ccc5ccc6nc(-c7ccccc7)oc6c5c4c3)ccc21] 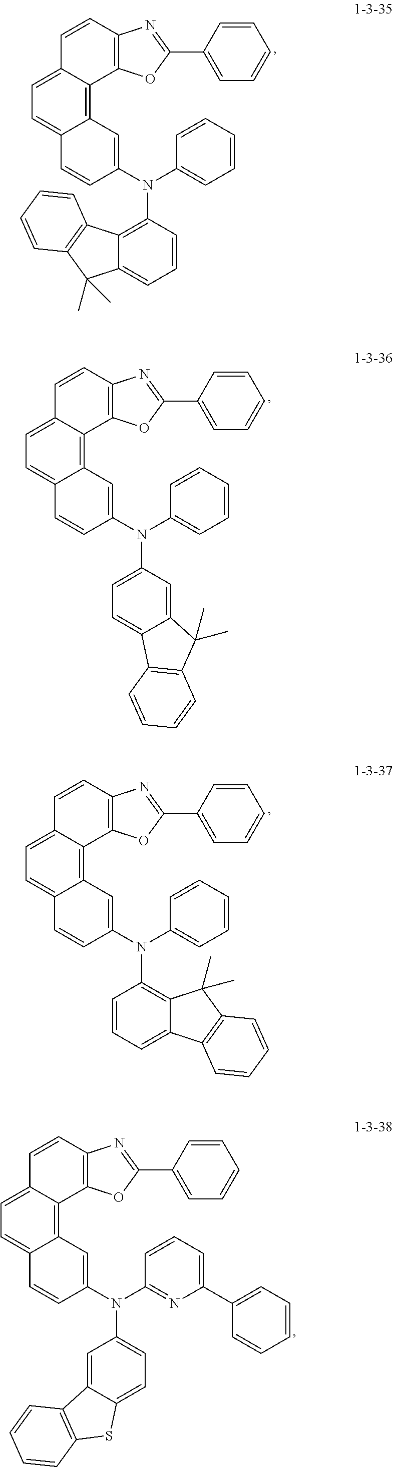 [SMILES: CC1(C)c2ccccc2-c2c(N(c3ccccc3)c3ccc4ccc5ccc6nc(-c7ccccc7)oc6c5c4c3)cccc21 ; CC1(C)c2ccccc2-c2ccc(N(c3ccccc3)c3ccc4ccc5ccc6nc(-c7ccccc7)oc6c5c4c3)cc21 ; CC1(C)c2ccccc2-c2cccc(N(c3ccccc3)c3ccc4ccc5ccc6nc(-c7ccccc7)oc6c5c4c3)c21 ; c1ccc(-c2cccc(N(c3ccc4sc5ccccc5c4c3)c3ccc4ccc5ccc6nc(-c7ccccc7)oc6c5c4c3)n2)cc1] 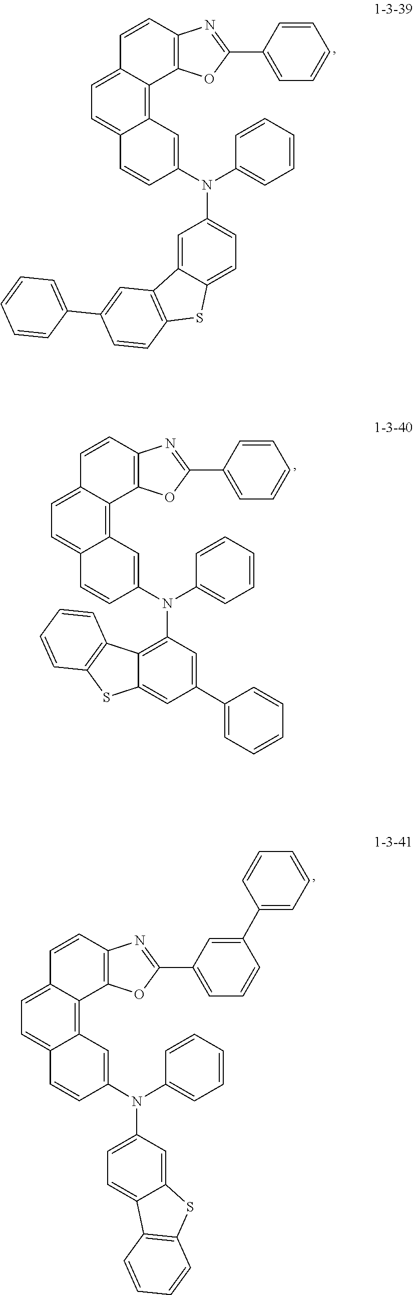 [SMILES: c1ccc(-c2ccc3sc4ccc(N(c5ccccc5)c5ccc6ccc7ccc8nc(-c9ccccc9)oc8c7c6c5)cc4c3c2)cc1 ; c1ccc(-c2cc(N(c3ccccc3)c3ccc4ccc5ccc6nc(-c7ccccc7)oc6c5c4c3)c3c(c2)sc2ccccc23)cc1 ; c1ccc(-c2cccc(-c3nc4ccc5ccc6ccc(N(c7ccccc7)c7ccc8c(c7)sc7ccccc78)cc6c5c4o3)c2)cc1] 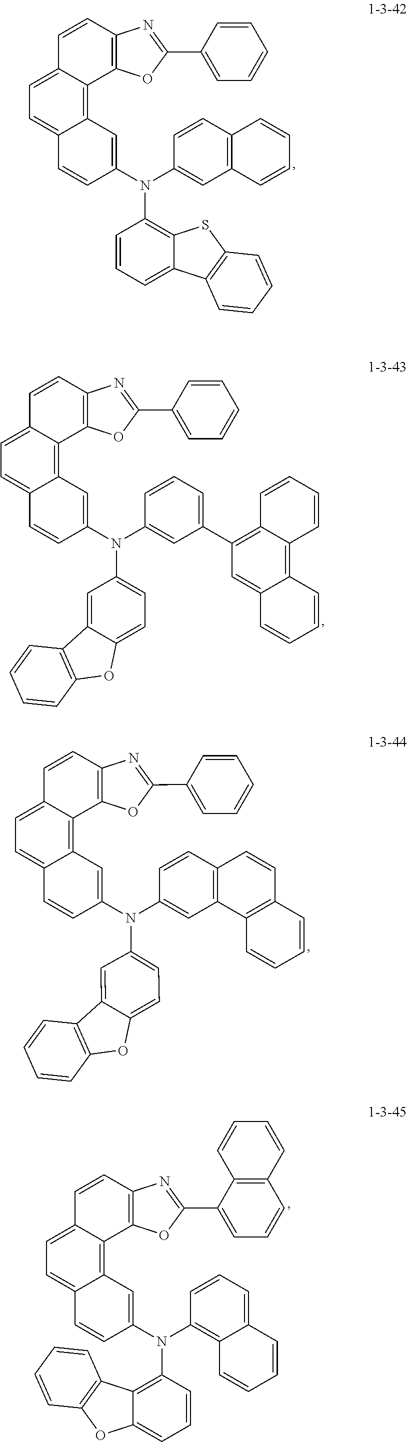 [SMILES: c1ccc(-c2nc3ccc4ccc5ccc(N(c6ccc7ccccc7c6)c6cccc7c6sc6ccccc67)cc5c4c3o2)cc1 ; c1ccc(-c2nc3ccc4ccc5ccc(N(c6cccc(-c7cc8ccccc8c8ccccc78)c6)c6ccc7oc8ccccc8c7c6)cc5c4c3o2)cc1 ; c1ccc(-c2nc3ccc4ccc5ccc(N(c6ccc7ccc8ccccc8c7c6)c6ccc7oc8ccccc8c7c6)cc5c4c3o2)cc1 ; c1ccc2c(-c3nc4ccc5ccc6ccc(N(c7cccc8ccccc78)c7cccc8oc9ccccc9c78)cc6c5c4o3)cccc2c1] 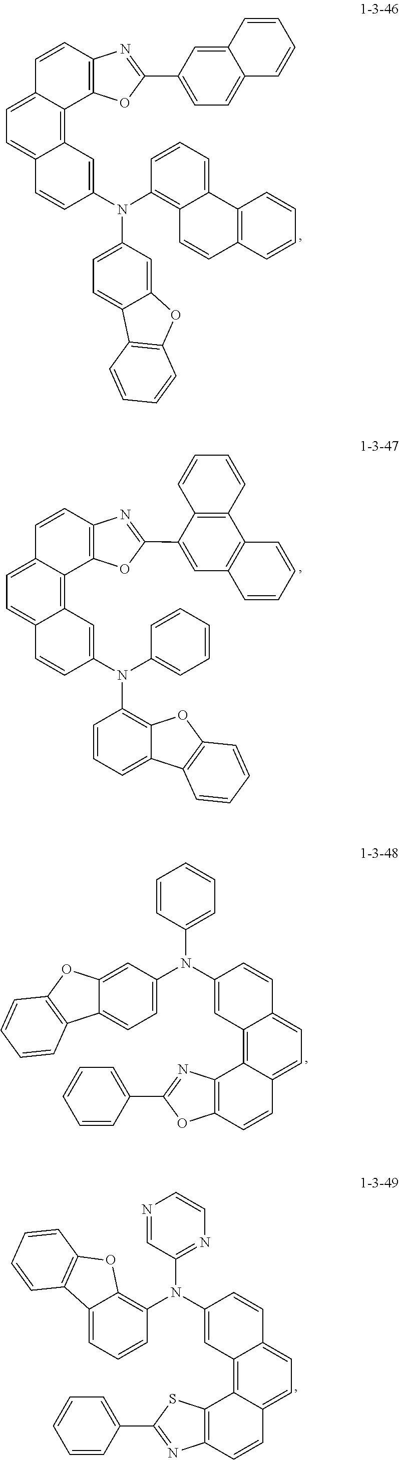 [SMILES: c1ccc2cc(-c3nc4ccc5ccc6ccc(N(c7ccc8c(c7)oc7ccccc78)c7cccc8c7ccc7ccccc78)cc6c5c4o3)ccc2c1 ; c1ccc(N(c2ccc3ccc4ccc5nc(-c6cc7ccccc7c7ccccc67)oc5c4c3c2)c2cccc3c2oc2ccccc23)cc1 ; c1ccc(-c2nc3c(ccc4ccc5ccc(N(c6ccccc6)c6ccc7c(c6)oc6ccccc67)cc5c43)o2)cc1 ; c1ccc(-c2nc3ccc4ccc5ccc(N(c6cnccn6)c6cccc7c6oc6ccccc67)cc5c4c3s2)cc1] 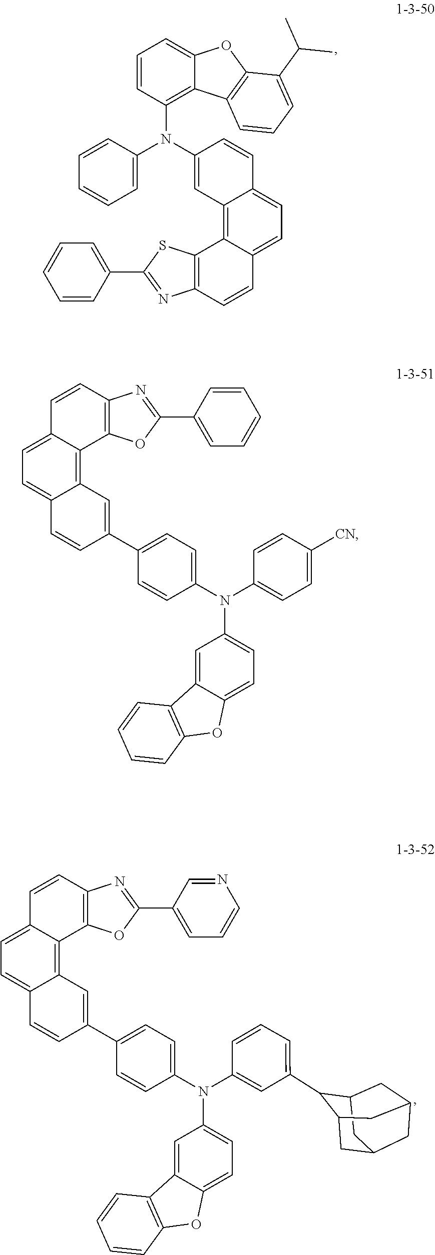 [SMILES: CC(C)c1cccc2c1oc1cccc(N(c3ccccc3)c3ccc4ccc5ccc6nc(-c7ccccc7)sc6c5c4c3)c12 ; N#Cc1ccc(N(c2ccc(-c3ccc4ccc5ccc6nc(-c7ccccc7)oc6c5c4c3)cc2)c2ccc3oc4ccccc4c3c2)cc1 ; c1cncc(-c2nc3ccc4ccc5ccc(-c6ccc(N(c7cccc(C8C9CC%10CC(C9)CC8C%10)c7)c7ccc8oc9ccccc9c8c7)cc6)cc5c4c3o2)c1] 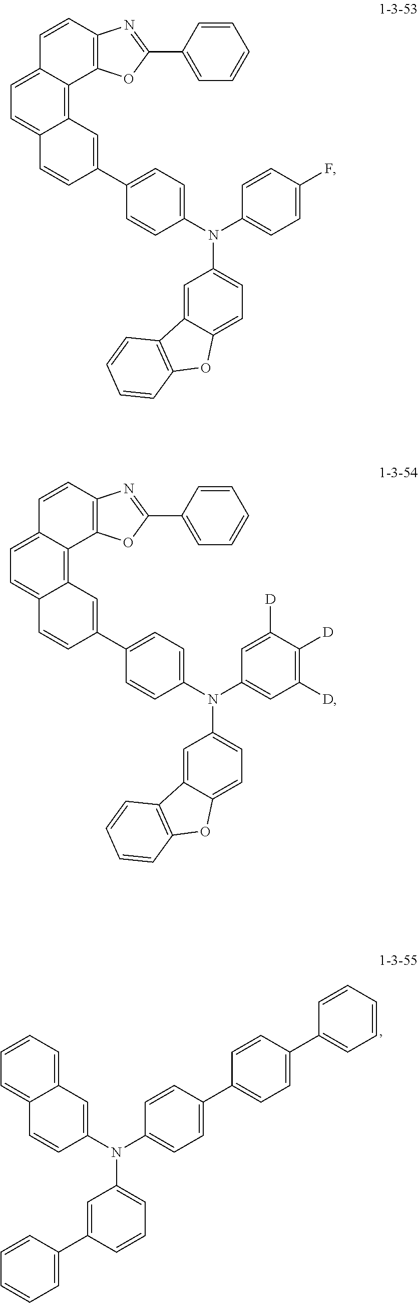 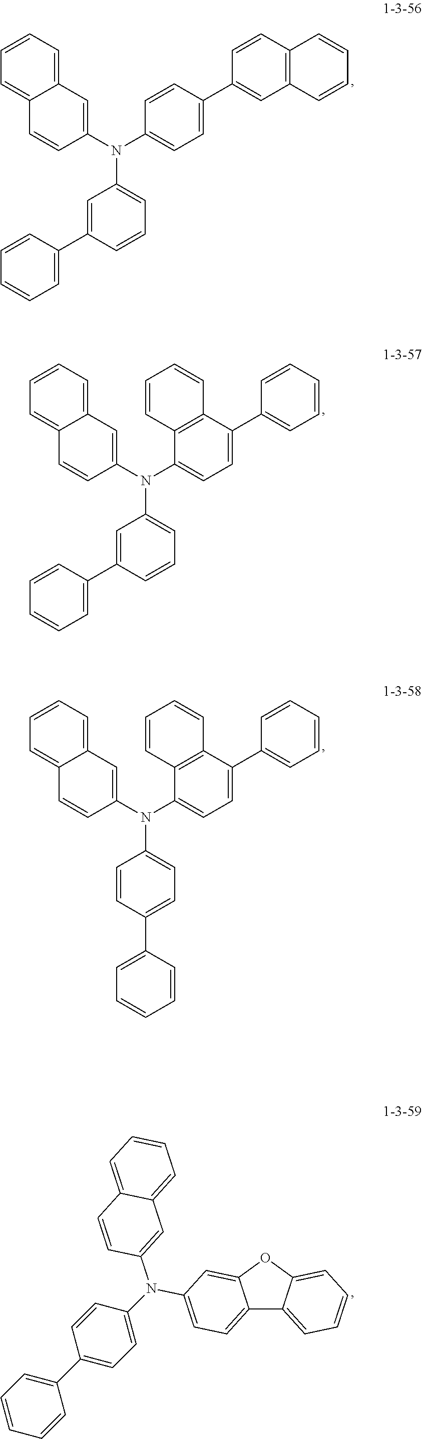 [SMILES: c1ccc(-c2cccc(N(c3ccc(-c4ccc5ccccc5c4)cc3)c3ccc4ccccc4c3)c2)cc1 ; c1ccc(-c2cccc(N(c3ccc4ccccc4c3)c3ccc(-c4ccccc4)c4ccccc34)c2)cc1 ; c1ccc(-c2ccc(N(c3ccc4ccccc4c3)c3ccc(-c4ccccc4)c4ccccc34)cc2)cc1 ; c1ccc(-c2ccc(N(c3ccc4ccccc4c3)c3ccc4c(c3)oc3ccccc34)cc2)cc1] 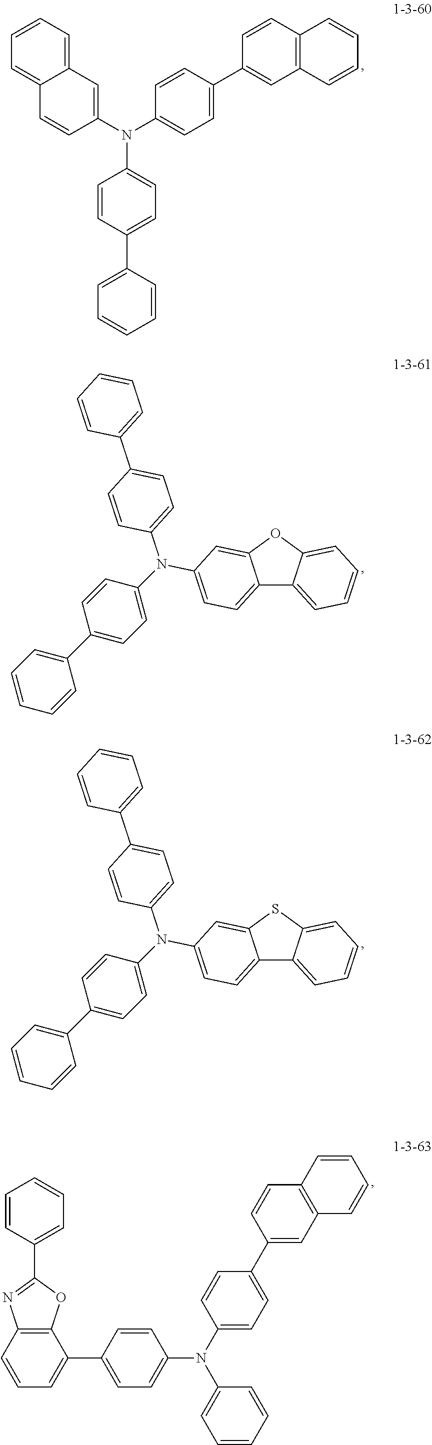 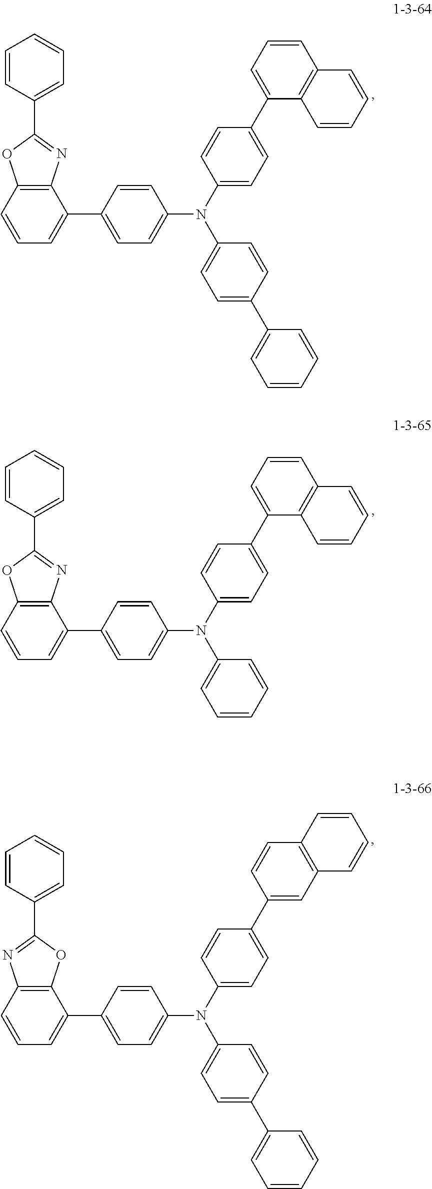 [SMILES: c1ccc(-c2ccc(N(c3ccc(-c4cccc5ccccc45)cc3)c3ccc(-c4cccc5oc(-c6ccccc6)nc45)cc3)cc2)cc1 ; c1ccc(-c2nc3c(-c4ccc(N(c5ccccc5)c5ccc(-c6cccc7ccccc67)cc5)cc4)cccc3o2)cc1 ; c1ccc(-c2ccc(N(c3ccc(-c4ccc5ccccc5c4)cc3)c3ccc(-c4cccc5nc(-c6ccccc6)oc45)cc3)cc2)cc1] 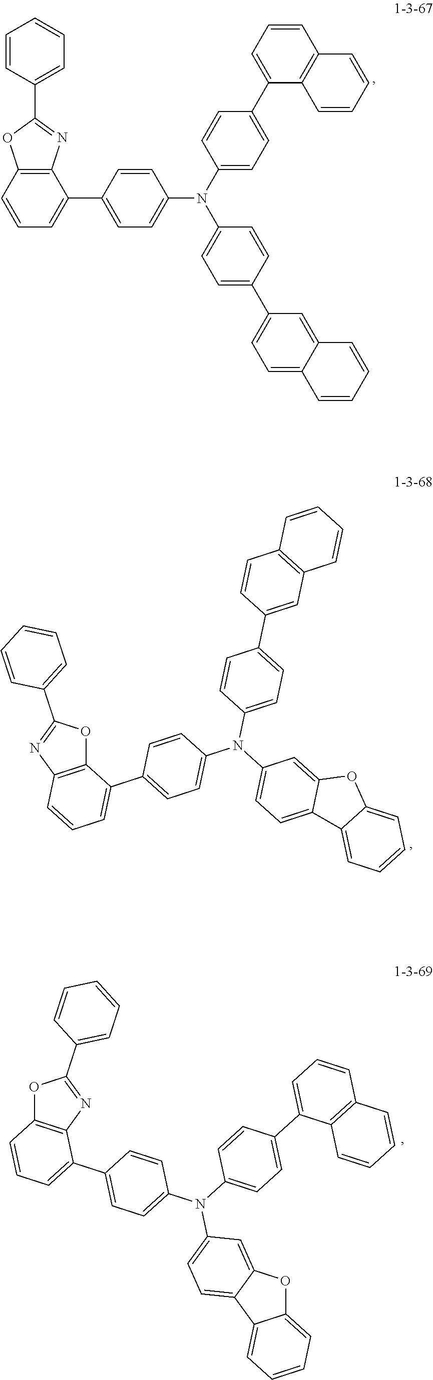 [SMILES: c1ccc(-c2nc3c(-c4ccc(N(c5ccc(-c6ccc7ccccc7c6)cc5)c5ccc(-c6cccc7ccccc67)cc5)cc4)cccc3o2)cc1 ; c1ccc(-c2nc3cccc(-c4ccc(N(c5ccc(-c6ccc7ccccc7c6)cc5)c5ccc6c(c5)oc5ccccc56)cc4)c3o2)cc1 ; c1ccc(-c2nc3c(-c4ccc(N(c5ccc(-c6cccc7ccccc67)cc5)c5ccc6c(c5)oc5ccccc56)cc4)cccc3o2)cc1] 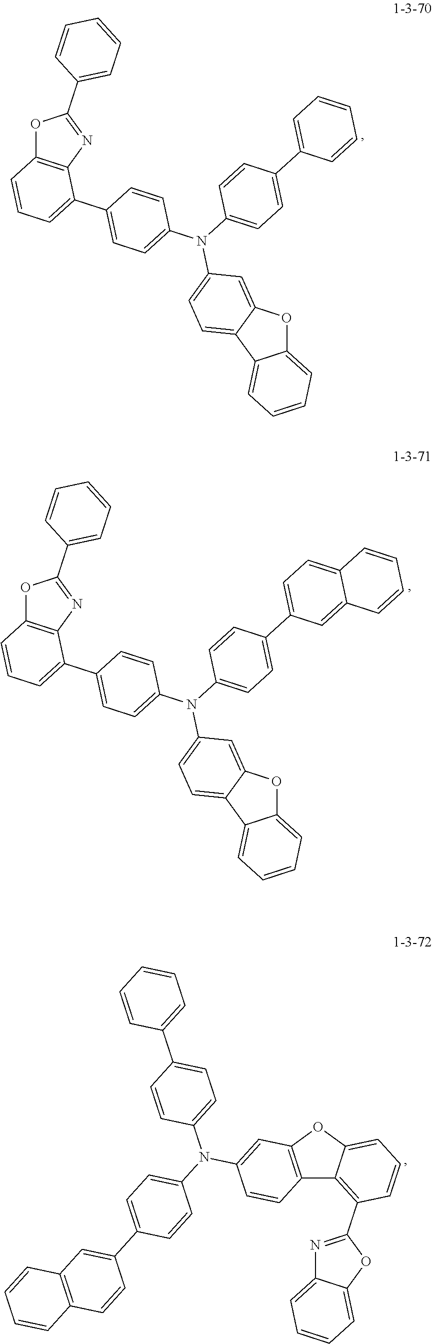 [SMILES: c1ccc(-c2ccc(N(c3ccc(-c4cccc5oc(-c6ccccc6)nc45)cc3)c3ccc4c(c3)oc3ccccc34)cc2)cc1 ; c1ccc(-c2nc3c(-c4ccc(N(c5ccc(-c6ccc7ccccc7c6)cc5)c5ccc6c(c5)oc5ccccc56)cc4)cccc3o2)cc1 ; c1ccc(-c2ccc(N(c3ccc(-c4ccc5ccccc5c4)cc3)c3ccc4c(c3)oc3cccc(-c5nc6ccccc6o5)c34)cc2)cc1] 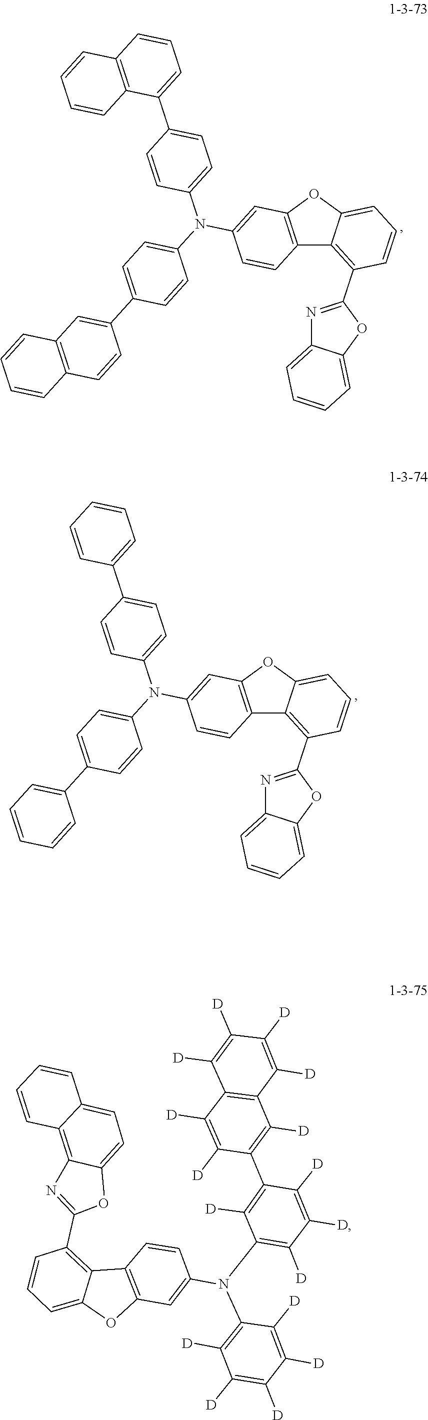 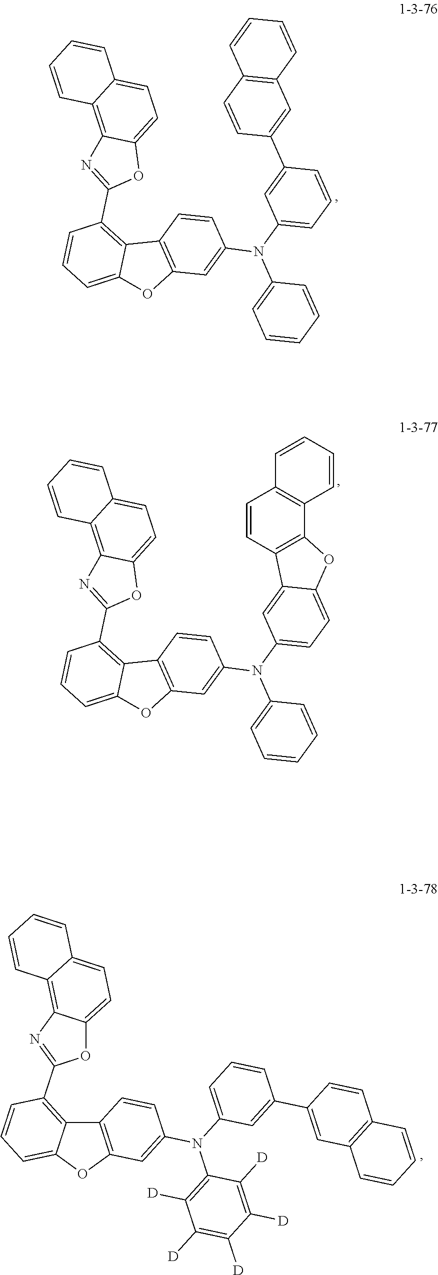 [SMILES: c1ccc(N(c2cccc(-c3ccc4ccccc4c3)c2)c2ccc3c(c2)oc2cccc(-c4nc5c(ccc6ccccc65)o4)c23)cc1 ; c1ccc(N(c2ccc3c(c2)oc2cccc(-c4nc5c(ccc6ccccc65)o4)c23)c2ccc3oc4c5ccccc5ccc4c3c2)cc1 ; [2H]c1c([2H])c([2H])c(N(c2cccc(-c3ccc4ccccc4c3)c2)c2ccc3c(c2)oc2cccc(-c4nc5c(ccc6ccccc65)o4)c23)c([2H])c1[2H]] 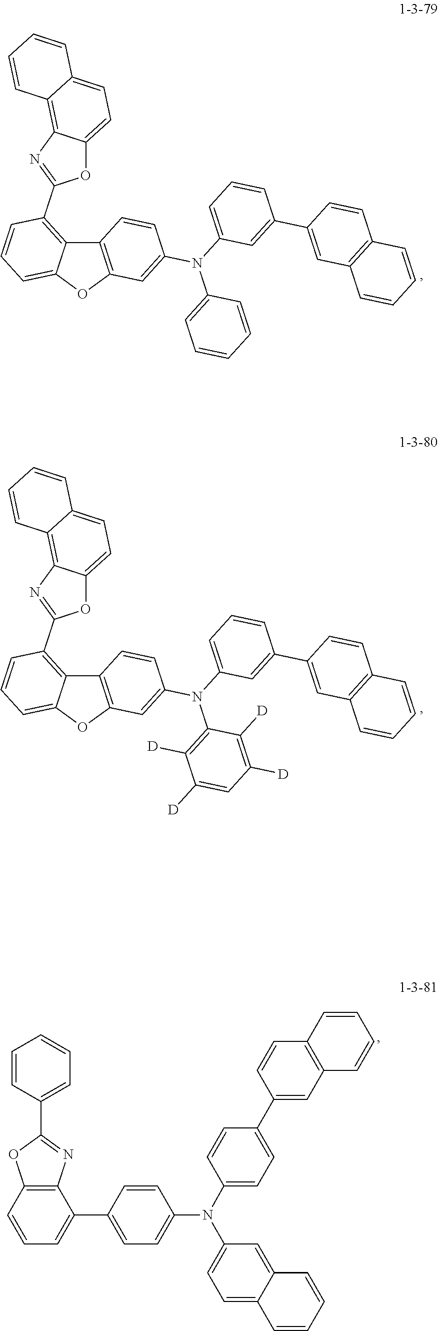 [SMILES: c1ccc(N(c2cccc(-c3ccc4ccccc4c3)c2)c2ccc3c(c2)oc2cccc(-c4nc5c(ccc6ccccc65)o4)c23)cc1 ; [2H]c1cc([2H])c([2H])c(N(c2cccc(-c3ccc4ccccc4c3)c2)c2ccc3c(c2)oc2cccc(-c4nc5c(ccc6ccccc65)o4)c23)c1[2H] ; c1ccc(-c2nc3c(-c4ccc(N(c5ccc(-c6ccc7ccccc7c6)cc5)c5ccc6ccccc6c5)cc4)cccc3o2)cc1] 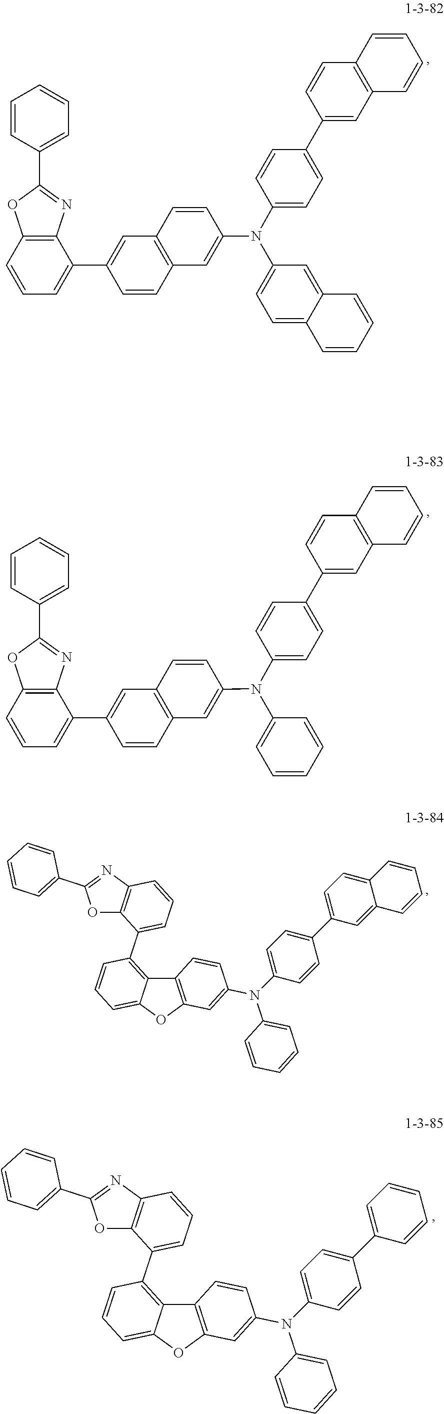 [SMILES: c1ccc(-c2nc3c(-c4ccc5cc(N(c6ccc(-c7ccc8ccccc8c7)cc6)c6ccc7ccccc7c6)ccc5c4)cccc3o2)cc1 ; c1ccc(-c2nc3c(-c4ccc5cc(N(c6ccccc6)c6ccc(-c7ccc8ccccc8c7)cc6)ccc5c4)cccc3o2)cc1 ; c1ccc(-c2nc3cccc(-c4cccc5oc6cc(N(c7ccccc7)c7ccc(-c8ccc9ccccc9c8)cc7)ccc6c45)c3o2)cc1 ; c1ccc(-c2ccc(N(c3ccccc3)c3ccc4c(c3)oc3cccc(-c5cccc6nc(-c7ccccc7)oc56)c34)cc2)cc1] 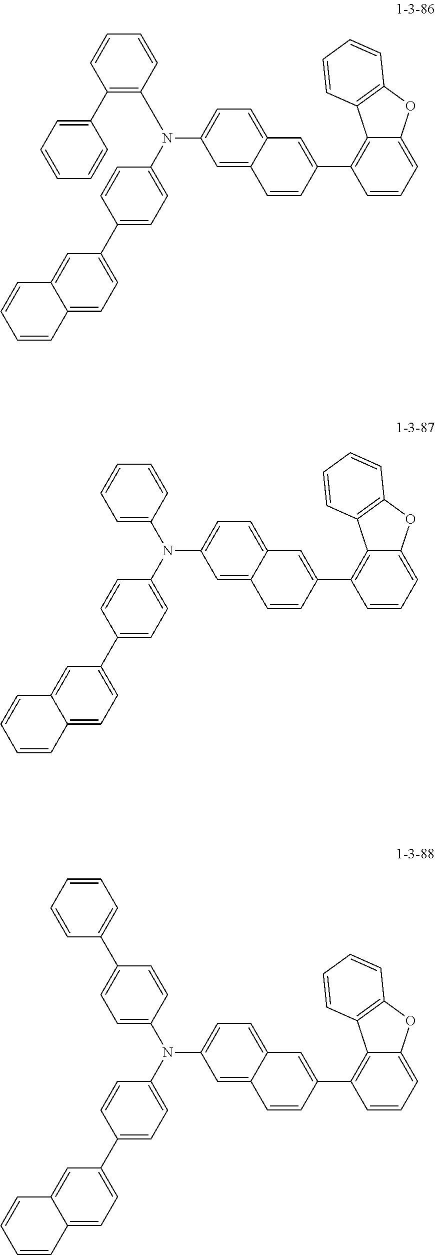 [SMILES: c1ccc(-c2ccccc2N(c2ccc(-c3ccc4ccccc4c3)cc2)c2ccc3cc(-c4cccc5oc6ccccc6c45)ccc3c2)cc1 ; c1ccc(N(c2ccc(-c3ccc4ccccc4c3)cc2)c2ccc3cc(-c4cccc5oc6ccccc6c45)ccc3c2)cc1 ; c1ccc(-c2ccc(N(c3ccc(-c4ccc5ccccc5c4)cc3)c3ccc4cc(-c5cccc6oc7ccccc7c56)ccc4c3)cc2)cc1] 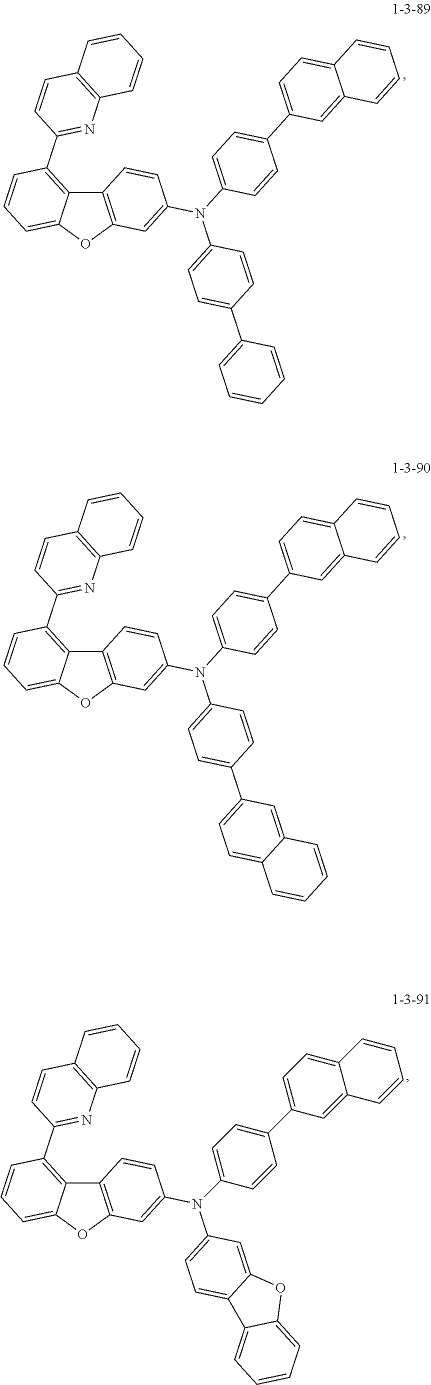 [SMILES: c1ccc(-c2ccc(N(c3ccc(-c4ccc5ccccc5c4)cc3)c3ccc4c(c3)oc3cccc(-c5ccc6ccccc6n5)c34)cc2)cc1 ; c1ccc2cc(-c3ccc(N(c4ccc(-c5ccc6ccccc6c5)cc4)c4ccc5c(c4)oc4cccc(-c6ccc7ccccc7n6)c45)cc3)ccc2c1 ; c1ccc2cc(-c3ccc(N(c4ccc5c(c4)oc4ccccc45)c4ccc5c(c4)oc4cccc(-c6ccc7ccccc7n6)c45)cc3)ccc2c1] 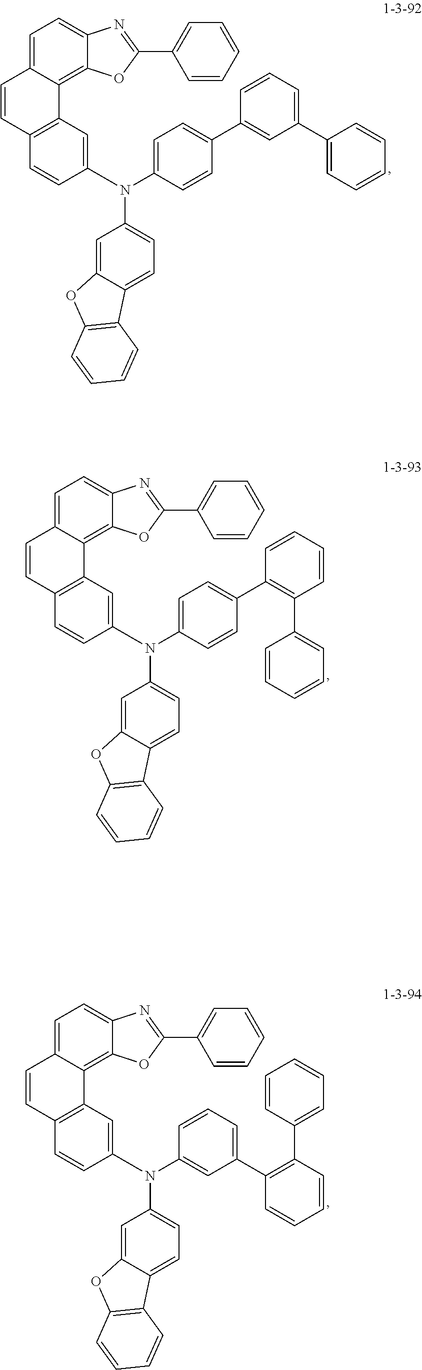 [SMILES: c1ccc(-c2cccc(-c3ccc(N(c4ccc5c(c4)oc4ccccc45)c4ccc5ccc6ccc7nc(-c8ccccc8)oc7c6c5c4)cc3)c2)cc1 ; c1ccc(-c2nc3ccc4ccc5ccc(N(c6ccc(-c7ccccc7-c7ccccc7)cc6)c6ccc7c(c6)oc6ccccc67)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1] 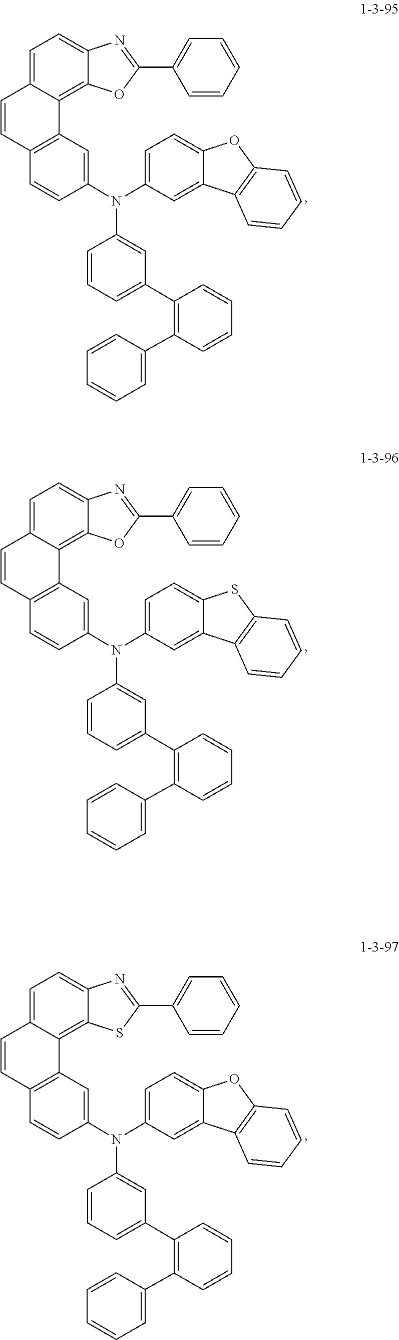 [SMILES: c1ccc(-c2nc3ccc4ccc5ccc(N(c6cccc(-c7ccccc7-c7ccccc7)c6)c6ccc7oc8ccccc8c7c6)cc5c4c3o2)cc1 ; c1ccc(-c2nc3ccc4ccc5ccc(N(c6cccc(-c7ccccc7-c7ccccc7)c6)c6ccc7sc8ccccc8c7c6)cc5c4c3o2)cc1 ; c1ccc(-c2nc3ccc4ccc5ccc(N(c6cccc(-c7ccccc7-c7ccccc7)c6)c6ccc7oc8ccccc8c7c6)cc5c4c3s2)cc1] 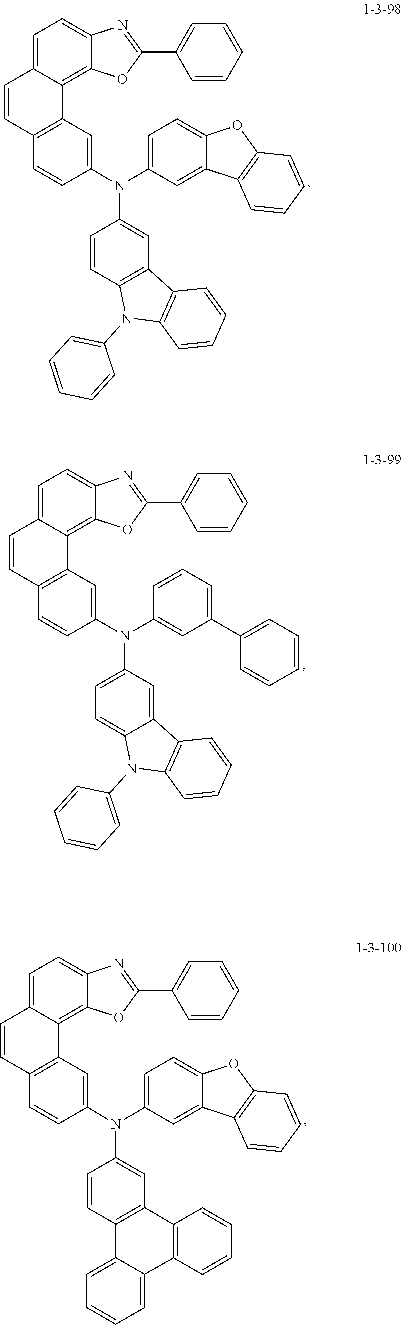 [SMILES: c1ccc(-c2nc3ccc4ccc5ccc(N(c6ccc7oc8ccccc8c7c6)c6ccc7c(c6)c6ccccc6n7-c6ccccc6)cc5c4c3o2)cc1 ; c1ccc(-c2cccc(N(c3ccc4ccc5ccc6nc(-c7ccccc7)oc6c5c4c3)c3ccc4c(c3)c3ccccc3n4-c3ccccc3)c2)cc1 ; c1ccc(-c2nc3ccc4ccc5ccc(N(c6ccc7oc8ccccc8c7c6)c6ccc7c8ccccc8c8ccccc8c7c6)cc5c4c3o2)cc1] 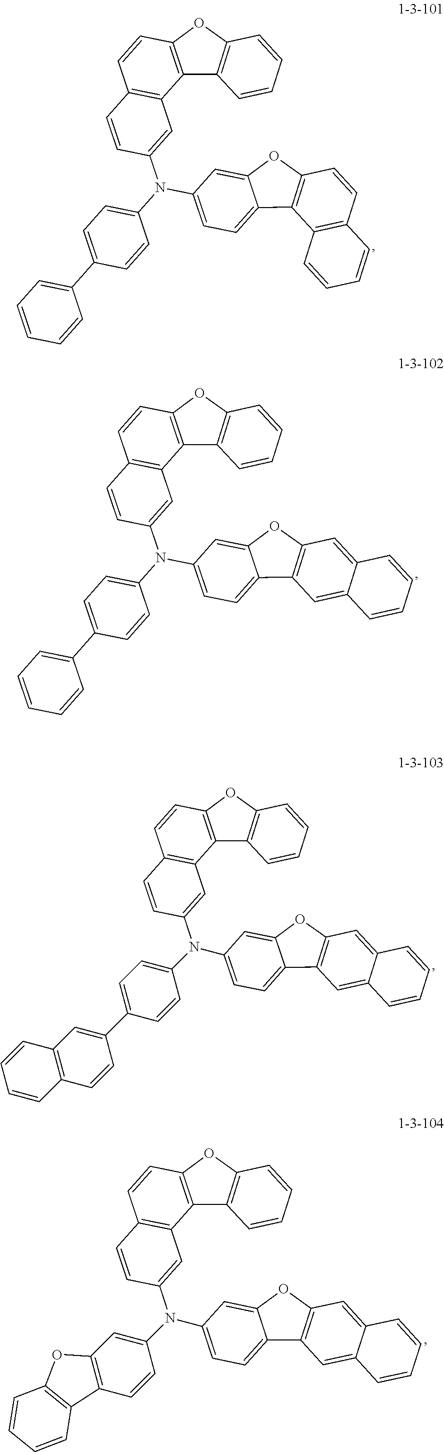 [SMILES: c1ccc(-c2ccc(N(c3ccc4c(c3)oc3ccc5ccccc5c34)c3ccc4ccc5oc6ccccc6c5c4c3)cc2)cc1 ; c1ccc(-c2ccc(N(c3ccc4c(c3)oc3cc5ccccc5cc34)c3ccc4ccc5oc6ccccc6c5c4c3)cc2)cc1 ; c1ccc2cc(-c3ccc(N(c4ccc5c(c4)oc4cc6ccccc6cc45)c4ccc5ccc6oc7ccccc7c6c5c4)cc3)ccc2c1 ; c1ccc2cc3c(cc2c1)oc1cc(N(c2ccc4c(c2)oc2ccccc24)c2ccc4ccc5oc6ccccc6c5c4c2)ccc13] 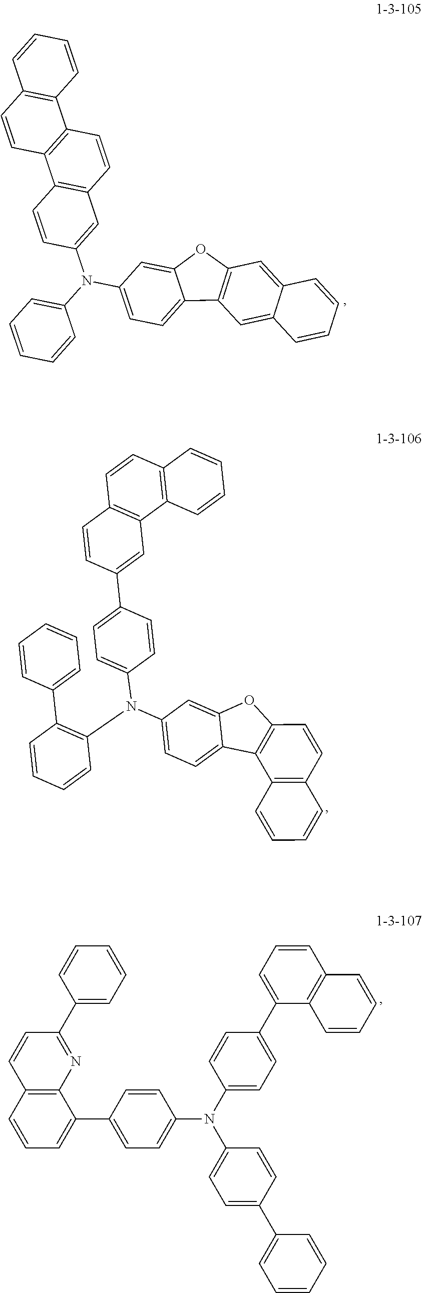 [SMILES: c1ccc(N(c2ccc3c(ccc4c5ccccc5ccc34)c2)c2ccc3c(c2)oc2cc4ccccc4cc23)cc1 ; c1ccc(-c2ccccc2N(c2ccc(-c3ccc4ccc5ccccc5c4c3)cc2)c2ccc3c(c2)oc2ccc4ccccc4c23)cc1 ; c1ccc(-c2ccc(N(c3ccc(-c4cccc5ccccc45)cc3)c3ccc(-c4cccc5ccc(-c6ccccc6)nc45)cc3)cc2)cc1] 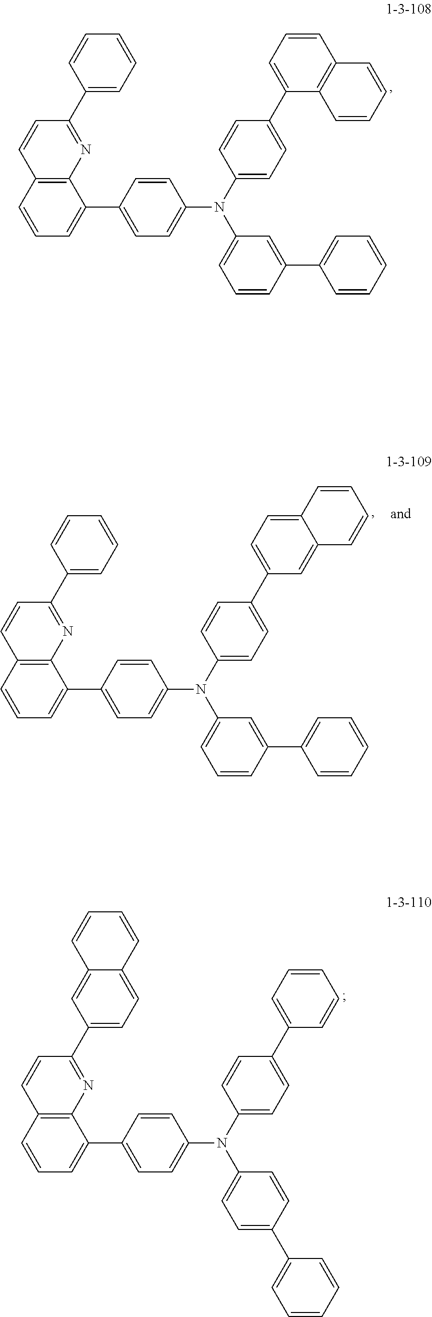 [SMILES: c1ccc(-c2cccc(N(c3ccc(-c4cccc5ccccc45)cc3)c3ccc(-c4cccc5ccc(-c6ccccc6)nc45)cc3)c2)cc1 ; c1ccc(-c2cccc(N(c3ccc(-c4ccc5ccccc5c4)cc3)c3ccc(-c4cccc5ccc(-c6ccccc6)nc45)cc3)c2)cc1 ; c1ccc(-c2ccc(N(c3ccc(-c4ccccc4)cc3)c3ccc(-c4cccc5ccc(-c6ccc7ccccc7c6)nc45)cc3)cc2)cc1]
wherein optionally, hydrogens in structures of Compound 1-1-1 to Compound 1-1-104, Compound 1-2-1 to Compound 1-2-100 and Compound 1-3-1 to Compound 1-3-110 can be partially or fully substituted with deuterium; and
the second host material is selected from the group consisting of Compound B-1 to Compound B-243: 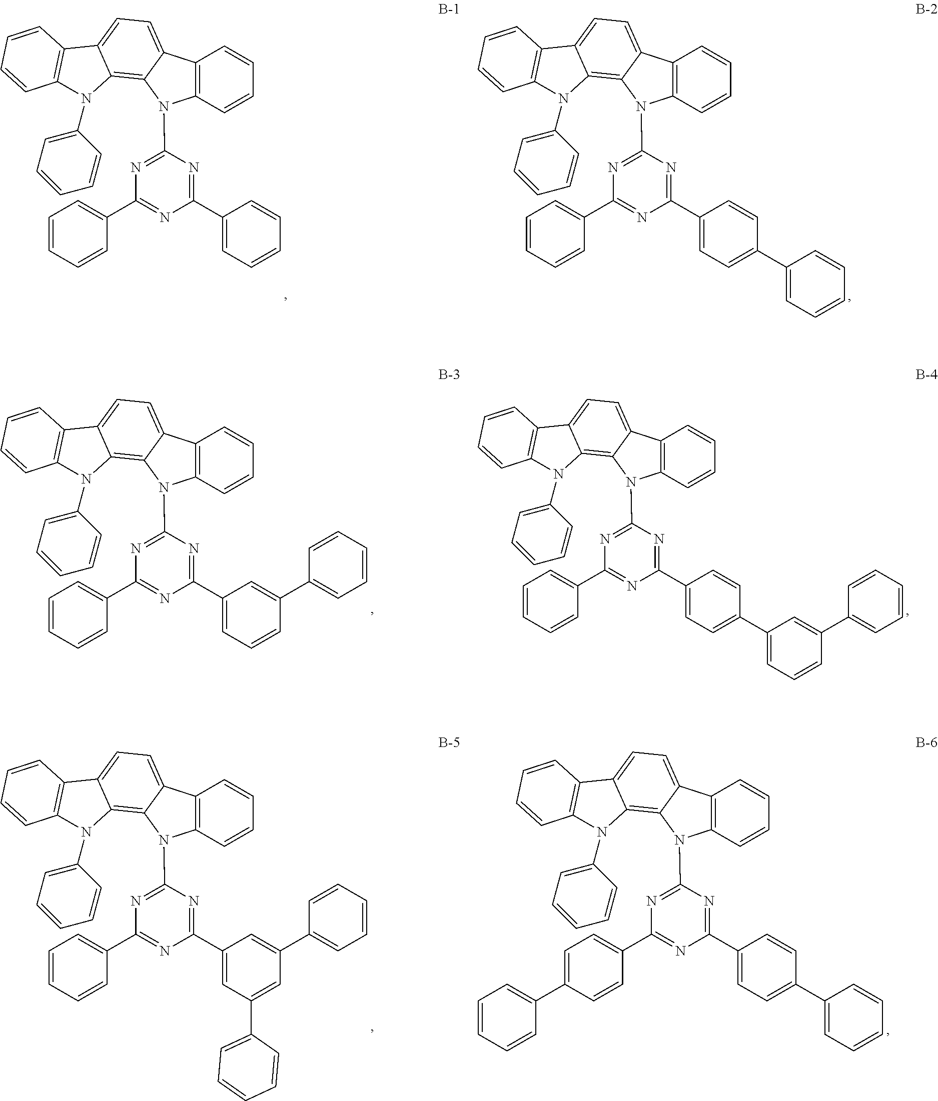 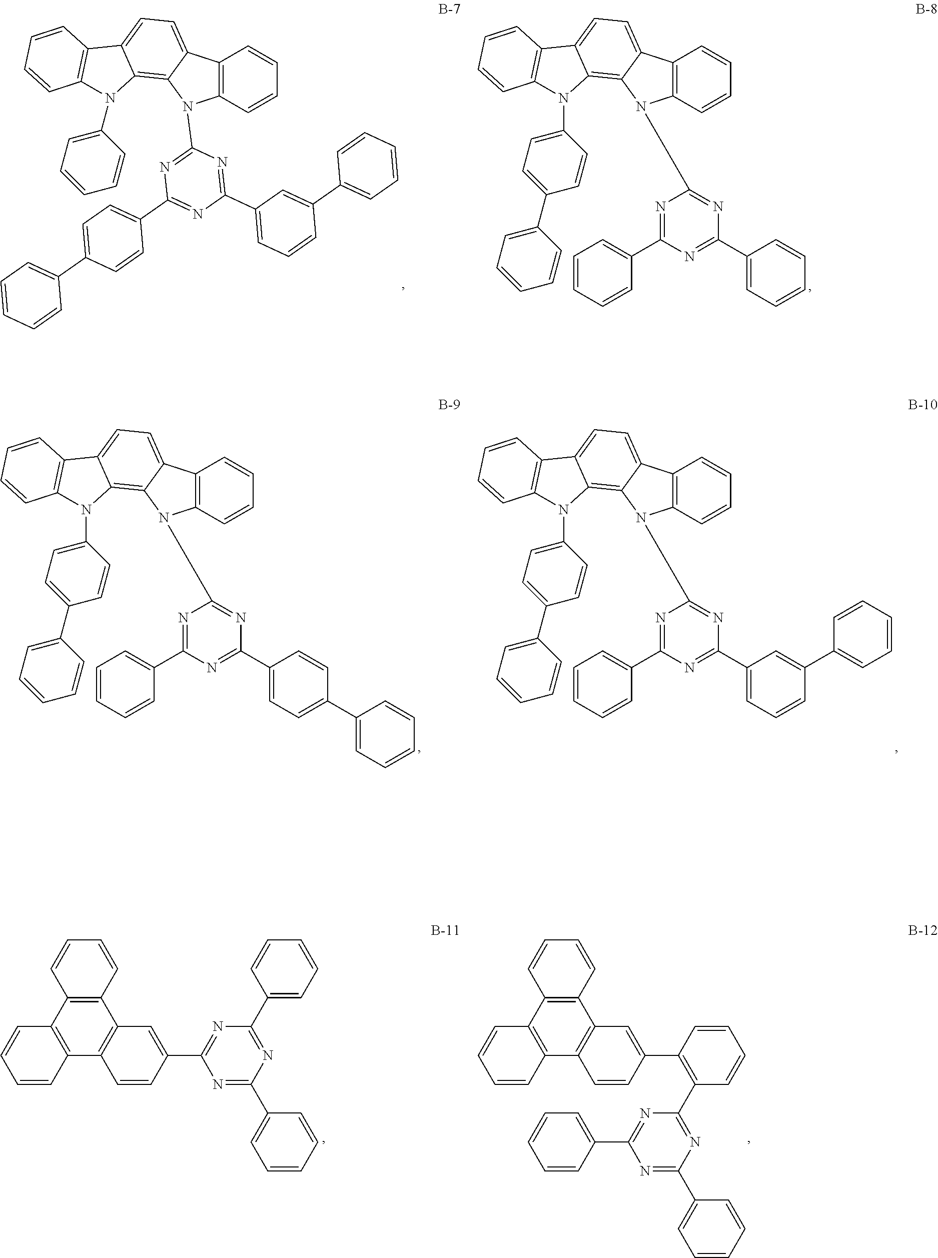 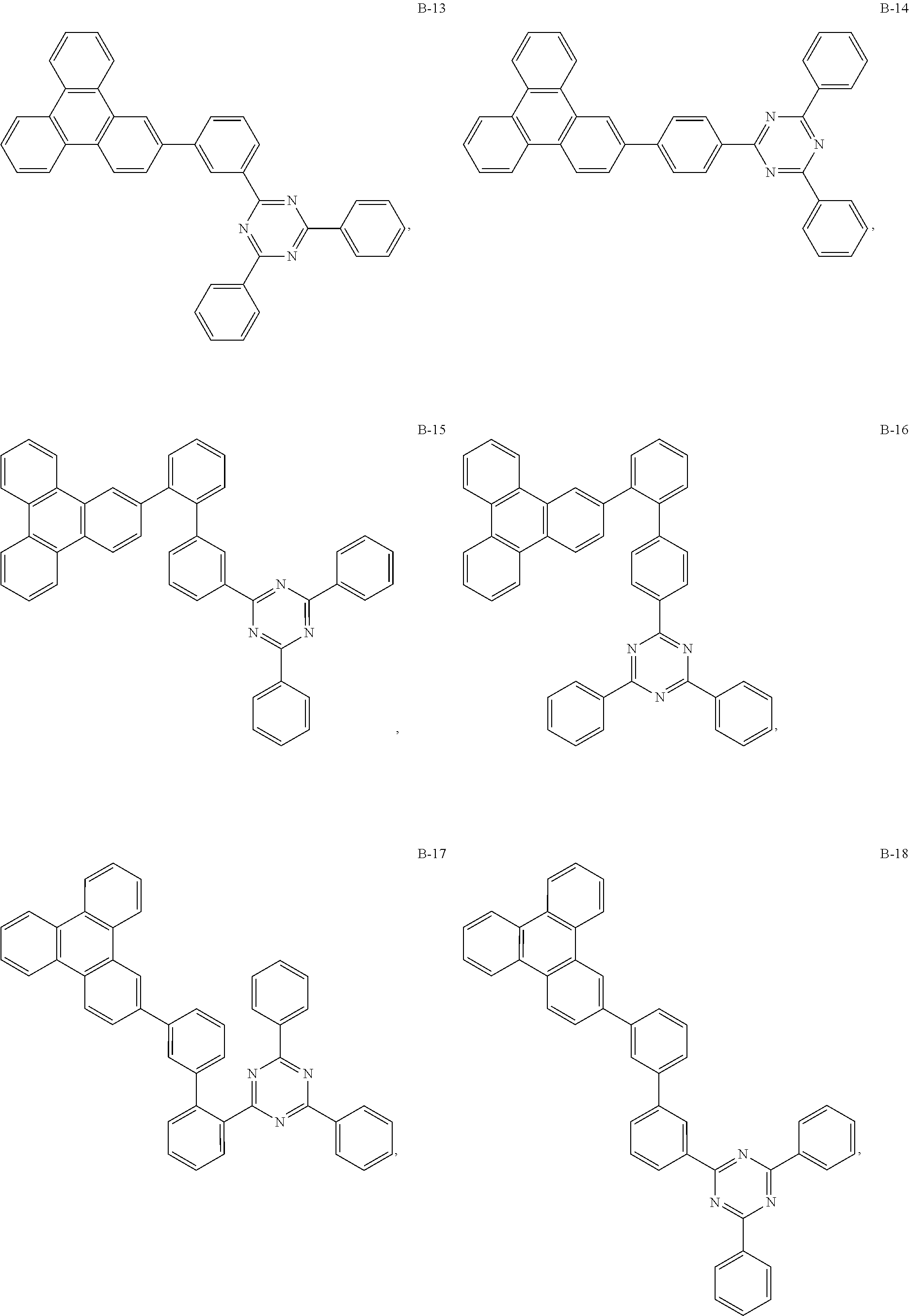 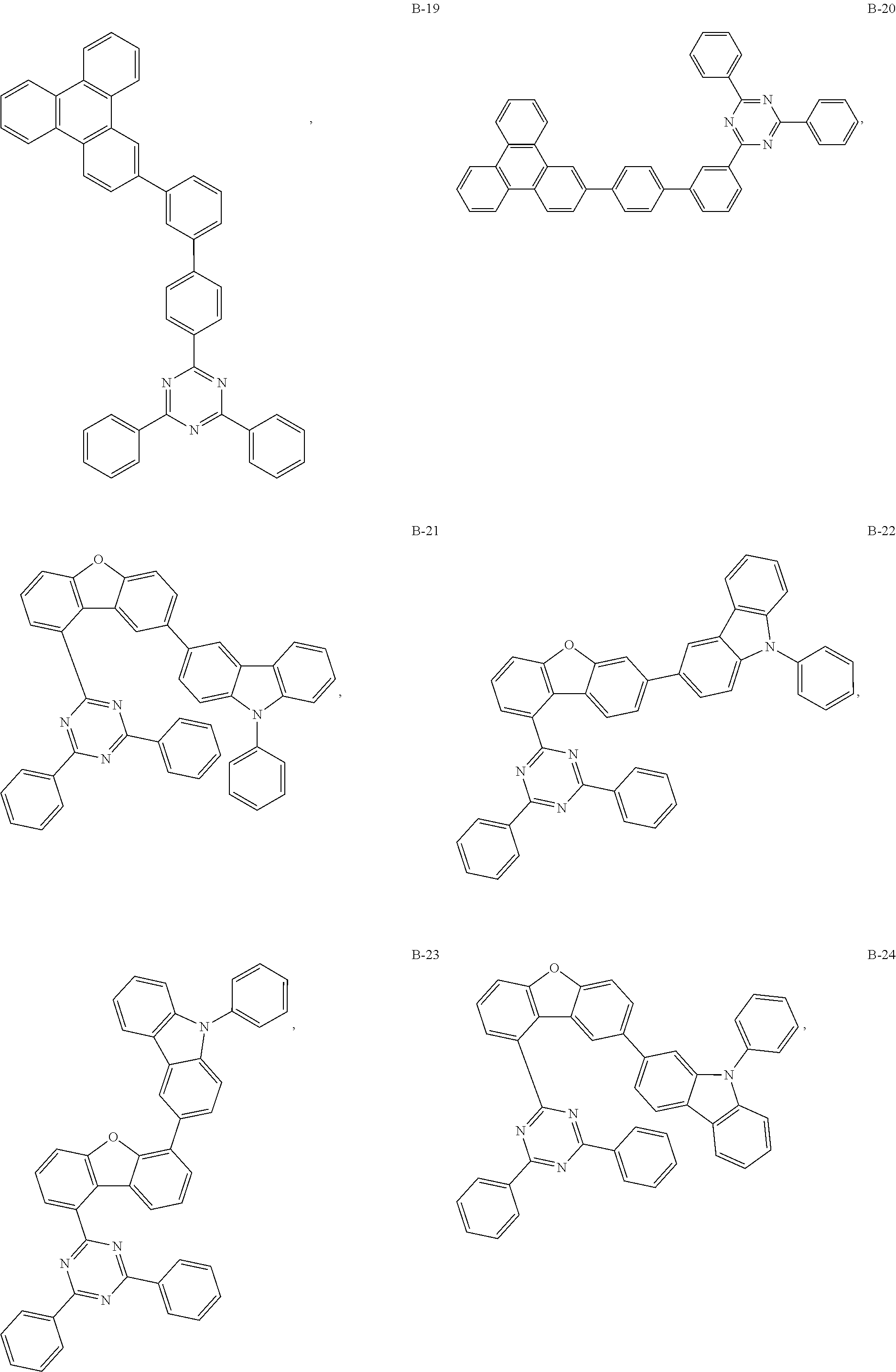 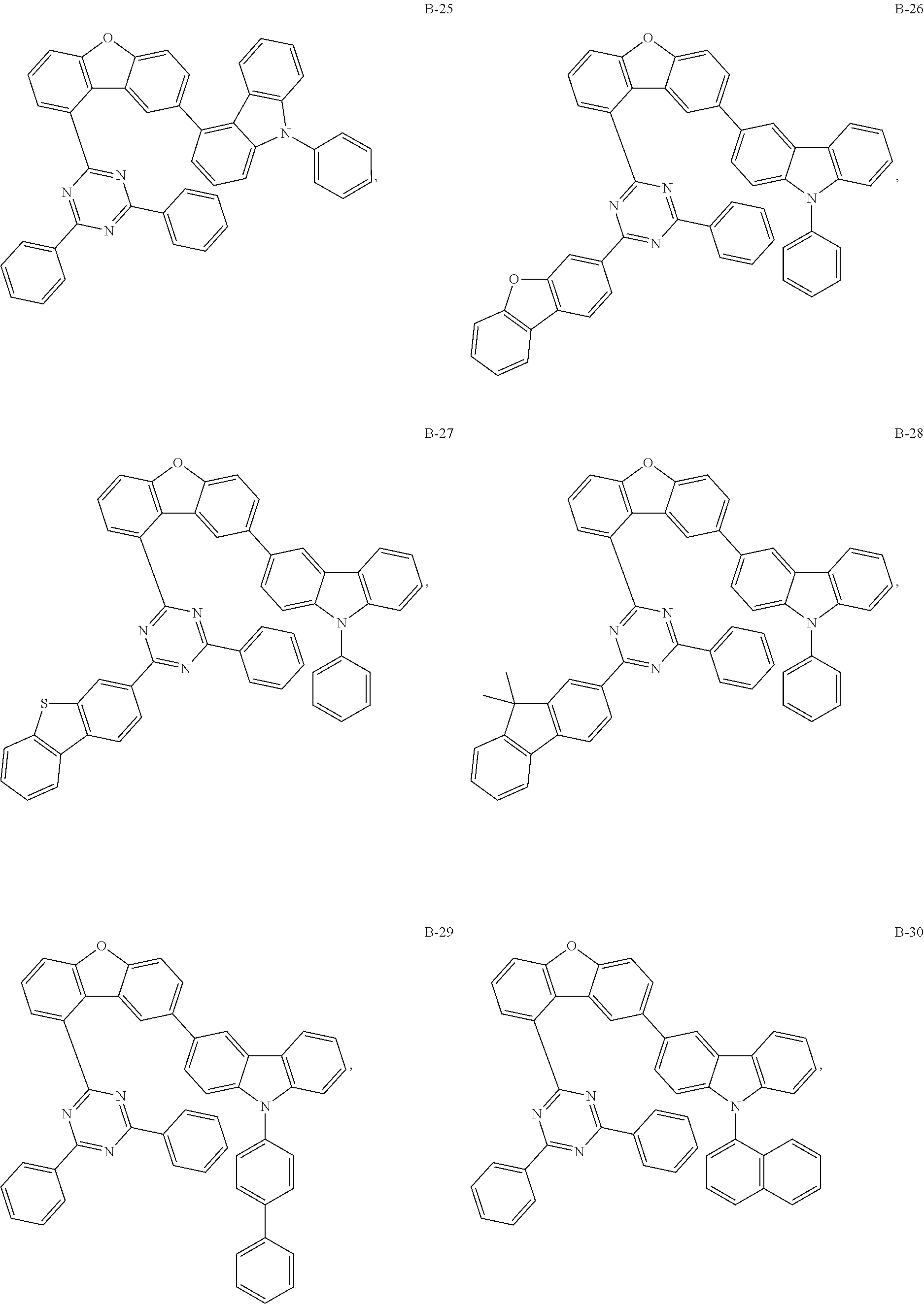 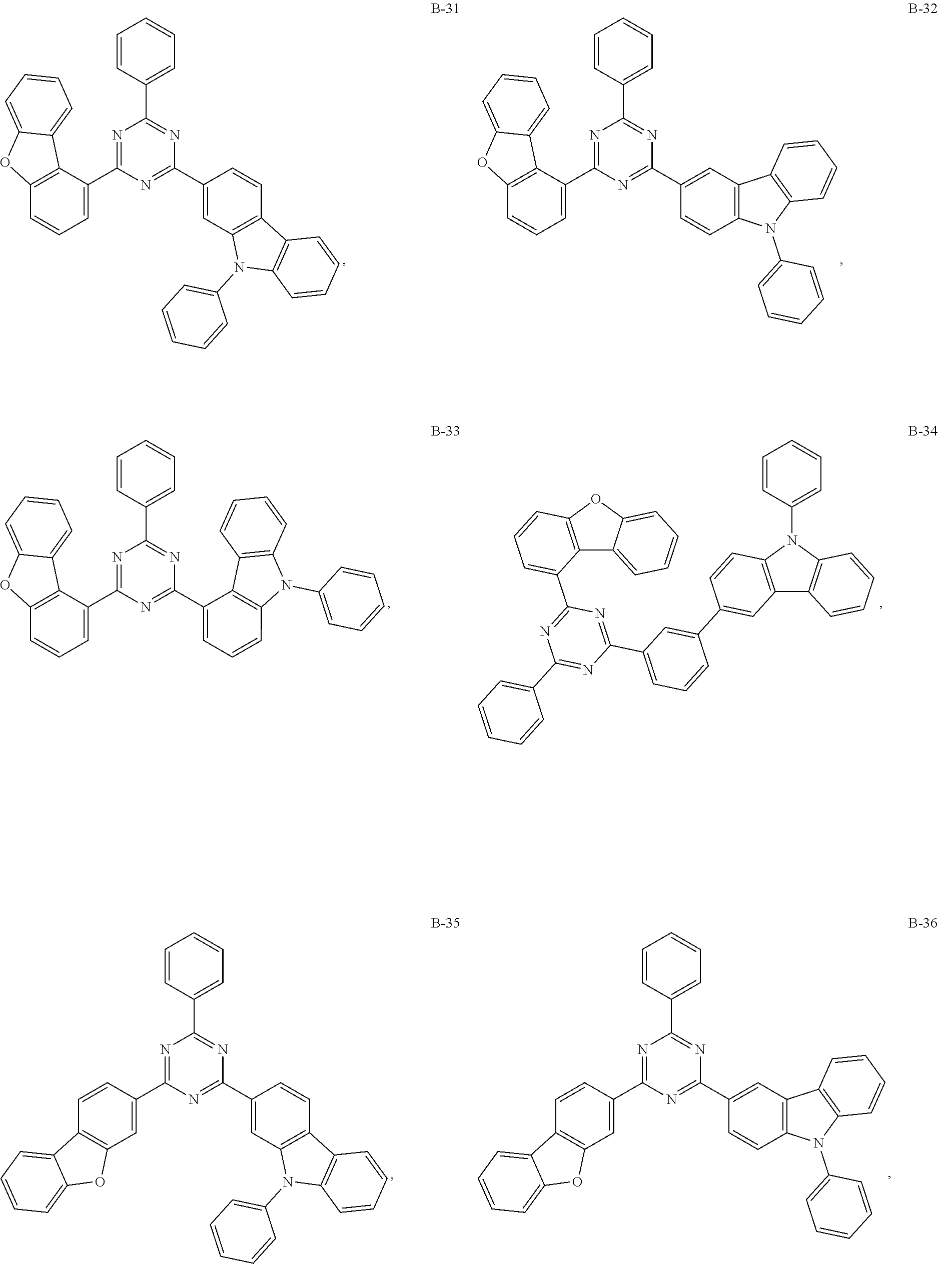 [SMILES: c1ccc(-c2nc(-c3ccc4c5ccccc5n(-c5ccccc5)c4c3)nc(-c3cccc4oc5ccccc5c34)n2)cc1 ; c1ccc(-c2nc(-c3ccc4c(c3)c3ccccc3n4-c3ccccc3)nc(-c3cccc4oc5ccccc5c34)n2)cc1 ; c1ccc(-c2nc(-c3cccc4oc5ccccc5c34)nc(-c3cccc4c3c3ccccc3n4-c3ccccc3)n2)cc1 ; c1ccc(-c2nc(-c3cccc(-c4ccc5c(c4)c4ccccc4n5-c4ccccc4)c3)nc(-c3cccc4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1] 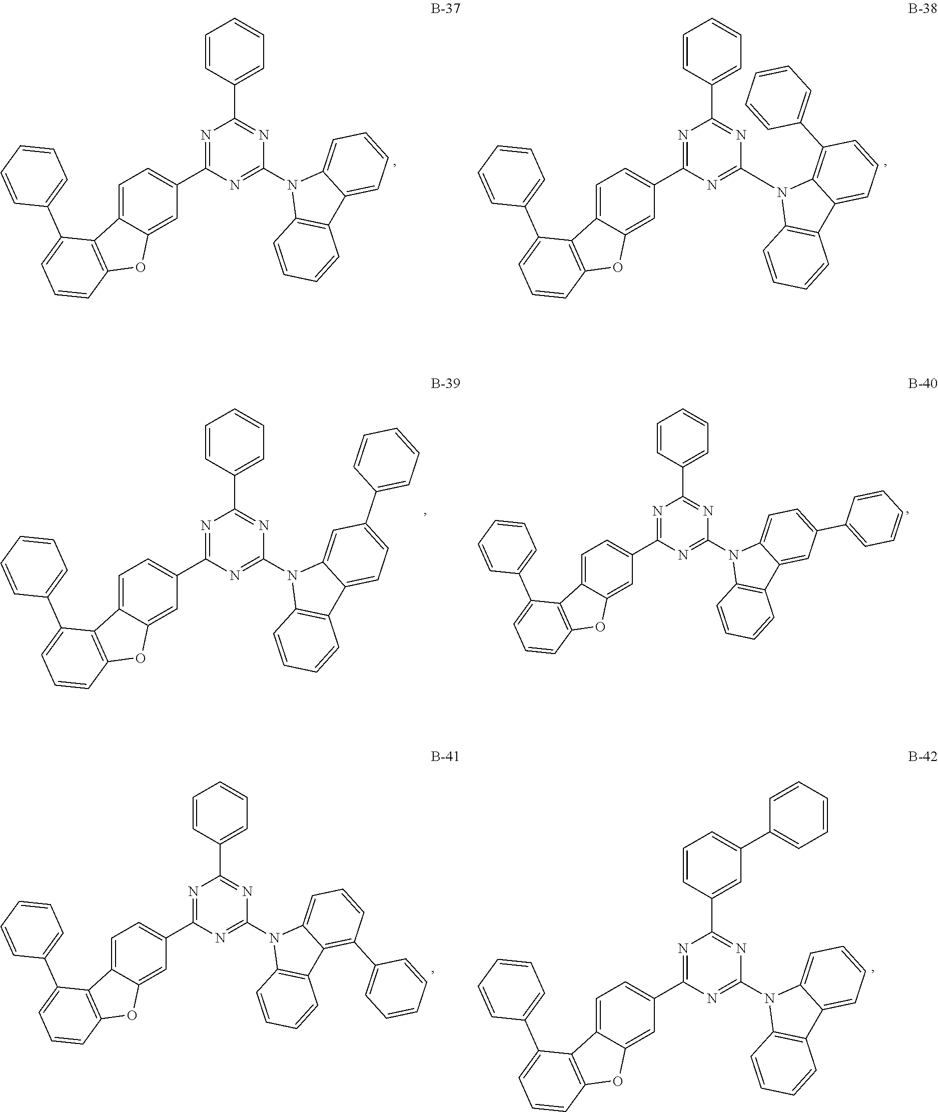 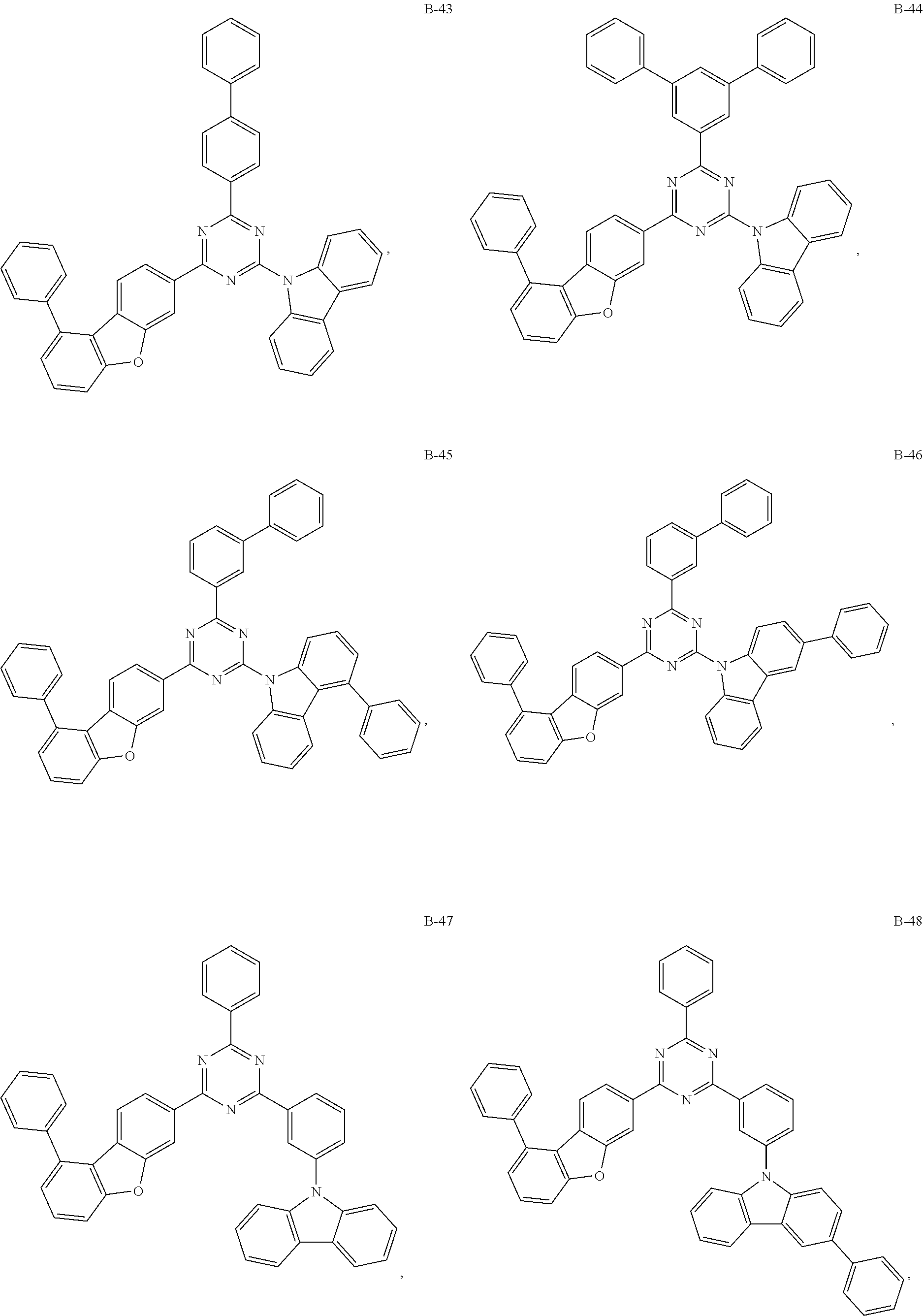 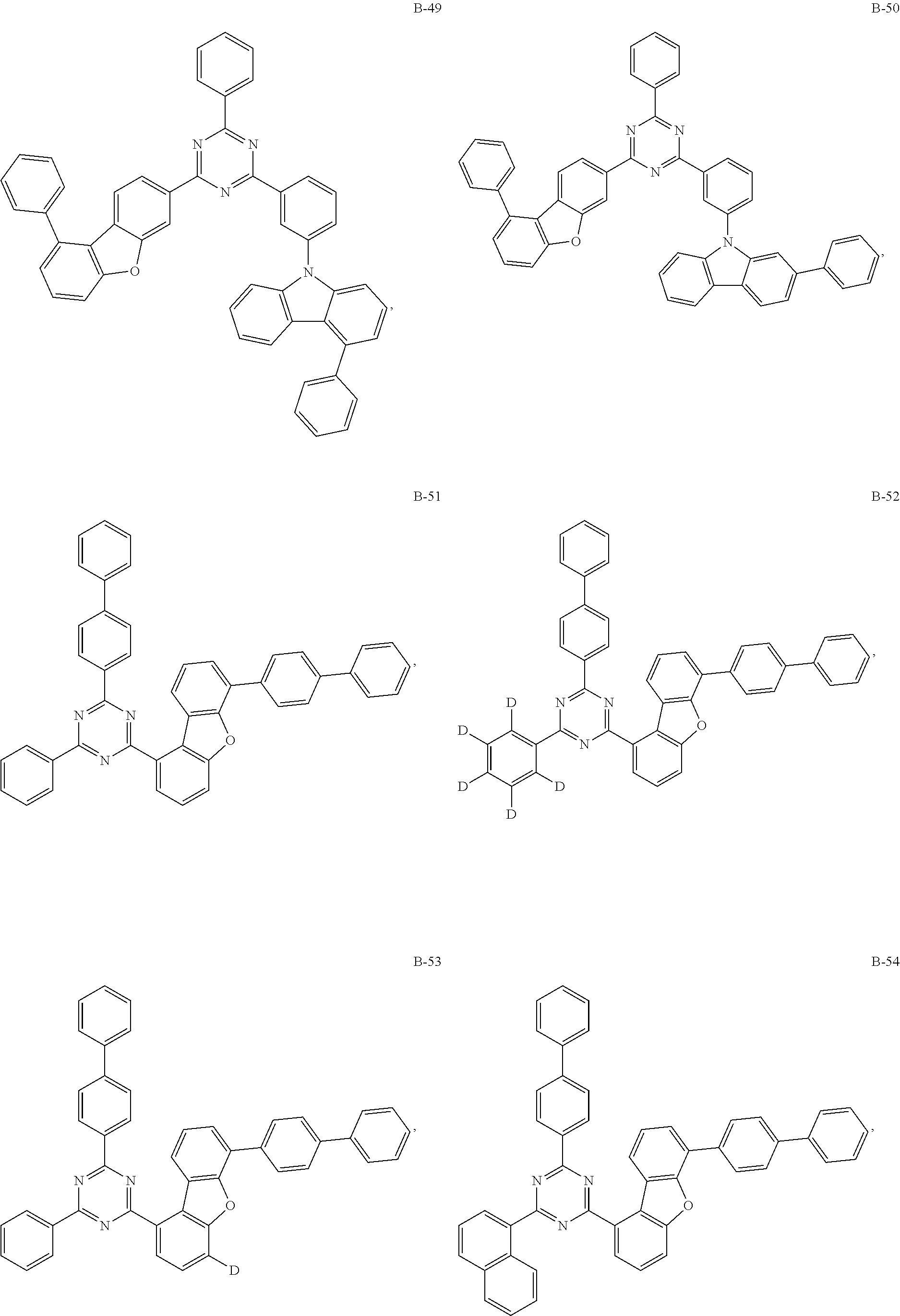 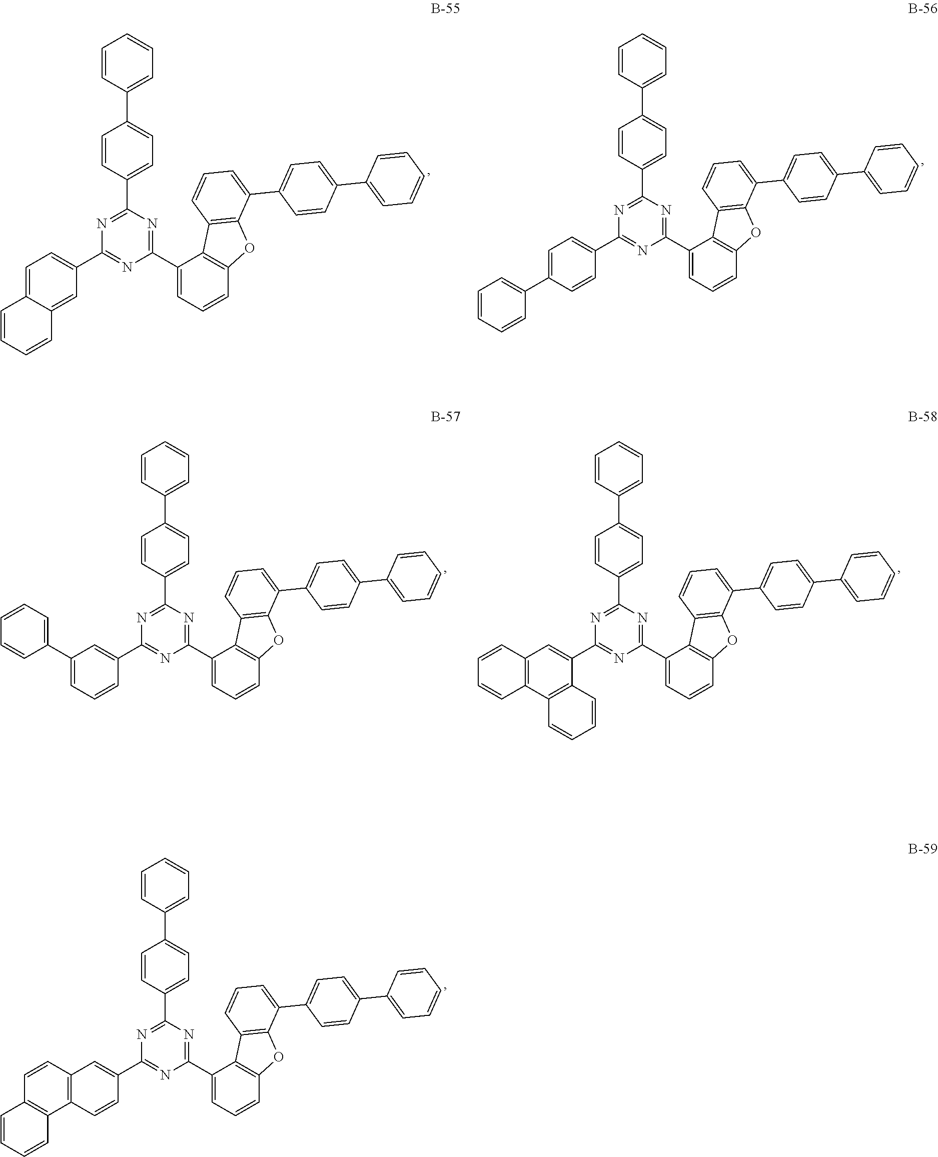 [SMILES: c1ccc(-c2ccc(-c3nc(-c4ccc5ccccc5c4)nc(-c4cccc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1 ; c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1] 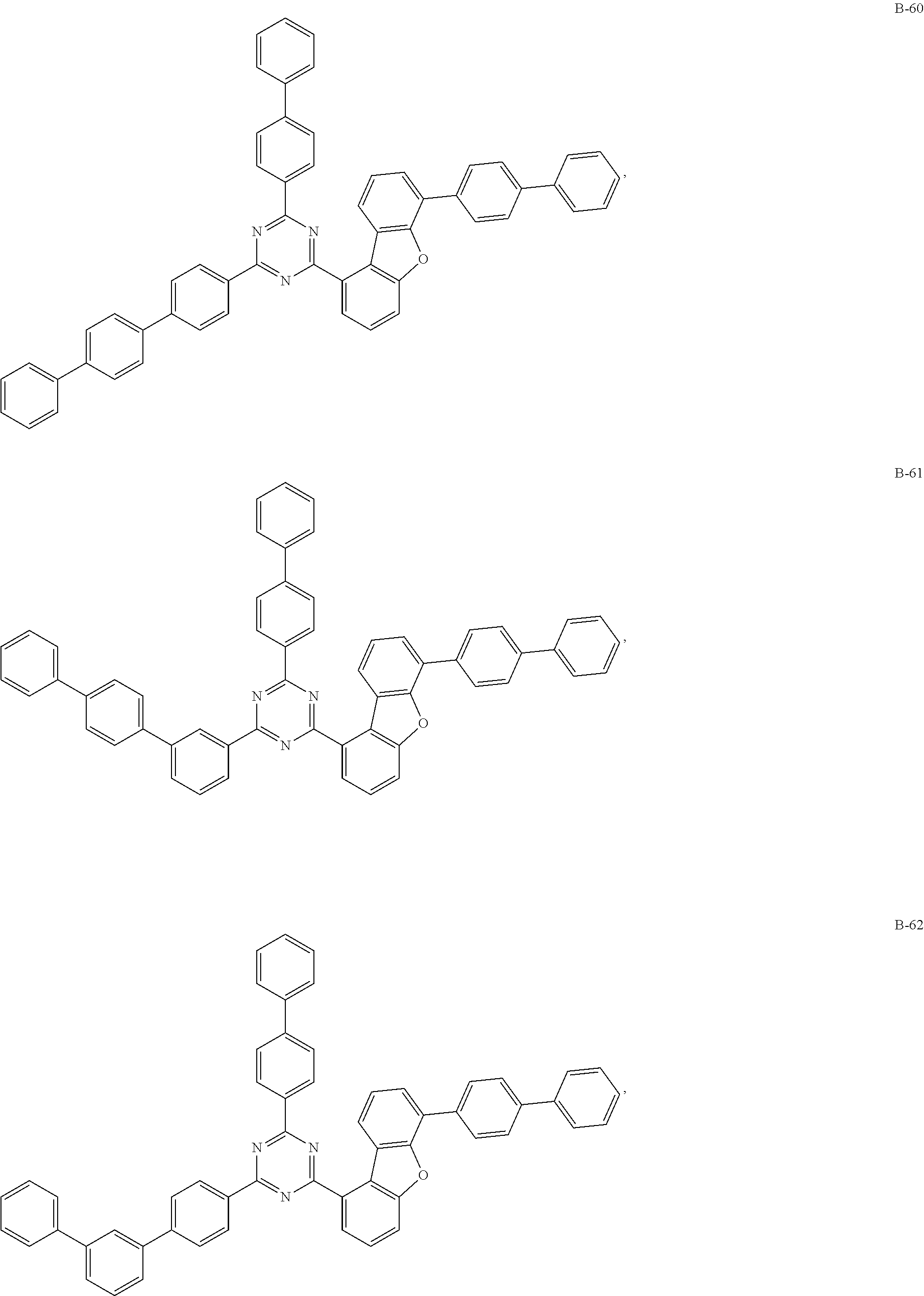 [SMILES: c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1] 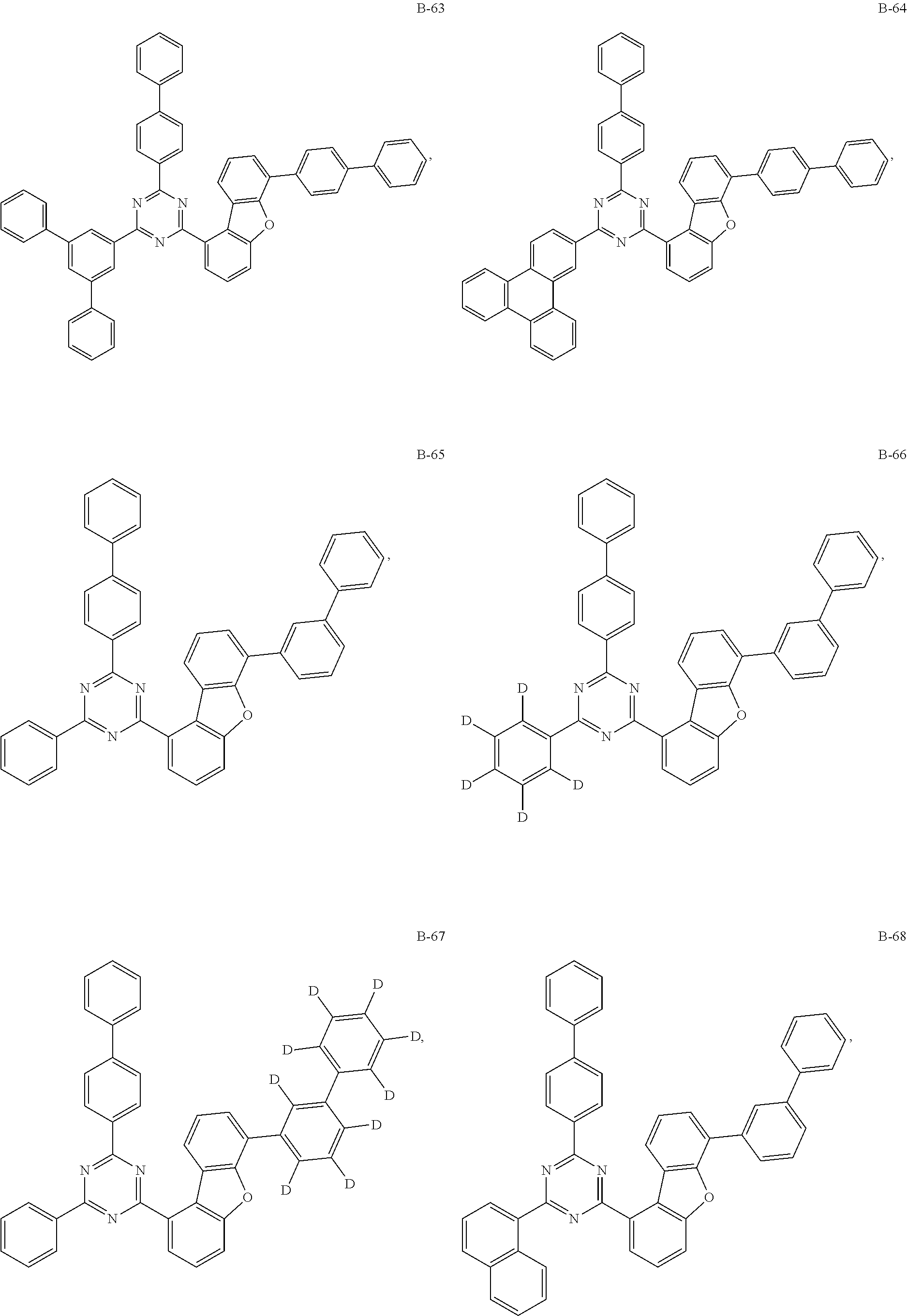 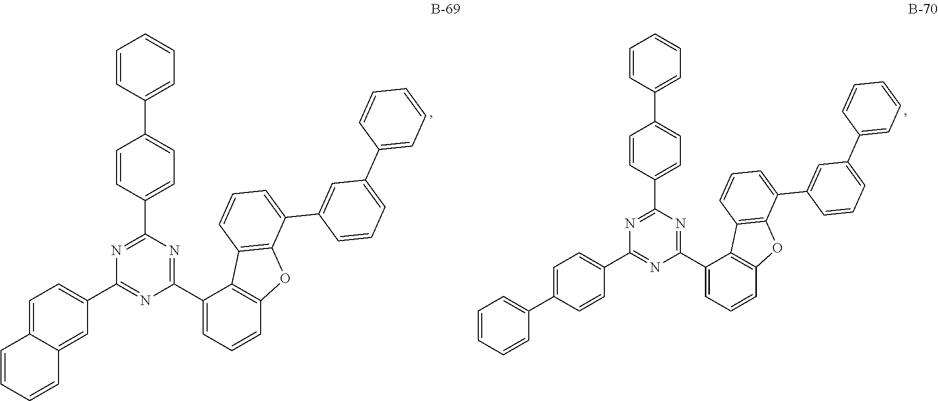 [SMILES: c1ccc(-c2ccc(-c3nc(-c4ccc5ccccc5c4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1] 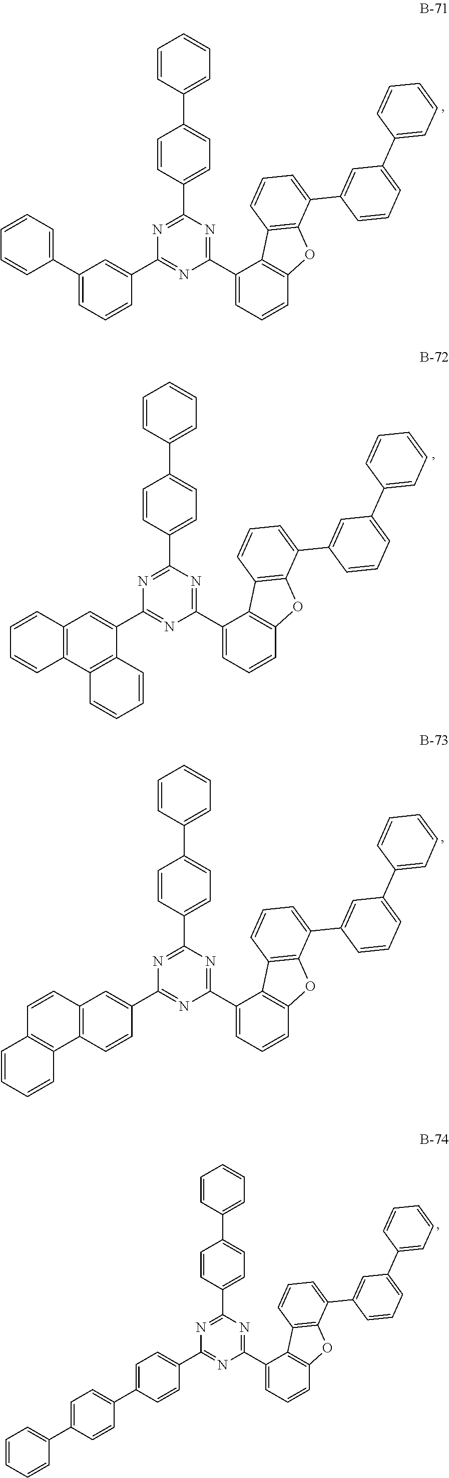 [SMILES: c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4cc5ccccc5c5ccccc45)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3ccc(-c4nc(-c5ccc(-c6ccccc6)cc5)nc(-c5cccc6oc7c(-c8cccc(-c9ccccc9)c8)cccc7c56)n4)cc3)cc2)cc1] 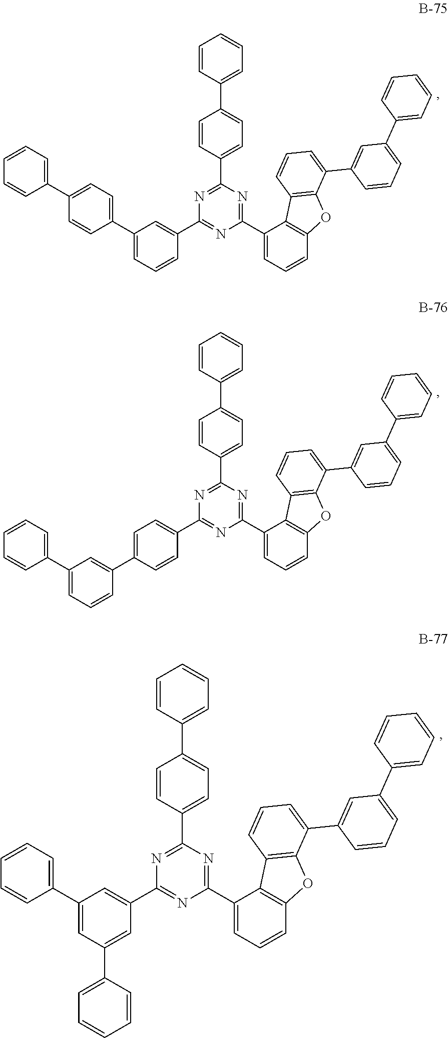 [SMILES: c1ccc(-c2ccc(-c3cccc(-c4nc(-c5ccc(-c6ccccc6)cc5)nc(-c5cccc6oc7c(-c8cccc(-c9ccccc9)c8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7cccc(-c8ccccc8)c7)cccc6c45)n3)cc2)cc1 ; c1ccc(-c2ccc(-c3nc(-c4cc(-c5ccccc5)cc(-c5ccccc5)c4)nc(-c4cccc5oc6c(-c7cccc(-c8ccccc8)c7)cccc6c45)n3)cc2)cc1] 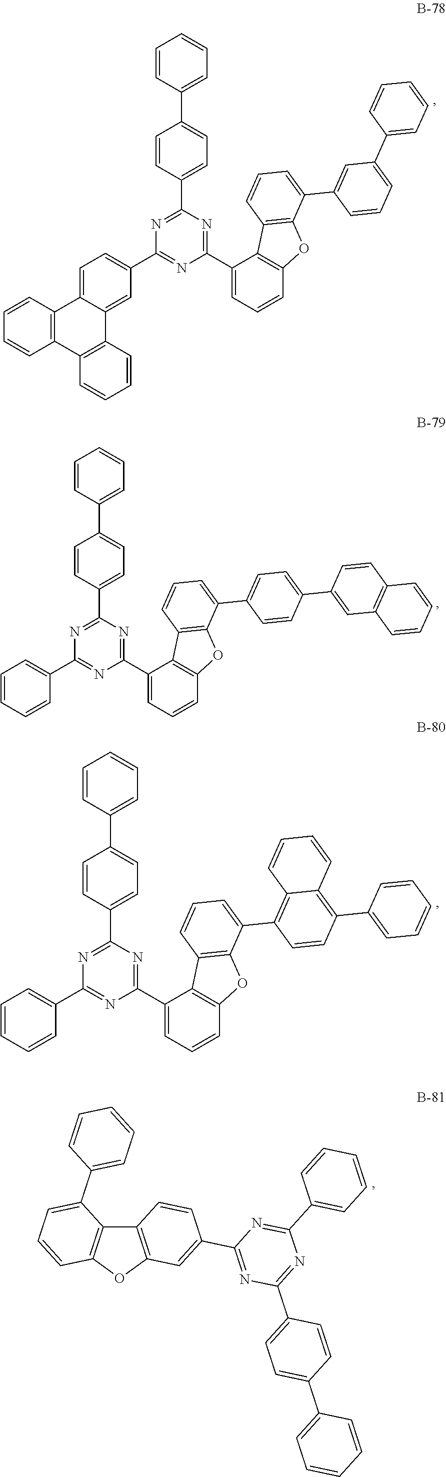 [SMILES: c1ccc(-c2ccc(-c3nc(-c4ccc5c6ccccc6c6ccccc6c5c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4cccc5oc6c(-c7ccc(-c8ccc9ccccc9c8)cc7)cccc6c45)n3)cc2)cc1 ; c1ccc(-c2ccc(-c3nc(-c4ccccc4)nc(-c4cccc5oc6c(-c7ccc(-c8ccccc8)c8ccccc78)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1] 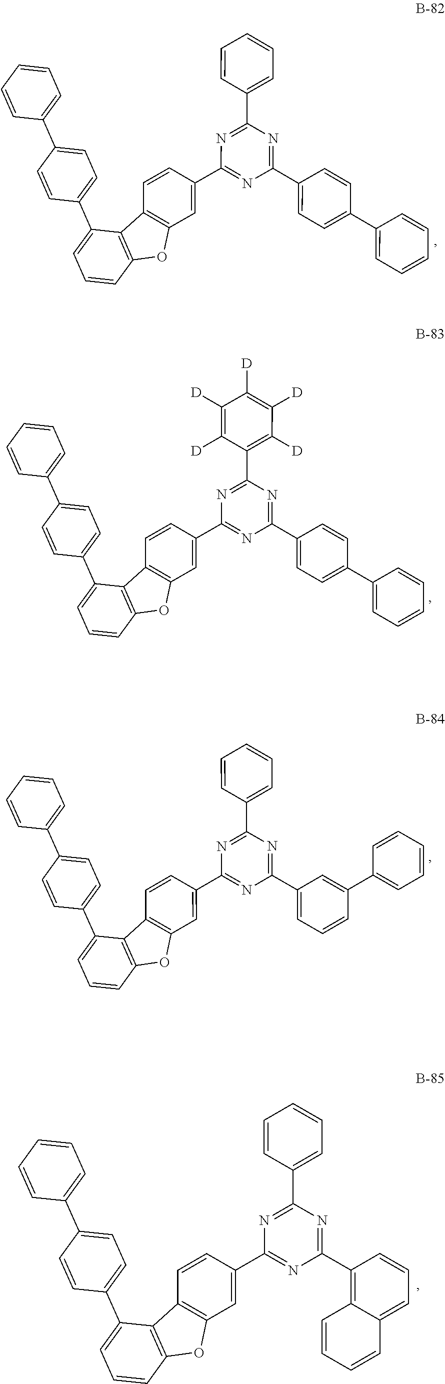 [SMILES: c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3cccc4oc5cc(-c6nc(-c7ccccc7)nc(-c7cccc8ccccc78)n6)ccc5c34)cc2)cc1] 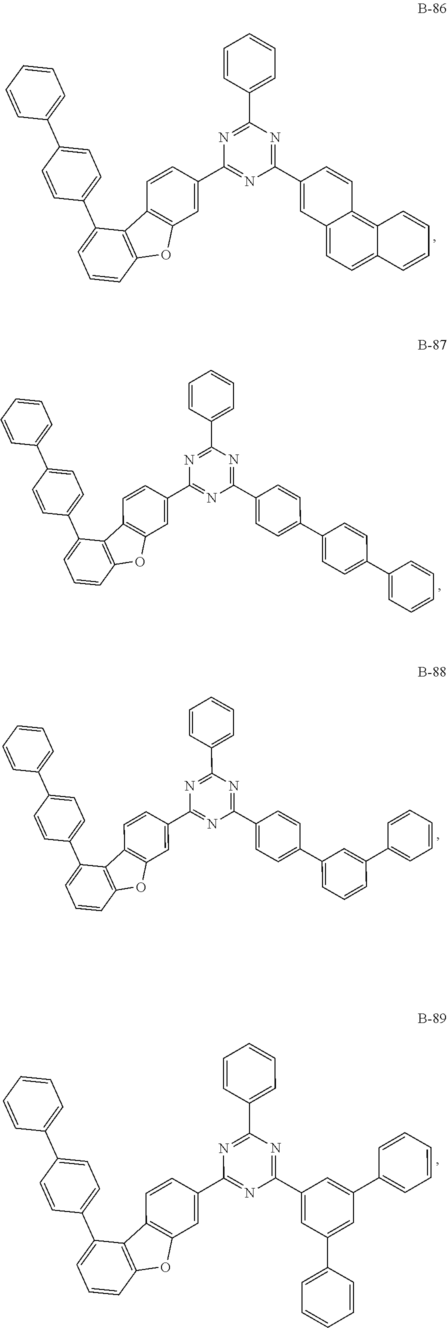 [SMILES: c1ccc(-c2ccc(-c3cccc4oc5cc(-c6nc(-c7ccccc7)nc(-c7ccc8c(ccc9ccccc98)c7)n6)ccc5c34)cc2)cc1 ; c1ccc(-c2ccc(-c3ccc(-c4nc(-c5ccccc5)nc(-c5ccc6c(c5)oc5cccc(-c7ccc(-c8ccccc8)cc7)c56)n4)cc3)cc2)cc1 ; c1ccc(-c2ccc(-c3cccc4oc5cc(-c6nc(-c7ccccc7)nc(-c7ccc(-c8cccc(-c9ccccc9)c8)cc7)n6)ccc5c34)cc2)cc1 ; c1ccc(-c2ccc(-c3cccc4oc5cc(-c6nc(-c7ccccc7)nc(-c7cc(-c8ccccc8)cc(-c8ccccc8)c7)n6)ccc5c34)cc2)cc1] 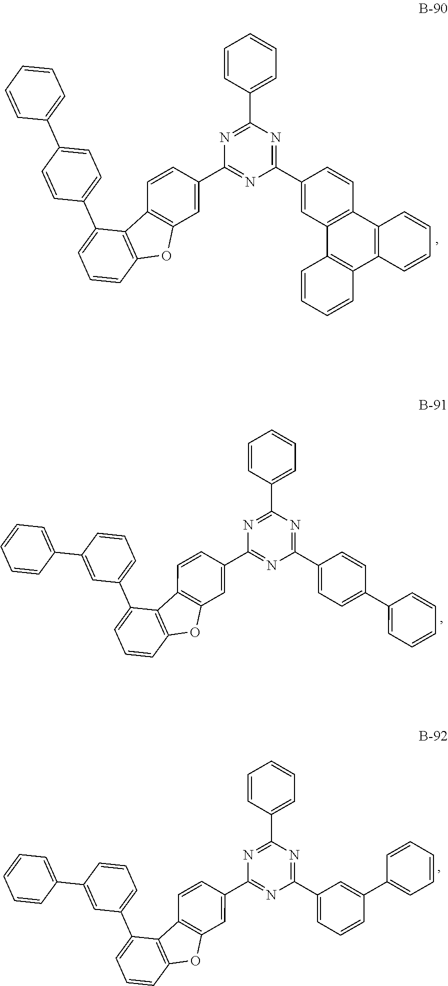 [SMILES: c1ccc(-c2ccc(-c3cccc4oc5cc(-c6nc(-c7ccccc7)nc(-c7ccc8c9ccccc9c9ccccc9c8c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1] 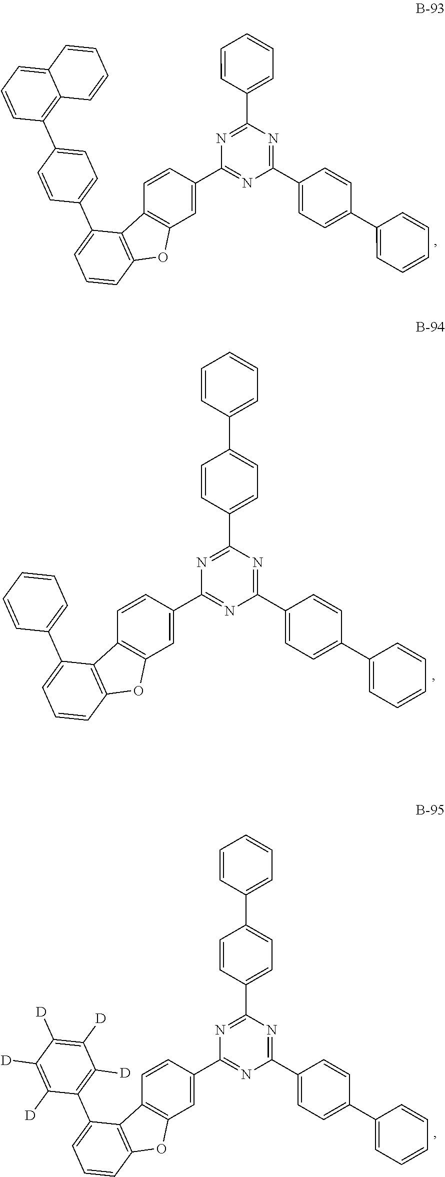 [SMILES: c1ccc(-c2ccc(-c3nc(-c4ccccc4)nc(-c4ccc5c(c4)oc4cccc(-c6ccc(-c7cccc8ccccc78)cc6)c45)n3)cc2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H]] 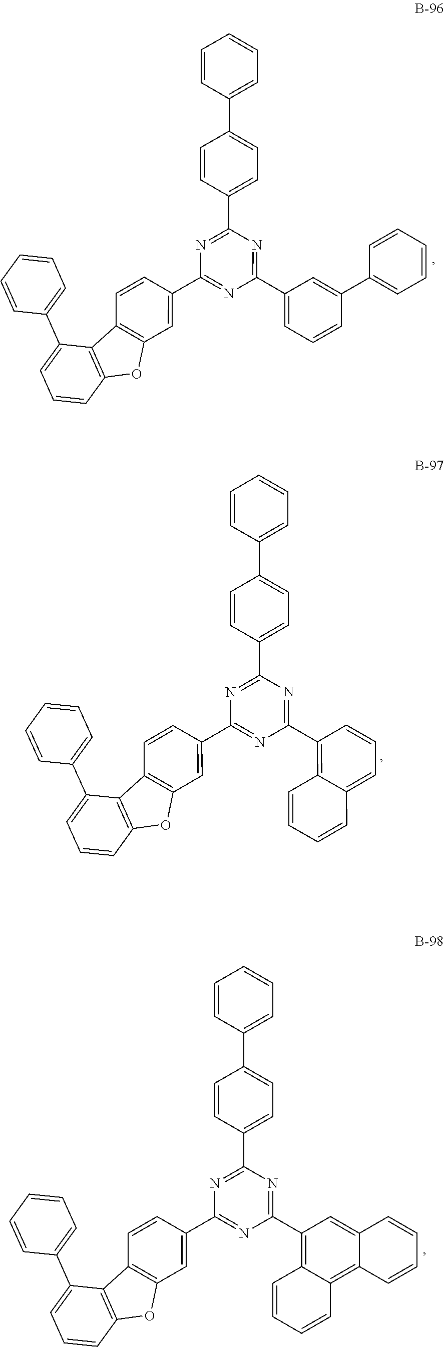 [SMILES: c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc5c(c4)oc4cccc(-c6ccccc6)c45)nc(-c4cccc5ccccc45)n3)cc2)cc1 ; c1ccc(-c2ccc(-c3nc(-c4ccc5c(c4)oc4cccc(-c6ccccc6)c45)nc(-c4cc5ccccc5c5ccccc45)n3)cc2)cc1] 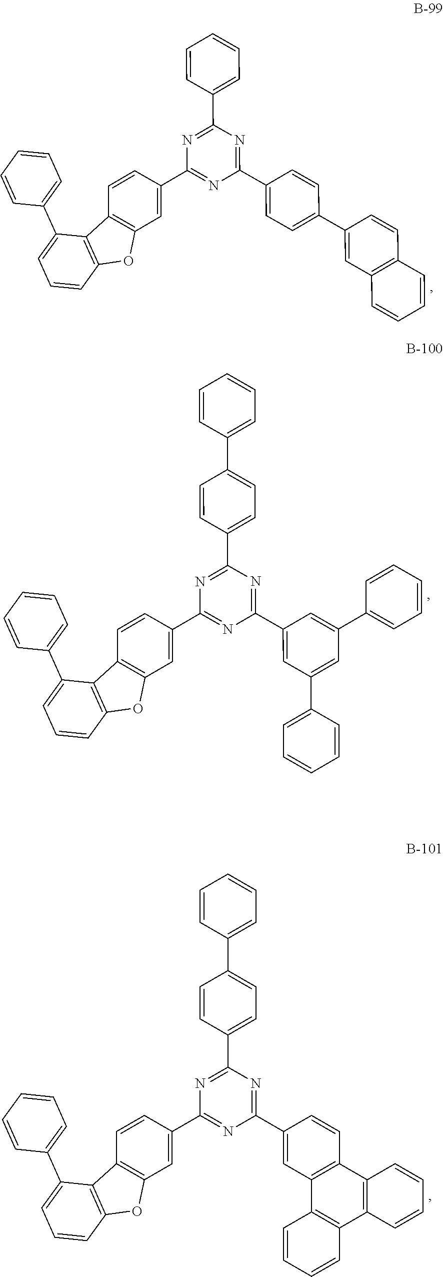 [SMILES: c1ccc(-c2nc(-c3ccc(-c4ccc5ccccc5c4)cc3)nc(-c3ccc4c(c3)oc3cccc(-c5ccccc5)c34)n2)cc1 ; c1ccc(-c2ccc(-c3nc(-c4cc(-c5ccccc5)cc(-c5ccccc5)c4)nc(-c4ccc5c(c4)oc4cccc(-c6ccccc6)c45)n3)cc2)cc1 ; c1ccc(-c2ccc(-c3nc(-c4ccc5c(c4)oc4cccc(-c6ccccc6)c45)nc(-c4ccc5c6ccccc6c6ccccc6c5c4)n3)cc2)cc1] 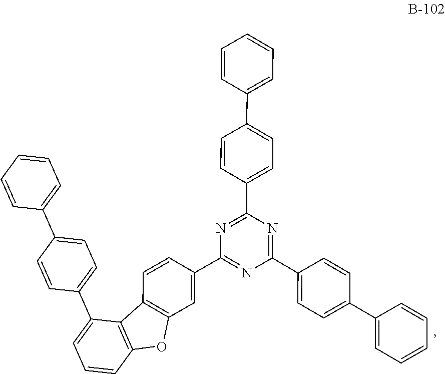 [SMILES: c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1] 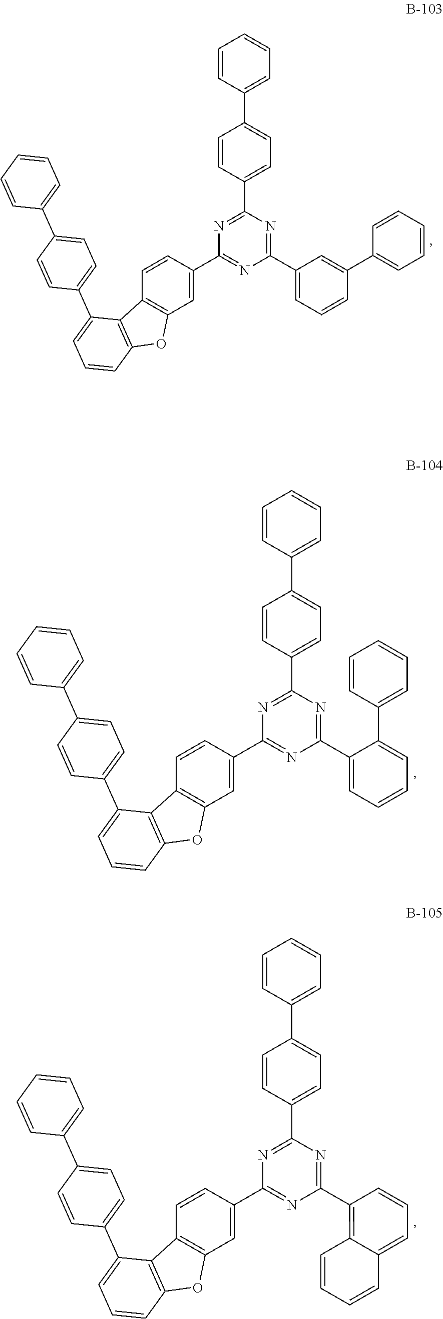 [SMILES: c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccc5c(c4)oc4cccc(-c6ccc(-c7ccccc7)cc6)c45)nc(-c4cccc5ccccc45)n3)cc2)cc1] 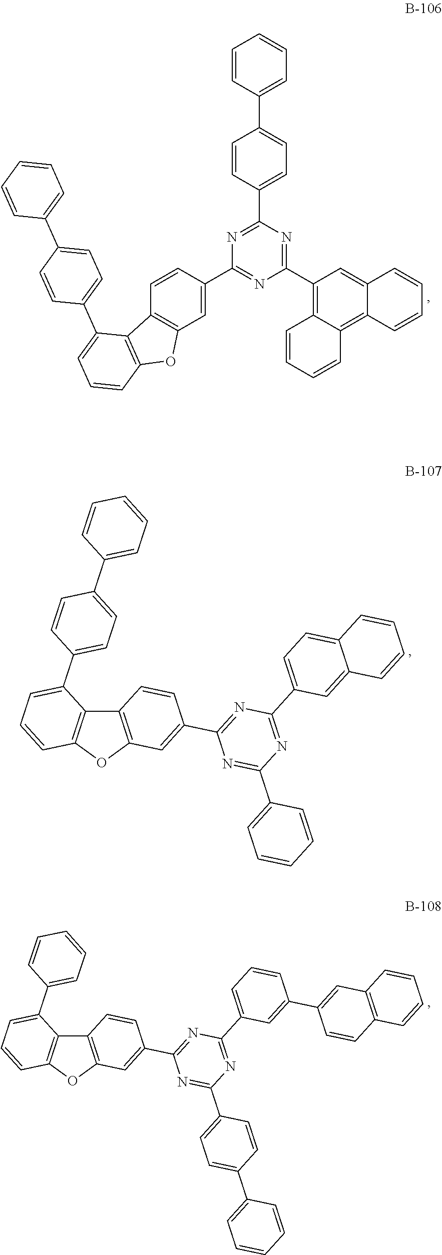 [SMILES: c1ccc(-c2ccc(-c3nc(-c4ccc5c(c4)oc4cccc(-c6ccc(-c7ccccc7)cc6)c45)nc(-c4cc5ccccc5c5ccccc45)n3)cc2)cc1 ; c1ccc(-c2ccc(-c3cccc4oc5cc(-c6nc(-c7ccccc7)nc(-c7ccc8ccccc8c7)n6)ccc5c34)cc2)cc1 ; c1ccc(-c2ccc(-c3nc(-c4cccc(-c5ccc6ccccc6c5)c4)nc(-c4ccc5c(c4)oc4cccc(-c6ccccc6)c45)n3)cc2)cc1] 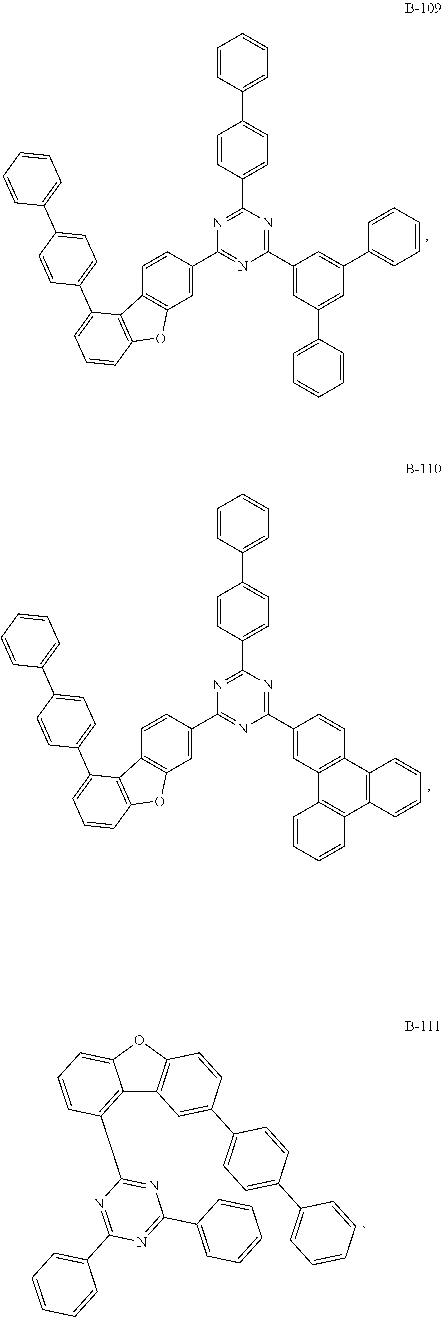 [SMILES: c1ccc(-c2ccc(-c3nc(-c4cc(-c5ccccc5)cc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccc5c6ccccc6c6ccccc6c5c4)n3)cc2)cc1 ; c1ccc(-c2ccc(-c3ccc4oc5cccc(-c6nc(-c7ccccc7)nc(-c7ccccc7)n6)c5c4c3)cc2)cc1] 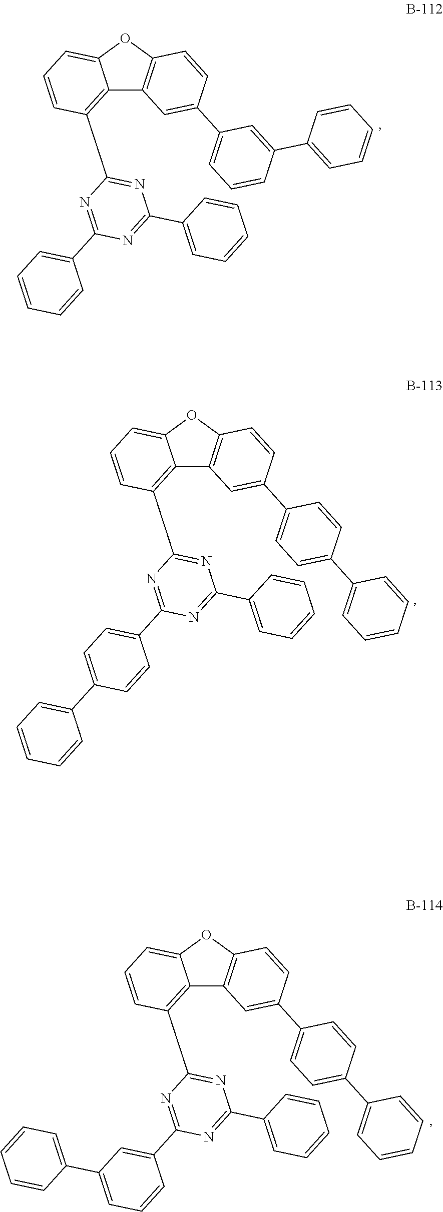 [SMILES: c1ccc(-c2cccc(-c3ccc4oc5cccc(-c6nc(-c7ccccc7)nc(-c7ccccc7)n6)c5c4c3)c2)cc1 ; c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2ccc(-c3ccc4oc5cccc(-c6nc(-c7ccccc7)nc(-c7cccc(-c8ccccc8)c7)n6)c5c4c3)cc2)cc1] 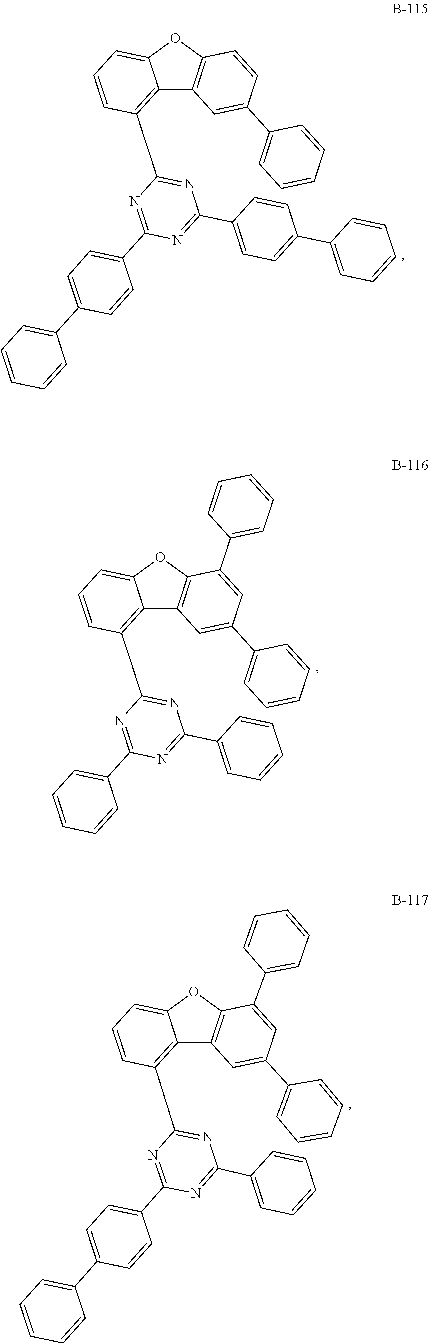 [SMILES: c1ccc(-c2ccc(-c3nc(-c4ccc(-c5ccccc5)cc4)nc(-c4cccc5oc6ccc(-c7ccccc7)cc6c45)n3)cc2)cc1 ; c1ccc(-c2cc(-c3ccccc3)c3oc4cccc(-c5nc(-c6ccccc6)nc(-c6ccccc6)n5)c4c3c2)cc1 ; c1ccc(-c2ccc(-c3nc(-c4ccccc4)nc(-c4cccc5oc6c(-c7ccccc7)cc(-c7ccccc7)cc6c45)n3)cc2)cc1] 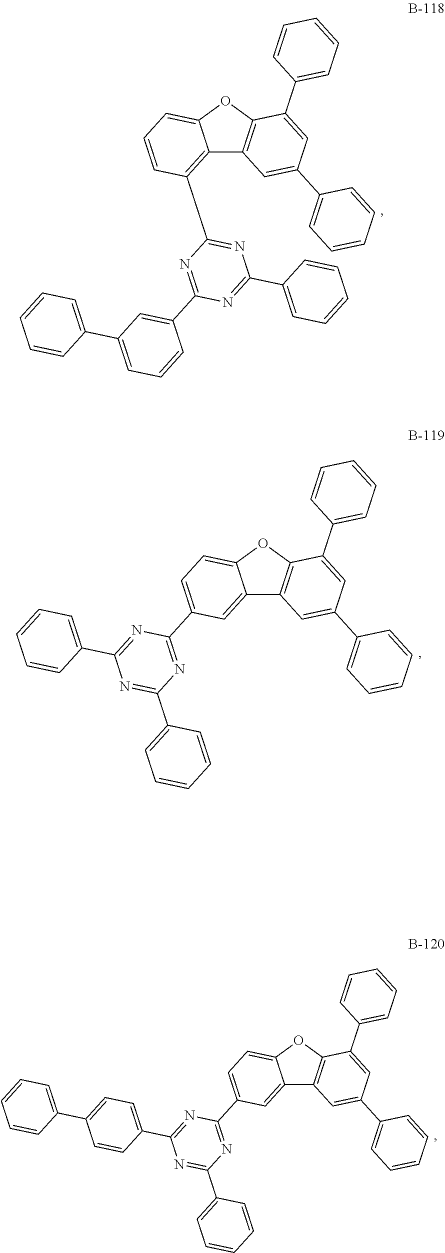 [SMILES: c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1] 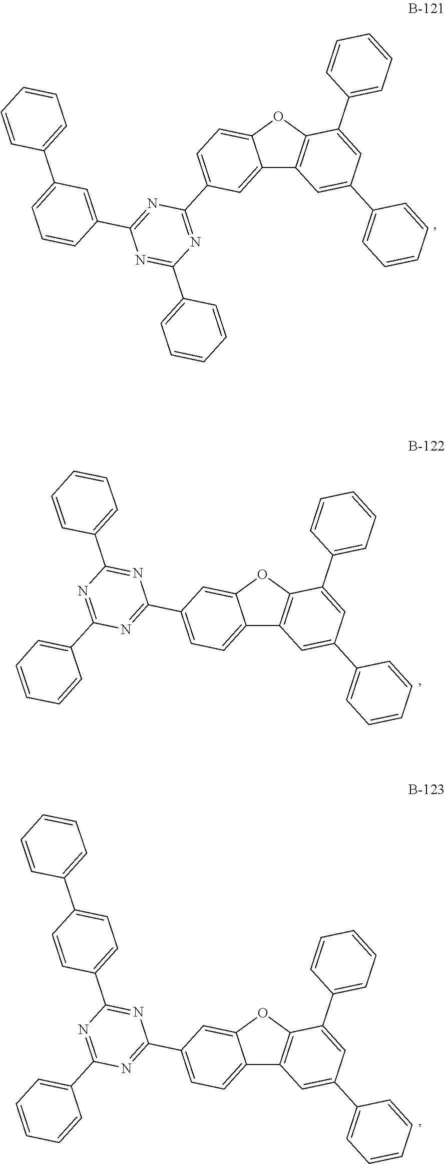 [SMILES: c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2cc(-c3ccccc3)c3oc4cc(-c5nc(-c6ccccc6)nc(-c6ccccc6)n5)ccc4c3c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1] 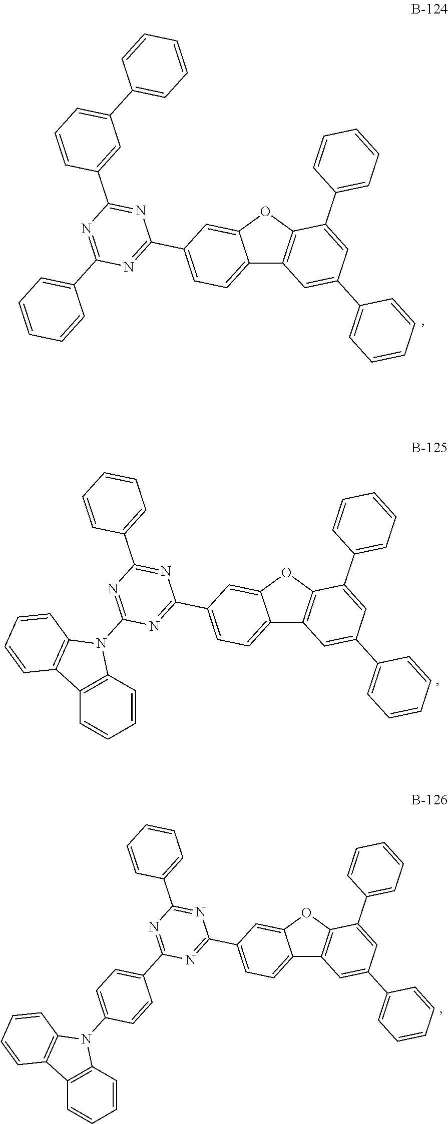 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1] 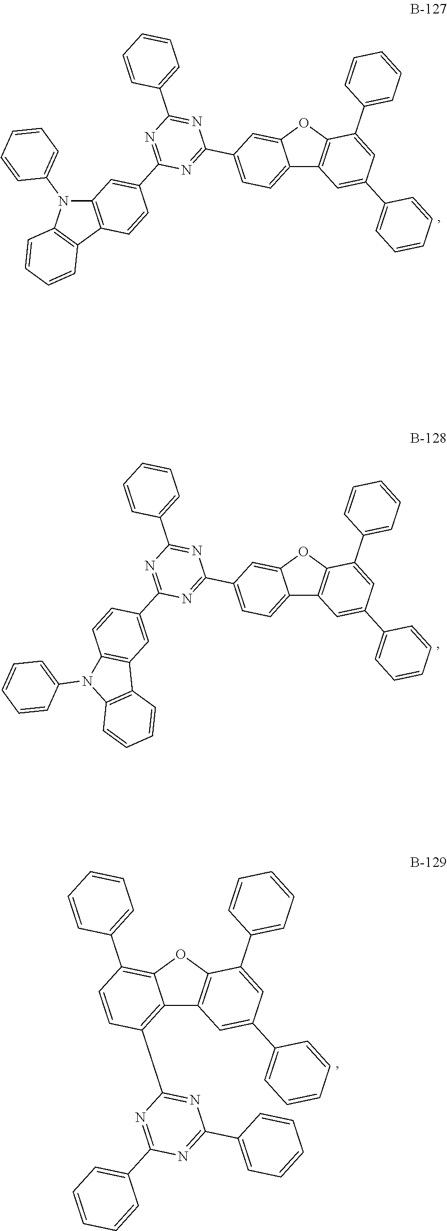 [SMILES: c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2cc(-c3ccccc3)c3oc4c(-c5ccccc5)ccc(-c5nc(-c6ccccc6)nc(-c6ccccc6)n5)c4c3c2)cc1] 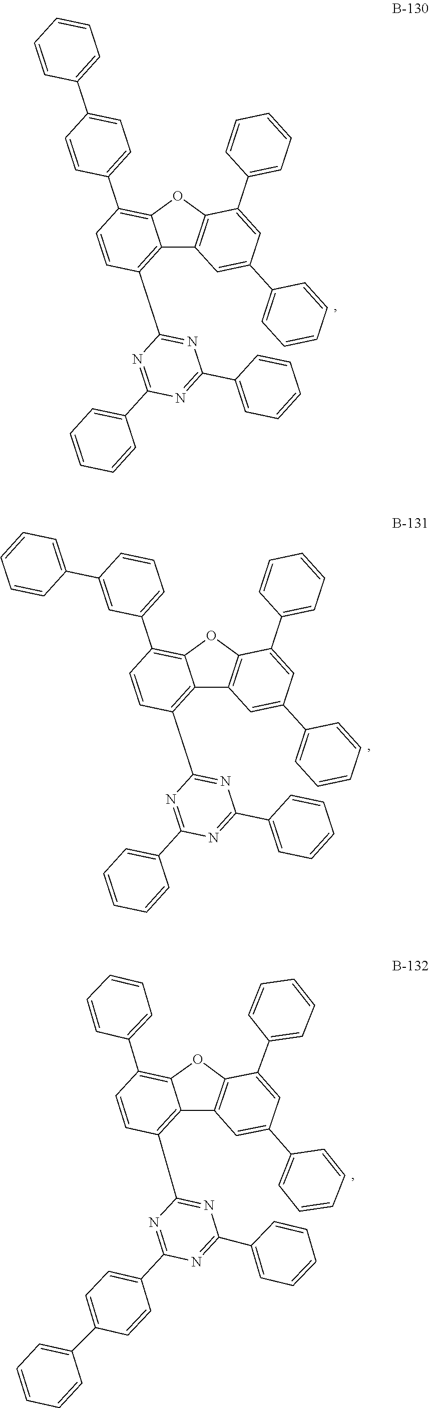 [SMILES: c1ccc(-c2ccc(-c3ccc(-c4nc(-c5ccccc5)nc(-c5ccccc5)n4)c4c3oc3c(-c5ccccc5)cc(-c5ccccc5)cc34)cc2)cc1 ; c1ccc(-c2cccc(-c3ccc(-c4nc(-c5ccccc5)nc(-c5ccccc5)n4)c4c3oc3c(-c5ccccc5)cc(-c5ccccc5)cc34)c2)cc1 ; c1ccc(-c2ccc(-c3nc(-c4ccccc4)nc(-c4ccc(-c5ccccc5)c5oc6c(-c7ccccc7)cc(-c7ccccc7)cc6c45)n3)cc2)cc1] 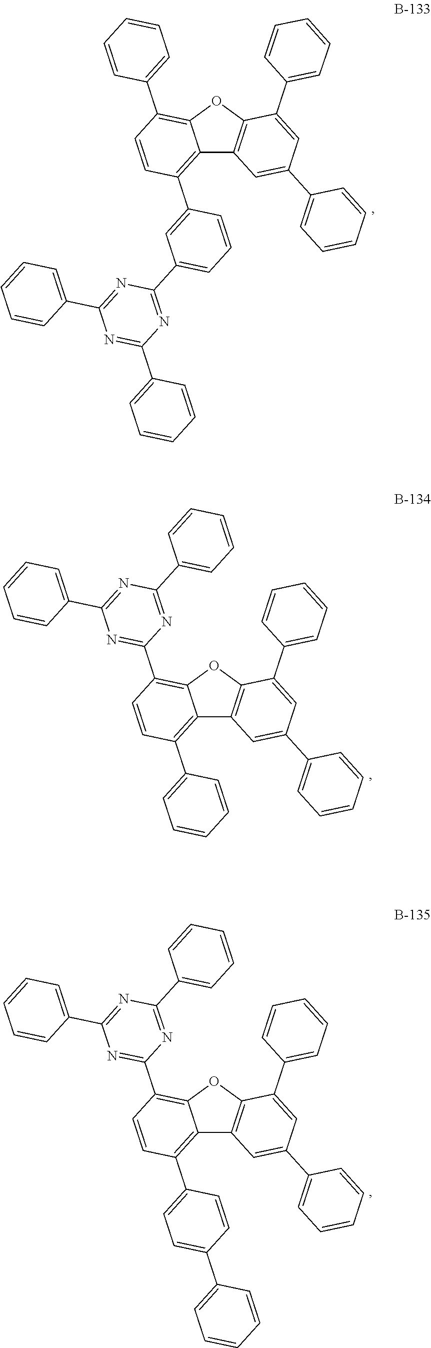 [SMILES: c1ccc(-c2cc(-c3ccccc3)c3oc4c(-c5ccccc5)ccc(-c5cccc(-c6nc(-c7ccccc7)nc(-c7ccccc7)n6)c5)c4c3c2)cc1 ; c1ccc(-c2cc(-c3ccccc3)c3oc4c(-c5nc(-c6ccccc6)nc(-c6ccccc6)n5)ccc(-c5ccccc5)c4c3c2)cc1 ; c1ccc(-c2ccc(-c3ccc(-c4nc(-c5ccccc5)nc(-c5ccccc5)n4)c4oc5c(-c6ccccc6)cc(-c6ccccc6)cc5c34)cc2)cc1] 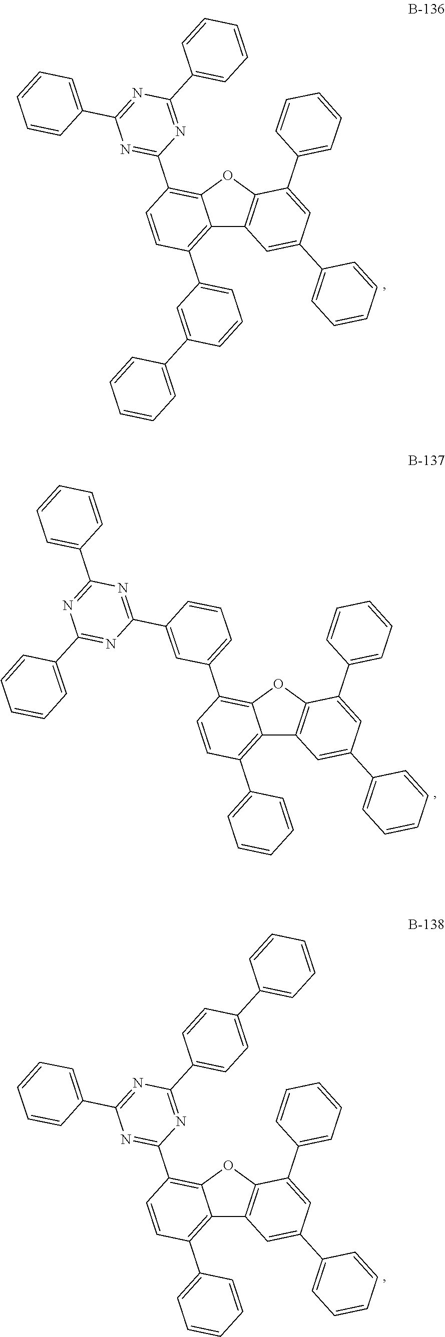 [SMILES: c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1 ; c1ccc(-c2cc(-c3ccccc3)c3oc4c(-c5cccc(-c6nc(-c7ccccc7)nc(-c7ccccc7)n6)c5)ccc(-c5ccccc5)c4c3c2)cc1 ; c1ccc(-c2ccc(-c3nc(-c4ccccc4)nc(-c4ccc(-c5ccccc5)c5c4oc4c(-c6ccccc6)cc(-c6ccccc6)cc45)n3)cc2)cc1] 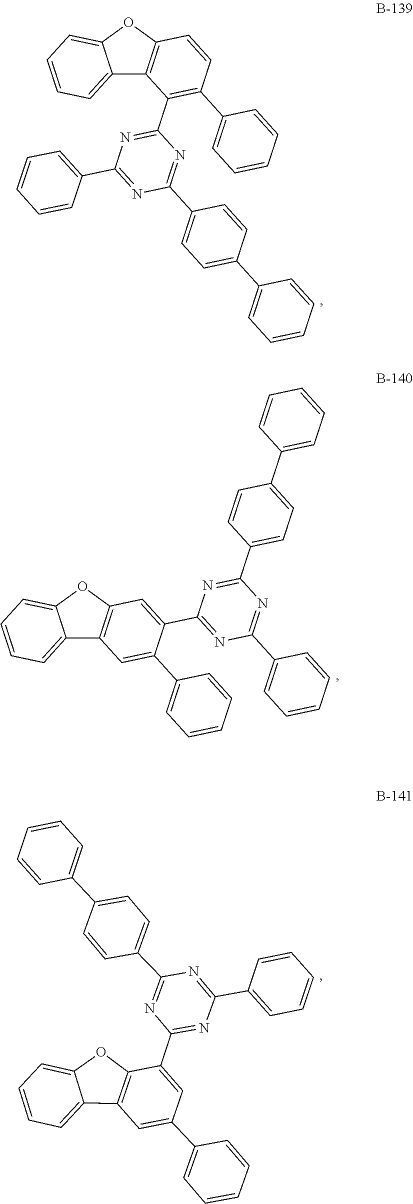 [SMILES: c1ccc(-c2ccc(-c3nc(-c4ccccc4)nc(-c4c(-c5ccccc5)ccc5oc6ccccc6c45)n3)cc2)cc1 ; c1ccc(-c2ccc(-c3nc(-c4ccccc4)nc(-c4cc5oc6ccccc6c5cc4-c4ccccc4)n3)cc2)cc1 ; c1ccc(-c2ccc(-c3nc(-c4ccccc4)nc(-c4cc(-c5ccccc5)cc5c4oc4ccccc45)n3)cc2)cc1] 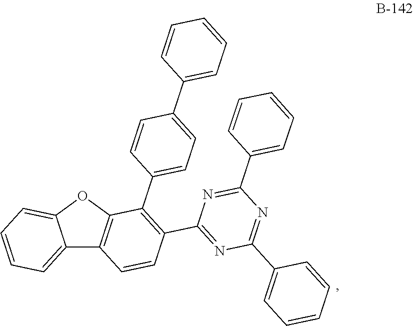 [SMILES: c1ccc(-c2ccc(-c3c(-c4nc(-c5ccccc5)nc(-c5ccccc5)n4)ccc4c3oc3ccccc34)cc2)cc1] 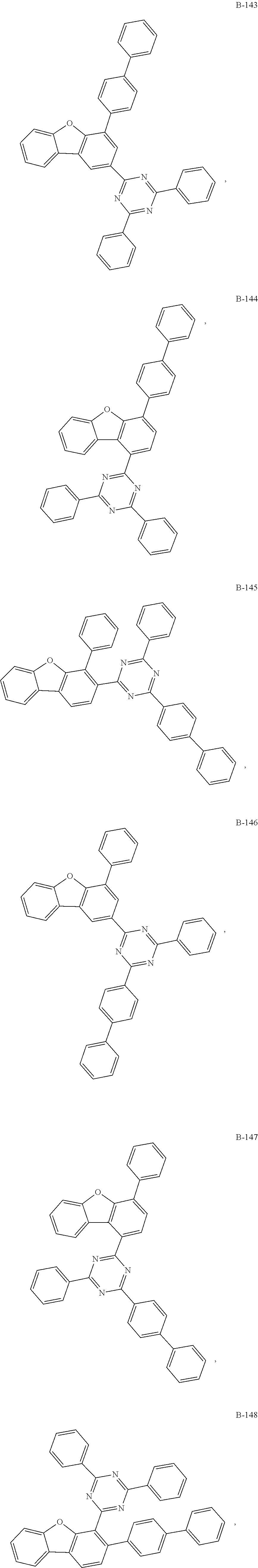 [SMILES: c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1 ; c1ccc(-c2ccc(-c3nc(-c4ccccc4)nc(-c4ccc5c(oc6ccccc65)c4-c4ccccc4)n3)cc2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2ccc(-c3ccc4c(oc5ccccc54)c3-c3nc(-c4ccccc4)nc(-c4ccccc4)n3)cc2)cc1] 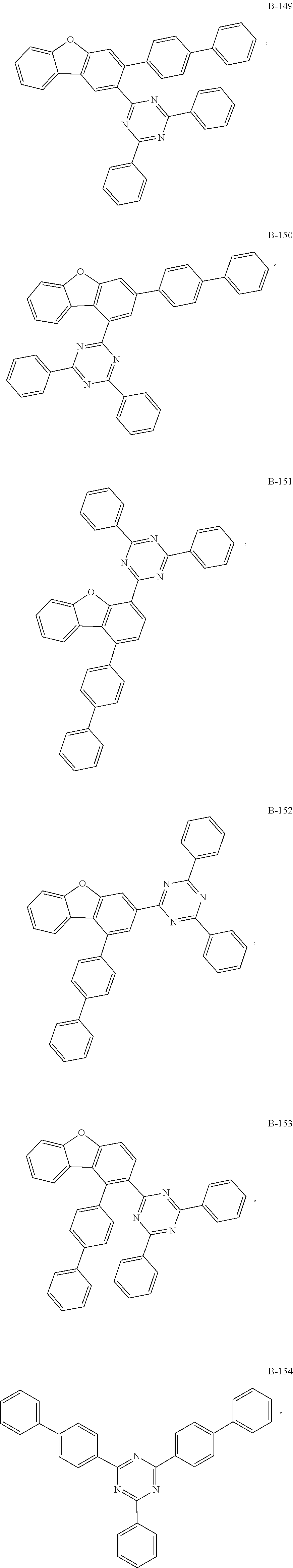 [SMILES: c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3ccc(-c4nc(-c5ccccc5)nc(-c5ccccc5)n4)c4oc5ccccc5c34)cc2)cc1 ; c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1 ; c1ccc(-c2ccc(-c3nc(-c4ccccc4)nc(-c4ccc(-c5ccccc5)cc4)n3)cc2)cc1] 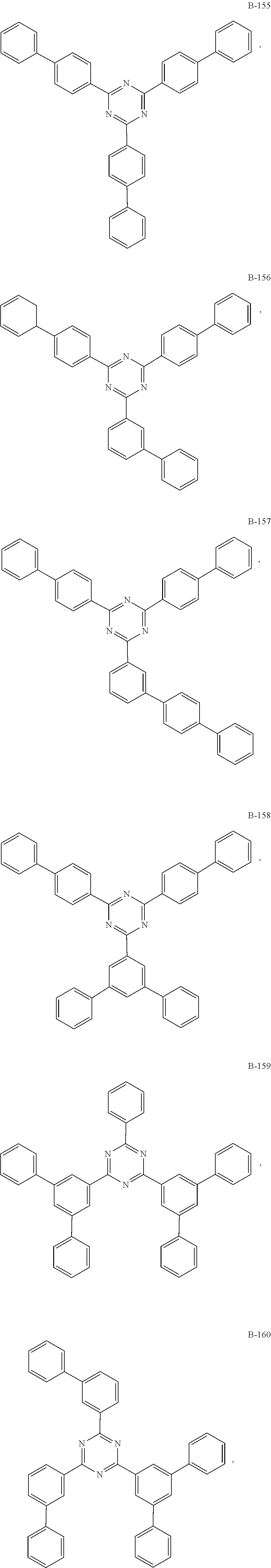 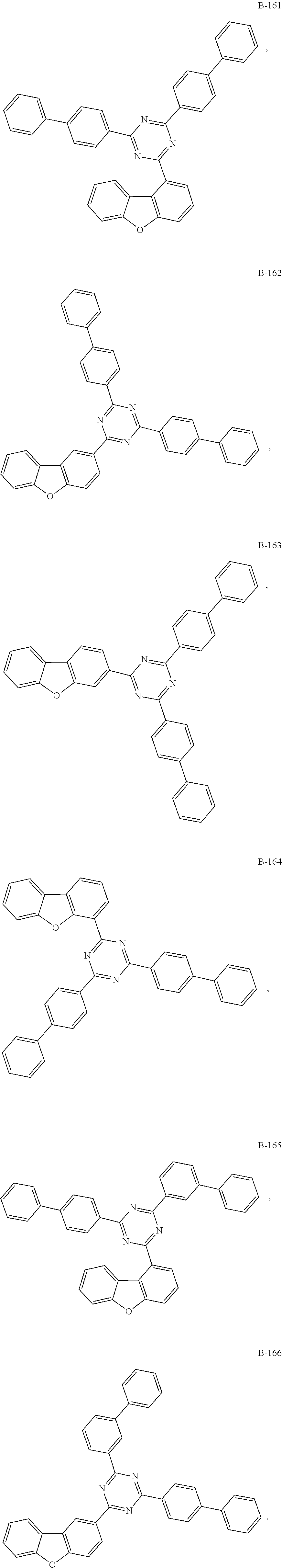 [SMILES: c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4cccc(-c5ccccc5)c4)nc(-c4cccc5oc6ccccc6c45)n3)cc2)cc1 ; c1ccc(-c2ccc(-c3nc(-c4cccc(-c5ccccc5)c4)nc(-c4ccc5oc6ccccc6c5c4)n3)cc2)cc1] 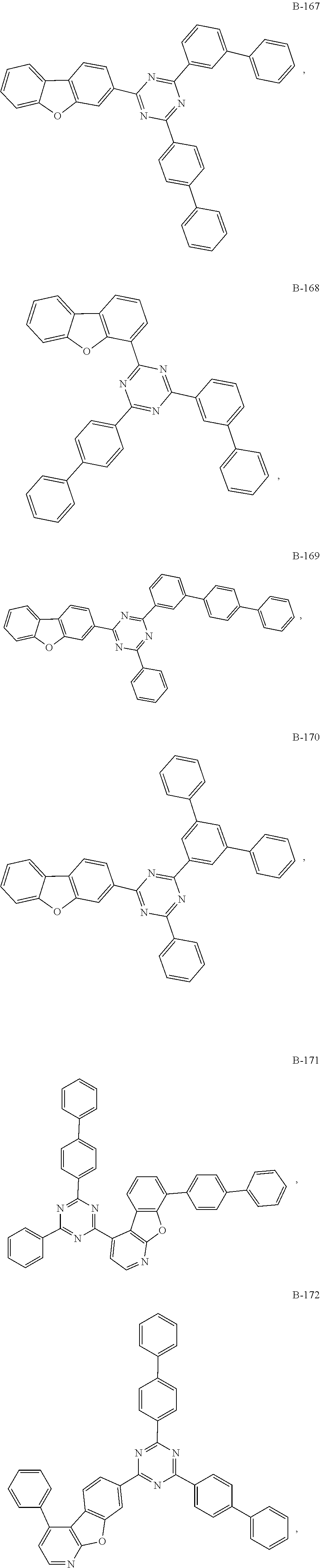 [SMILES: c1ccc(-c2ccc(-c3nc(-c4cccc(-c5ccccc5)c4)nc(-c4ccc5c(c4)oc4ccccc45)n3)cc2)cc1 ; c1ccc(-c2ccc(-c3nc(-c4cccc(-c5ccccc5)c4)nc(-c4cccc5c4oc4ccccc45)n3)cc2)cc1 ; c1ccc(-c2ccc(-c3cccc(-c4nc(-c5ccccc5)nc(-c5ccc6c(c5)oc5ccccc56)n4)c3)cc2)cc1 ; c1ccc(-c2cc(-c3ccccc3)cc(-c3nc(-c4ccccc4)nc(-c4ccc5c(c4)oc4ccccc45)n3)c2)cc1 ; c1ccc(-c2ccc(-c3nc(-c4ccccc4)nc(-c4ccnc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4ccc5c(c4)oc4nccc(-c6ccccc6)c45)n3)cc2)cc1] 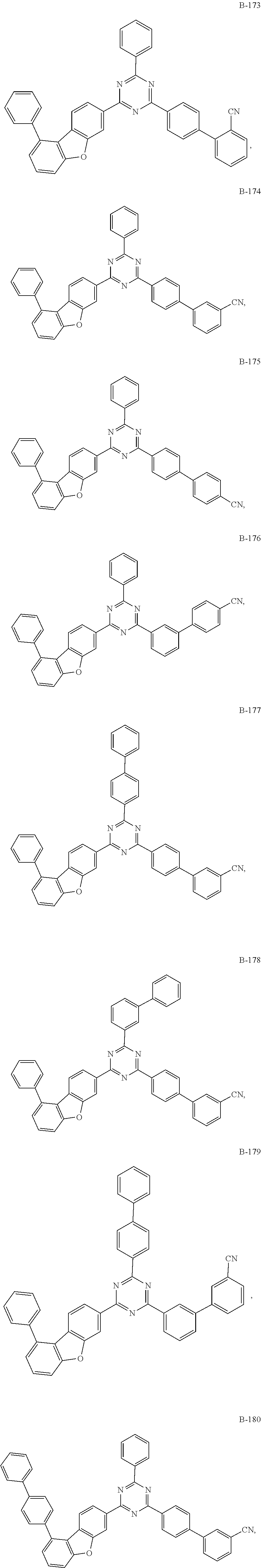 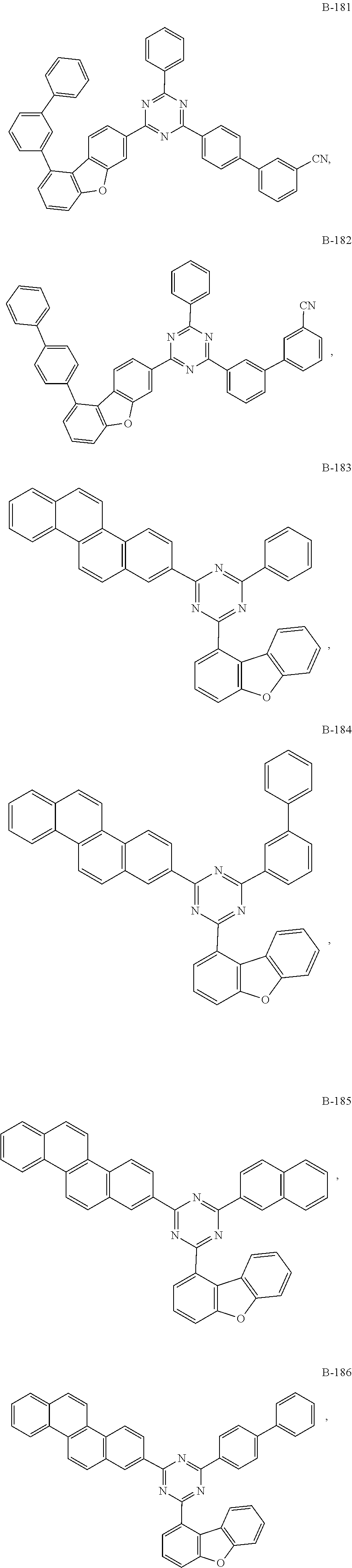 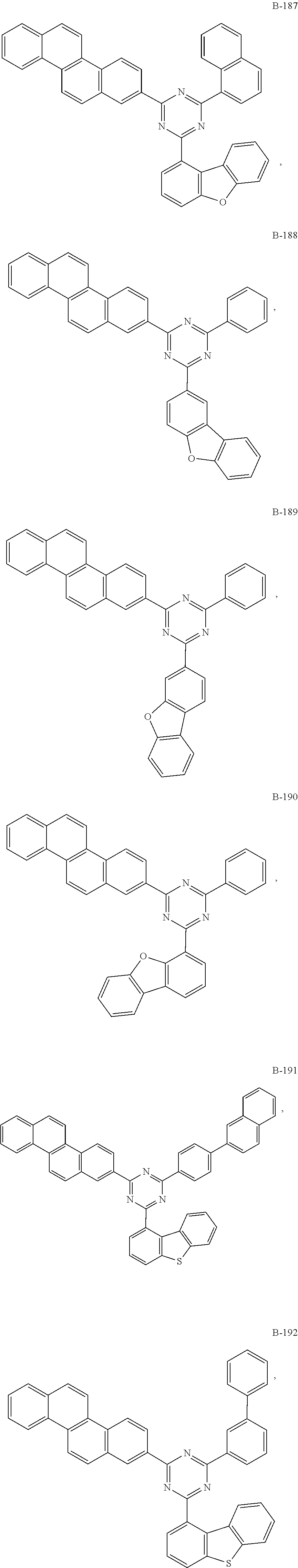 [SMILES: c1ccc2c(-c3nc(-c4ccc5c(ccc6c7ccccc7ccc56)c4)nc(-c4cccc5oc6ccccc6c45)n3)cccc2c1 ; c1ccc(-c2nc(-c3ccc4c(ccc5c6ccccc6ccc45)c3)nc(-c3ccc4oc5ccccc5c4c3)n2)cc1 ; c1ccc(-c2nc(-c3ccc4c(ccc5c6ccccc6ccc45)c3)nc(-c3ccc4c(c3)oc3ccccc34)n2)cc1 ; c1ccc(-c2nc(-c3ccc4c(ccc5c6ccccc6ccc45)c3)nc(-c3cccc4c3oc3ccccc34)n2)cc1 ; c1ccc2cc(-c3ccc(-c4nc(-c5ccc6c(ccc7c8ccccc8ccc67)c5)nc(-c5cccc6sc7ccccc7c56)n4)cc3)ccc2c1 ; c1ccc(-c2cccc(-c3nc(-c4ccc5c(ccc6c7ccccc7ccc56)c4)nc(-c4cccc5sc6ccccc6c45)n3)c2)cc1] 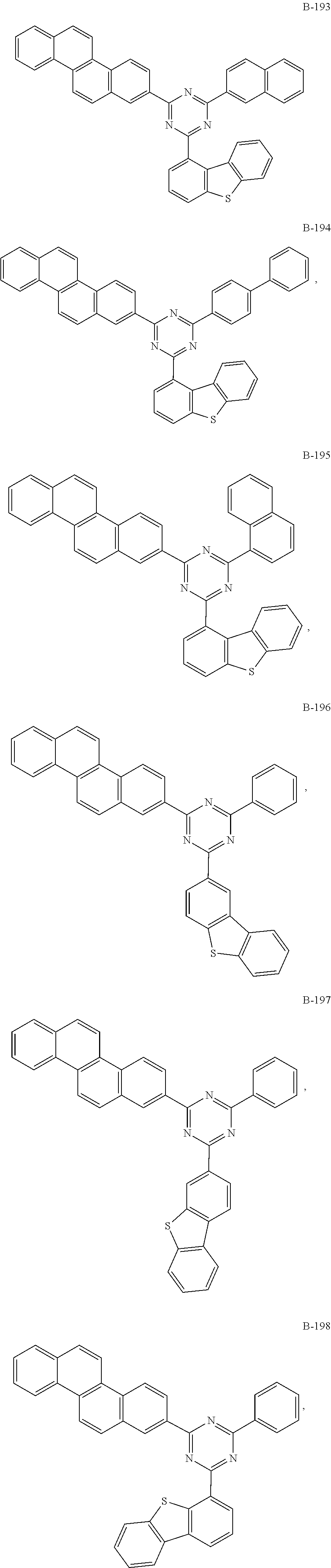 [SMILES: c1ccc2cc(-c3nc(-c4ccc5c(ccc6c7ccccc7ccc56)c4)nc(-c4cccc5sc6ccccc6c45)n3)ccc2c1 ; c1ccc(-c2ccc(-c3nc(-c4ccc5c(ccc6c7ccccc7ccc56)c4)nc(-c4cccc5sc6ccccc6c45)n3)cc2)cc1 ; c1ccc2c(-c3nc(-c4ccc5c(ccc6c7ccccc7ccc56)c4)nc(-c4cccc5sc6ccccc6c45)n3)cccc2c1 ; c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3cccc4c3sc3ccccc34)n2)cc1] 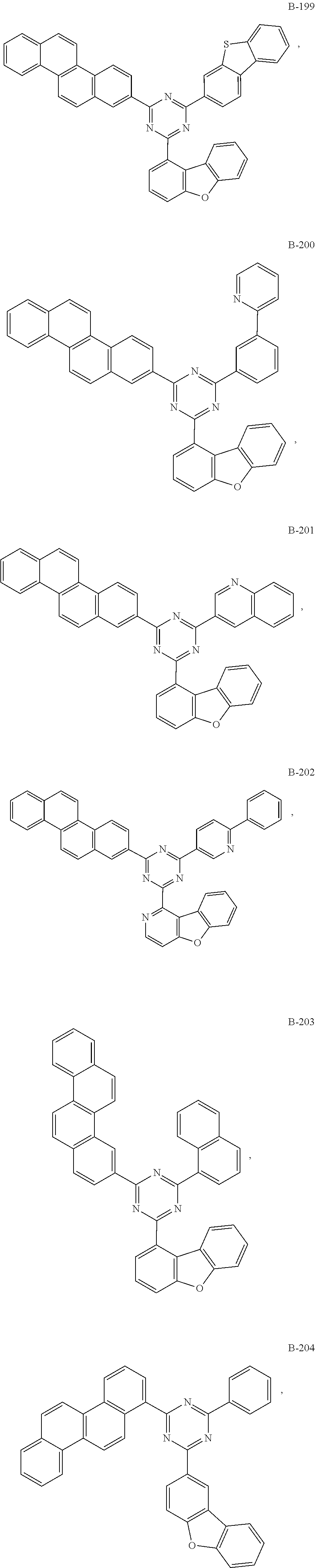 [SMILES: c1ccc2c(c1)ccc1c3ccc(-c4nc(-c5ccc6c(c5)sc5ccccc56)nc(-c5cccc6oc7ccccc7c56)n4)cc3ccc21 ; c1ccc(-c2cccc(-c3nc(-c4ccc5c(ccc6c7ccccc7ccc56)c4)nc(-c4cccc5oc6ccccc6c45)n3)c2)nc1 ; c1ccc2ncc(-c3nc(-c4ccc5c(ccc6c7ccccc7ccc56)c4)nc(-c4cccc5oc6ccccc6c45)n3)cc2c1 ; c1ccc(-c2ccc(-c3nc(-c4ccc5c(ccc6c7ccccc7ccc56)c4)nc(-c4nccc5oc6ccccc6c45)n3)cn2)cc1 ; c1ccc2c(-c3nc(-c4ccc5ccc6c7ccccc7ccc6c5c4)nc(-c4cccc5oc6ccccc6c45)n3)cccc2c1 ; c1ccc(-c2nc(-c3ccc4oc5ccccc5c4c3)nc(-c3cccc4c3ccc3c5ccccc5ccc43)n2)cc1] 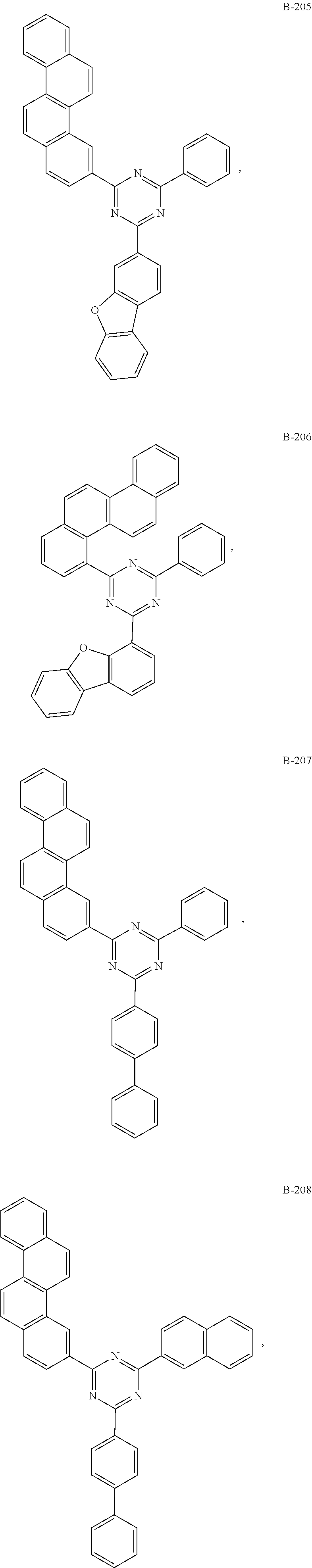 [SMILES: c1ccc(-c2nc(-c3ccc4c(c3)oc3ccccc34)nc(-c3ccc4ccc5c6ccccc6ccc5c4c3)n2)cc1 ; c1ccc(-c2nc(-c3cccc4c3oc3ccccc34)nc(-c3cccc4ccc5c6ccccc6ccc5c34)n2)cc1 ; c1ccc(-c2ccc(-c3nc(-c4ccccc4)nc(-c4ccc5ccc6c7ccccc7ccc6c5c4)n3)cc2)cc1 ; c1ccc(-c2ccc(-c3nc(-c4ccc5ccccc5c4)nc(-c4ccc5ccc6c7ccccc7ccc6c5c4)n3)cc2)cc1] 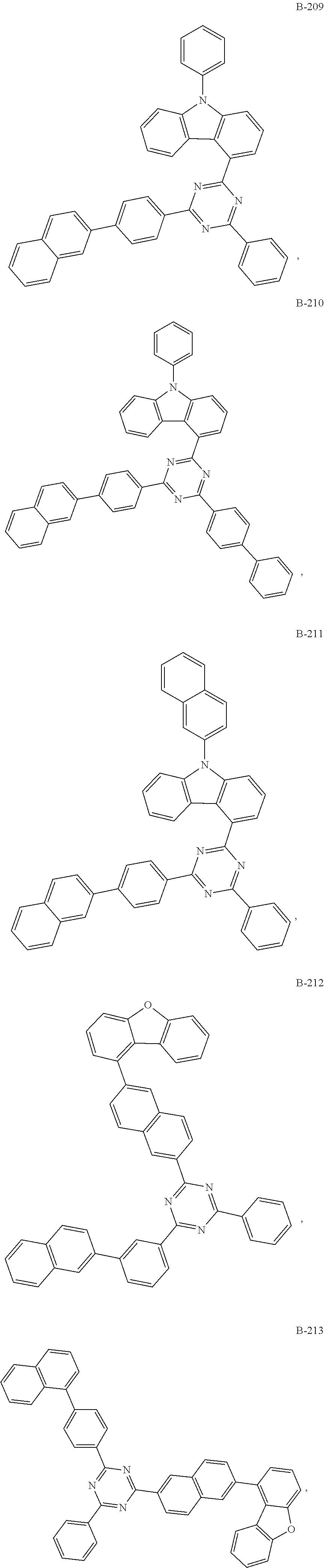 [SMILES: c1ccc(-c2nc(-c3ccc(-c4ccc5ccccc5c4)cc3)nc(-c3cccc4c3c3ccccc3n4-c3ccccc3)n2)cc1 ; c1ccc(-c2ccc(-c3nc(-c4ccc(-c5ccc6ccccc6c5)cc4)nc(-c4cccc5c4c4ccccc4n5-c4ccccc4)n3)cc2)cc1 ; c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2nc(-c3cccc(-c4ccc5ccccc5c4)c3)nc(-c3ccc4cc(-c5cccc6oc7ccccc7c56)ccc4c3)n2)cc1 ; c1ccc(-c2nc(-c3ccc(-c4cccc5ccccc45)cc3)nc(-c3ccc4cc(-c5cccc6oc7ccccc7c56)ccc4c3)n2)cc1] 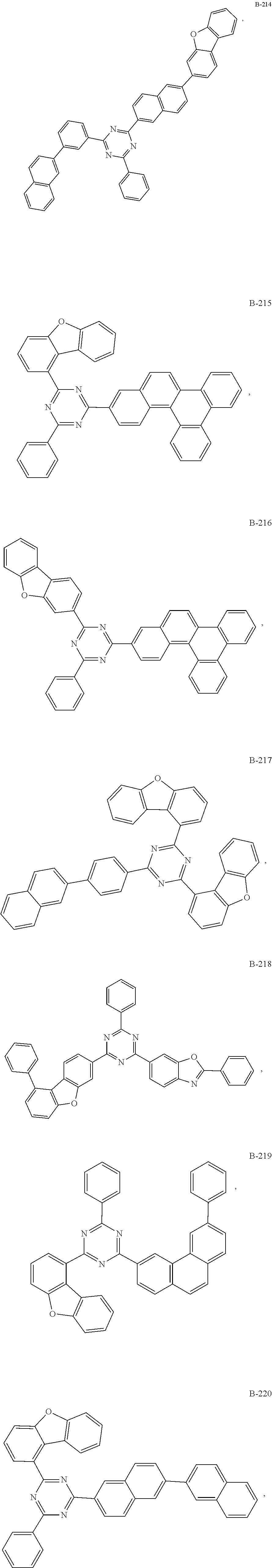 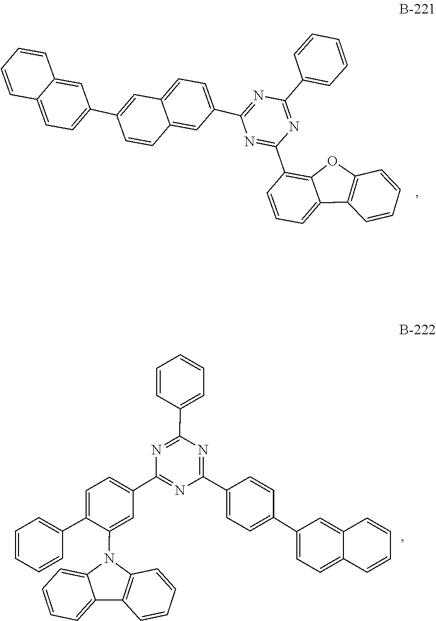 [SMILES: c1ccc(-c2nc(-c3ccc4cc(-c5ccc6ccccc6c5)ccc4c3)nc(-c3cccc4c3oc3ccccc34)n2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1] 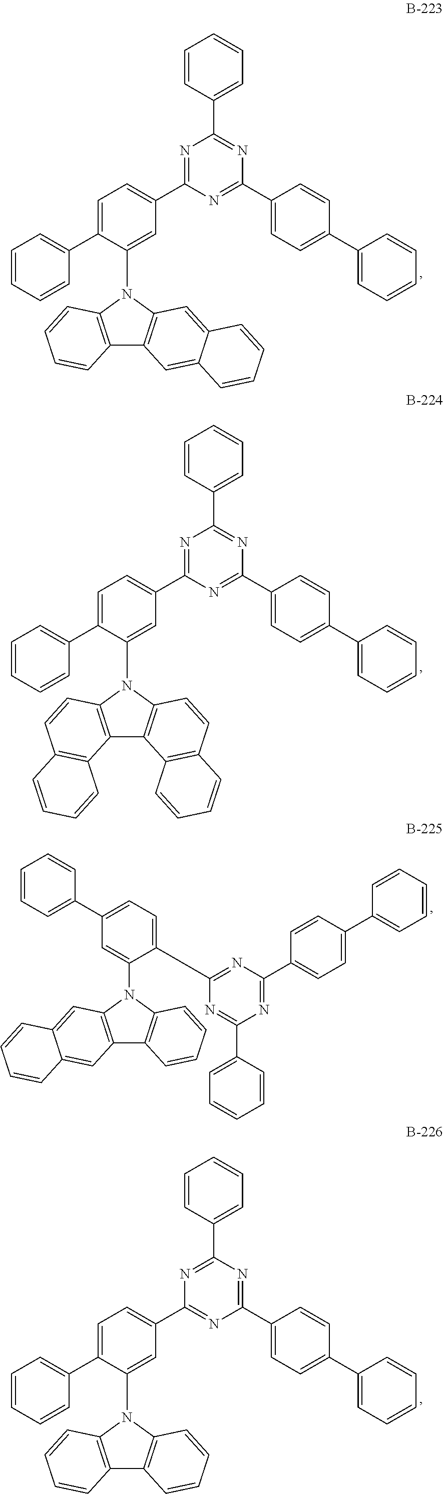 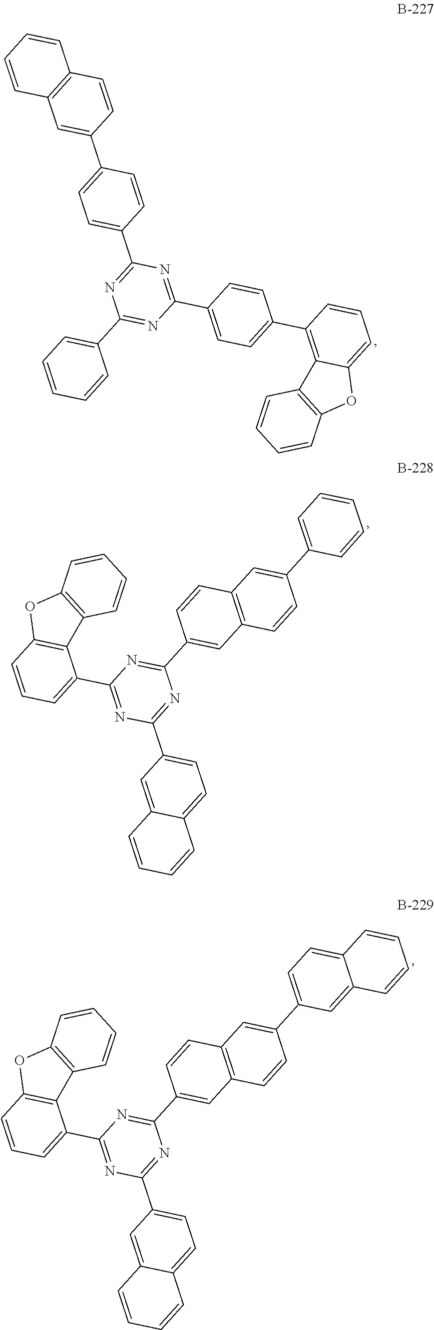 [SMILES: c1ccc(-c2nc(-c3ccc(-c4ccc5ccccc5c4)cc3)nc(-c3ccc(-c4cccc5oc6ccccc6c45)cc3)n2)cc1 ; c1ccc(-c2ccc3cc(-c4nc(-c5ccc6ccccc6c5)nc(-c5cccc6oc7ccccc7c56)n4)ccc3c2)cc1 ; c1ccc2cc(-c3ccc4cc(-c5nc(-c6ccc7ccccc7c6)nc(-c6cccc7oc8ccccc8c67)n5)ccc4c3)ccc2c1] 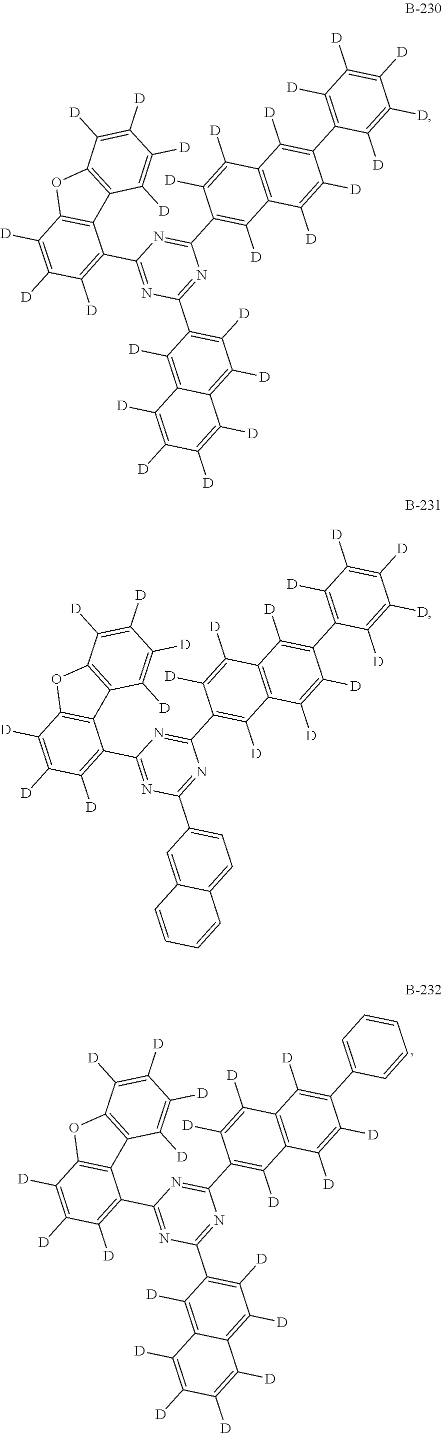 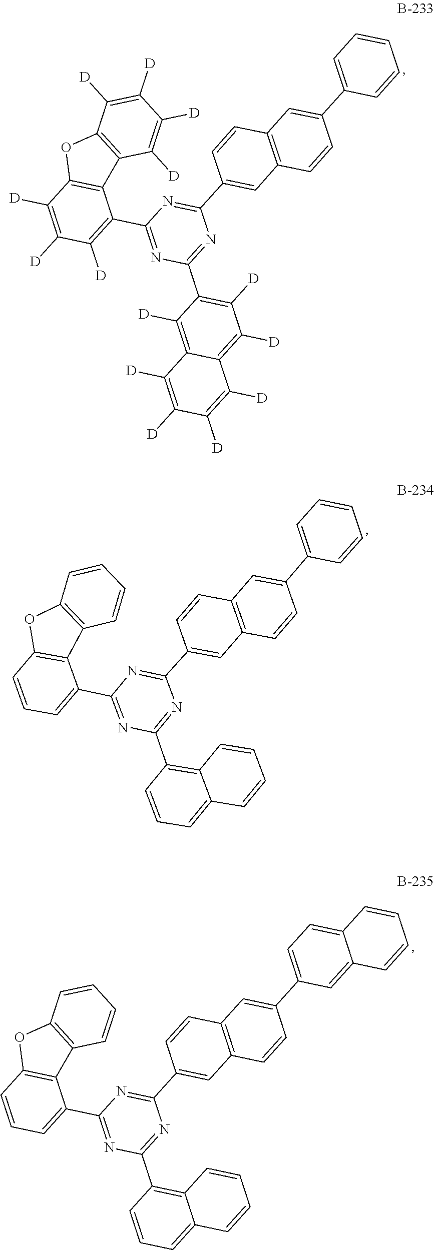 [SMILES: [2H]c1c([2H])c([2H])c2c(oc3c([2H])c([2H])c([2H])c(-c4nc(-c5ccc6cc(-c7ccccc7)ccc6c5)nc(-c5c([2H])c([2H])c6c([2H])c([2H])c([2H])c([2H])c6c5[2H])n4)c32)c1[2H] ; c1ccc(-c2ccc3cc(-c4nc(-c5cccc6ccccc56)nc(-c5cccc6oc7ccccc7c56)n4)ccc3c2)cc1 ; c1ccc2cc(-c3ccc4cc(-c5nc(-c6cccc7ccccc67)nc(-c6cccc7oc8ccccc8c67)n5)ccc4c3)ccc2c1] 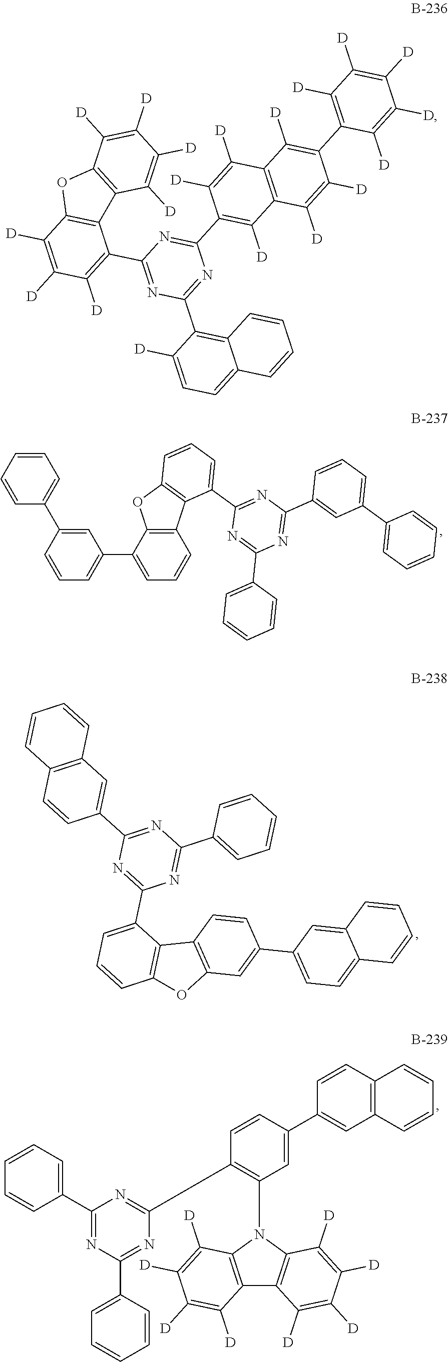 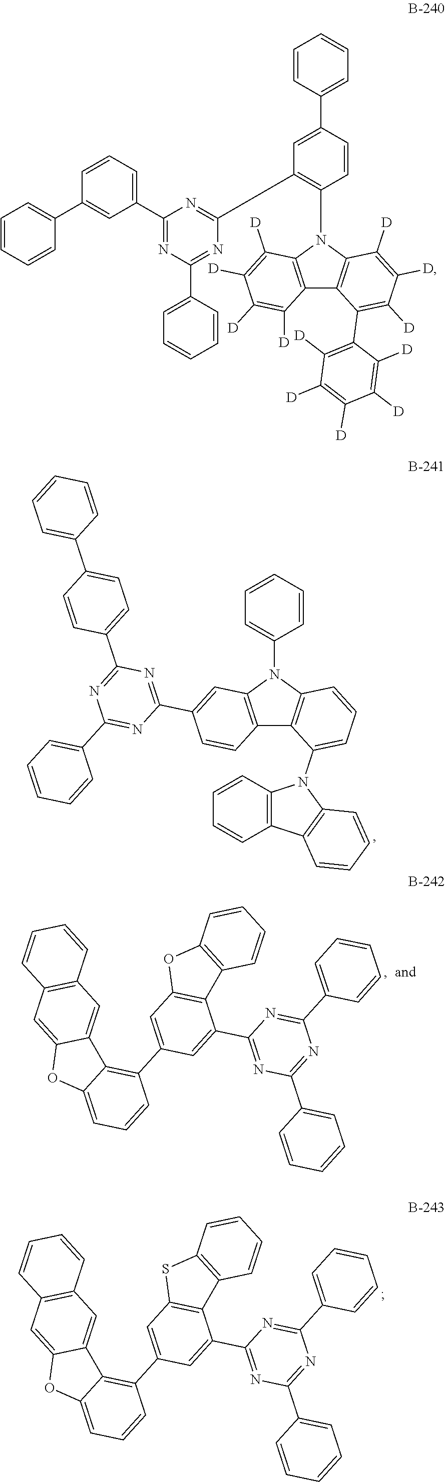
wherein optionally, hydrogens in structures of the Compound B-1 to Compound B-243 can be partially or fully substituted with deuterium.

15. The organic electroluminescent device of claim 13, the light-emitting layer comprises at least one metal complex;
preferably, the metal complex is a phosphorescent sensitizer; and
more preferably, the metal complex is selected from the group consisting of Compound RD1 to Compound RD214 and Compound GD1 to Compound GD185: 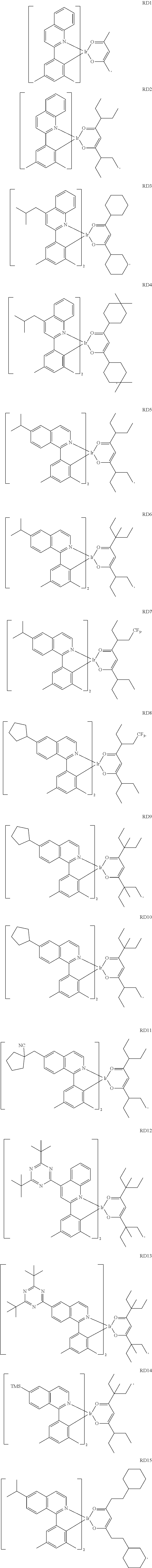 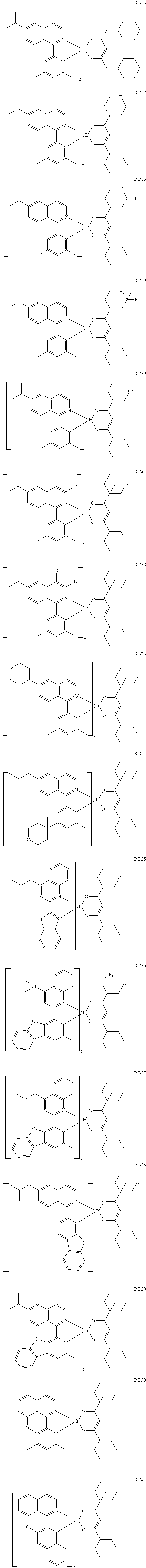 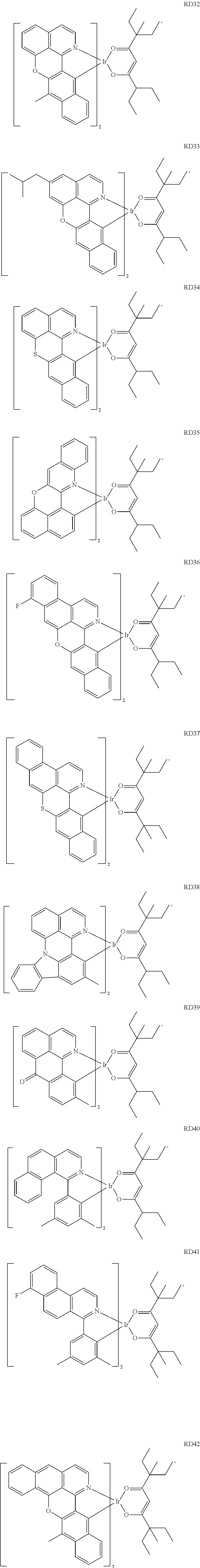 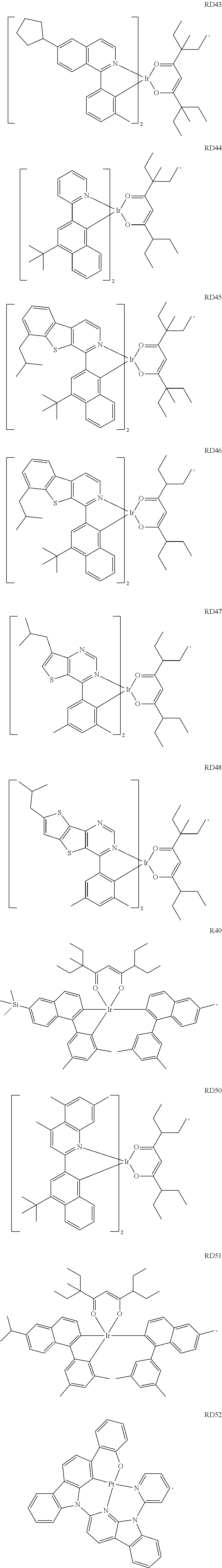 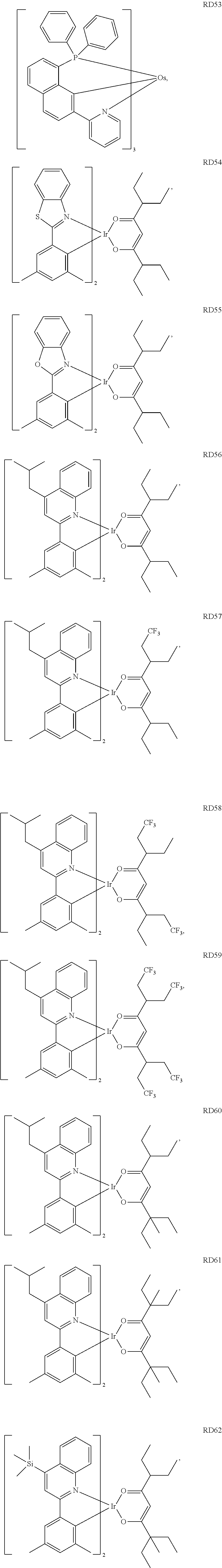 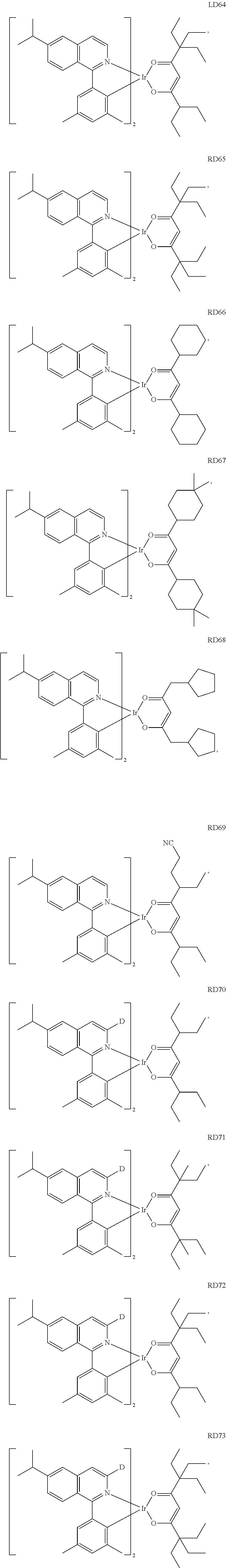 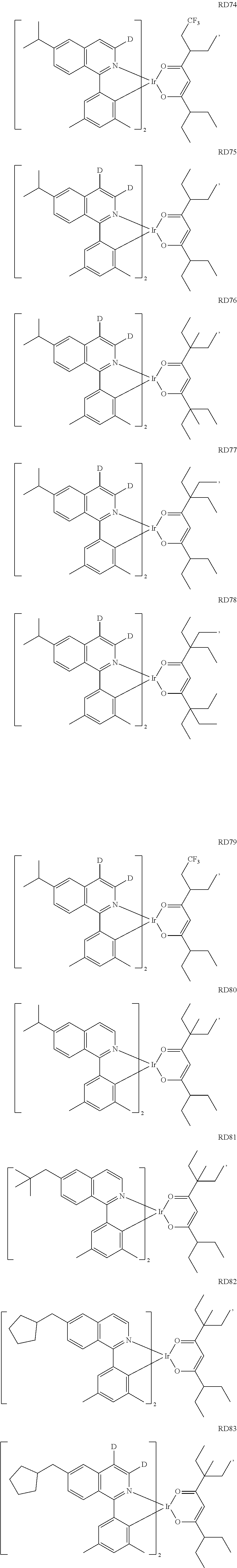 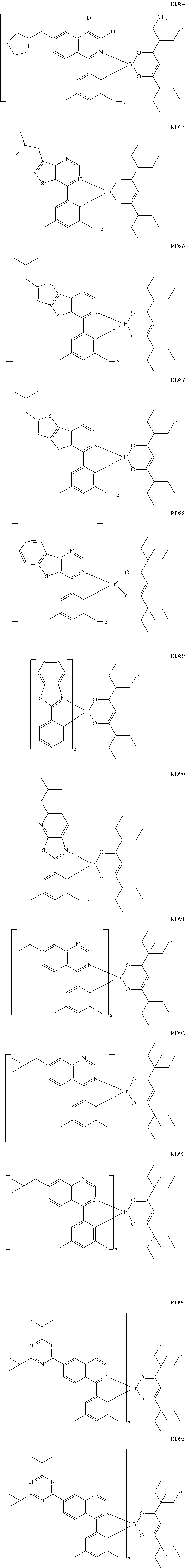 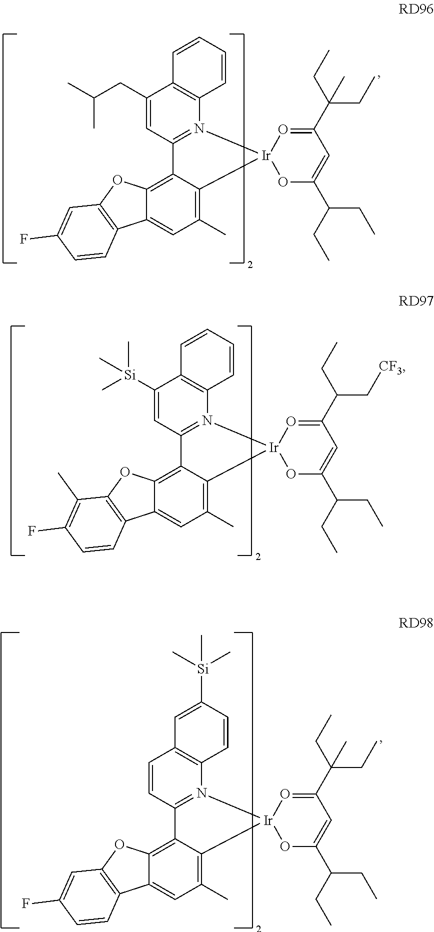 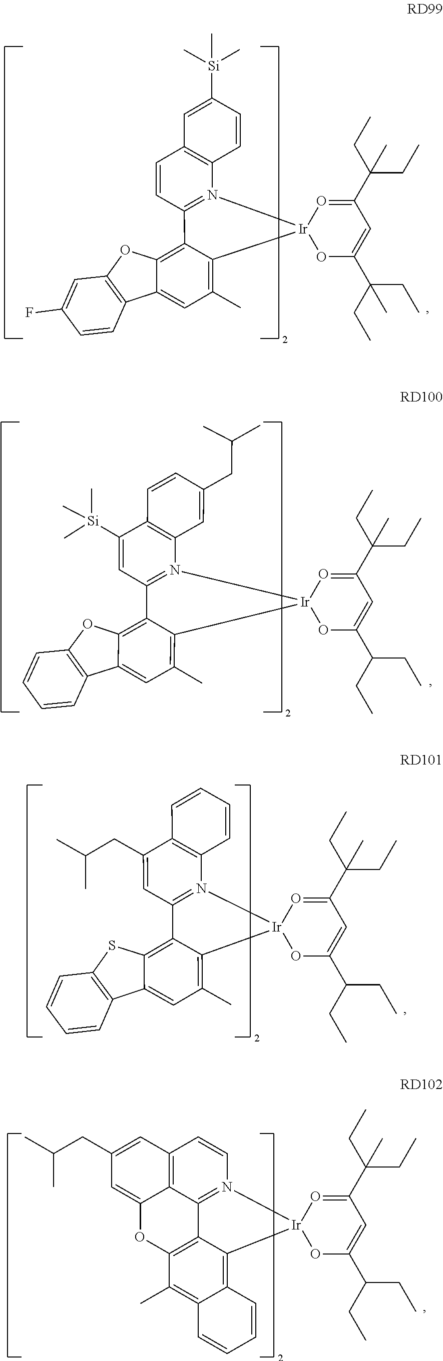 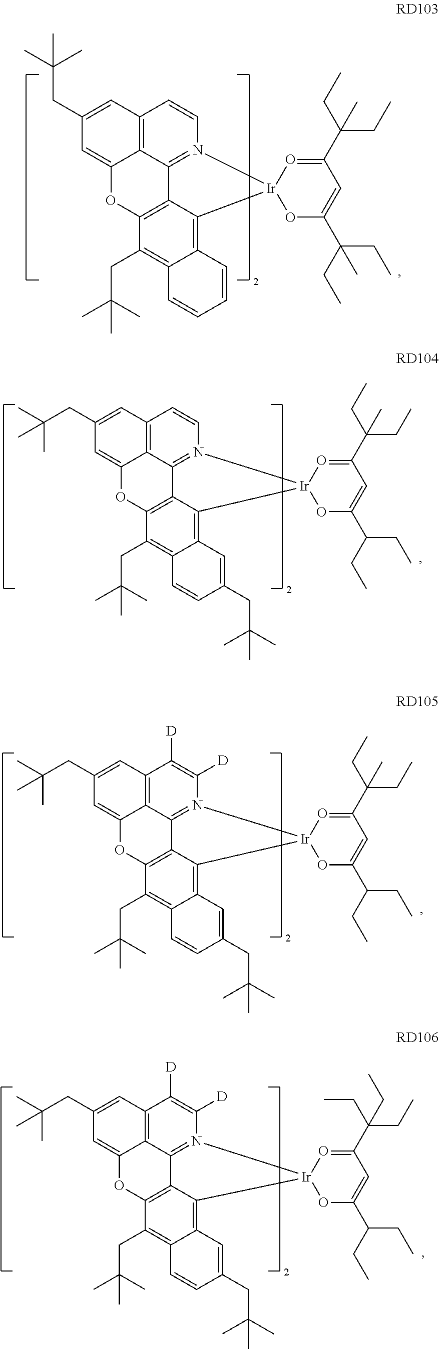 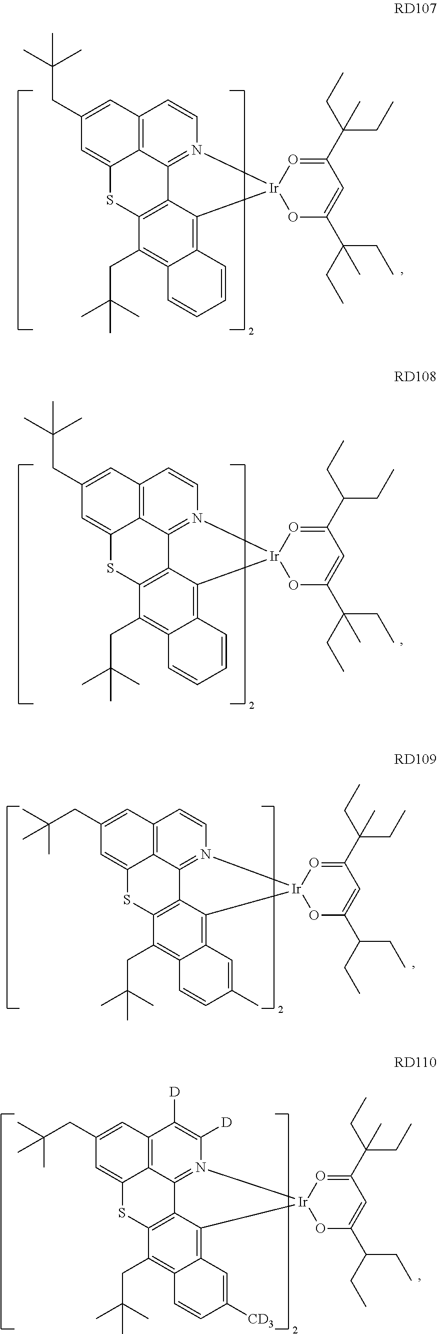 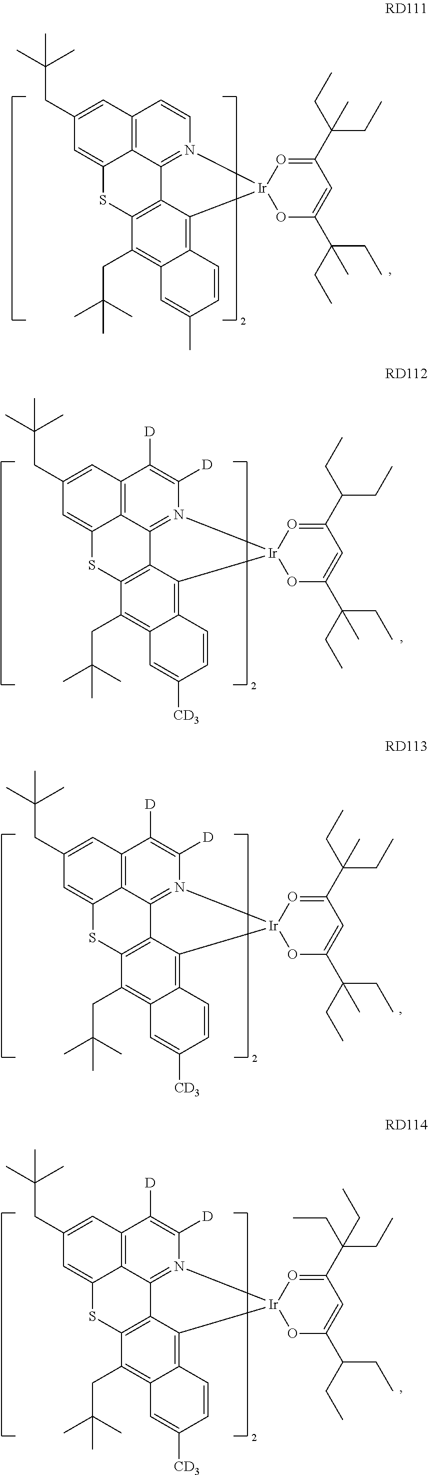 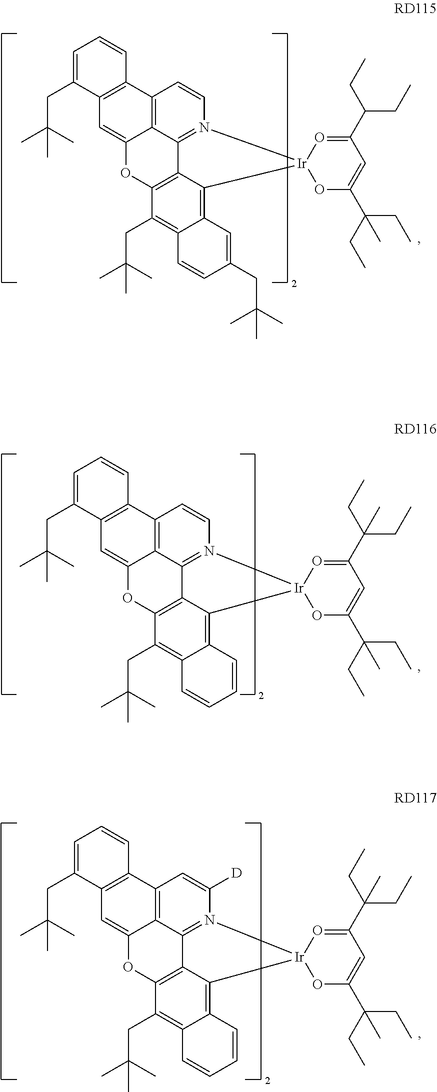 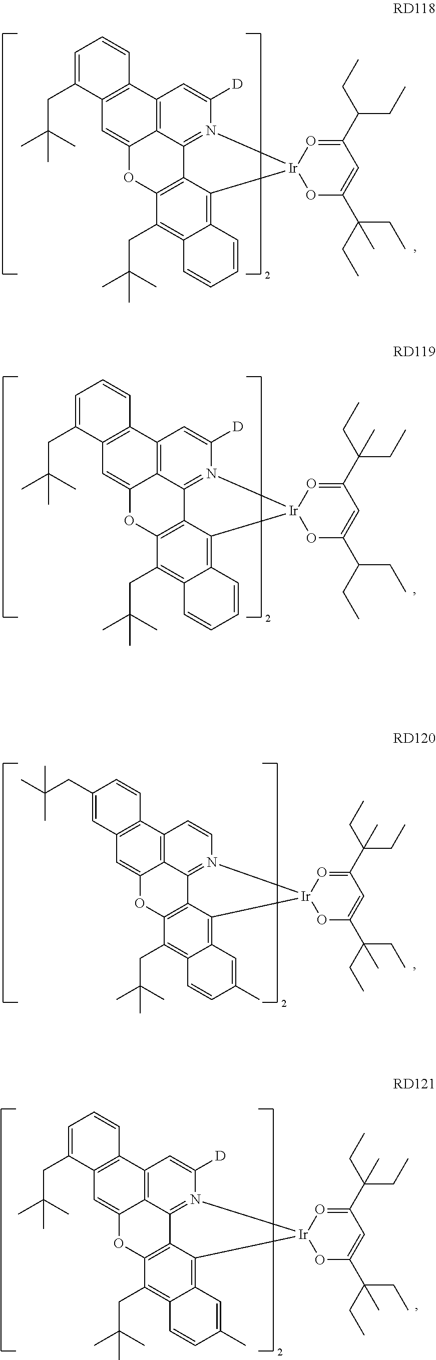 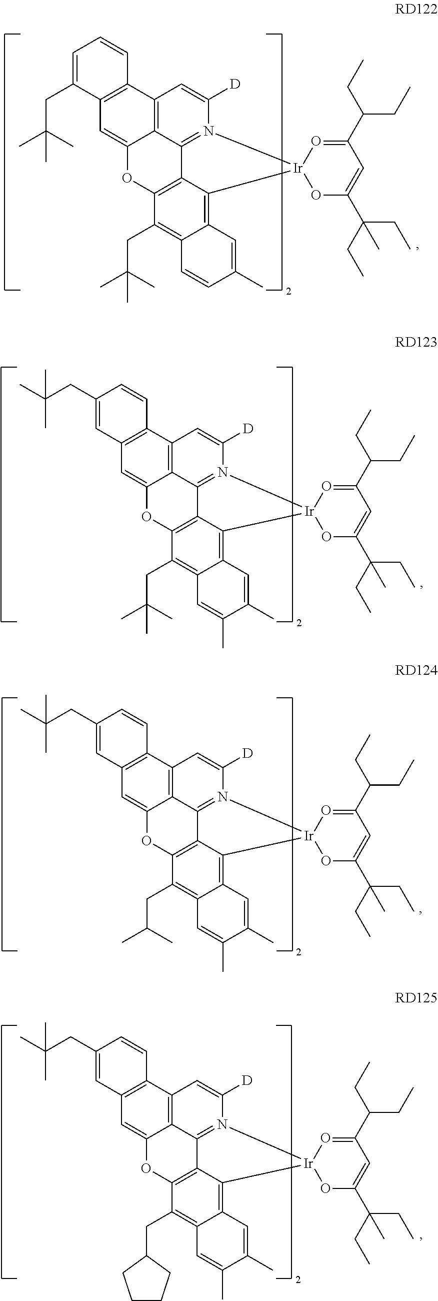 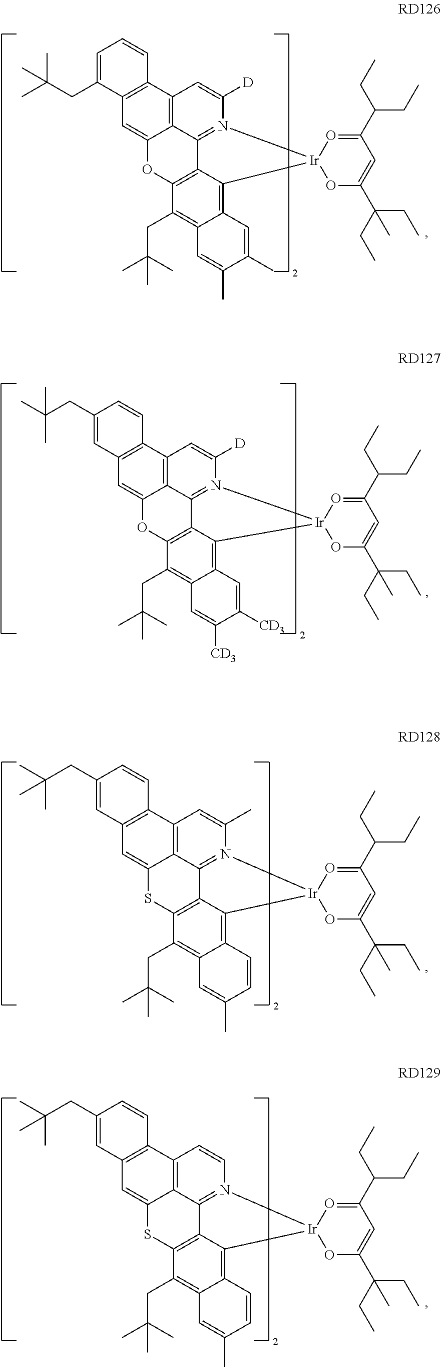 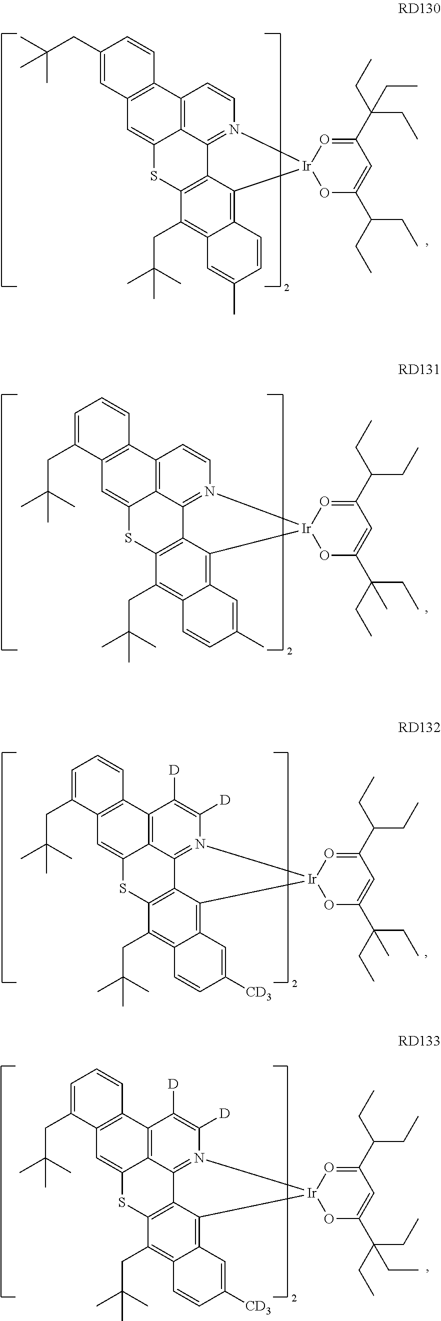 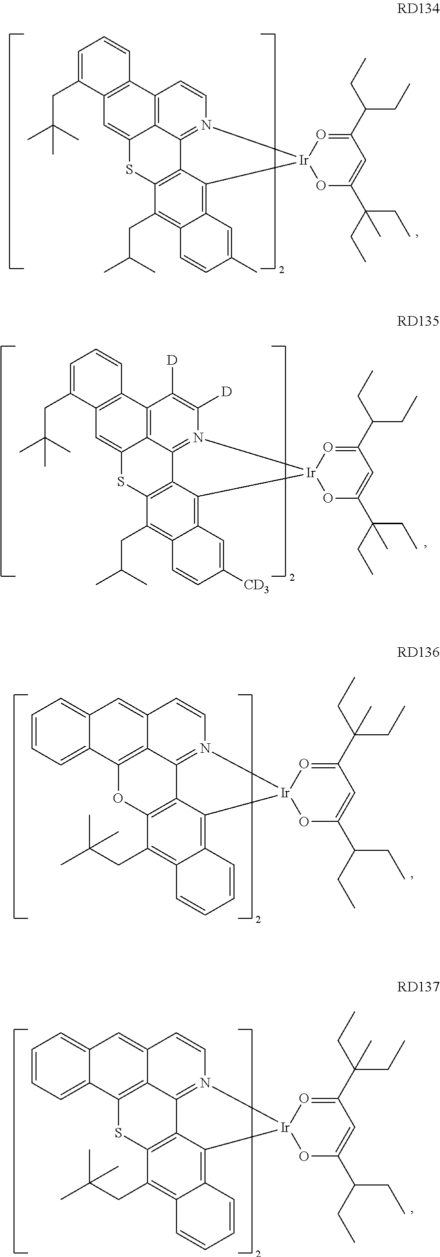 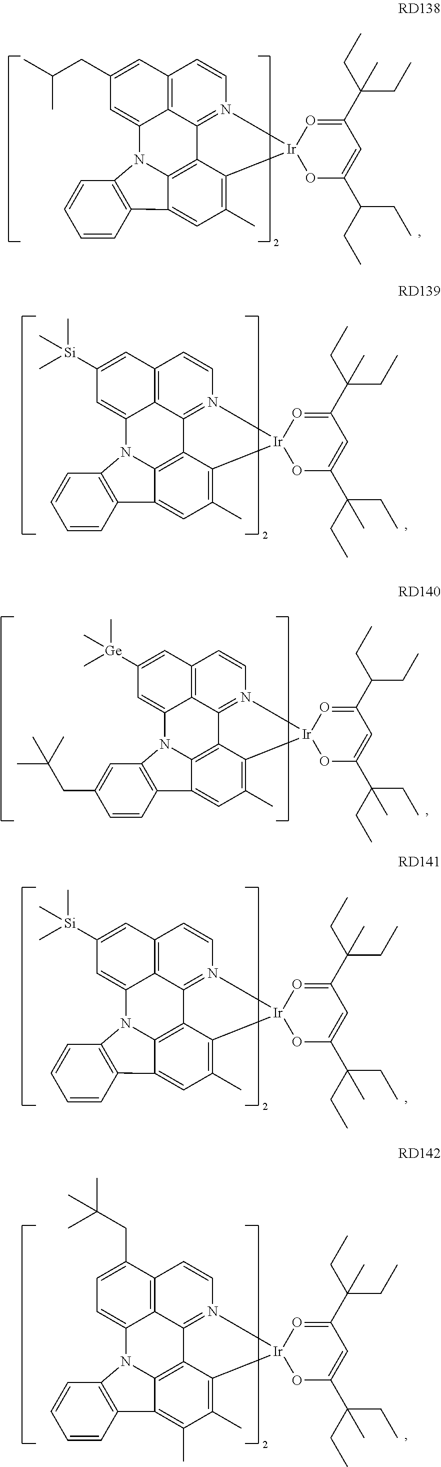 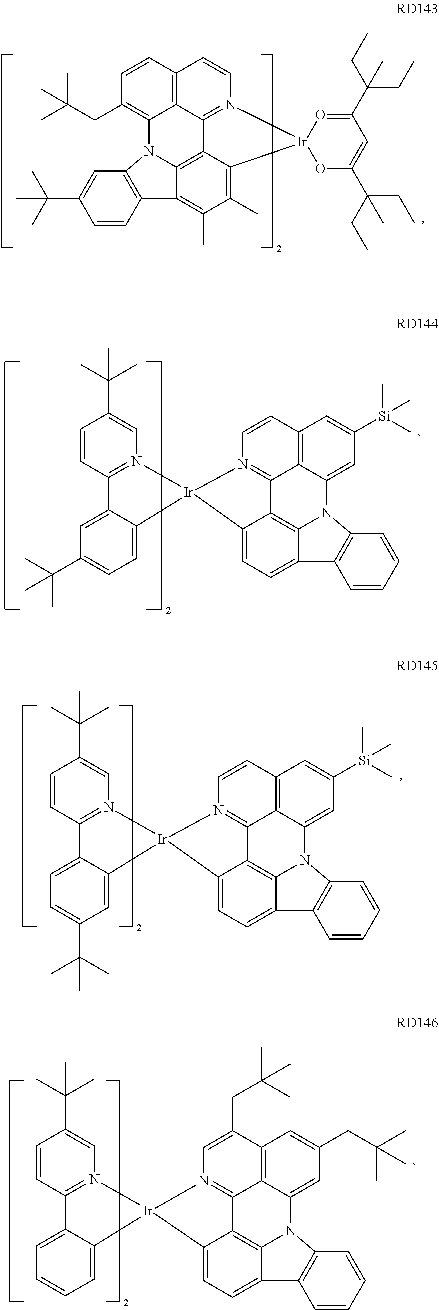 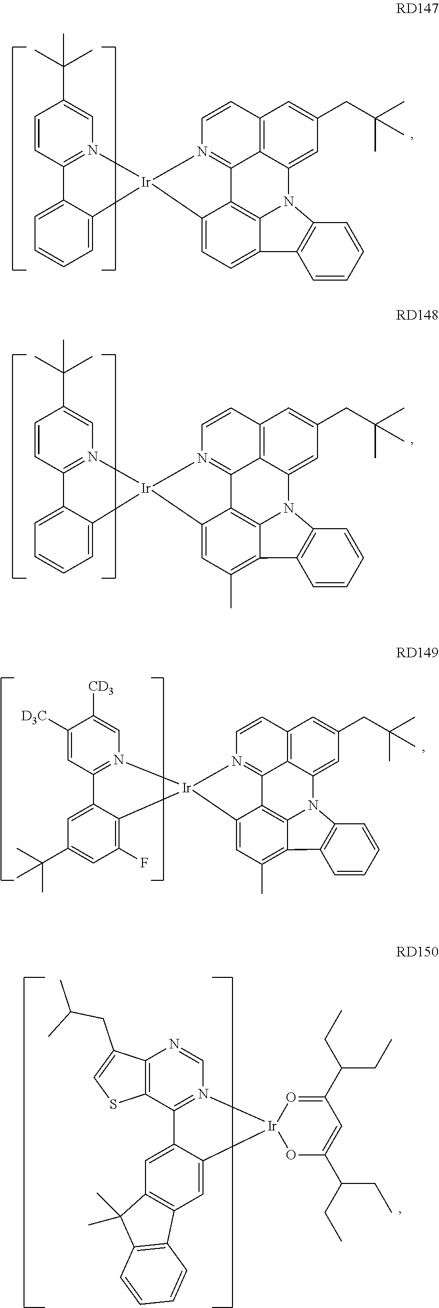 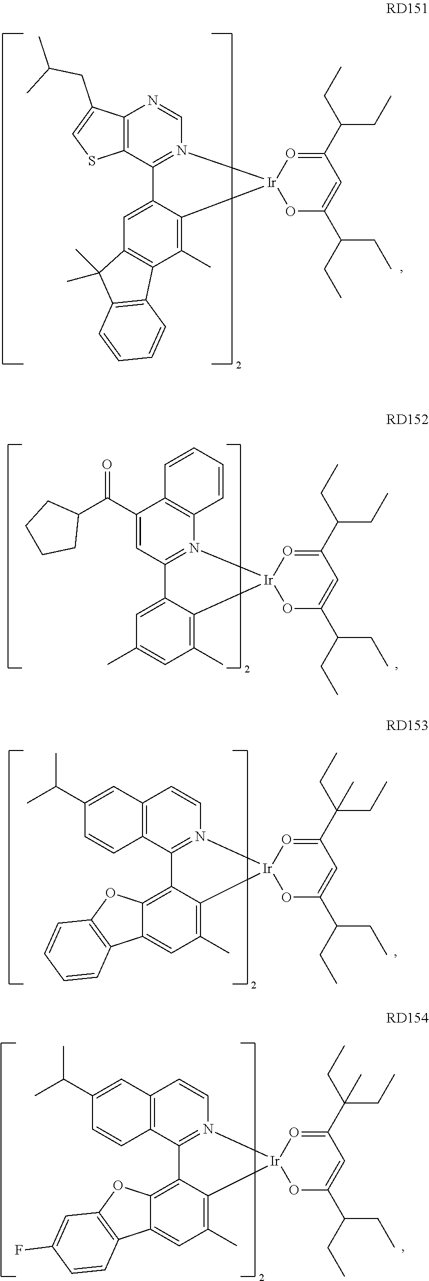 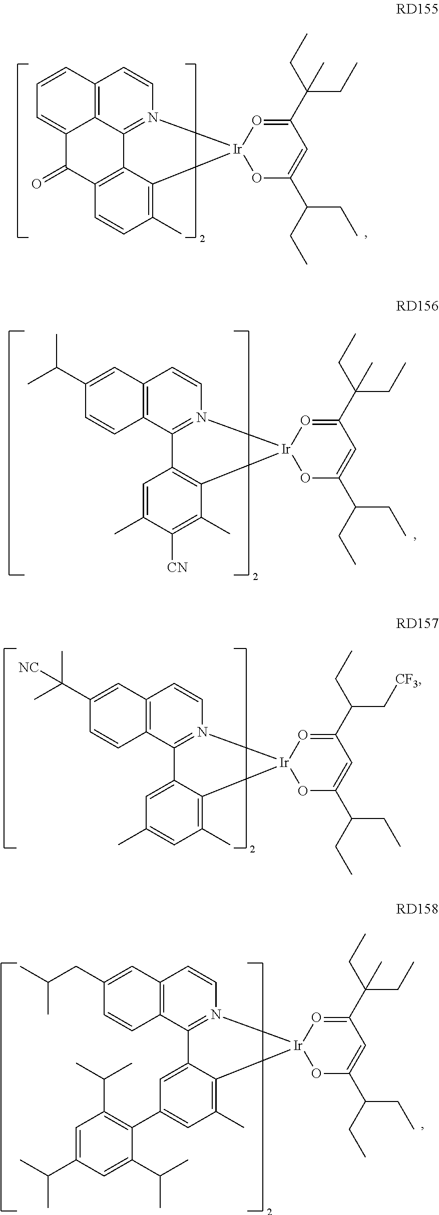 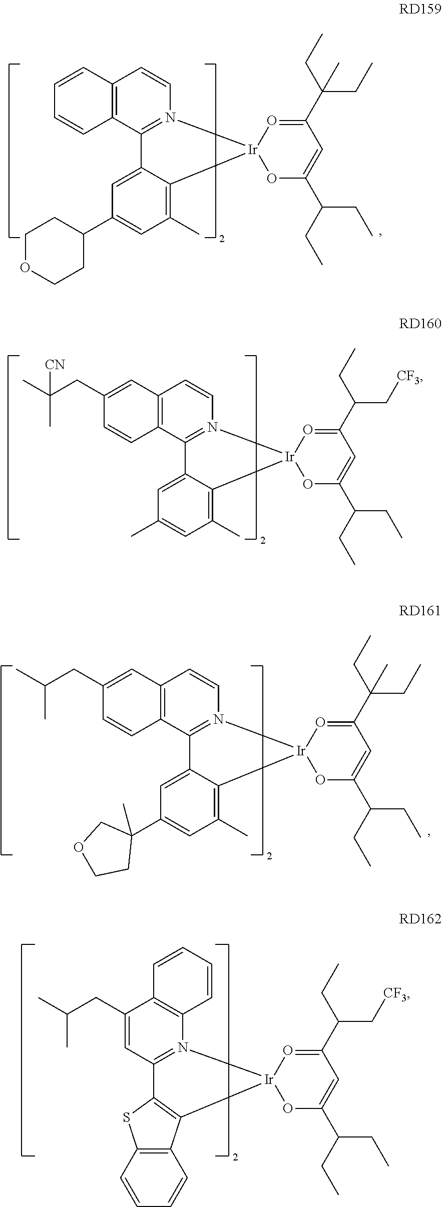 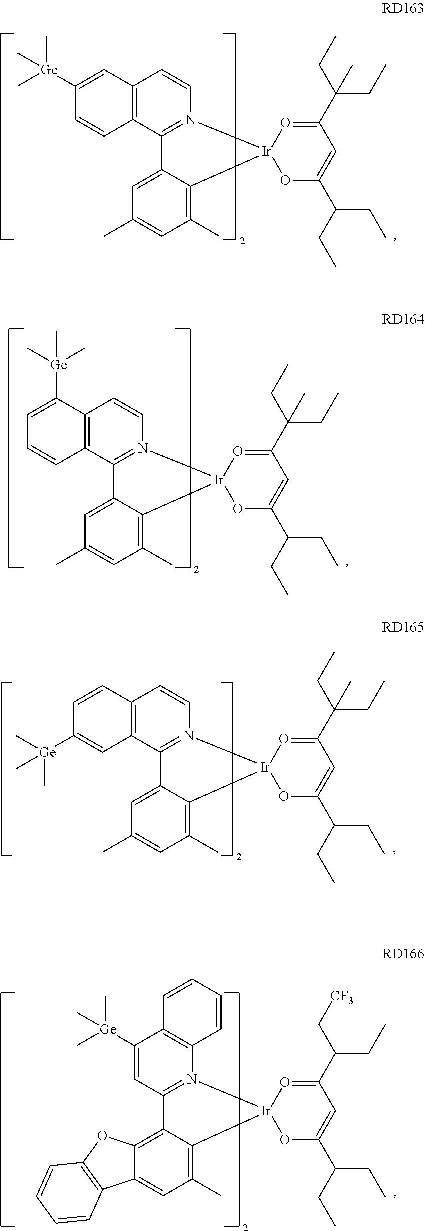 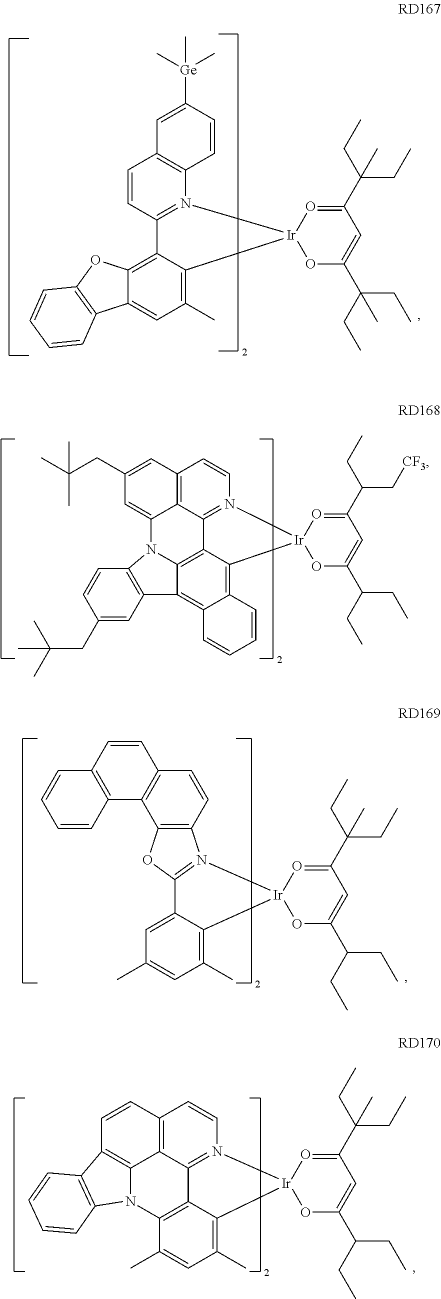 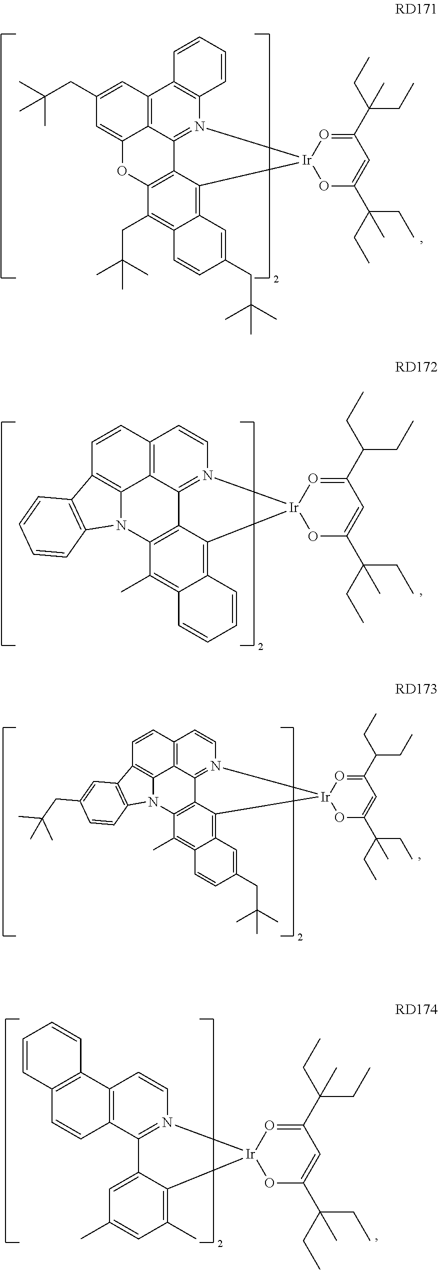 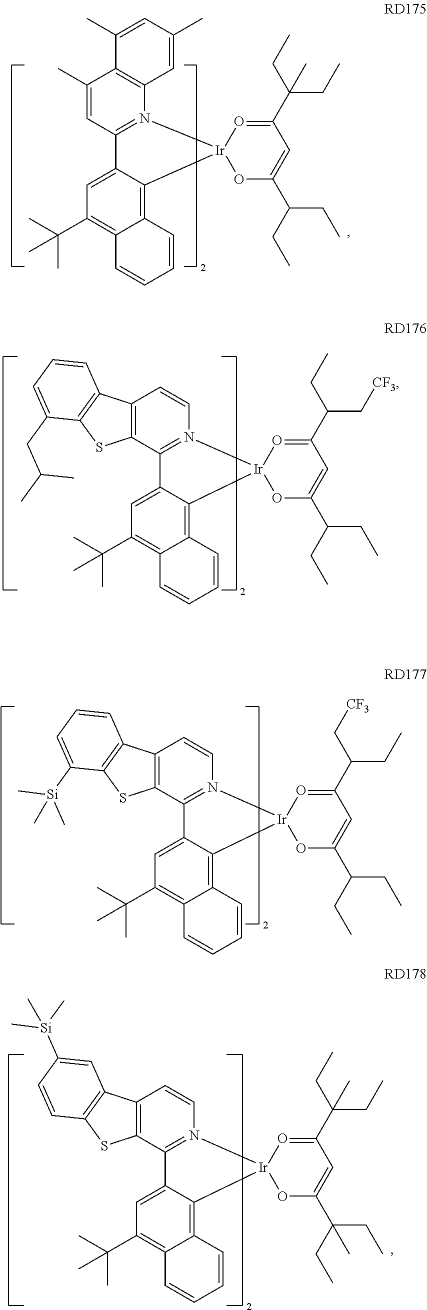 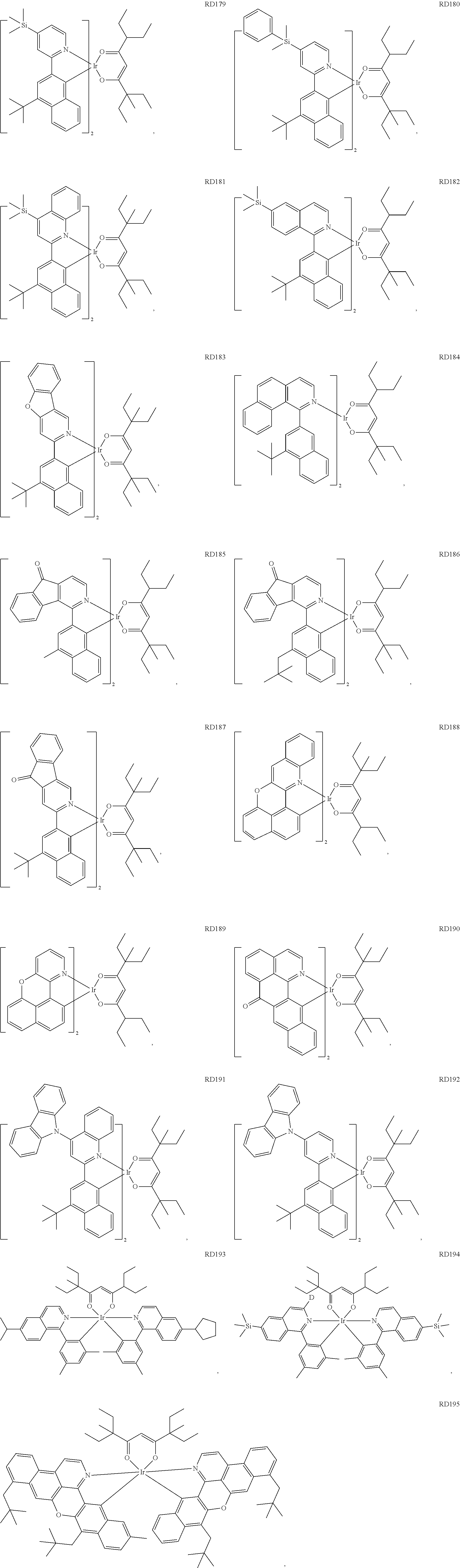 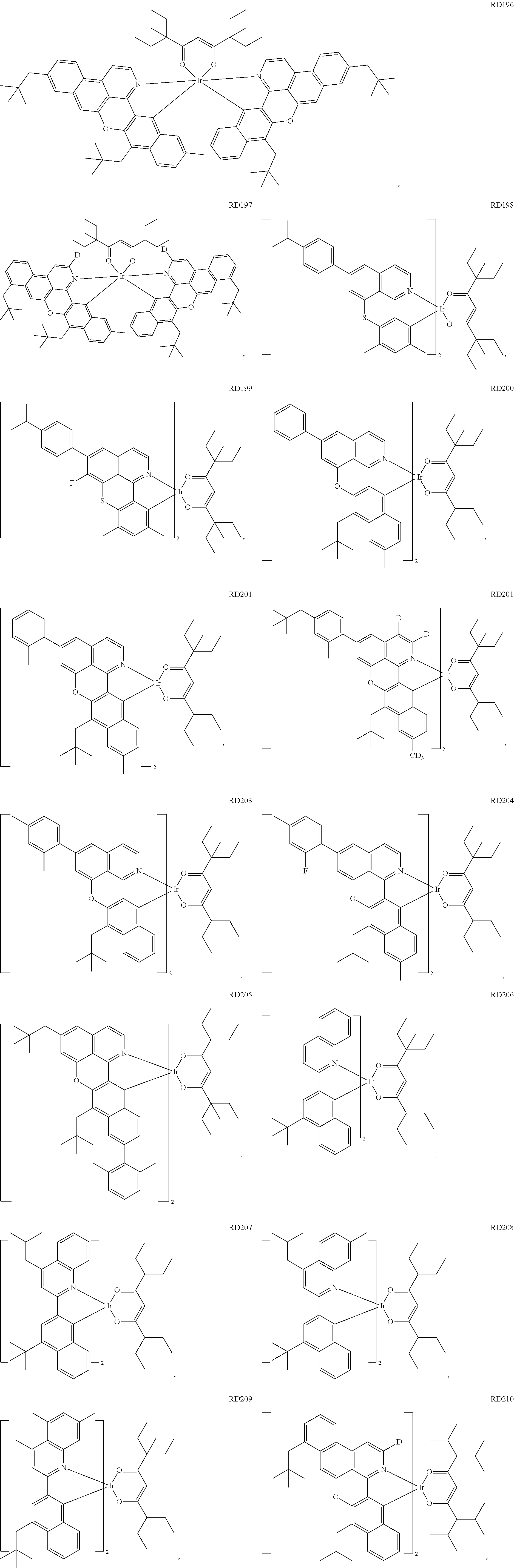 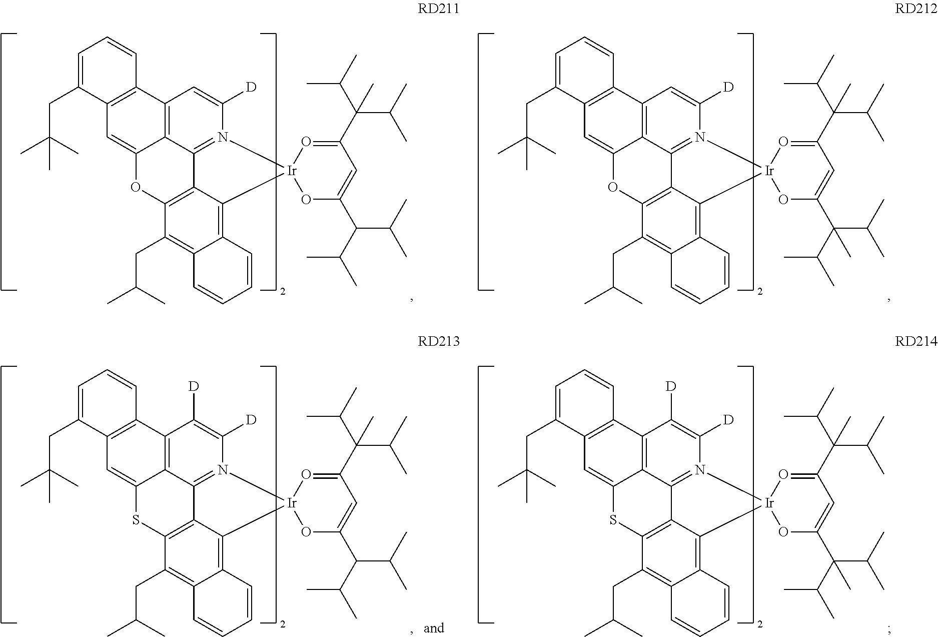 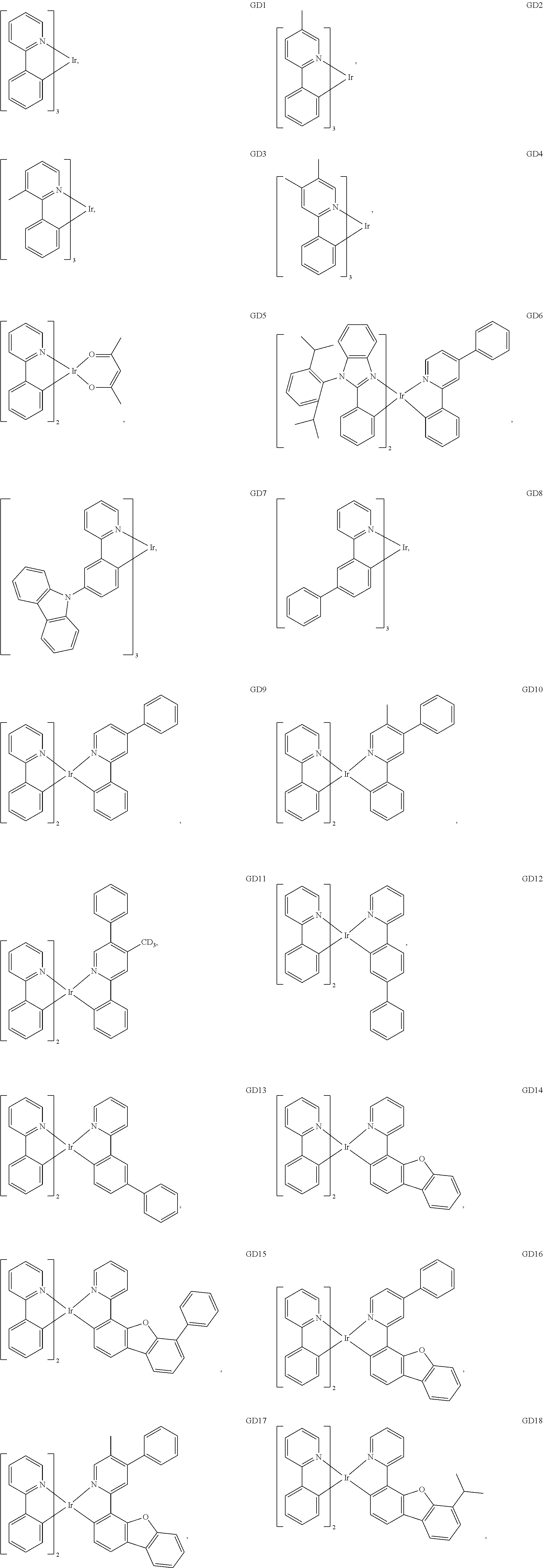 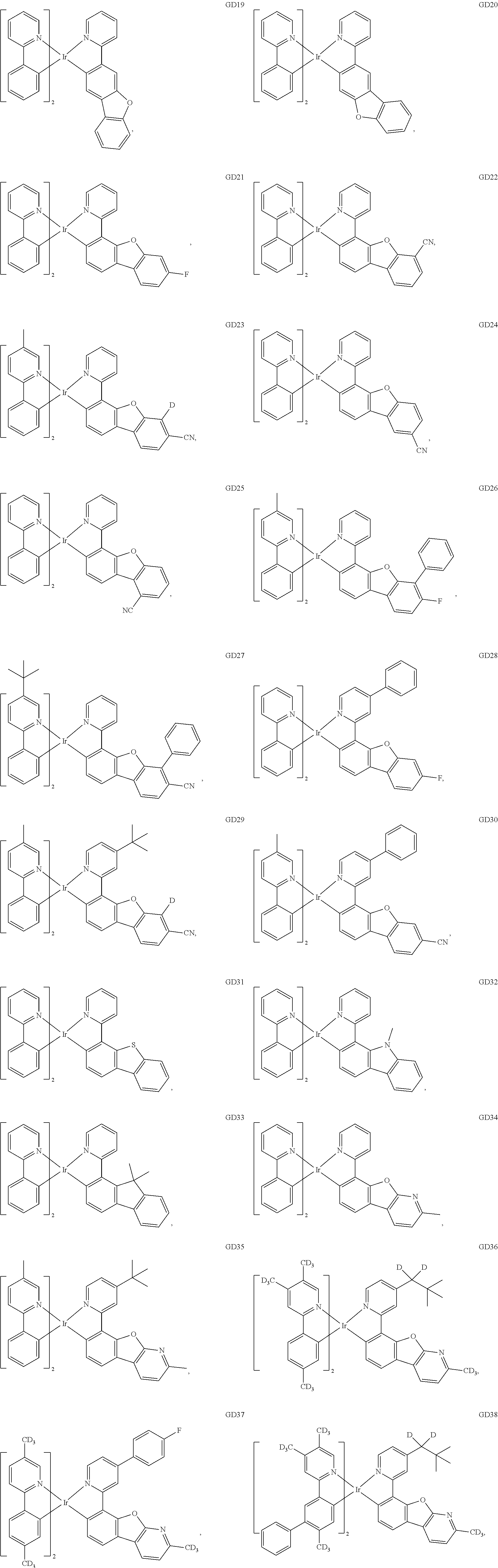 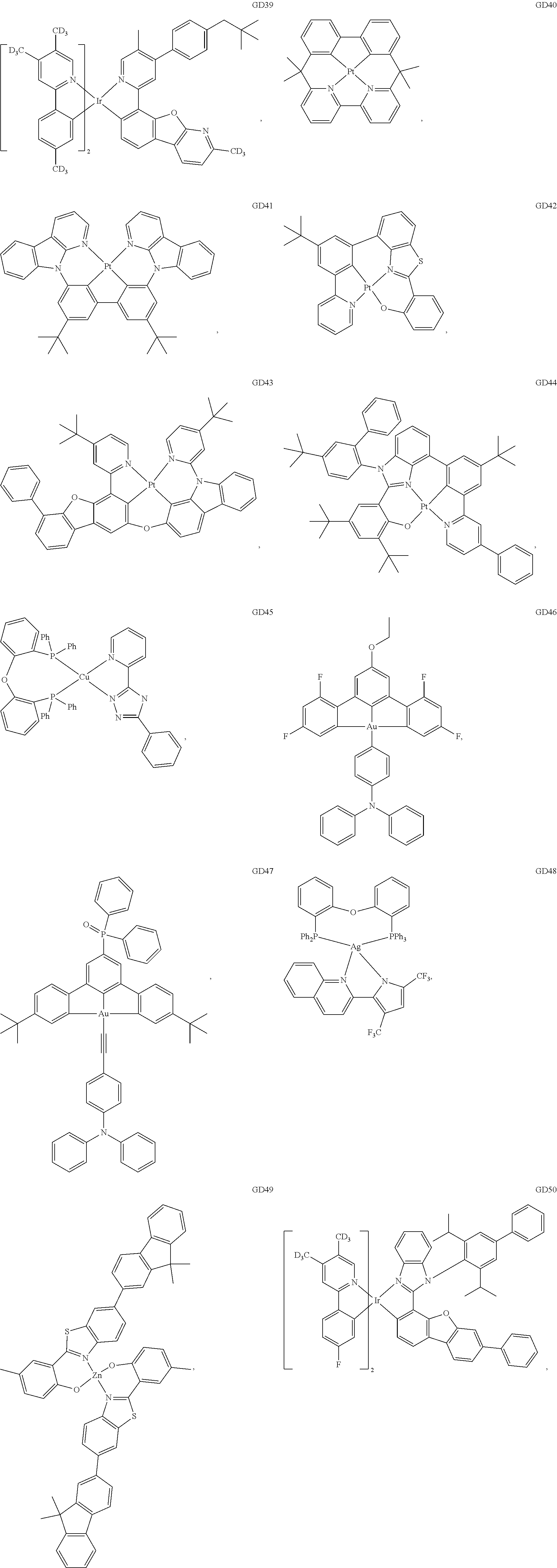 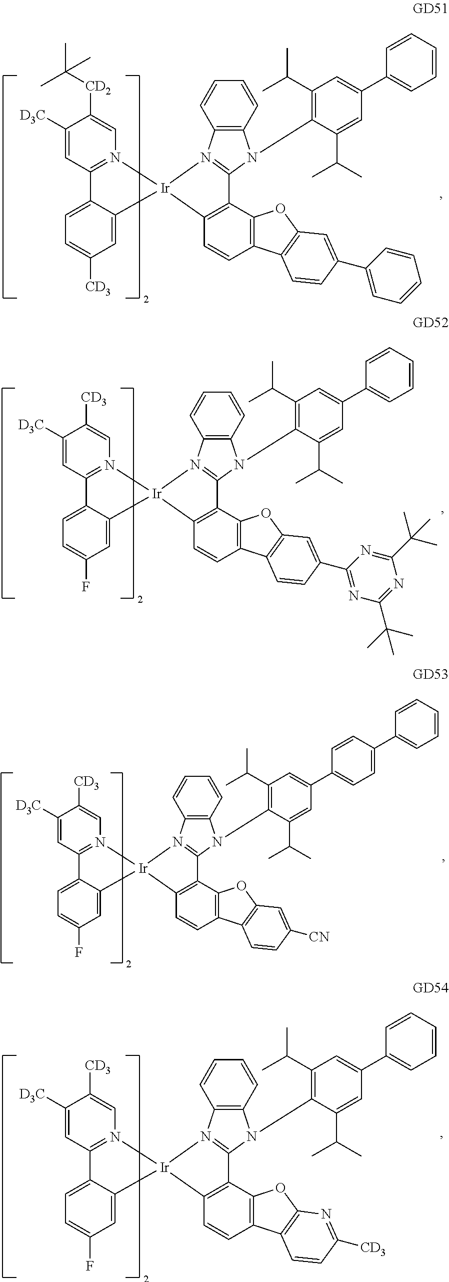 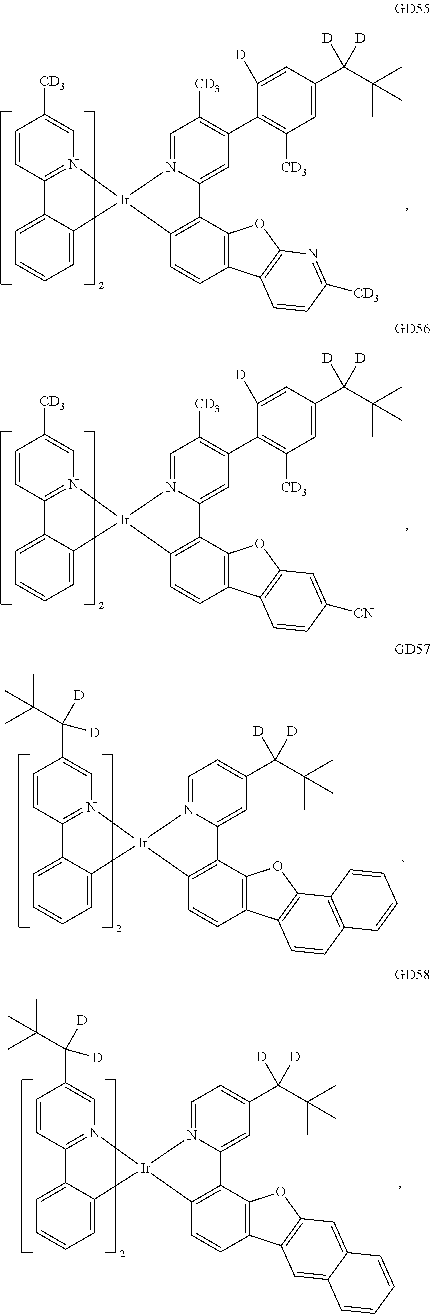 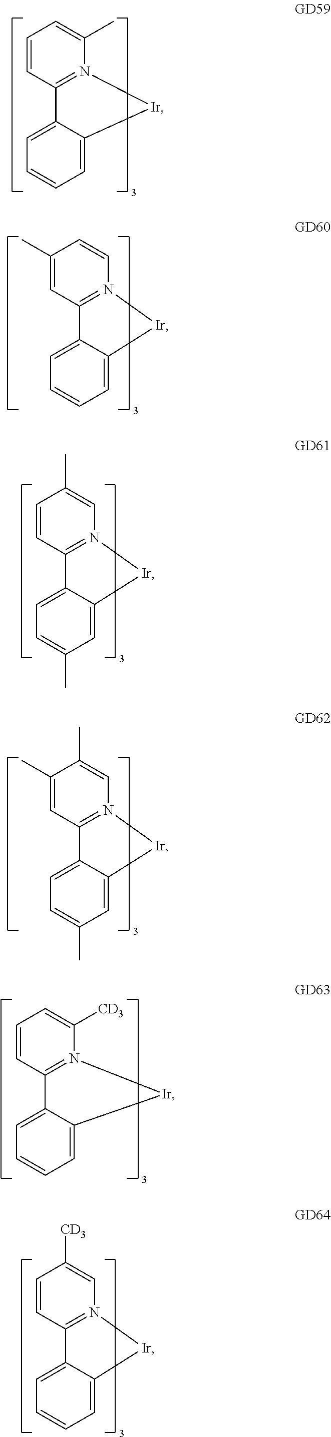 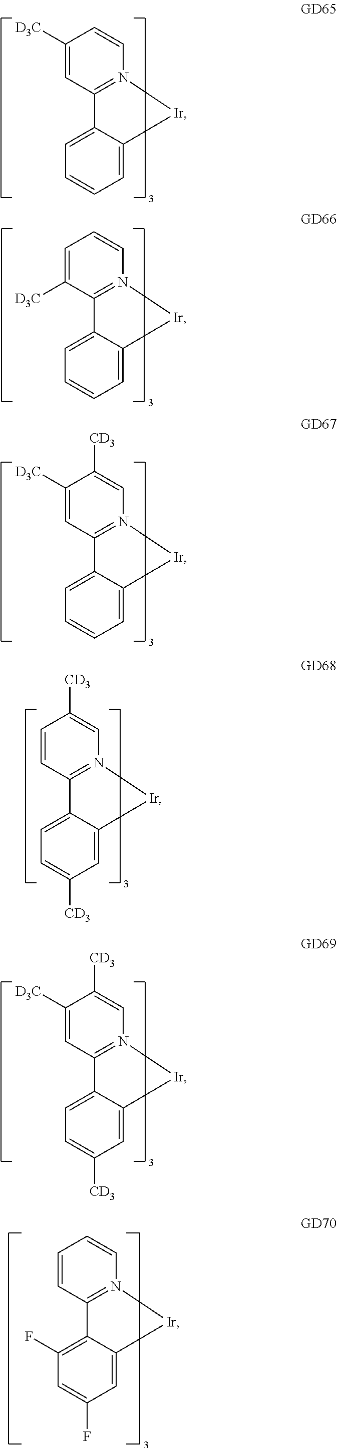 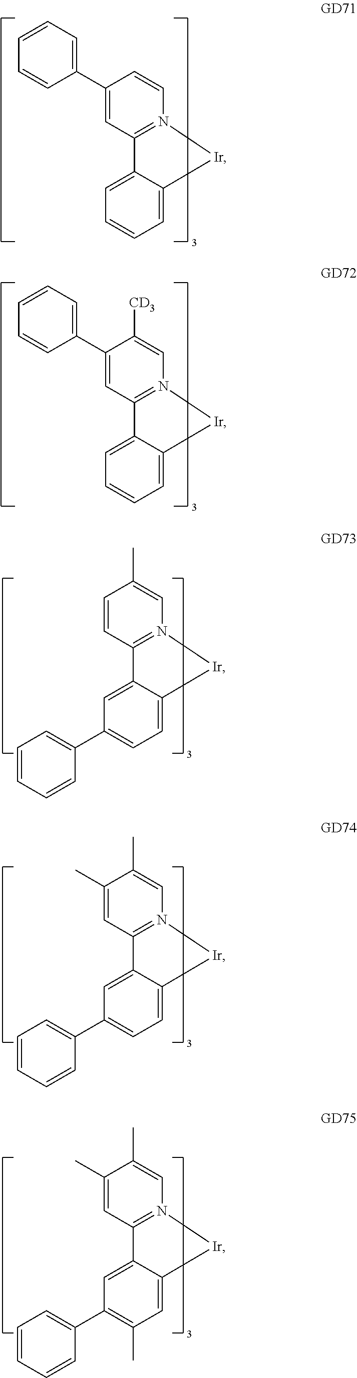 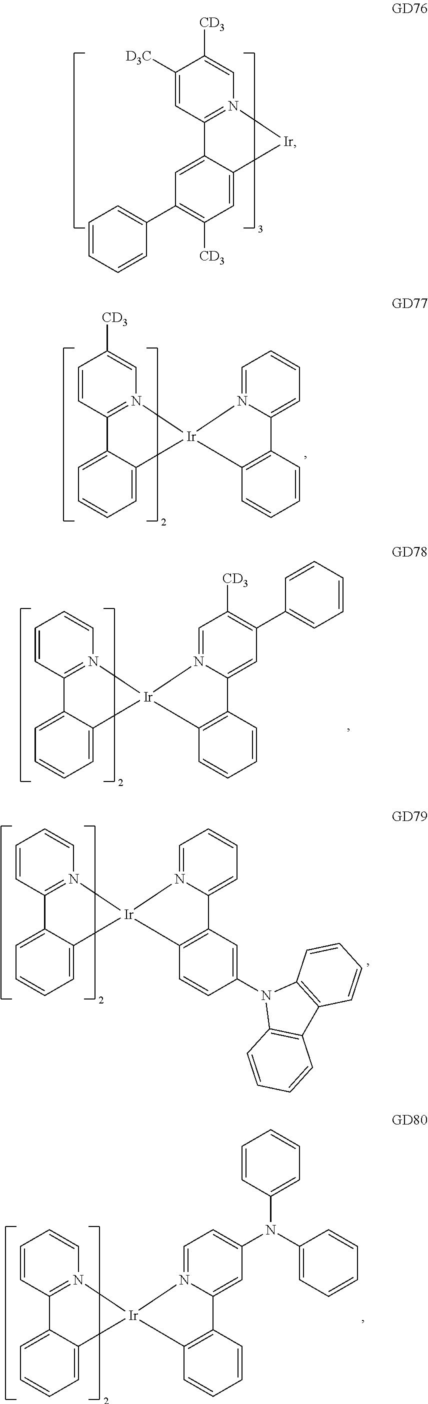 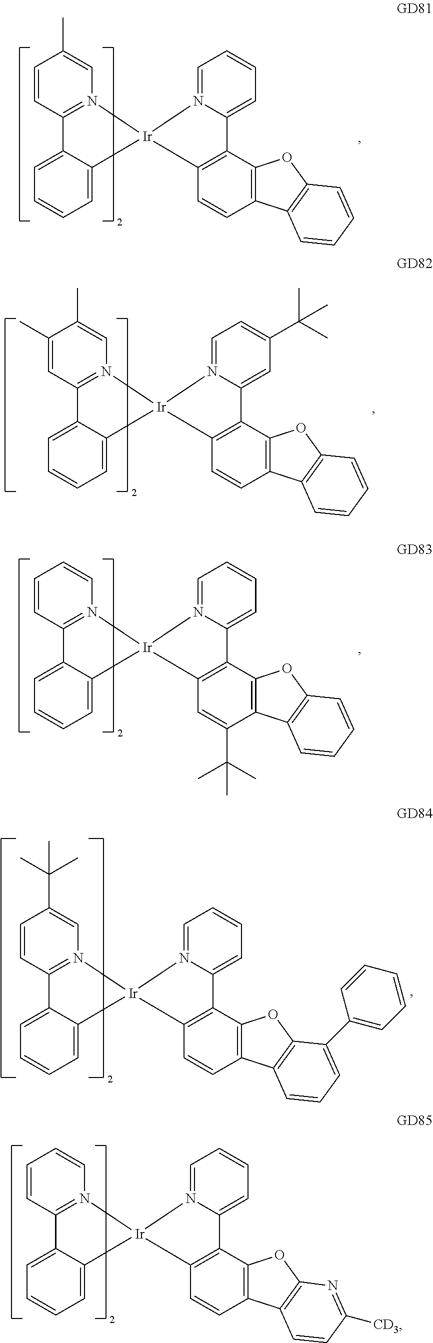 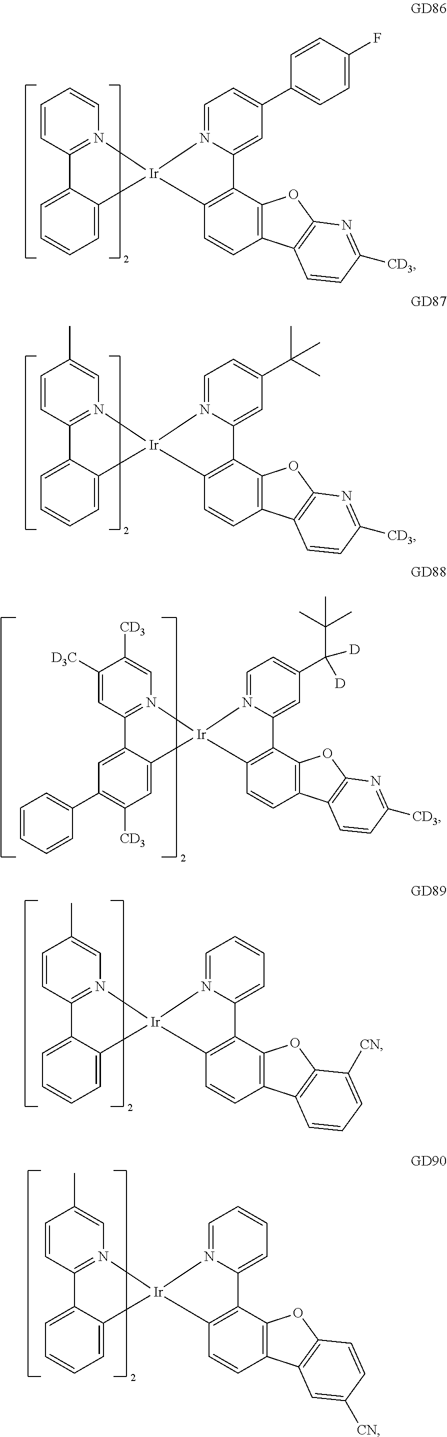 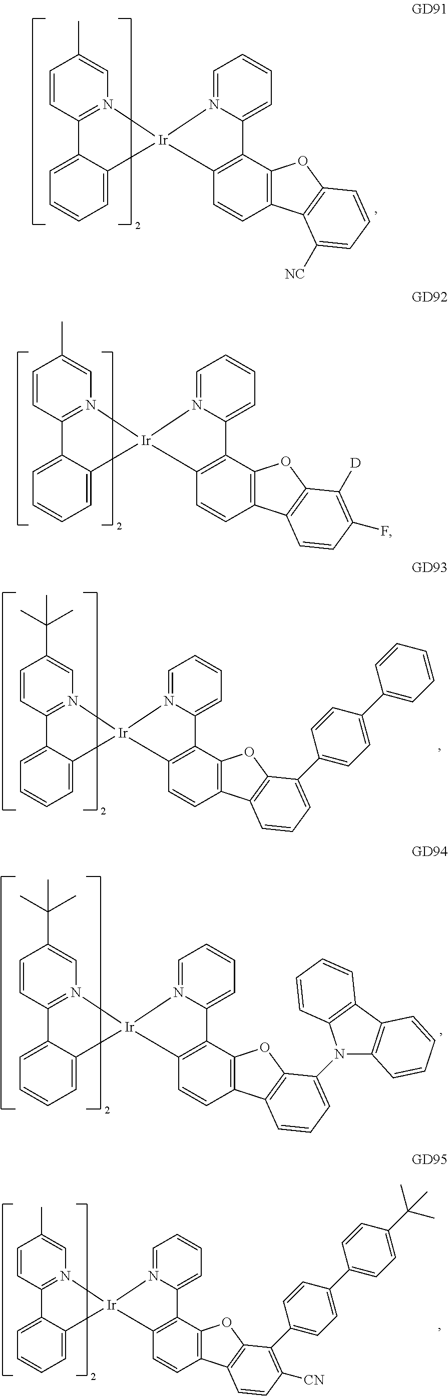 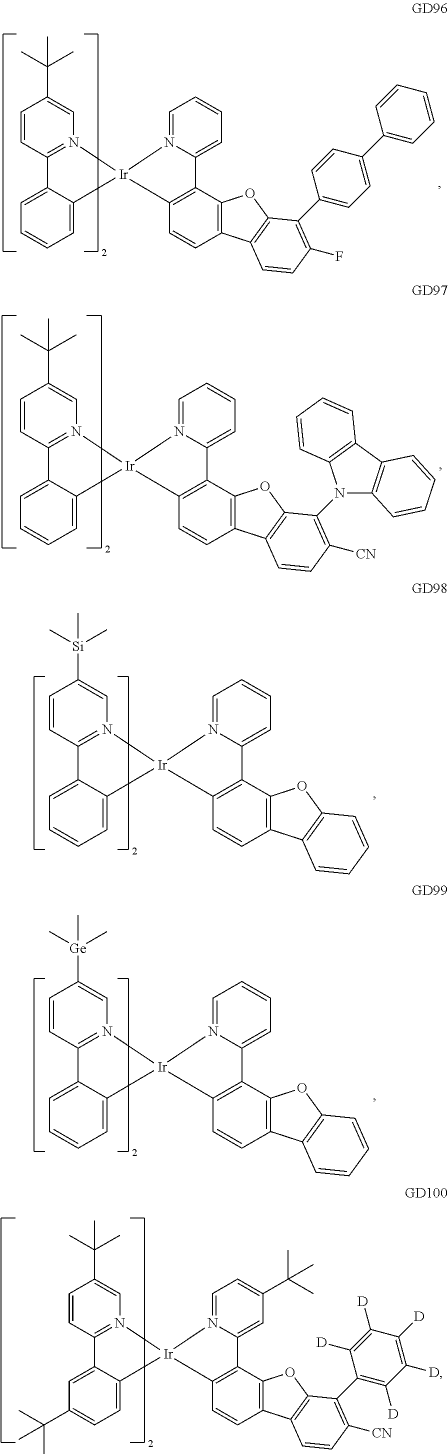 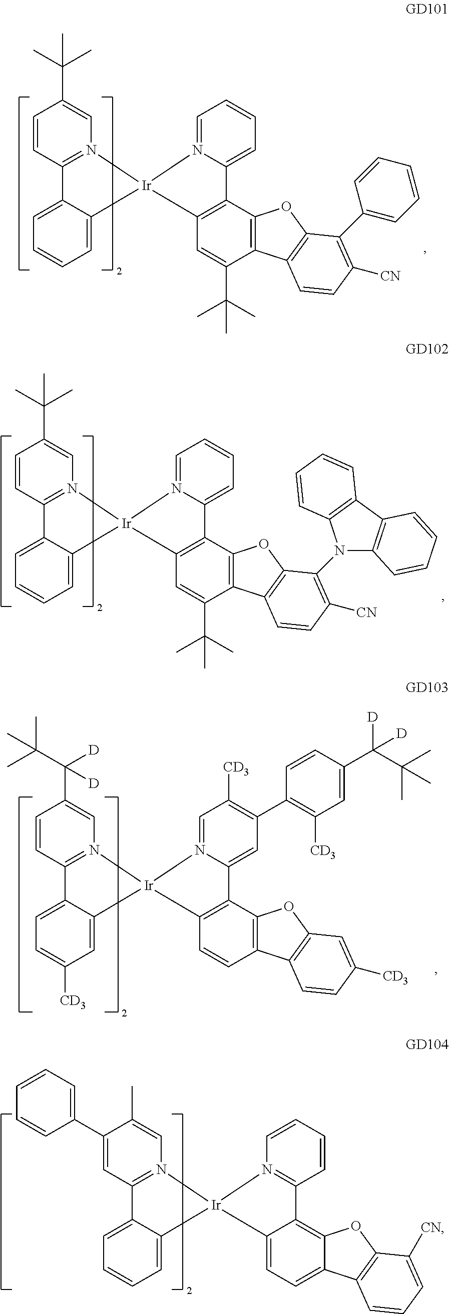 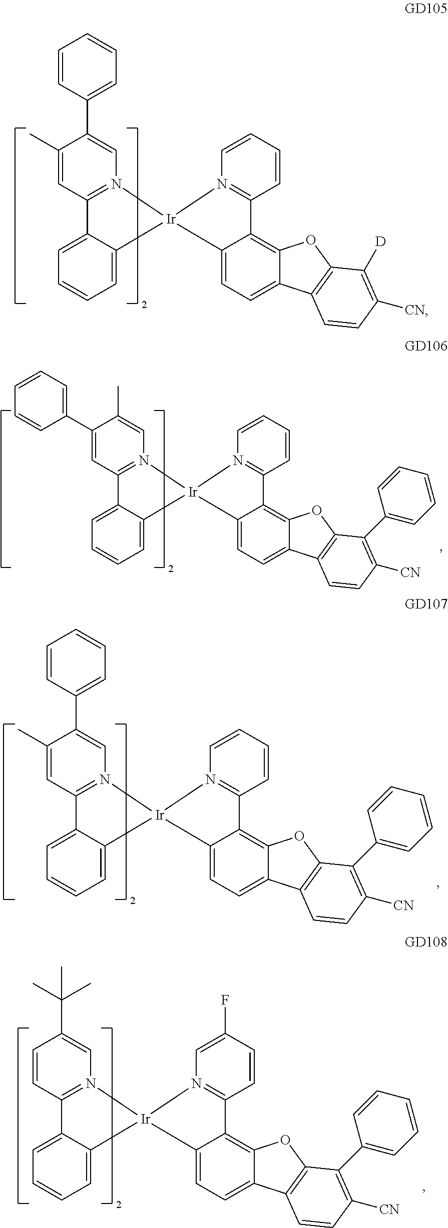 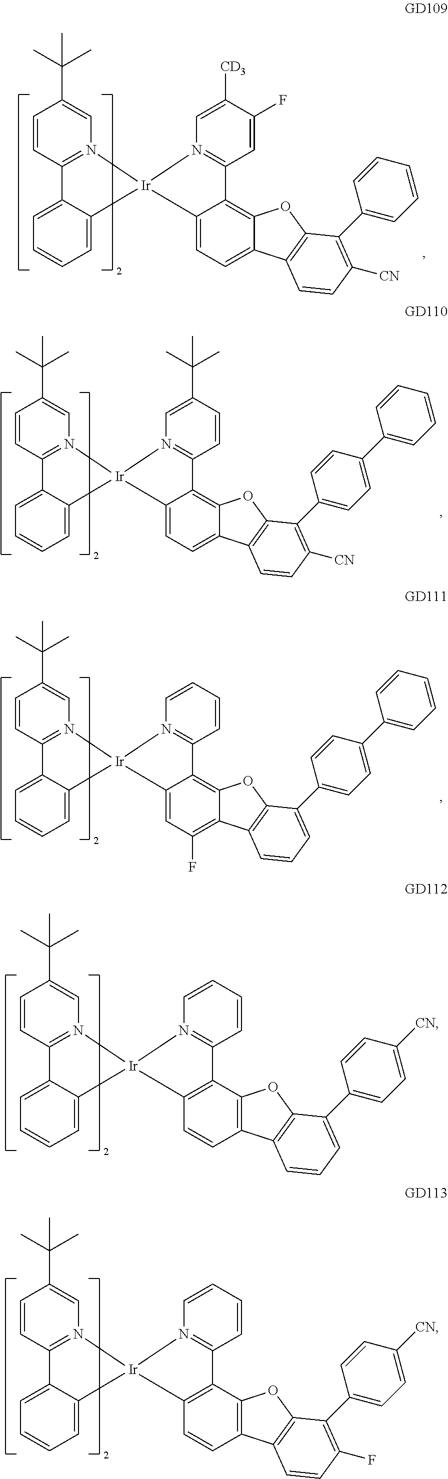 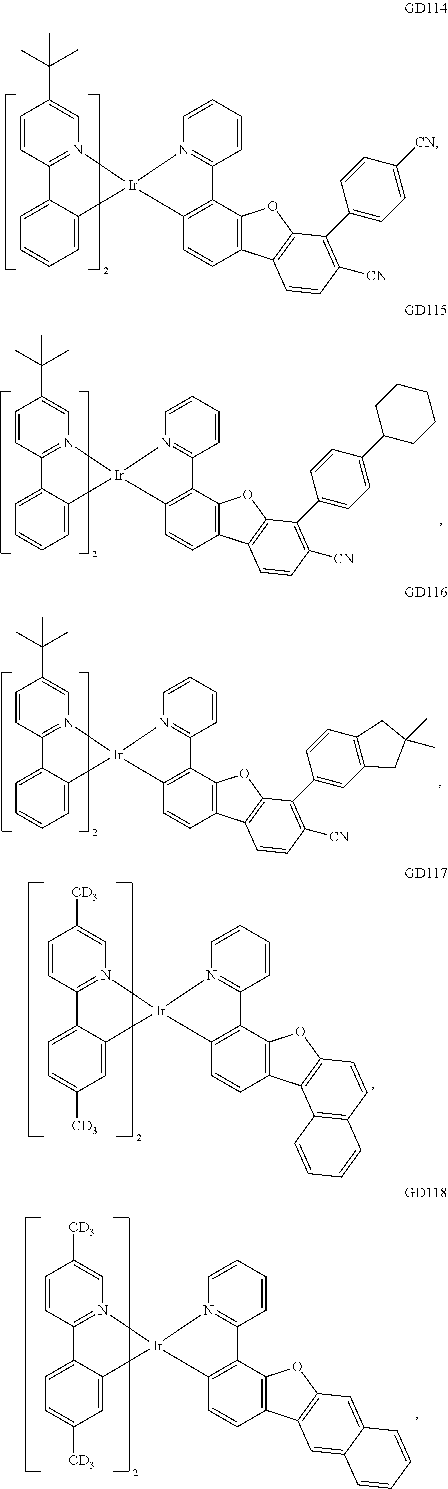 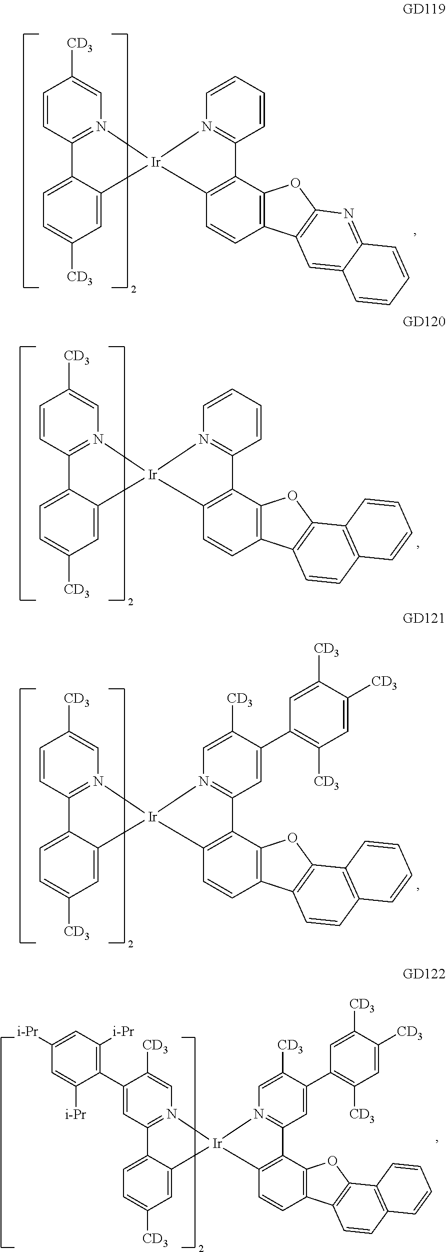 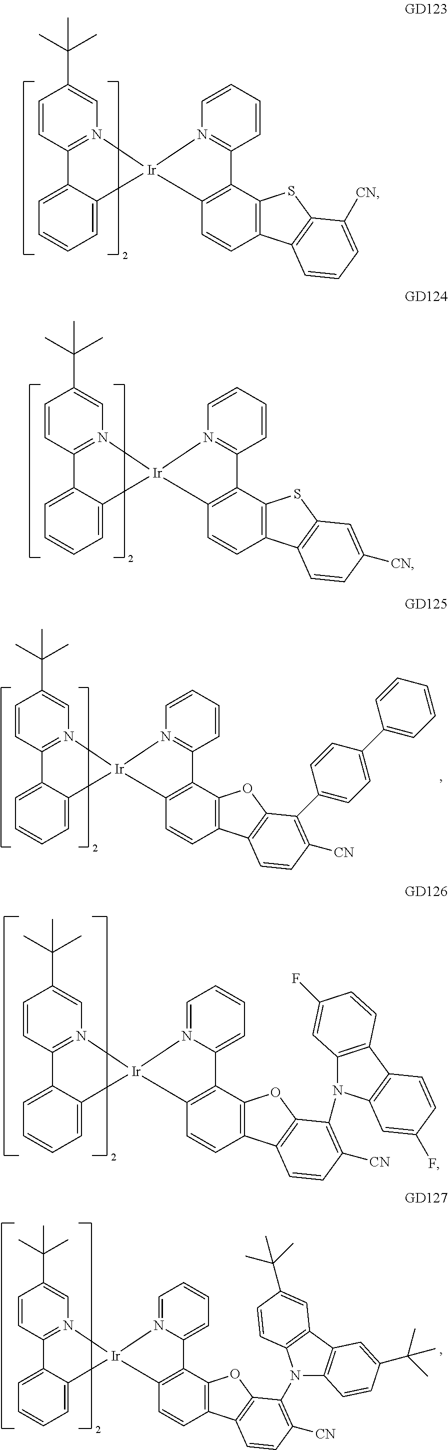 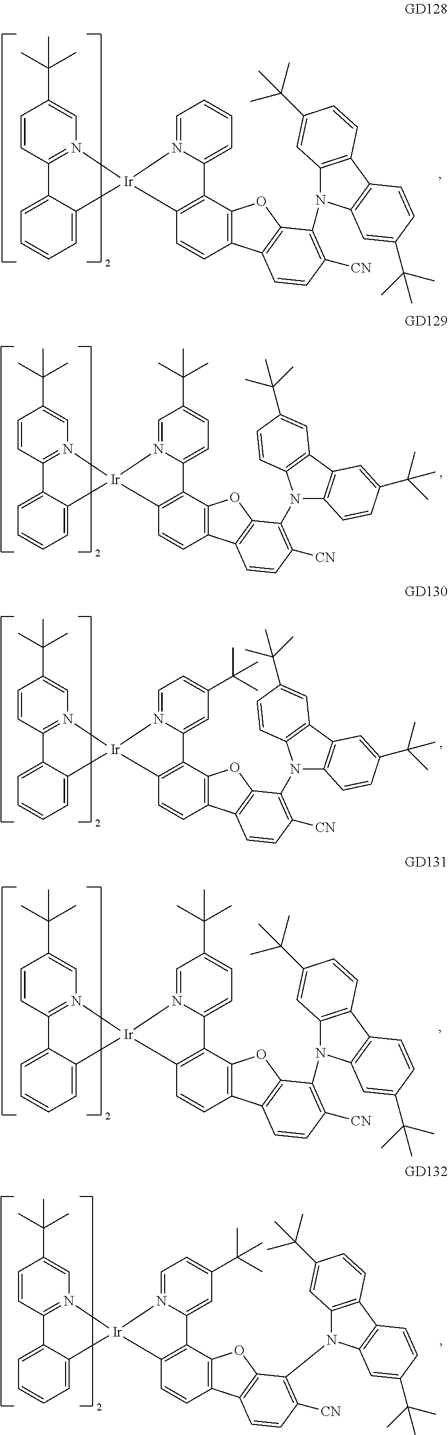 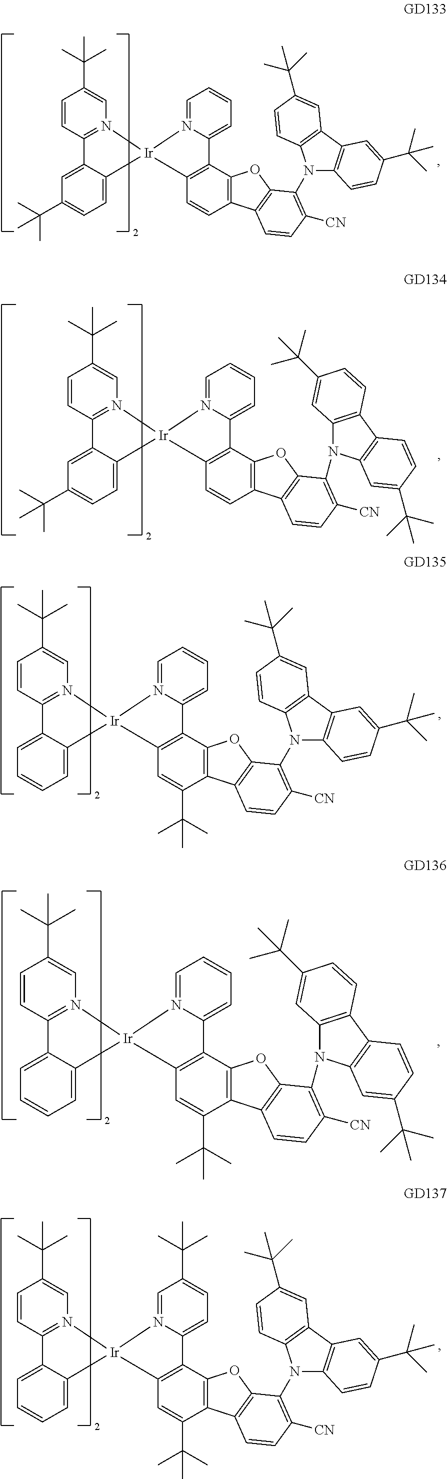 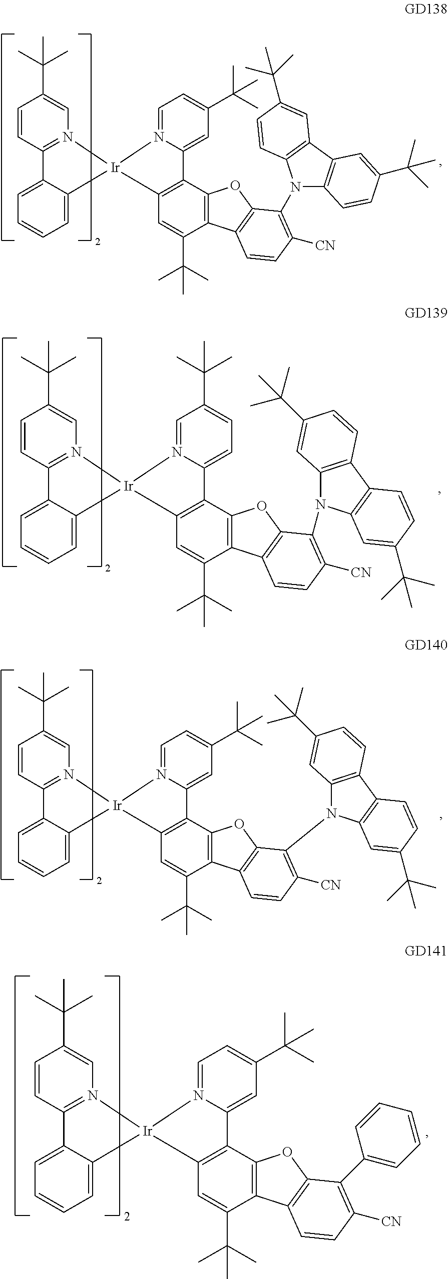 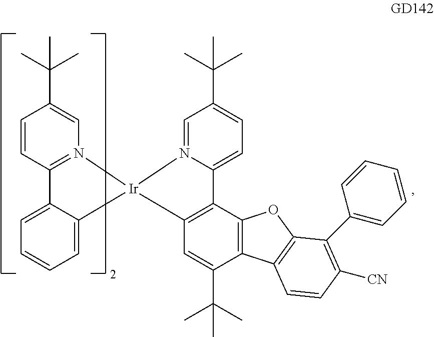 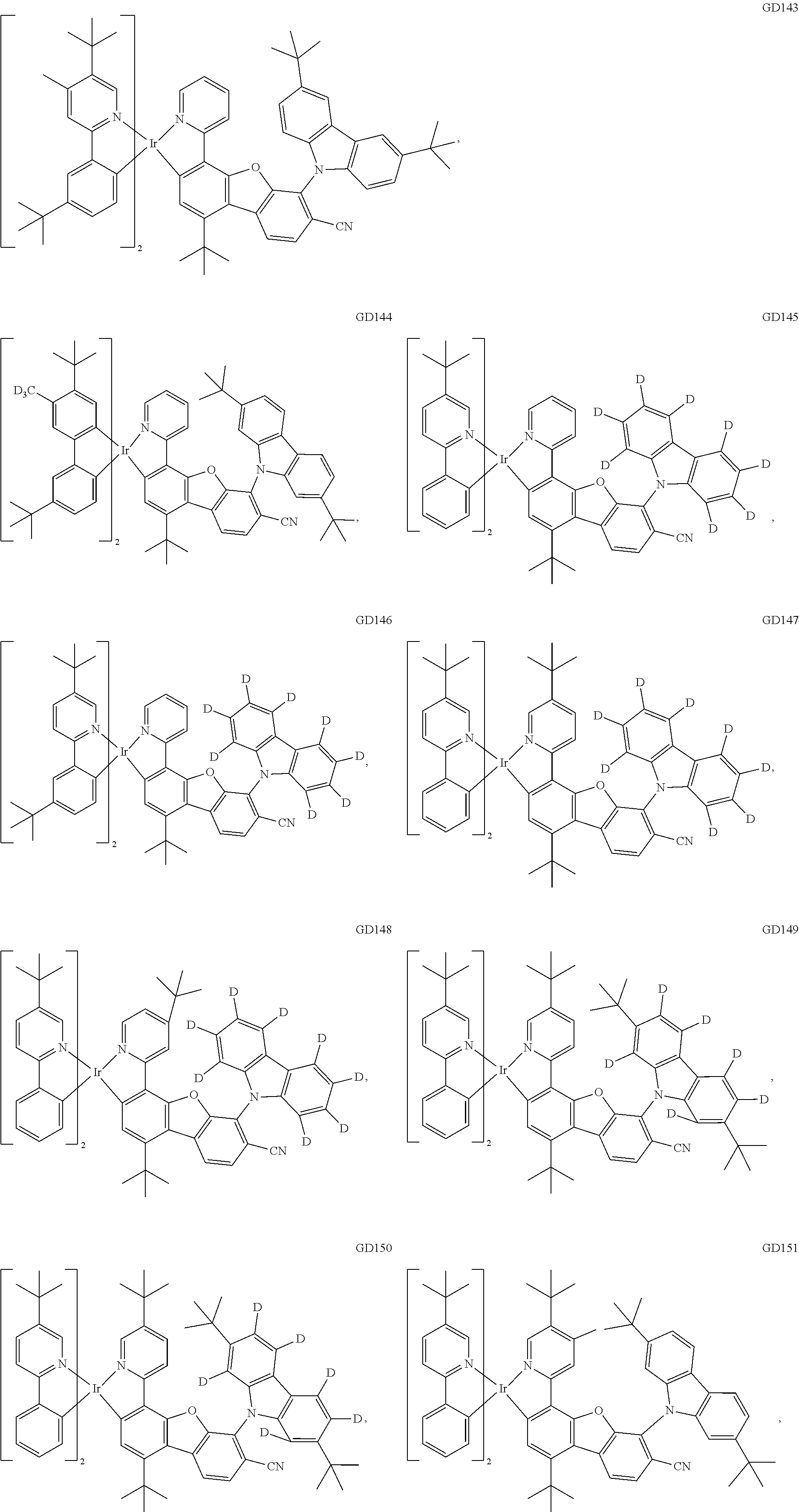 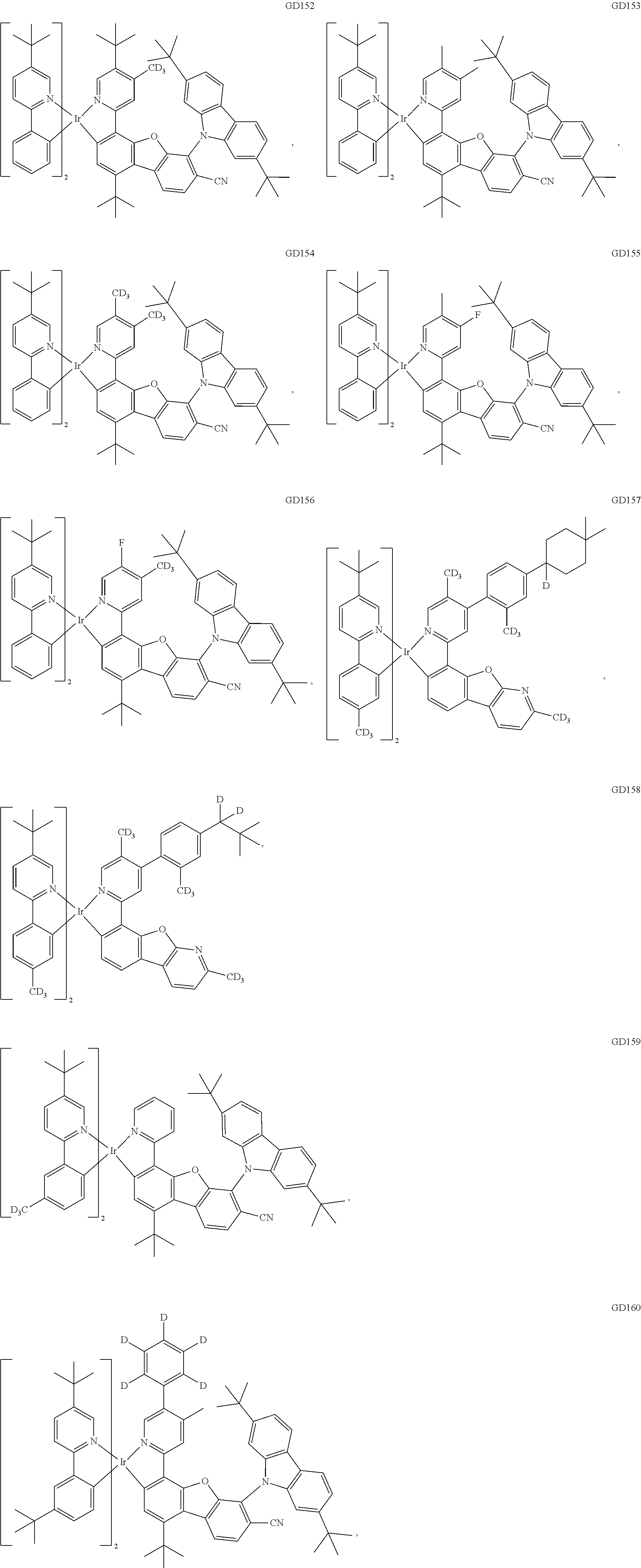 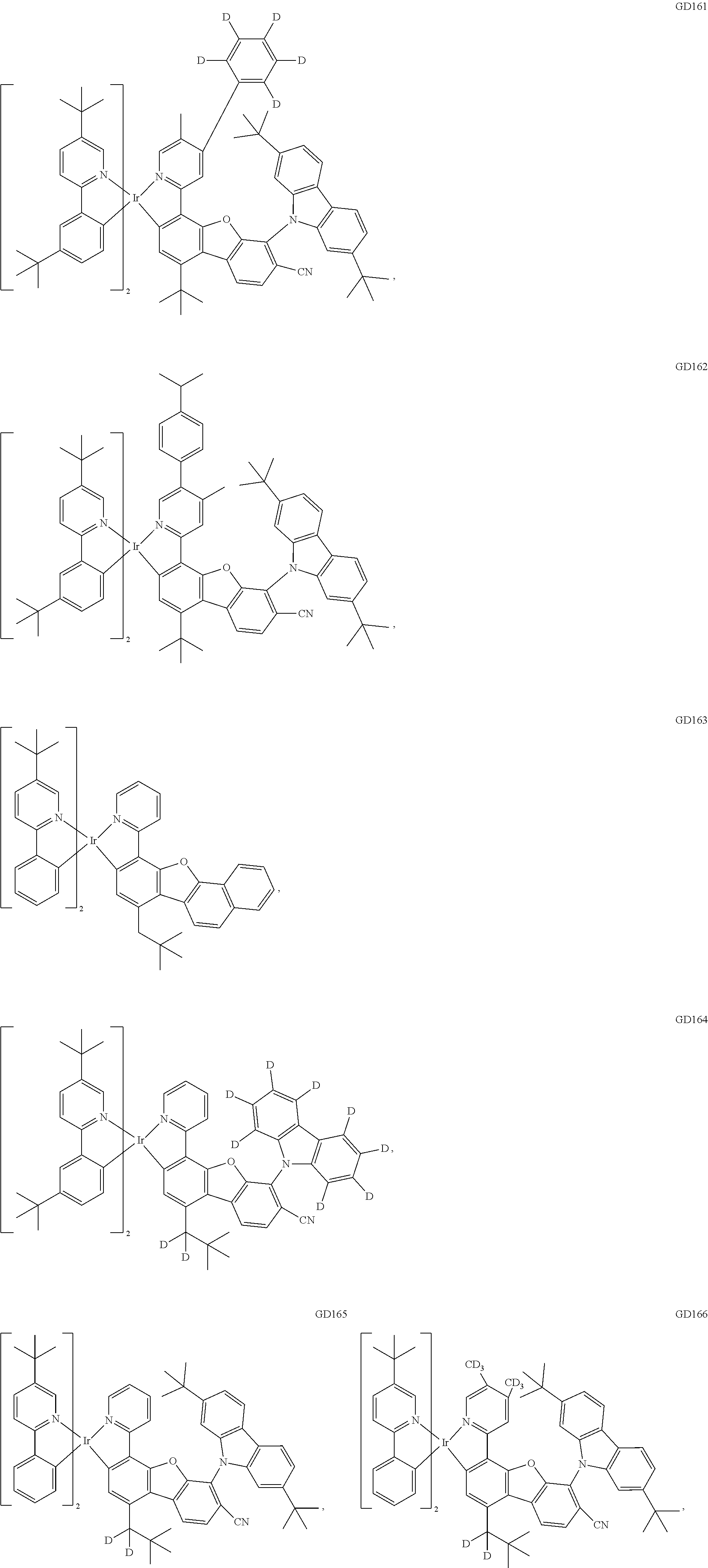 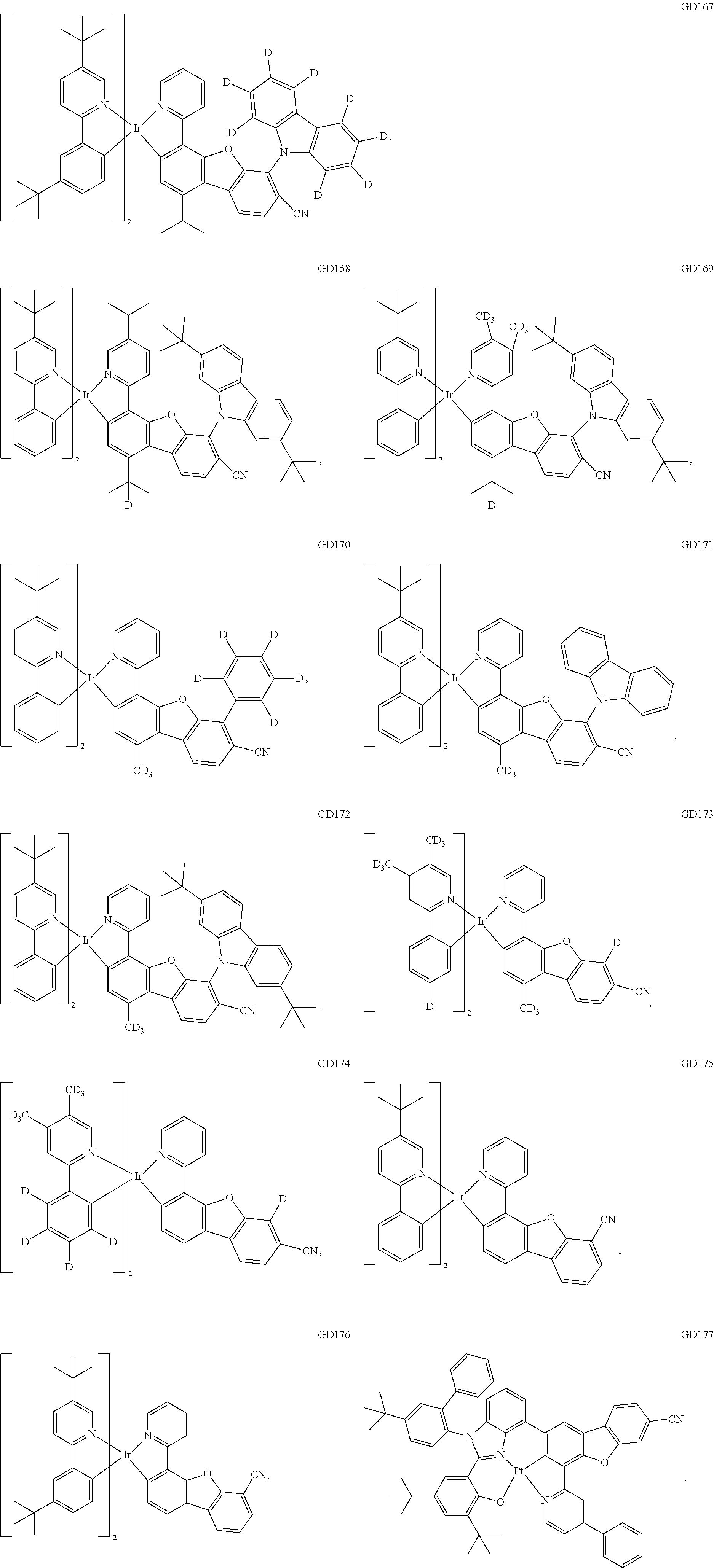 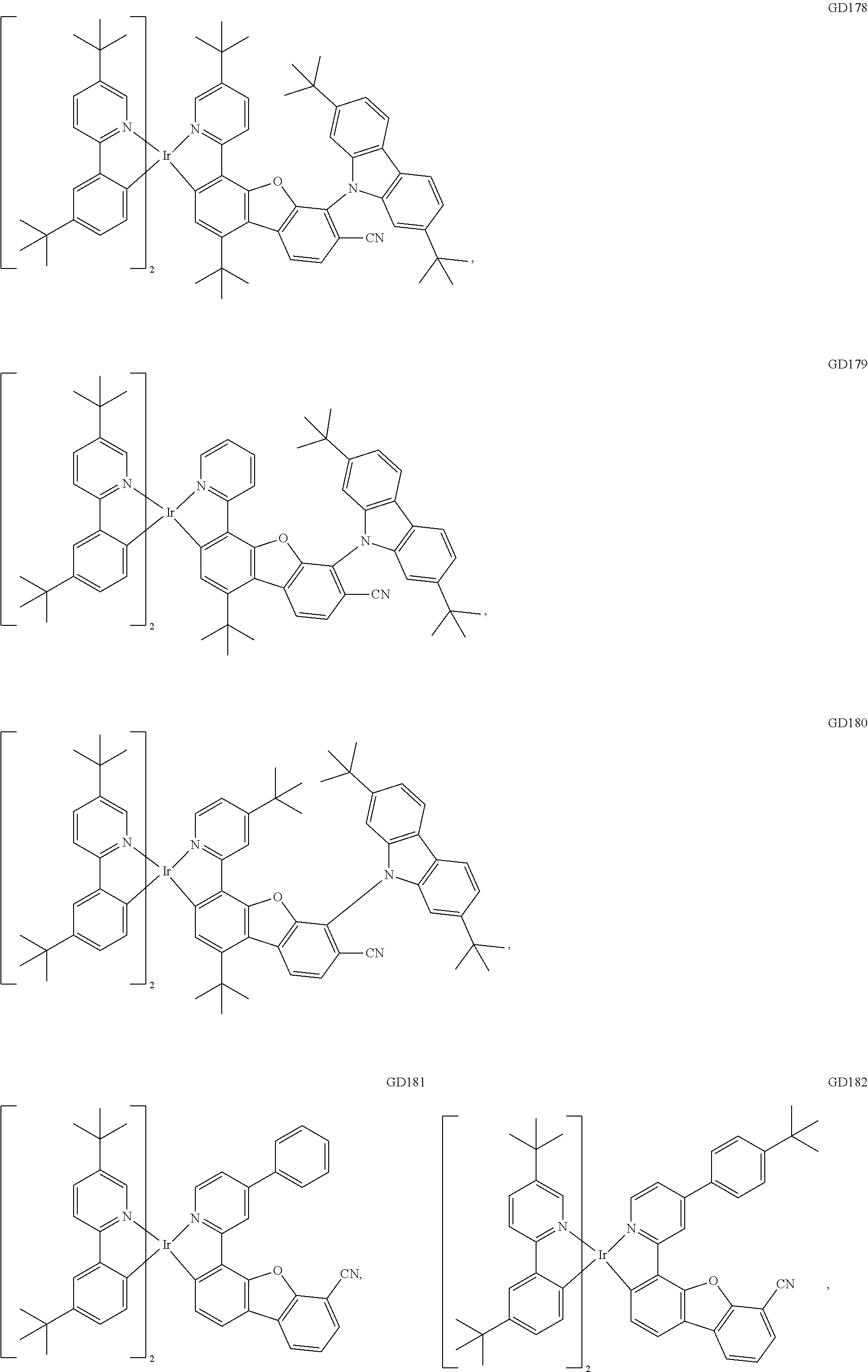 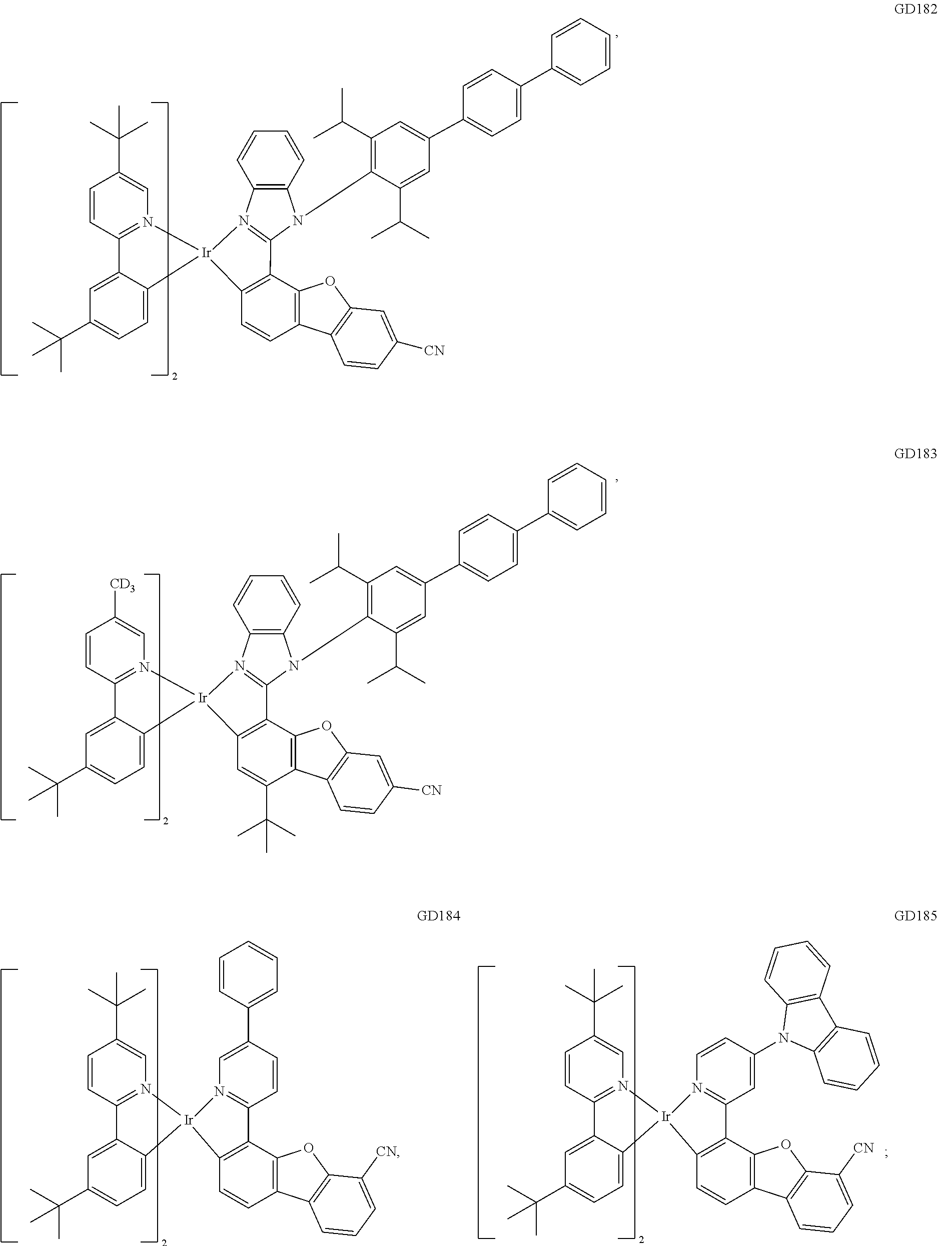
wherein optionally, hydrogens in structures of the Compound RD1 to Compound RD214 and Compound GD1 to Compound GD185 can be partially or fully substituted with deuterium.

16. A compound composition, comprising the compound of claim 1.
